(19) United States
(12) Patent Application Publication
(10) Pub. No.: US 2023/0263057 A1
(43) Pub. Date: Aug. 17, 2023

(54) LIGHT-EMITTING DEVICE INCLUDING CONDENSED CYCLIC COMPOUND, ELECTRONIC APPARATUS INCLUDING THE SAME, AND THE CONDENSED CYCLIC COMPOUND

(71) Applicant: Samsung Display Co., Ltd., Yongin-si (KR)

(72) Inventors: Kyoung Sunwoo, Yongin-si (KR); Seran Kim, Yongin-si (KR); Sunyoung Pak, Yongin-si (KR); Jangyeol Baek, Yongin-si (KR); Munki Sim, Yongin-si (KR); Chanseok Oh, Yongin-si (KR); Moran Ha, Yongin-si (KR)

(73) Assignee: Samsung Display Co., Ltd., Yongin-si (KR)

(21) Appl. No.: 18/103,751

(22) Filed: Jan. 31, 2023

(30) Foreign Application Priority Data
Feb. 15, 2022 (KR) 10-2022-0019788

(51) Int. Cl. H10K 85/60; C07F 5/02; C07F 7/08; H10K 85/40

(52) U.S. Cl. CPC H10K 85/658; H10K 85/6572; H10K 85/654; C07F 5/027; C07F 7/0812; H10K 85/40; H10K 85/6576; H10K 85/6574; C07B 2200/05; H10K 2101/27

(57) ABSTRACT

Embodiments provide a condensed cyclic compound, a light-emitting device that includes the condensed cyclic compound, and an electronic apparatus that includes the light-emitting device. The light-emitting device includes a first electrode, a second electrode facing the first electrode, and an interlayer between the first electrode and the second electrode and including an emission layer, wherein the emission layer includes the condensed cyclic compound. The condensed cyclic compound is represented by Formula 1, which is explained in the specification:

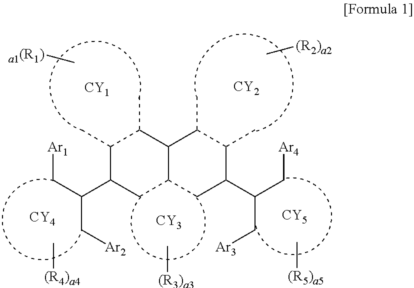

### CROSS-REFERENCE TO RELATED APPLICATION(S)

This application claims priority to and benefits of Korean Patent Application No. 10-2022-0019788 under 35 U.S.C. § 119, filed on Feb. 15, 2022, in the Korean Intellectual Property Office, the entire contents of which are incorporated herein by reference.

### BACKGROUND

### 1. Technical Field

Embodiments relate to a light-emitting device including a condensed cyclic compound, an electronic apparatus including the light-emitting device, and the condensed cyclic compound.

### 2. Description of the Related Art

Organic light-emitting devices are self-emissive devices that, as compared with devices of the related art, have wide viewing angles, high contrast ratios, short response times, and excellent characteristics in terms of luminance, driving voltage, and response speed, and produce full-color images.

In an example, an organic light-emitting device may have a structure in which a first electrode is arranged on a substrate, and a hole transport region, an emission layer, an electron transport region, and a second electrode are sequentially formed on the first electrode. Holes provided from the first electrode move toward the emission layer through the hole transport region, and electrons provided from the second electrode move toward the emission layer through the electron transport region. Carriers, such as holes and electrons, recombine in the emission layer to produce excitons. The excitons may transition from an excited state to a ground state, thus generating light.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments include a light-emitting device including a novel condensed cyclic compound, an electronic apparatus including the light-emitting device, and the condensed cyclic compound.

Additional aspects will be set forth in part in the description which follows and, in part, will be apparent from the description, or may be learned by practice of the embodiments of the disclosure.

According to embodiments, a light-emitting device may include a first electrode, a second electrode facing the first electrode, and an interlayer between the first electrode and the second electrode and including an emission layer, wherein the emission layer includes a condensed cyclic compound represented by Formula 1:

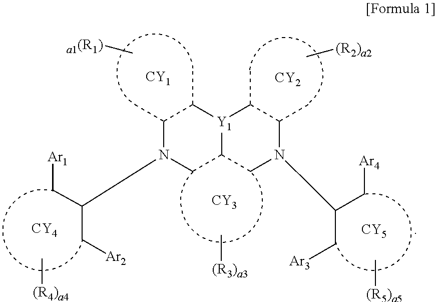

In Formula 1,

Y₁ may be boron (B), P(═O), or P(═S),

ring CY₁ to ring CY₃ may each independently be a C₅-C₆₀ carbocyclic group or a C₁-C₆₀ heterocyclic group,

ring CY₄ and ring CY₅ may each independently be a C₁-C₆₀ heterocyclic group including at least one nitrogen atom,

Ar₁ to Ar₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₁ to R₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

a1 to a5 may each independently be an integer from 0 to 10,

two or more of R₁(s) in the number of a1 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₂(s) in the number of a2 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₃(s) in the number of a3 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

R₁₀ₐ may be:

deuterium, —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and

Q₁ to Q₃, Q₁₁ to Q₁₃, Q₂₁ to Q₂₃, and Q₃₁ to Q₃₃ may each independently be hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, a difference between a triplet energy level (eV) and a singlet energy level (eV) of the condensed cyclic compound represented by Formula 1 may be equal to or less than about 0.2 eV.

In an embodiment, the emission layer may emit light having a maximum emission wavelength in a range of about 430 nm to about 480 nm.

In an embodiment, the emission layer may include: a first compound including the condensed cyclic compound represented by Formula 1; and a second compound including a group represented by Formula 20, a third compound including at least one π electron-deficient nitrogen-containing C₁-C₆₀ cyclic group, a fourth compound including a transition metal, or any combination thereof, wherein the first compound, the second compound, the third compound, and the fourth compound may be different from each other, and Formula 20 is explained below.

In an embodiment, the emission layer may include: the first compound including the condensed cyclic compound represented by Formula 1; and at least one of the second compound and the third compound, wherein the emission layer may optionally further include the fourth compound.

In an embodiment, the third compound may include a pyridine group, a pyrimidine group, a pyrazine group, a pyridazine group, a triazine group, or any combination thereof.

In an embodiment, the fourth compound may include a compound represented by Formula 401, which is explained below

According to embodiments, an electronic apparatus may include the light-emitting device.

In an embodiment, the electronic apparatus may further include a thin-film transistor, wherein the thin-film transistor may include a source electrode and a drain electrode, and the first electrode of the light-emitting device may be electrically connected to the source electrode or the drain electrode.

According to embodiments, a condensed cyclic compound may be represented by Formula 1.

In an embodiment, ring CY₁ to ring CY₃ may not include nitrogen.

In an embodiment, ring CY₄ and ring CY₅ may each independently be a 6-membered ring including at least one nitrogen atom.

In an embodiment, the condensed cyclic compound represented by Formula 1 may be represented by Formula 1-1 or Formula 1-2, which are explained below.

In an embodiment, in Formula 1, a moiety represented by

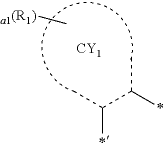

or a moiety represented by

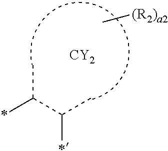

may each independently be a moiety represented by one of Formulae CY1(1) to CY1(14), which are explained below.

In an embodiment, in Formula 1, a moiety represented by

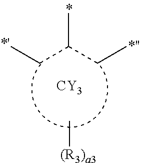

may be a moiety represented by one of Formulae CY3(1) to CY3(6), which are explained below.

In an embodiment, Ar₁ to Ar₄ may each independently be: a phenyl group, a biphenyl group, or a naphthyl group; or a phenyl group, a biphenyl group, or a naphthyl group, each substituted with deuterium or a C₁-C₁₀ alkyl group.

In an embodiment, R₁ to R₃ may each independently be hydrogen, deuterium, a C₁-C₆₀ alkyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ, wherein R₁₀ₐ is explained below.

In an embodiment, R₁ to R₃ may each independently be: hydrogen or deuterium a C₁-C₂₀ alkyl group unsubstituted or substituted with deuterium; or a group represented by one of Formulae 1A-1 to 1A-13, which are explained below.

In an embodiment, a sum of a1+a2+a3 may be 1 or more.

In an embodiment, the condensed cyclic compound may be one of Compounds 1 to 132, which are explained below.

It is to be understood that the embodiments above are described in a generic and explanatory sense only and not for the purpose of limitation, and the disclosure is not limited to the embodiments described above.

### BRIEF DESCRIPTION OF THE DRAWINGS

The above and other aspects and features of the disclosure will be more apparent by describing in detail embodiments thereof with reference to the accompanying drawings, in which:

FIG. 1 shows a schematic cross-sectional view of a light-emitting device according to an embodiment;

FIG. 2 shows a schematic cross-sectional view of an electronic apparatus according to an embodiment; and

FIG. 3 shows a schematic cross-sectional view of an electronic apparatus according to another embodiment.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, the sizes, thicknesses, ratios, and dimensions of the elements may be exaggerated for ease of description and for clarity. Like numbers refer to like elements throughout.

In the description, it will be understood that when an element (or region, layer, part, etc.) is referred to as being “on”, “connected to”, or “coupled to” another element, it can be directly on, connected to, or coupled to the other element, or one or more intervening elements may be present therebetween. In a similar sense, when an element (or region, layer, part, etc.) is described as “covering” another element, it can directly cover the other element, or one or more intervening elements may be present therebetween.

In the description, when an element is “directly on,” “directly connected to,” or “directly coupled to” another element, there are no intervening elements present. For example, “directly on” may mean that two layers or two elements are disposed without an additional element such as an adhesion element therebetween.

As used herein, the expressions used in the singular such as “a,” “an,” and “the,” are intended to include the plural forms as well, unless the context clearly indicates otherwise.

As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or”.

In the specification and the claims, the term “at least one of” is intended to include the meaning of “at least one selected from the group of” for the purpose of its meaning and interpretation. For example, “at least one of A and B” may be understood to mean “A, B, or A and B.” When preceding a list of elements, the term, “at least one of,” modifies the entire list of elements and does not modify the individual elements of the list.

It will be understood that, although the terms first, second, etc. may be used herein to describe various elements, these elements should not be limited by these terms. These terms are only used to distinguish one element from another element.

Thus, a first element could be termed a second element without departing from the teachings of the disclosure. Similarly, a second element could be termed a first element, without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “about” or “approximately” as used herein is inclusive of the stated value and means within an acceptable range of deviation for the recited value as determined by one of ordinary skill in the art, considering the measurement in question and the error associated with measurement of the recited quantity (i.e., the limitations of the measurement system). For example, “about” may mean within one or more standard deviations, or within +20%, 10%, or ±5% of the stated value.

It should be understood that the terms “comprises,” “comprising,” “includes,” “including,” “have,” “having,” “contains,” “containing,” and the like are intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

An aspect of the disclosure provides a light-emitting device (for example, an organic light-emitting device) which may include a first electrode, a second electrode facing the first electrode, and an interlayer between the first electrode and the second electrode and including an emission layer, wherein the emission layer may include a condensed cyclic compound represented by Formula 1.

Hereinafter, the condensed cyclic compound represented by Formula 1 will be described in detail:

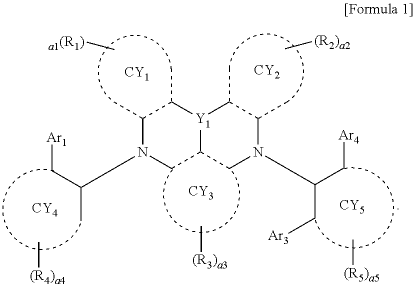

In Formula 1, Y₁ may be boron (B), P(═O), or P(═S).

For example, Y₁ may be B.

In Formula 1, ring CY₁ to ring CY₃ may each independently be a C₅-C₆₀ carbocyclic group or a C₁-C₆₀ heterocyclic group.

For example, ring CY₁ to ring CY₃ may each independently be a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, ring CY₁ to ring CY₃ may not include nitrogen.

In an embodiment, ring CY₁ to ring CY₃ may be a benzene group or a naphthalene group.

In Formula 1, ring CY₄ and ring CY₅ may each independently be a C₁-C₆₀ heterocyclic group including at least one nitrogen atom.

For example, ring CY₄ and ring CY₅ may each independently be an indole group, a carbazole group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group.

In an embodiment, ring CY₄ and ring CY₅ may each include one nitrogen.

In an embodiment, ring CY₄ and ring CY₅ may each independently be a 6-membered ring including at least one nitrogen atom.

In an embodiment, ring CY₄ and ring CY₅ may each independently be a pyridine group or an isoquinoline group.

In an embodiment, the condensed cyclic compound represented by Formula 1 may be represented by Formula 1-1 or 1-2:

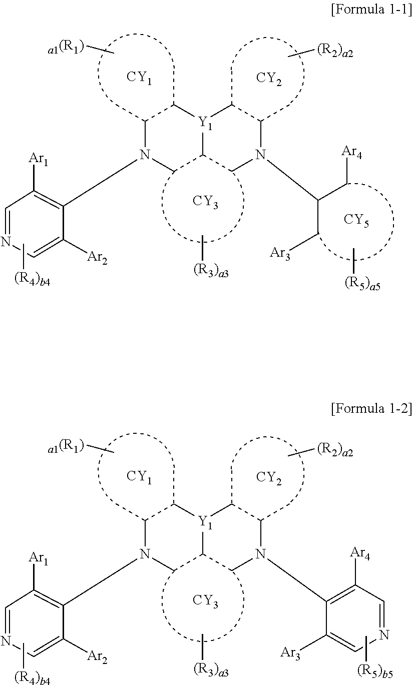

In Formulae 1-1 and 1-2, b4 and b5 may each independently be an integer from 0 to 2.

In Formulae 1-1 and 1-2, Y₁, ring CY₁ to ring CY₃, ring CY₅, Ar₁ to Ar₄, R₁ to R₅, a1 to a3, and a5 may each be the same as described herein.

In Formula 1, Ar₁ to Ar₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ. R₁₀ₐ may be the same as described herein.

In an embodiment, Ar₁ to Ar₄ may each independently be a C₃-C₃₀ cycloalkyl group unsubstituted or substituted with at least one R₁₀ₐ, a C₁-C₃₀ heterocycloalkyl group unsubstituted or substituted with at least one R₁₀ₐ, a C₆-C₃₀ aryl group unsubstituted or substituted with at least one R₁₀ₐ, a C₁-C₃₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ.

For example, Ar₁ to Ar₄ may each independently be a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In an embodiment, Ar₁ to Ar₄ may each independently be: a phenyl group, a biphenyl group, or a naphthyl group; or a phenyl group, a biphenyl group, or a naphthyl group, each substituted with deuterium or a C₁-C₁₀ alkyl group (e.g., a methyl group or a t-butyl group).

In Formula 1, R₁ to R₅ may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂). R₁₀ₐ and Q₁ to Q₃ may each be the same as described herein.

For example, R₁ to R₅ may each independently be: hydrogen, deuterium, —F, —Cl, —Br, —I, a hydroxyl group, a cyano group, a nitro group, an amidino group, a hydrazine group, a hydrazone group, a C₁-C₂₀ alkyl group, or a C₁-C₂₀ alkoxy group;

a C₁-C₂₀ alkyl group or a C₁-C₂₀ alkoxy group, each substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, and a pyrimidinyl group;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, or an azadibenzosilolyl group, each unsubstituted or substituted with at least one of deuterium, —F, —Cl, —Br, —I, —CD₃, —CD₂H, —CDH₂, —CF₃, —CF₂H, —CFH₂, a hydroxyl group, a cyano group, a nitro group, an amidino group, a hydrazine group, a hydrazone group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a 1,2,3,4-tetrahydronaphthalenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), and —P(═O)(Q₃₁)(Q₃₂); and

—Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

Q₁ to Q₃ and Q₃₁ to Q₃₃ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an isopropyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with at least one of deuterium, a C₁-C₁₀ alkyl group, a phenyl group, a biphenyl group, a pyridinyl group, a pyrimidinyl group, a pyridazinyl group, a pyrazinyl group, and a triazinyl group.

In an embodiment, R₁ to R₃ may each independently be hydrogen, deuterium, a C₁-C₆₀ alkyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ. R₁₀ₐ may be the same as described herein.

In an embodiment, R₁ to R₃ may each independently be:

hydrogen or deuterium;

a C₁-C₂₀ alkyl group unsubstituted or substituted with deuterium; or

a group represented by one of Formulae 1A-1 to 1A-13:

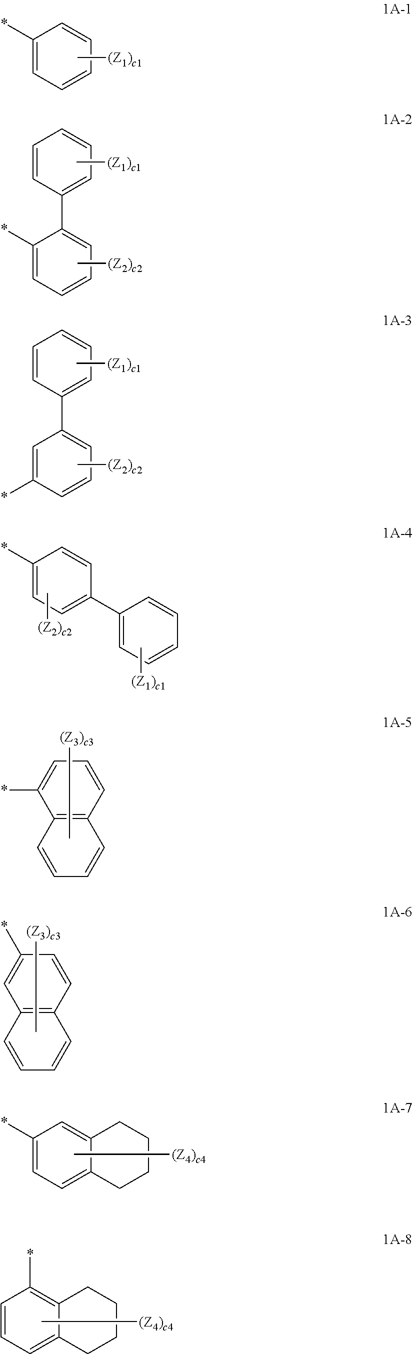

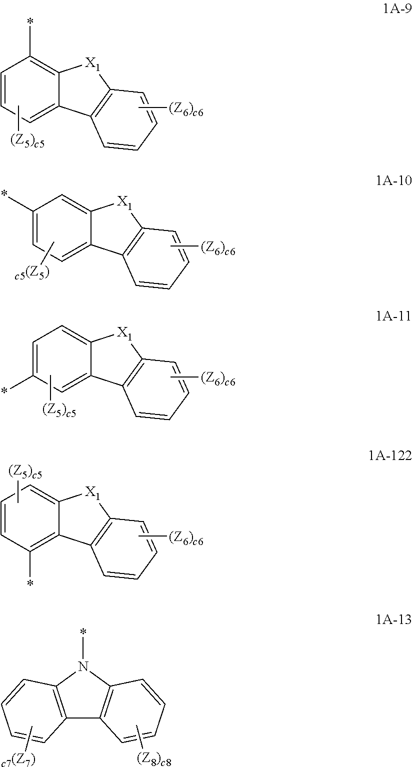

In Formulae 1A-1 to 1A-13,

X₁ may be O, S, N(R₁ₐ), C(R₁ₐ)(R_{1b}), or Si(R₁ₐ)(R_{1b}),

Z₁ to Z₈, R₁ₐ, and R_{1b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

c1 may be an integer from 0 to 5,

c2 and c6 to c8 may each independently be an integer from 0 to 4,

c3 may be an integer from 0 to 7,

c4 may be an integer from 0 to 11,

c5 may be an integer from 0 to 3,

* indicates a binding site to a neighboring atom, and

R₁₀ₐ and Q₁ to Q₃ may each be the same as described herein.

In an embodiment, R₄ and R₅ may each independently be hydrogen or deuterium.

In Formula 1, a1 to a5 may each independently be an integer from 0 to 10.

In an embodiment, the sum of a1+a2+a3 may be 1 or more. For example, the sum of a1+a2+a3 may be 1, 2, or 3.

In Formula 1, two or more of R₁(s) in the number of a1 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,

two or more of R₂(s) in the number of a2 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ, and

two or more of R₃(s) in the number of a3 may optionally be bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ.

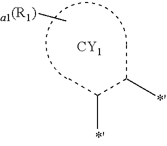

In an embodiment, in Formula 1, a moiety represented by

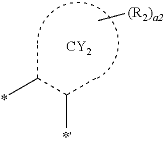

or a moiety represented by may each independently be a moiety represented by one of Formulae CY1(1) to CY1(14):

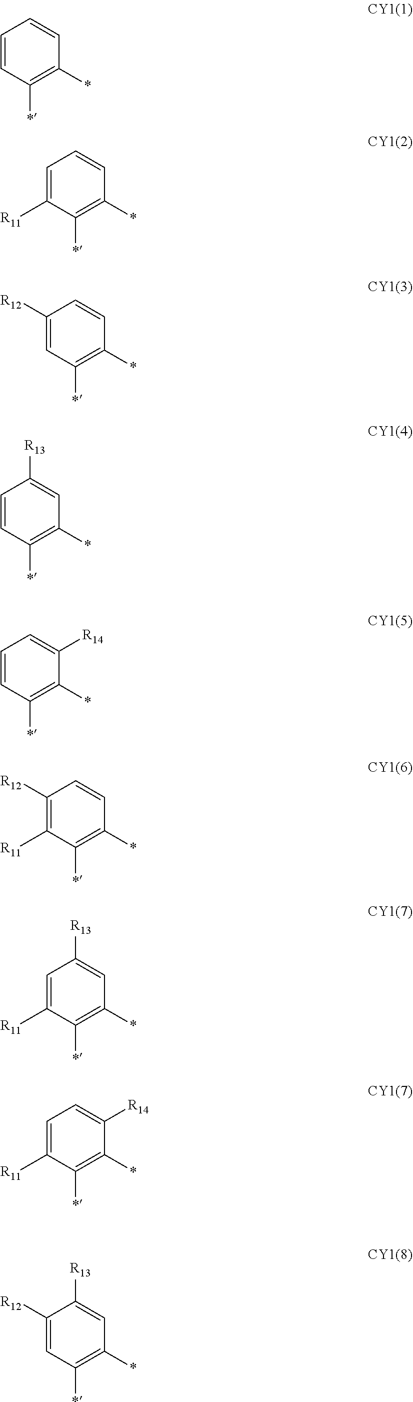

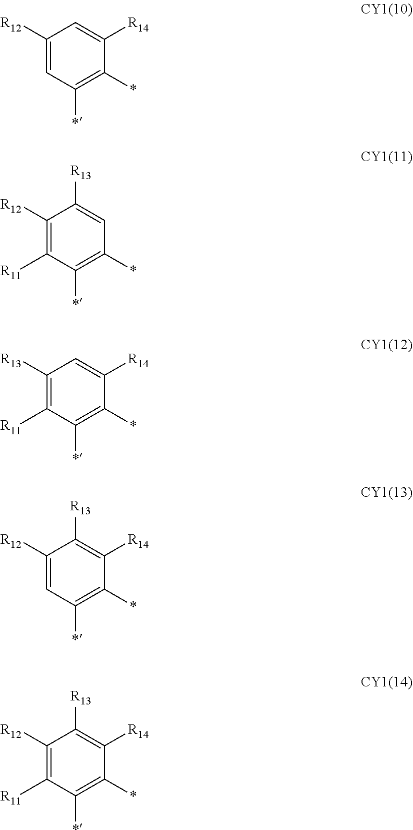

In Formulae CY1(1) to CY1(14),

R₁₁ to R₁₄ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

* indicates a binding site to neighboring Y₁ in Formula 1,

*′ indicates a binding site to neighboring N in Formula 1, and

R₁₀ₐ and Q₁ to Q₃ may each be the same as described herein.

In an embodiment, in Formulae CY1(1) to CY1(14), R₁₁ to R₁₄ may each independently be: deuterium; a C₁-C₂₀ alkyl group unsubstituted or substituted with deuterium; or a group represented by one of Formulae 1A-1 to 1A-13. Formulae 1A-1 to 1A-13 may each be the same as described herein.

In an embodiment, in Formula 1, a moiety represented by

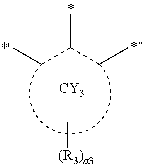

may be a moiety represented by one of Formulae CY3(1) to CY3(6):

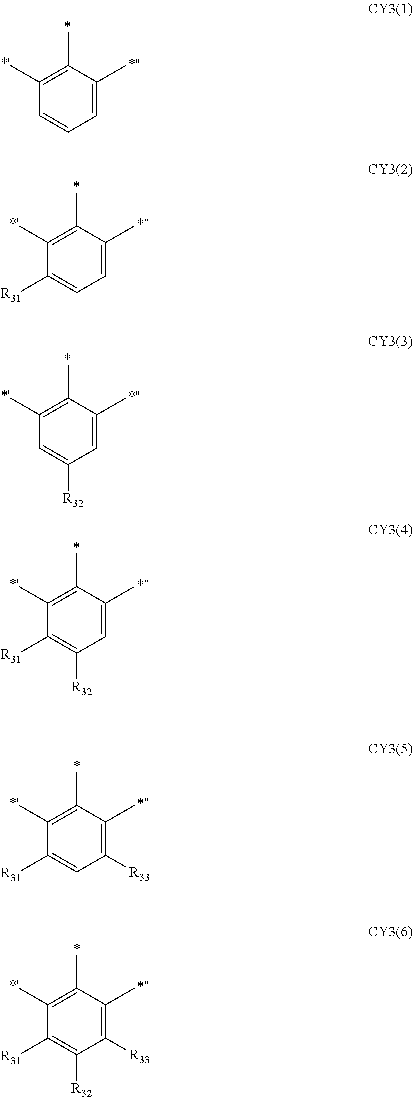

In Formulae CY3(1) to CY3(6),

R₃₁ to R₃₃ may each independently be deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),

* indicates a binding site to neighboring Y₁ in Formula 1,

*′ and *″ each indicate a binding site to neighboring N in Formula 1, and

R₁₀ₐ and Q₁ to Q₃ may each be the same as described herein.

In an embodiment, in Formulae CY3(1) to CY3(6), R₃₁ to R₃₃ may each independently be: deuterium; a C₁-C₂₀ alkyl group unsubstituted or substituted with deuterium; or a group represented by one of Formulae 1A-1 to 1A-13. Formulae 1A-1 to 1A-13 may each be the same as described herein.

In an embodiment, the condensed cyclic compound may be one of Compounds 1 to 132:

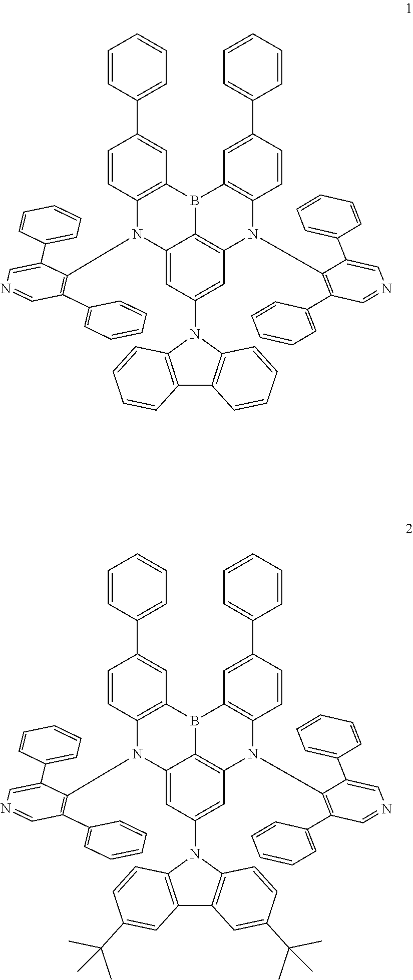 [SMILES: c1ccc(-c2ccc3c(c2)B2c4cc(-c5ccccc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1 ; CC(C)(C)c1ccc2c(c1)c1cc(C(C)(C)C)ccc1n2-c1cc2c3c(c1)N(c1c(-c4ccccc4)cncc1-c1ccccc1)c1ccc(-c4ccccc4)cc1B3c1cc(-c3ccccc3)ccc1N2c1c(-c2ccccc2)cncc1-c1ccccc1]

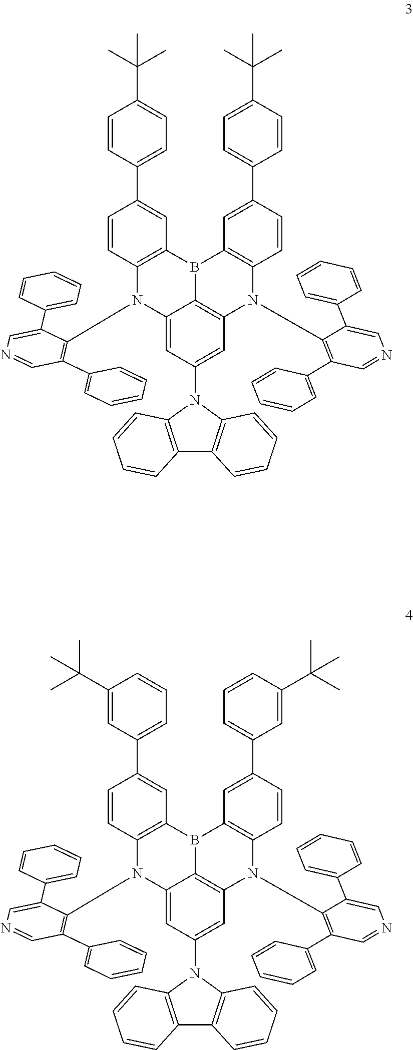 [SMILES: CC(C)(C)c1ccc(-c2ccc3c(c2)B2c4cc(-c5ccc(C(C)(C)C)cc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1 ; CC(C)(C)c1cccc(-c2ccc3c(c2)B2c4cc(-c5cccc(C(C)(C)C)c5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)c1]

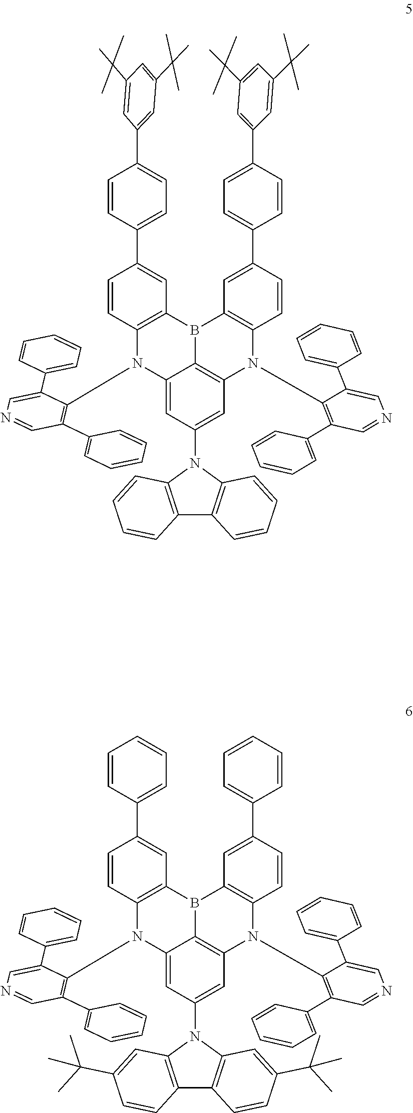 [SMILES: CC(C)(C)c1cc(-c2ccc(-c3ccc4c(c3)B3c5cc(-c6ccc(-c7cc(C(C)(C)C)cc(C(C)(C)C)c7)cc6)ccc5N(c5c(-c6ccccc6)cncc5-c5ccccc5)c5cc(-n6c7ccccc7c7ccccc76)cc(c53)N4c3c(-c4ccccc4)cncc3-c3ccccc3)cc2)cc(C(C)(C)C)c1 ; CC(C)(C)c1ccc2c3ccc(C(C)(C)C)cc3n(-c3cc4c5c(c3)N(c3c(-c6ccccc6)cncc3-c3ccccc3)c3ccc(-c6ccccc6)cc3B5c3cc(-c5ccccc5)ccc3N4c3c(-c4ccccc4)cncc3-c3ccccc3)c2c1]

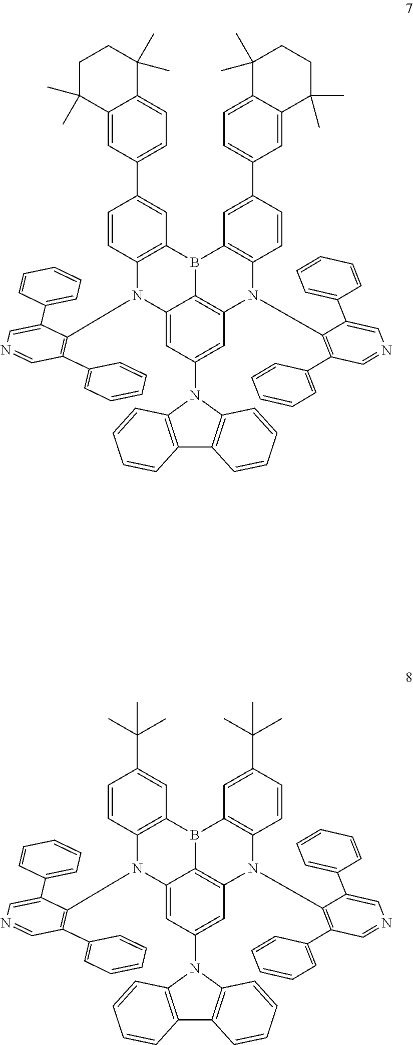 [SMILES: CC1(C)CCC(C)(C)c2cc(-c3ccc4c(c3)B3c5cc(-c6ccc7c(c6)C(C)(C)CCC7(C)C)ccc5N(c5c(-c6ccccc6)cncc5-c5ccccc5)c5cc(-n6c7ccccc7c7ccccc76)cc(c53)N4c3c(-c4ccccc4)cncc3-c3ccccc3)ccc21 ; CC(C)(C)c1ccc2c(c1)B1c3cc(C(C)(C)C)ccc3N(c3c(-c4ccccc4)cncc3-c3ccccc3)c3cc(-n4c5ccccc5c5ccccc54)cc(c31)N2c1c(-c2ccccc2)cncc1-c1ccccc1]

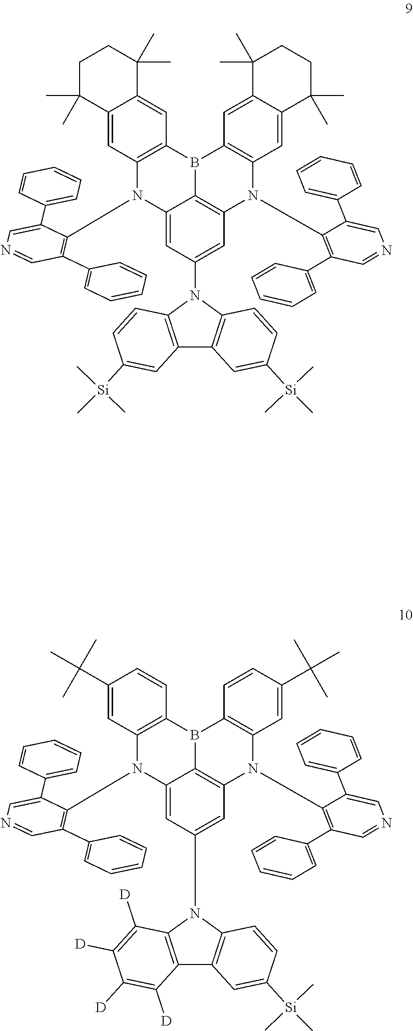 [SMILES: CC1(C)CCC(C)(C)c2cc3c(cc21)B1c2cc4c(cc2N(c2c(-c5ccccc5)cncc2-c2ccccc2)c2cc(-n5c6ccc([Si](C)(C)C)cc6c6cc([Si](C)(C)C)ccc65)cc(c21)N3c1c(-c2ccccc2)cncc1-c1ccccc1)C(C)(C)CCC4(C)C ; [2H]c1c([2H])c([2H])c2c(c1[2H])c1cc([Si](C)(C)C)ccc1n2-c1cc2c3c(c1)N(c1c(-c4ccccc4)cncc1-c1ccccc1)c1cc(C(C)(C)C)ccc1B3c1ccc(C(C)(C)C)cc1N2c1c(-c2ccccc2)cncc1-c1ccccc1]

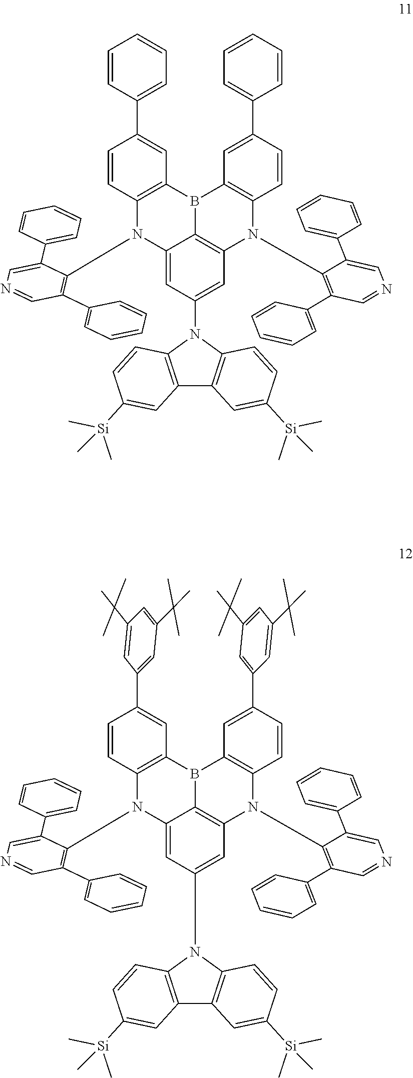 [SMILES: C[Si](C)(C)c1ccc2c(c1)c1cc([Si](C)(C)C)ccc1n2-c1cc2c3c(c1)N(c1c(-c4ccccc4)cncc1-c1ccccc1)c1ccc(-c4ccccc4)cc1B3c1cc(-c3ccccc3)ccc1N2c1c(-c2ccccc2)cncc1-c1ccccc1 ; CC(C)(C)c1cc(-c2ccc3c(c2)B2c4cc(-c5cc(C(C)(C)C)cc(C(C)(C)C)c5)ccc4N(c4c(-c5ccccc5)cncc4-c4ccccc4)c4cc(-n5c6ccc([Si](C)(C)C)cc6c6cc([Si](C)(C)C)ccc65)cc(c42)N3c2c(-c3ccccc3)cncc2-c2ccccc2)cc(C(C)(C)C)c1]

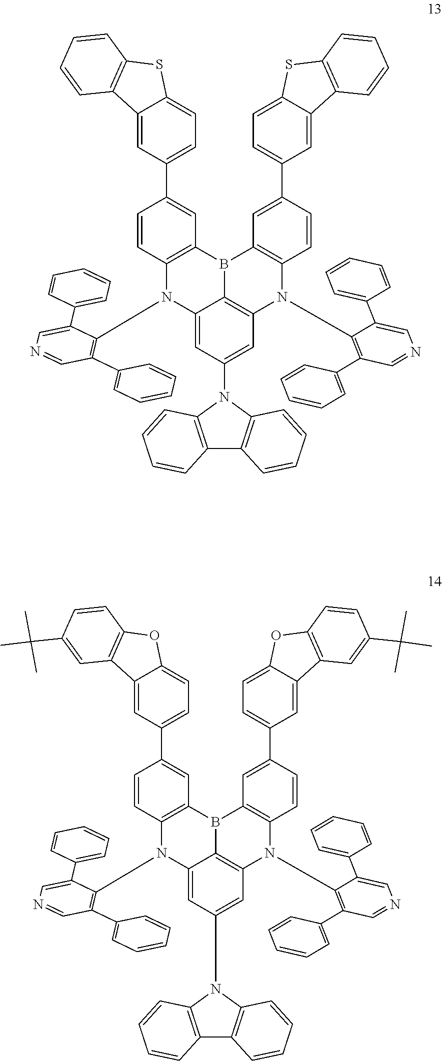 [SMILES: c1ccc(-c2cncc(-c3ccccc3)c2N2c3ccc(-c4ccc5sc6ccccc6c5c4)cc3B3c4cc(-c5ccc6sc7ccccc7c6c5)ccc4N(c4c(-c5ccccc5)cncc4-c4ccccc4)c4cc(-n5c6ccccc6c6ccccc65)cc2c43)cc1 ; CC(C)(C)c1ccc2oc3ccc(-c4ccc5c(c4)B4c6cc(-c7ccc8oc9ccc(C(C)(C)C)cc9c8c7)ccc6N(c6c(-c7ccccc7)cncc6-c6ccccc6)c6cc(-n7c8ccccc8c8ccccc87)cc(c64)N5c4c(-c5ccccc5)cncc4-c4ccccc4)cc3c2c1]

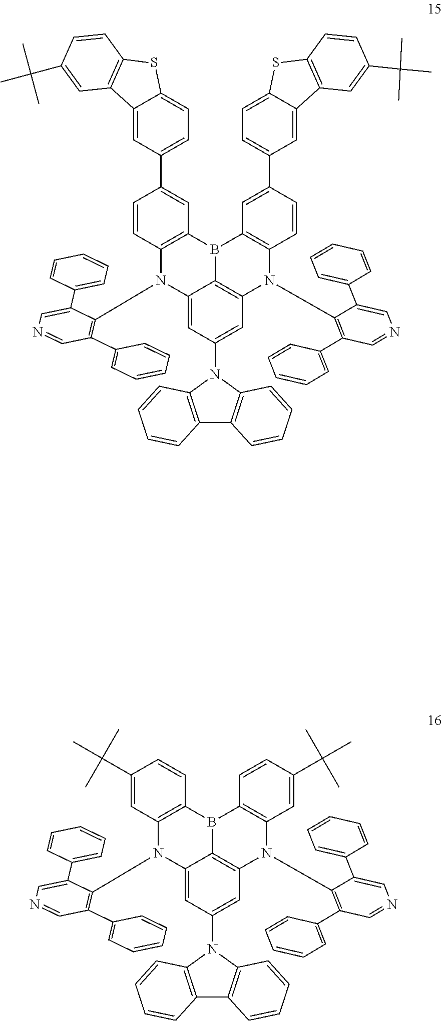 [SMILES: CC(C)(C)c1ccc2sc3ccc(-c4ccc5c(c4)B4c6cc(-c7ccc8sc9ccc(C(C)(C)C)cc9c8c7)ccc6N(c6c(-c7ccccc7)cncc6-c6ccccc6)c6cc(-n7c8ccccc8c8ccccc87)cc(c64)N5c4c(-c5ccccc5)cncc4-c4ccccc4)cc3c2c1 ; CC(C)(C)c1ccc2c(c1)N(c1c(-c3ccccc3)cncc1-c1ccccc1)c1cc(-n3c4ccccc4c4ccccc43)cc3c1B2c1ccc(C(C)(C)C)cc1N3c1c(-c2ccccc2)cncc1-c1ccccc1]

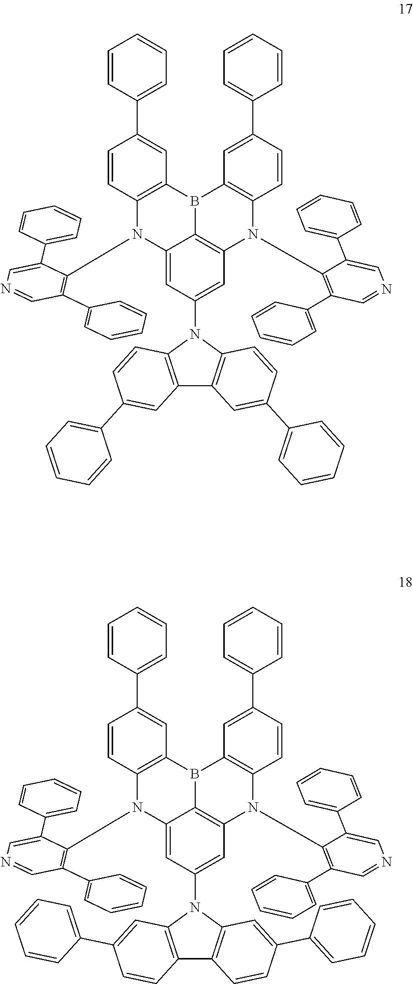 [SMILES: c1ccc(-c2ccc3c(c2)B2c4cc(-c5ccccc5)ccc4N(c4c(-c5ccccc5)cncc4-c4ccccc4)c4cc(-n5c6ccc(-c7ccccc7)cc6c6cc(-c7ccccc7)ccc65)cc(c42)N3c2c(-c3ccccc3)cncc2-c2ccccc2)cc1 ; c1ccc(-c2ccc3c(c2)B2c4cc(-c5ccccc5)ccc4N(c4c(-c5ccccc5)cncc4-c4ccccc4)c4cc(-n5c6cc(-c7ccccc7)ccc6c6ccc(-c7ccccc7)cc65)cc(c42)N3c2c(-c3ccccc3)cncc2-c2ccccc2)cc1]

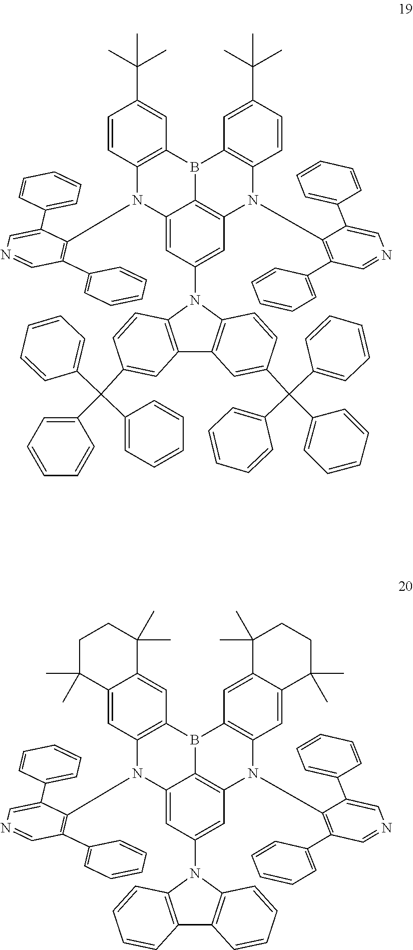 [SMILES: CC(C)(C)c1ccc2c(c1)B1c3cc(C(C)(C)C)ccc3N(c3c(-c4ccccc4)cncc3-c3ccccc3)c3cc(-n4c5ccc(C(c6ccccc6)(c6ccccc6)c6ccccc6)cc5c5cc(C(c6ccccc6)(c6ccccc6)c6ccccc6)ccc54)cc(c31)N2c1c(-c2ccccc2)cncc1-c1ccccc1 ; CC1(C)CCC(C)(C)c2cc3c(cc21)B1c2cc4c(cc2N(c2c(-c5ccccc5)cncc2-c2ccccc2)c2cc(-n5c6ccccc6c6ccccc65)cc(c21)N3c1c(-c2ccccc2)cncc1-c1ccccc1)C(C)(C)CCC4(C)C]

The condensed cyclic compound represented by Formula 1 may have a low highest occupied molecular orbital (HOMO) energy level by introducing an electron-withdrawing group (EWG) such as ring CY₄ or ring CY₅.

Thus, when the condensed cyclic compound represented by Formula 1 is used in an emission layer of the light-emitting device, a trap-assisted recombination (TAR) pathway in which carriers directly recombine in a light-emitting material may be suppressed, thereby improving lifespan characteristics of the light-emitting device. Due to a low HOMO energy level, energy may be readily received from a host in the emission layer, thereby also improving efficiency of the light-emitting device.

In an embodiment, a difference between a triplet energy level (eV) and a singlet energy level (eV) in the condensed cyclic compound represented by Formula 1 may be equal to or less than about 0.5 eV. For example, a difference between a triplet energy level (eV) and a singlet energy level (eV) in the condensed cyclic compound represented by Formula 1 may be equal to or less than about 0.4 eV. For example, a difference between a triplet energy level (eV) and a singlet energy level (eV) in the condensed cyclic compound represented by Formula 1 may be equal to or less than about 0.3 eV. For example, a difference between a triplet energy level (eV) and a singlet energy level (eV) in the condensed cyclic compound represented by Formula 1 may be equal to or less than about 0.2 eV. The triplet energy level (eV) and the singlet energy level (eV) may be values evaluated using a DFT method of a Gaussian program, which is structure-optimized at the B3LYP/6-31G(d,p) level, or the triplet energy level (eV) and the singlet energy level (eV) may be values calculated from a measured room temperature photoluminescence spectrum and a measured low-temperature photoluminescence spectrum.

When a difference between the triplet energy level and the singlet energy level of the condensed cyclic compound represented by Formula 1 is as described above, triplet excitons may be rapidly harvested as singlet excitons by a reverse intersystem crossing (RISC) mechanism. Accordingly, when the condensed cyclic compound represented by Formula 1 is used in the light-emitting device, the efficiency and lifespan characteristics of the light-emitting device may be improved.

Methods of synthesizing the condensed cyclic compound represented by Formula 1 may be readily understood to those of ordinary skill in the art by referring to the Synthesis Examples and the Examples described herein.

In an embodiment, the first electrode of the light-emitting device may be an anode; the second electrode of the light-emitting device may be a cathode; and the interlayer may further include a hole transport region between the first electrode and the emission layer and an electron transport region between the emission layer and the second electrode,

wherein the hole transport region may include a hole injection layer, a hole transport layer, an emission auxiliary layer, an electron blocking layer, or any combination thereof, and

the electron transport region may include a buffer layer, a hole blocking layer, an electron control layer, an electron transport layer, an electron injection layer, or any combination thereof.

In embodiments, the condensed cyclic compound may be included between the first electrode and the second electrode of the light-emitting device. In an embodiment, the condensed cyclic compound may be included in the interlayer of the light-emitting device, for example, in the emission layer of the interlayer.

In embodiments, the condensed cyclic compound included in the emission layer may be a thermally activated delayed fluorescence (TADF) emitter, and the emission layer may emit delayed fluorescence. The emission layer may emit red light, green light, blue light, and/or white light. For example, the emission layer may emit blue light. The blue light may have a maximum emission wavelength in a range of about 400 nm to about 490 nm. For example, the blue light may have a maximum emission wavelength in a range of about 420 nm to about 480 nm. For example, the blue light may have a maximum emission wavelength in a range of about 430 nm to 480 nm. In an embodiment, the emission layer may emit light having a maximum emission wavelength in a range of about 430 nm to 480 nm. The emission layer may further include a host, and an amount of the host may be greater than an amount of the condensed cyclic compound represented by Formula 1.

In embodiments, the light-emitting device may include a capping layer arranged outside the first electrode or outside the second electrode.

For example, the light-emitting device may further include at least one of a first capping layer arranged outside the first electrode and a second capping layer arranged outside the second electrode, and at least one of the first capping layer and the second capping layer may include the condensed cyclic compound represented by Formula 1.

The first capping layer and/or the second capping layer may each be the same as described herein.

In an embodiment, the light-emitting device may further include:

a first capping layer arranged outside the first electrode and including the condensed cyclic compound represented by Formula 1;

a second capping layer arranged outside the second electrode and including the condensed cyclic compound represented by Formula 1; or

the first capping layer and the second capping layer.

The expression “(interlayer and/or capping layer) includes a condensed cyclic compound” as used herein may be understood as “(interlayer and/or capping layer) may include one kind of condensed cyclic compound represented by Formula 1 or two or more different kinds of condensed cyclic compounds, each represented by Formula 1.”

In an embodiment, the interlayer and/or the capping layer may include Compound 1 only as the condensed cyclic compound. In this regard, Compound 1 may be present in the emission layer of the light-emitting device. In embodiments, the interlayer may include, as the condensed cyclic compound, Compound 1 and Compound 2. In this regard, Compound 1 and Compound 2 may be present in a same layer (for example, both Compound 1 and Compound 2 may be present in the emission layer), or may be present in different layers (for example, Compound 1 may be present in the emission layer, and Compound 2 may be present in the electron transport region).

The term “interlayer” as used herein refers to a single layer and/or multiple layers between the first electrode and the second electrode of the light-emitting device.

In an embodiment, the emission layer in the light-emitting device may include:

a first compound including the condensed cyclic compound represented by Formula 1; and

a second compound including a group represented by Formula 20, a third compound including at least one π electron-deficient nitrogen-containing C₁-C₆₀ cyclic group, a fourth compound including a transition metal, or any combination thereof,

wherein the first compound, the second compound, the third compound, and the fourth compound may be different from each other:

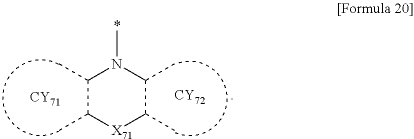

In Formula 20, ring CY₇₁ and ring CY₇₂ may each independently be a π electron-rich C₃-C₆₀ cyclic group or a pyridine group.

In Formula 20, X₇₁ may be:

a single bond; or

a linking group including O, S, N, B, C, Si, or any combination thereof.

In Formula 20, * indicates a binding site to a neighboring atom.

In Formula 20, CBP and mCBP are excluded from the second compound:

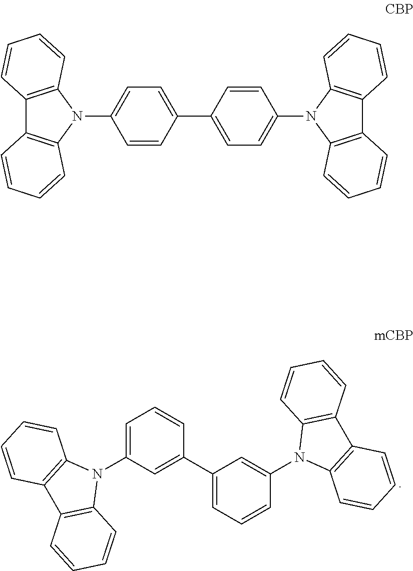 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1]

### Second Compound to Fourth Compound

In an embodiment, the emission layer may include:

the first compound; and

at least one of the second compound and the third compound.

In embodiments, the emission layer may optionally further include the fourth compound.

In embodiments, the emission layer may include the first compound, the second compound, the third compound, and the fourth compound.

In an embodiment, the second compound may include a compound represented by Formula 20-1, a compound represented by Formula 20-2, a compound represented by Formula 20-3, a compound represented by Formula 20-4, a compound represented by Formula 20-5, or any combination thereof:

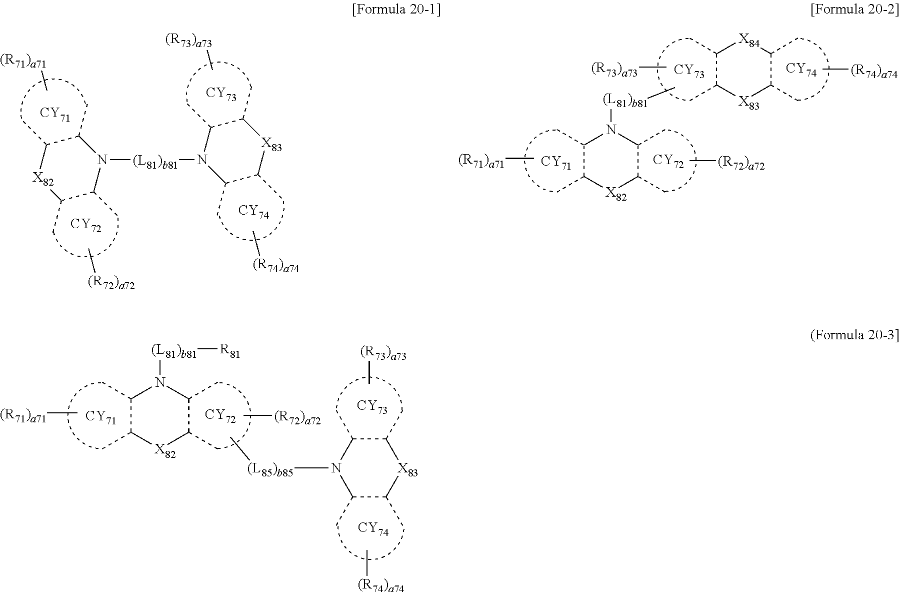

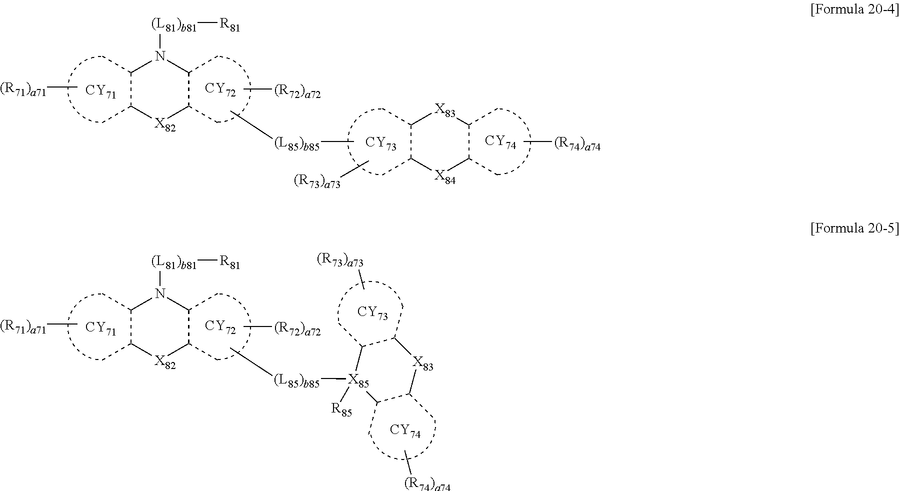

In Formulae 20-1 to 20-5,

ring CY₇₁ to ring CY₇₄ may each independently be a π electron-rich C₃-C₆₀ cyclic group or a pyridine group,

X₈₂ may be a single bond, B, O, S, N-[(L₈₂)_{b82}-R₈₂], C(R₈₂ₐ)(R_{82b}), or Si(R₈₂ₐ)(R_{82b}),

X₈₃ may be a single bond, B, O, S, N-[(L₈₃)_{b83}-R₈₃], C(R₈₃ₐ)(R_{83b}), or Si(R₈₃ₐ)(R_{83b}),

X₈₄ may be B, O, S, N-[(L₈₄)_{b84}-R₈₄], C(R₈₄ₐ)(R_{84b}), or Si(R₈₄ₐ)(R_{84b}),

X₈₅ may be C or Si,

L₈₁ to L₈₅ may each independently be a single bond, *—C(Q₄)(Q₅)-*′, *—Si(Q₄)(Q₅)-*′, a π electron-rich C₃-C₆₀ cyclic group unsubstituted or substituted with at least one R₁₀ₐ, or a pyridine group unsubstituted or substituted with at least one R₁₀ₐ, wherein Q₄ and Q₅ may each independently be the same as described in connection with Q₁,

b81 to b85 may each independently be an integer from 1 to 5,

R₇₁ to R₇₄, R₈₁ to R₈₅, R₈₂ₐ, R_{82b}, R₈₃ₐ, R_{83b}, R₈₄ₐ, and R_{84b} may each be the same as described herein,

a71 to a74 may each independently be an integer from 0 to 20, and

R₁₀ₐ may be the same as described herein.

In an embodiment, the third compound may include a pyridine group, a pyrimidine group, a pyrazine group, a pyridazine group, a triazine group, or any combination thereof.

In an embodiment, the third compound may include a compound represented by Formula 30:

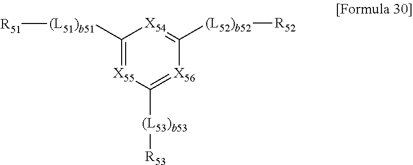

In Formula 30,

L₅₁ to L₅₃ may each independently be a single bond, a C₃-C₆₀ carbocyclic group unsubstituted or substituted with at least one R₁₀ₐ, or a C₁-C₆₀ heterocyclic group unsubstituted or substituted with at least one R₁₀ₐ,

b51 to b53 may each independently be an integer from 1 to 5,

X₅₄ may be N or C(R₅₄), X₅₅ may be N or C(R₅₅), X₅₆ may be N or C(R₅₆), and at least one of X₅₄ to X₅₆ may be N,

R₅₁ to R₅₆ may each be the same as described herein, and

R₁₀ₐ may be the same as described herein.

In an embodiment, the fourth compound may include a compound represented by Formula 401:

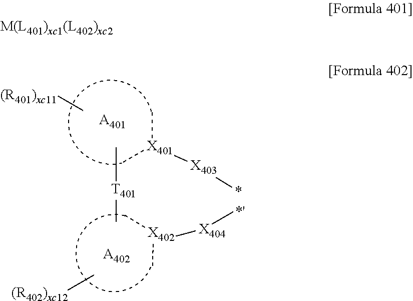

In Formulae 401 and 402,

M may be a transition metal (for example, iridium (Ir), platinum (Pt), palladium (Pd), osmium (Os), titanium (Ti), gold (Au), hafnium (Hf), europium (Eu), terbium (Tb), rhodium (Rh), rhenium (Re), or thulium (Tm)),

L₄₀₁ may be a ligand represented by Formula 402, and xc1 may be 1, 2, or 3, wherein when xc1 is 2 or more, two or more of L₄₀₁(s) may be identical to or different from each other,

L₄₀₂ may be an organic ligand, and xc2 may be 0, 1, 2, 3, or 4, wherein when xc2 is 2 or more, two or more of L₄₀₂(s) may be identical to or different from each other,

X₄₀₁ and X₄₀₂ may each independently be nitrogen or carbon,

ring A₄₀₁ and ring A₄₀₂ may each independently be a C₃-C₆₀ carbocyclic group or a C₁-C₆₀ heterocyclic group,

T₄₀₁ may be a single bond, *—O—*′, *—S*′, *—C(═O)—*′, *—N(Q₄₁₁)-*′, *—C(Q₄₁₁)(Q₄₁₂)-*′, *—C(Q₄₁₁)═C(Q₄₁₂)-*, *—C(Q₄₁₁)=*′, or *=O═*′,

X₄₀₃ and X₄₀₄ may each independently be a chemical bond, O, S, N(Q₄₁₃), B(Q₄₁₃), P(Q₄₁₃), C(Q₄₁₃)(Q₄₁₄), or Si(Q₄₁₃)(Q₄₁₄),

R₄₀₁ and R₄₀₂ may each independently be hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),

xc11 and xc12 may each independently be an integer from 0 to 10,

Q₄₁₁ to Q₄₁₄ and Q₄₀₁ to Q₄₀₃ may each independently be: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group; or a C₂-C₆₀ heteroarylalkyl group,

* and *′ in Formula 402 each indicate a binding site to M in Formula 401, and

R₁₀ₐ may be the same as described herein.

Description of Formulae 20, 20-1 to 20-5, and 30

In an embodiment, a group represented by

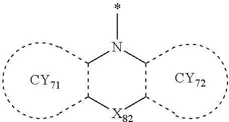

in Formulae 20-1 and 20-2 may be a group represented by one of Formulae CY71-1(1) to CY71-1(8), and/or

a group represented by

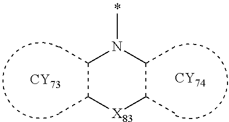

in Formulae 20-1 and 20-3 may be a group represented by one of Formulae CY71-2(1) to CY71-2(8), and/or

a group represented by

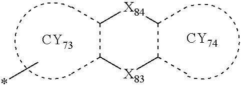

in Formulae 20-2 and 20-4 may be a group represented by one of Formulae CY71-3(1) to CY71-3(32), and/or

a group represented by

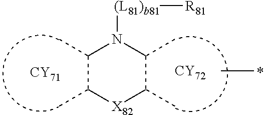

in Formulae 20-3 to 20-5 may be a group represented by one of Formulae CY71-4(1) to CY71-4(32), and/or

a group represented by

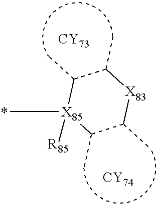

in Formula 20-5 may be a group represented by one of Formulae CY71-5(1) to CY71-5(8):

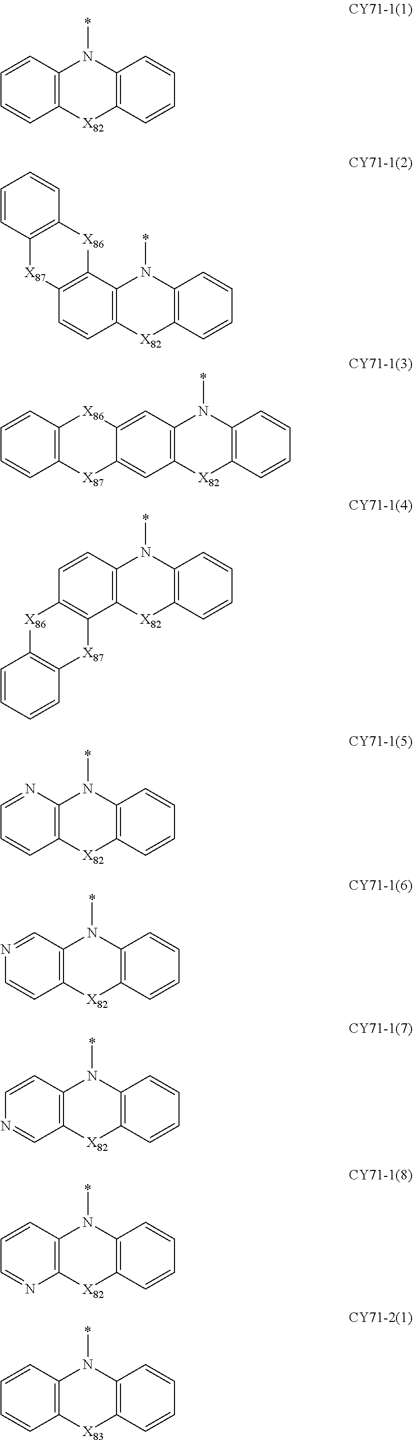

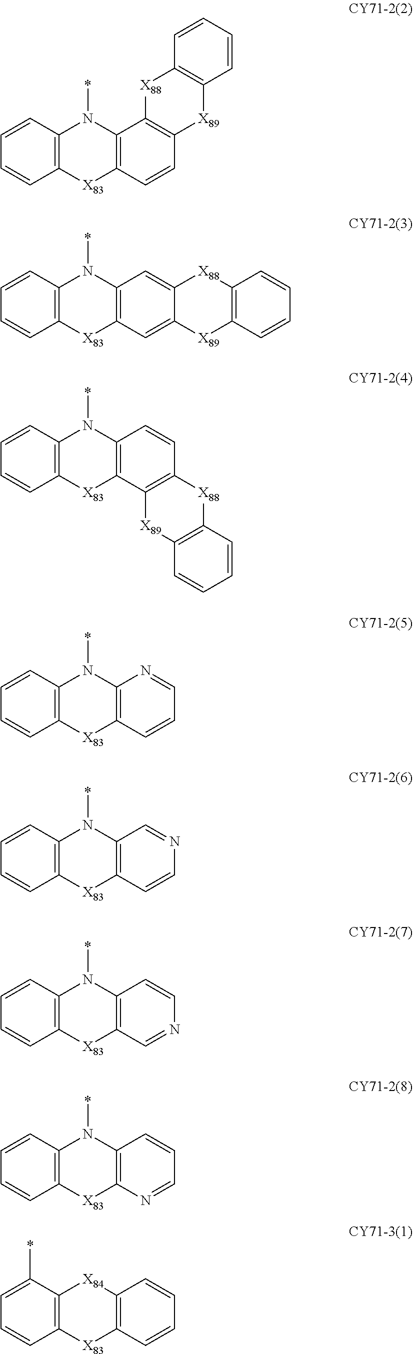

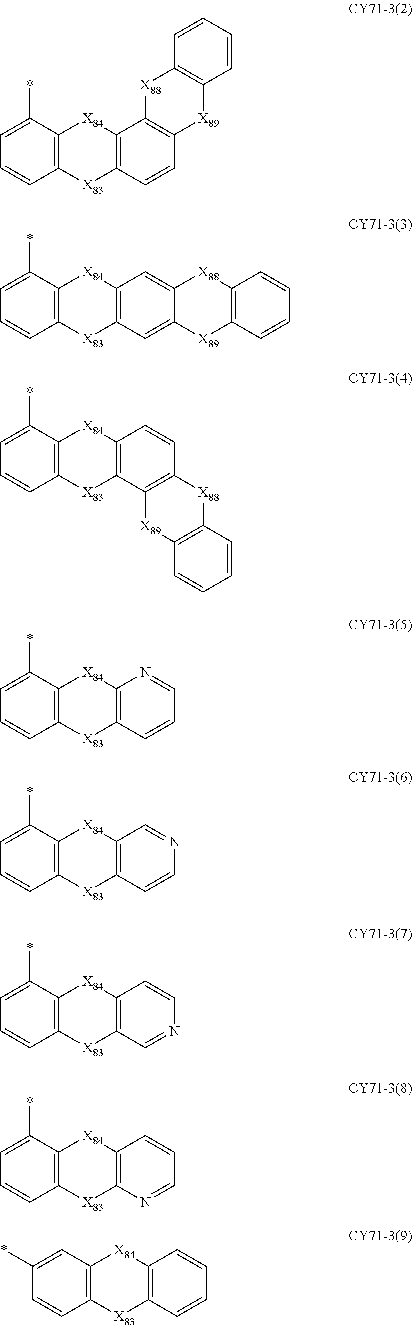

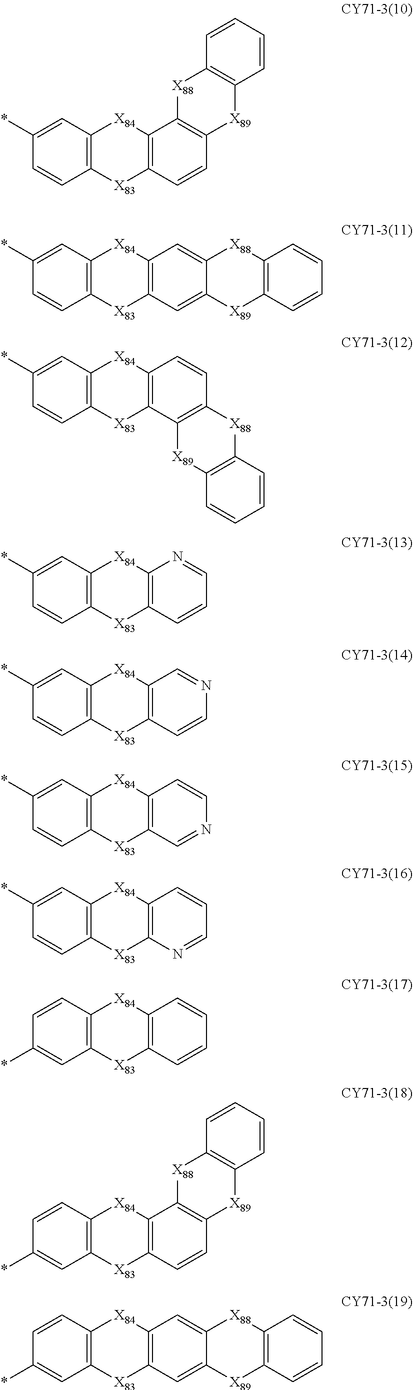

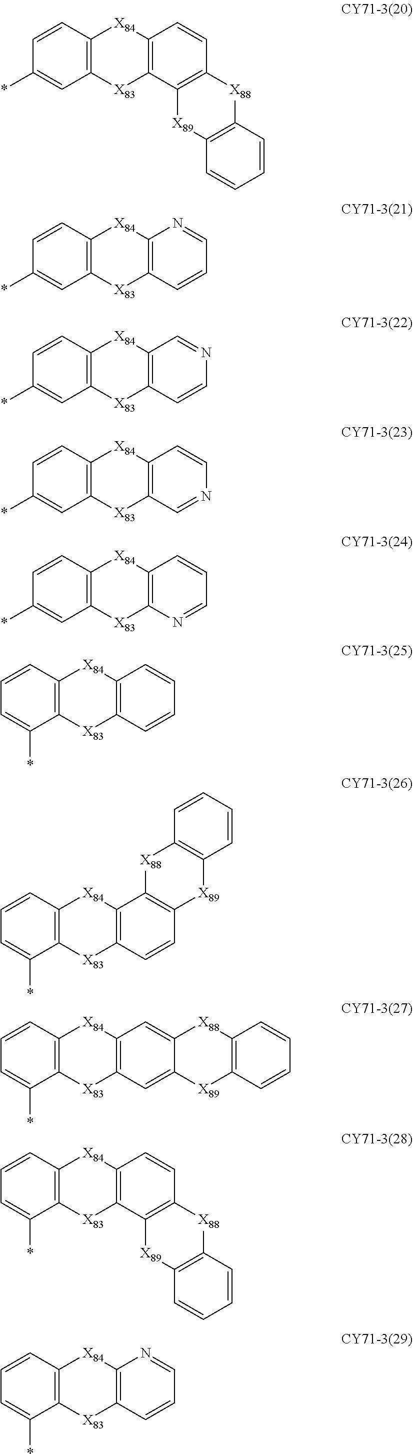

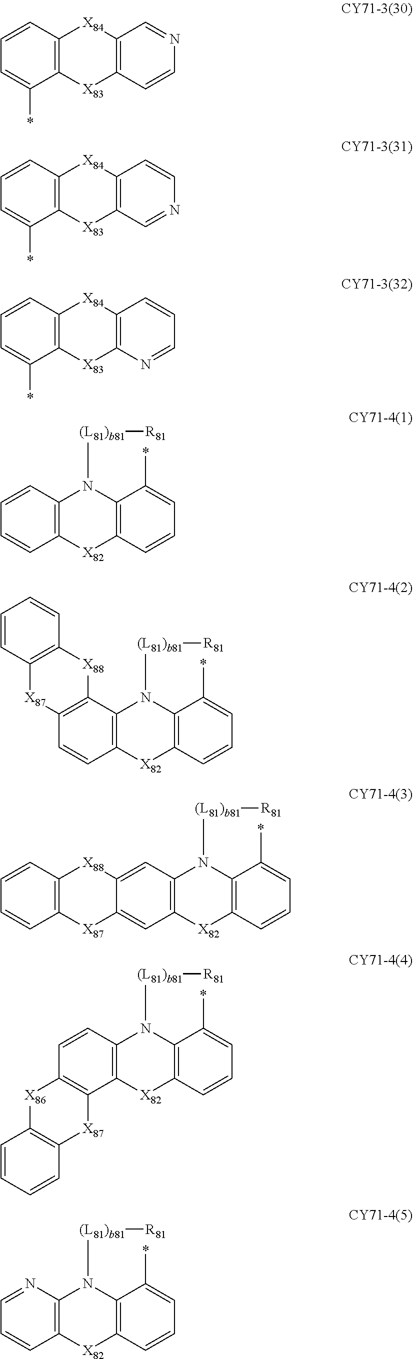

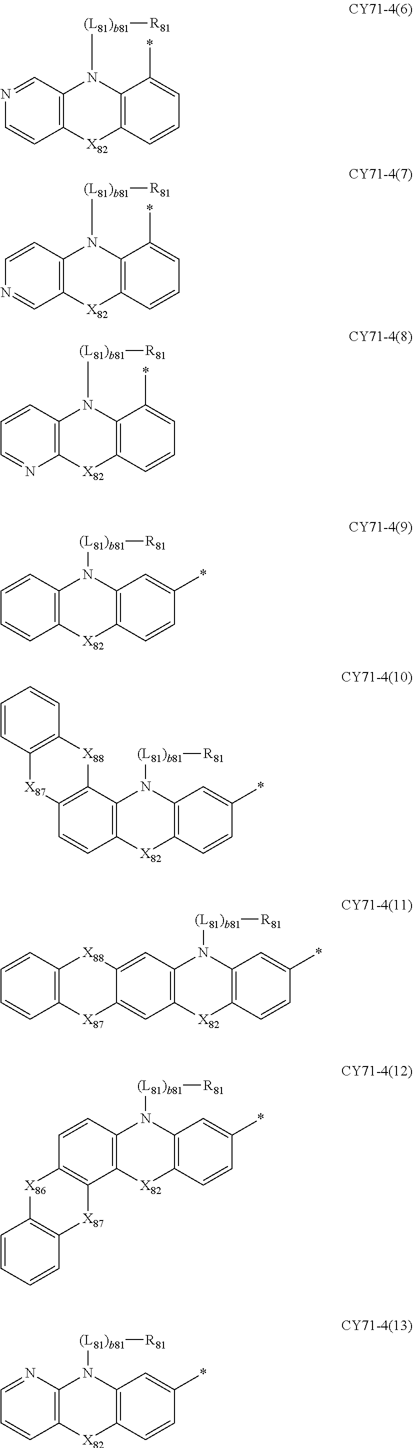

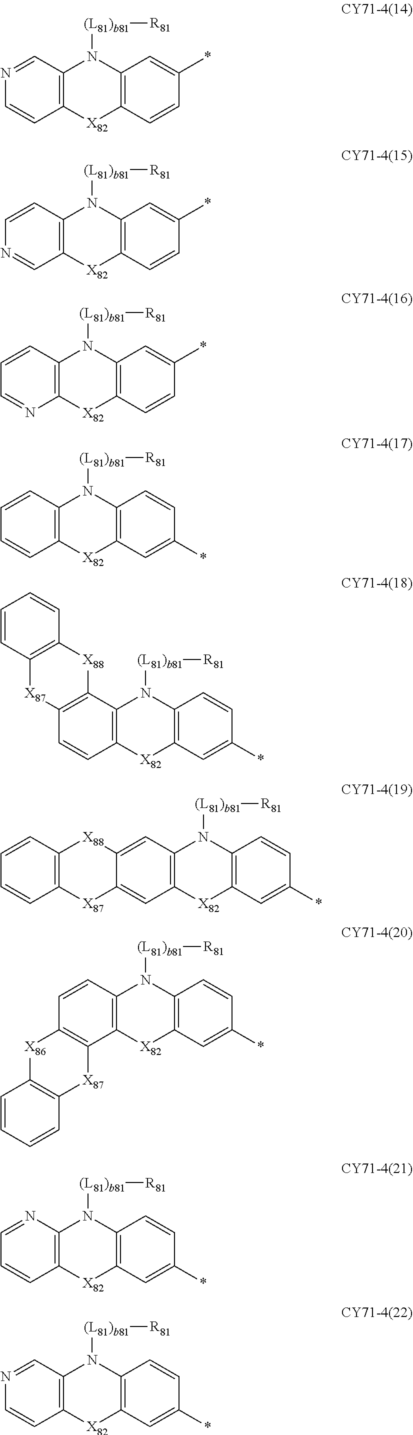

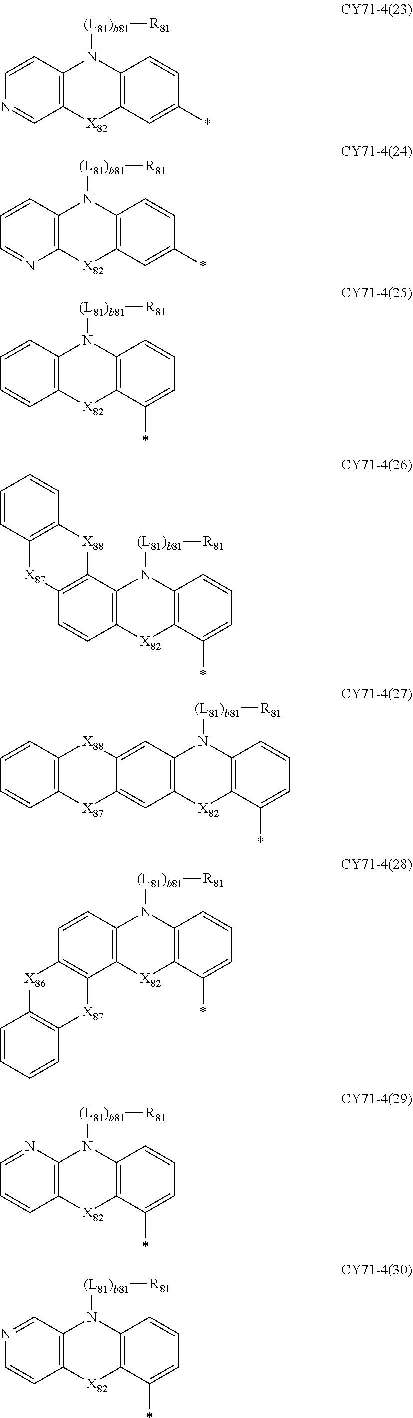

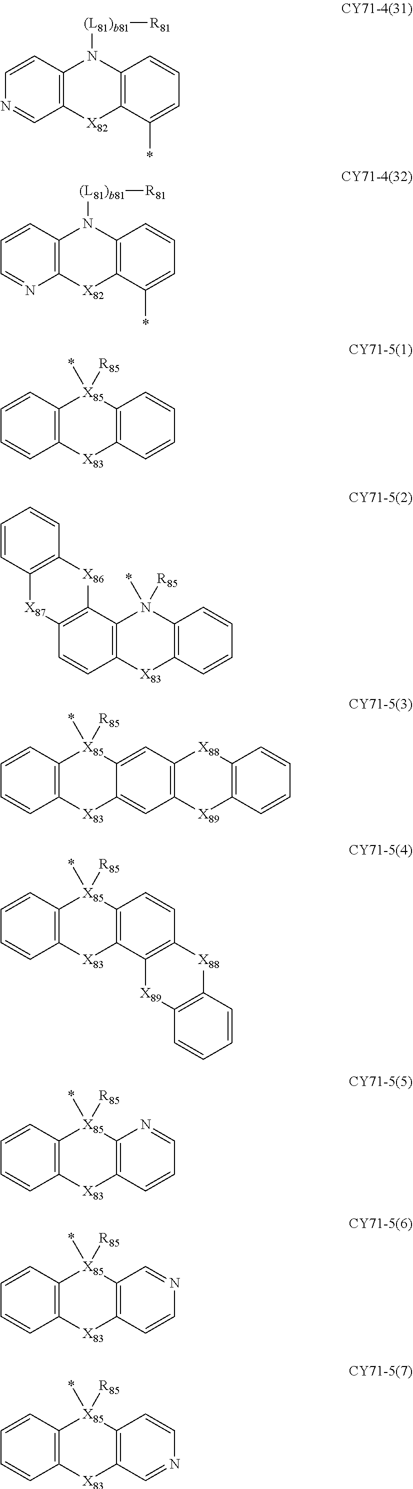

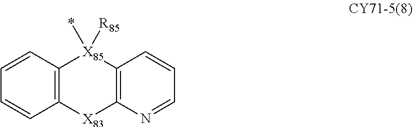

In Formulae CY71-1(1) to CY71-1(8), CY71-2(1) to CY71-2(8), CY71-3(1) to CY71-3(32), CY71-4(1) to CY71-4(32), and CY71-5(1) to CY71-5(8),

X₈₂ to X₈₅, L₈₁, b81, R₈₁, and R₈₅ may each be the same as described herein,

X₈₆ may be a single bond, O, S, N(R₈₆), B(R₈₆), C(R₈₆ₐ)(R_{86b}), or Si(R₈₆ₐ)(R_{86b}),

X₈₇ may be a single bond, O, S, N(R₈₇), B(R₈₇), C(R₈₇ₐ)(R_{87b}), or Si(R₈₇ₐ)(R_{87b}),

in Formulae CY71-1(1) to CY71-1(8) and CY71-4(1) to CY71-4(32), X₈₆ and X₈₇ may not each be a single bond at the same time,

X₈₈ may be a single bond, O, S, N(R₈₈), B(R₈₈), C(R₈₈ₐ)(R_{88b}), or Si(R₈₈ₐ)(R_{88b}),

X₈₉ may be a single bond, O, S, N(R₈₉), B(R₈₉), C(R₈₉ₐ)(R_{89b}), or Si(R₈₉ₐ)(R_{89b}),

in Formulae CY71-2(1) to CY71-2(8), CY71-3(1) to CY71-3(32), and CY71-5(1) to CY71-5(8), X₈₈ and X₈₉ may not each be a single bond at the same time, and

R₈₆ to Rae, R₈₆ₐ, R_{86b}, R₈₇ₐ, R_{87b}, R₈₈ₐ, R_{88b}, R₈₉ₐ, and R_{89b} may each independently be the same as described in connection with R₈₁.

In Formula 30, b51 to b53 respectively indicate the number of L₅₁(s) to the number of L₅₃(s), and may each independently be an integer from 1 to 5. When b51 is 2 or more, two or more of L₅₁(s) may be identical to or different from each other, when b52 is 2 or more, two or more of L₅₂(s) may be identical to or different from each other, and when b53 is 2 or more, two or more of L₅₃(s) may be identical to or different from each other. In an embodiment, b51 to b53 may each independently be 1 or 2.

In embodiments, in Formula 30, L₅₁ to L₅₃ may each independently be:

a single bond; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a dibenzooxacilline group, a dibenzothiacilline group, a dibenzodihydroazacilline group, a dibenzodihydrodicilline group, a dibenzodihydrocilline group, a dibenzodioxane group, a dibenzooxathiene group, a dibenzooxazine group, a dibenzopyran group, a dibenzodithiine group, a dibenzothiazine group, a dibenzothiopyran group, a dibenzocyclohexadiene group, a dibenzodihydropyridine group, or a dibenzodihydropyrazine group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof, and

Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

In an embodiment, in Formula 30, a bond between L₅₁ and R₅₁, a bond between L₅₂ and R₅₂, a bond between L₅₃ and R₅₃, a bond between two or more L₅₁(s), a bond between two or more L₅₂(s), a bond between two or more L₅₃(s), a bond between L₅₁ and carbon between X₅₄ and X₅₅ in Formula 30, a bond between L₅₂ and carbon between X₅₄ and X₅₆ in Formula 30, and a bond between L₅₃ and carbon between X₅₅ and X₅₆ in Formula 30 may each be a carbon-carbon single bond.

In Formula 30, X₅₄ may be N or C(R₅₄), X₅₅ may be N or C(R₅₅), X₅₆ may be N or C(R₅₆), and at least one of X₅₄ to X₅₆ may be N. R₅₄ to R₅₆ may each be the same as described herein. For example, two or three of X₅₄ to X₅₆ may each be N.

In the specification, R₅₁ to R₅₆, R₇₁ to R₇₄, R₈₁ to R₈₅, R₈₂ₐ, R_{82b}, R₈₃ₐ, R_{83b}, R₈₄ₐ, and R_{84b} may each independently be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), wherein Q₁ to Q₃ may each be the same as described herein.

For example, R₅₁ to R₅₆, R₇₁ to R₇₄, R₈₁ to R₈₅, R₈₂ₐ, R_{82b}, R₈₃ₐ, R_{83b}, R₈₄ₐ, and R_{84b} in Formulae 20-1 to 20-5 and 30; and R₁₀ₐ may each independently be:

hydrogen, deuterium, —F, —Cl, —Br, —I, a hydroxyl group, a cyano group, a nitro group, a C₁-C₂₀ alkyl group, or a C₁-C₂₀ alkoxy group;

a C₁-C₂₀ alkyl group or a C₁-C₂₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₁₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a naphthyl group, a pyridinyl group, a pyrimidinyl group, or any combination thereof;

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof; or

—C(Q₁)(Q₂)(Q₃), —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂), and

Q₁ to Q₃ and Q₃₁ to Q₃₃ may each independently be:

—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or

an n-propyl group, an iso-propyl group, an n-butyl group, an isobutyl group, a sec-butyl group, a tert-butyl group, an n-pentyl group, an isopentyl group, a sec-pentyl group, a tert-pentyl group, a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof:

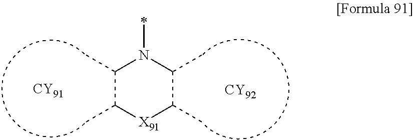

In Formula 91,

ring CY₉₁ and ring CY₉₂ may each independently be a C₅-C₃₀ carbocyclic group unsubstituted or substituted with at least one R₁₀ₐ or a C₁-C₃₀ heterocyclic group unsubstituted or substituted with at least one R₁₀ₐ,

X₉₁ may be a single bond, O, S, N(R₉₁), B(R₉₁), C(R₉₁ₐ)(R_{91b}), or Si(R₉₁ₐ)(R_{91b}),

R₉₁, R₉₁ₐ, and R_{91b} may respectively be the same as described in connection with R₈₂, R₈₂ₐ, and R_{82b} as described herein,

R₁₀ₐ may be the same as described herein, and

* indicates a binding site to a neighboring atom.

For example, in Formula 91,

ring CY₉₁ and ring CY₉₂ may each independently be a benzene group, a pyridine group, a pyrimidine group, a pyrazine group, a pyridazine group, or a triazine group, each unsubstituted or substituted with at least one R₁₀ₐ, and

R₉₁, R₉₁ₐ, and R_{91b} may each independently be:

hydrogen or a C₁-C₁₀ alkyl group; or

a phenyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof.

In embodiments, R₅₁ to R₅₆, R₇₁ to R₇₄, R₈₁ to R₈₅, R₈₂ₐ, R_{82b}, R₈₃ₐ, R_{83b}, R₈₄ₐ, and R_{84b} in Formulae 20-1 to 20-5, and 30; and R₁₀ₐ may each independently be:

hydrogen, deuterium, —F, a cyano group, a nitro group, —CH₃, —CD₃, —CD₂H, —CDH₂, —CF₃, —CF₂H, —CFH₂, a group represented by one of Formulae 9-1 to 9-19, a group represented by one of Formulae 10-1 to 10-246, —C(Q₁)(Q₂)(Q₃), —Si(Q₁)(Q₂)(Q₃), or —P(═O)(Q₁)(Q₂), wherein Q₁ to Q₃ may each be the same as described herein:

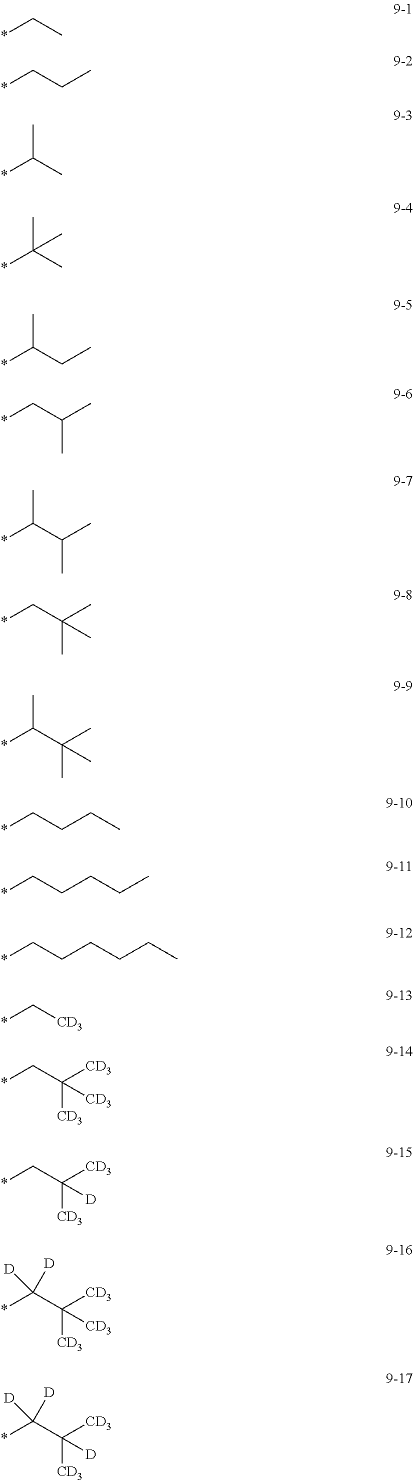

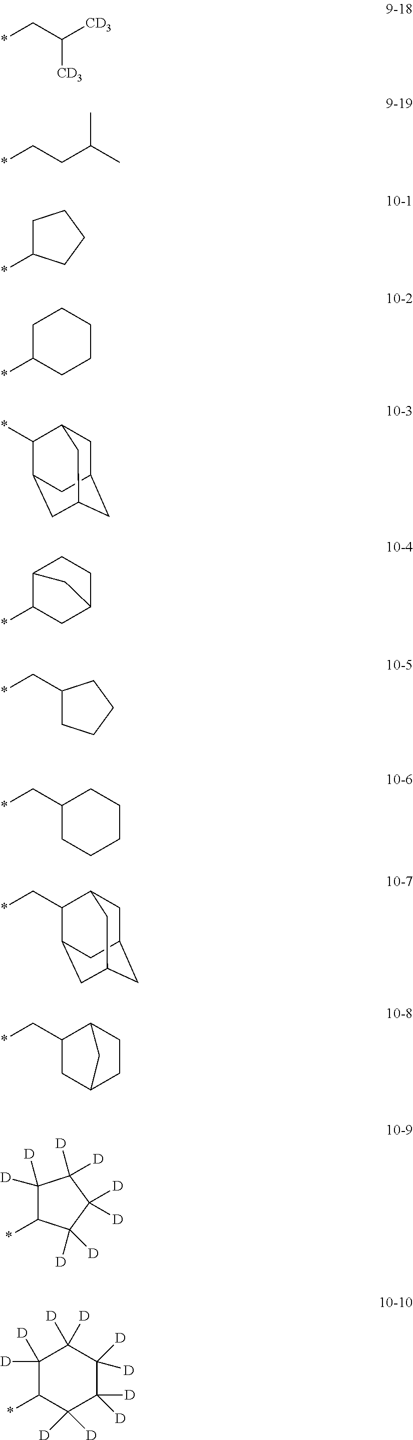

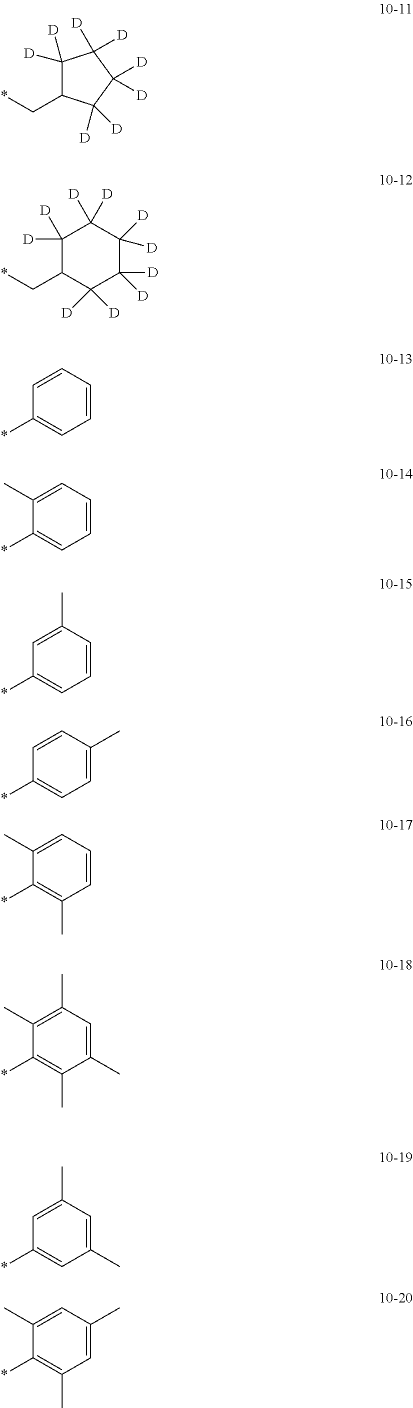

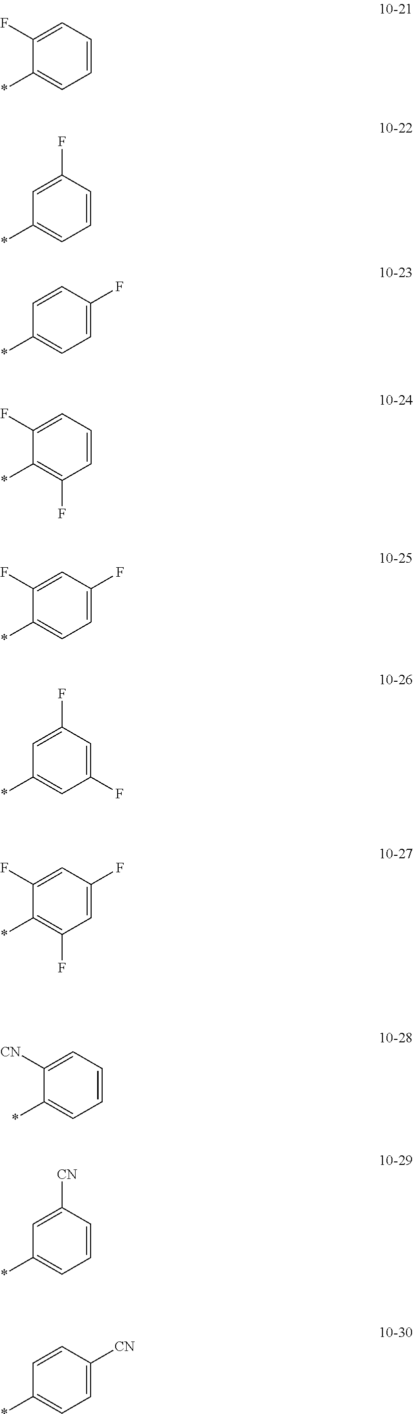

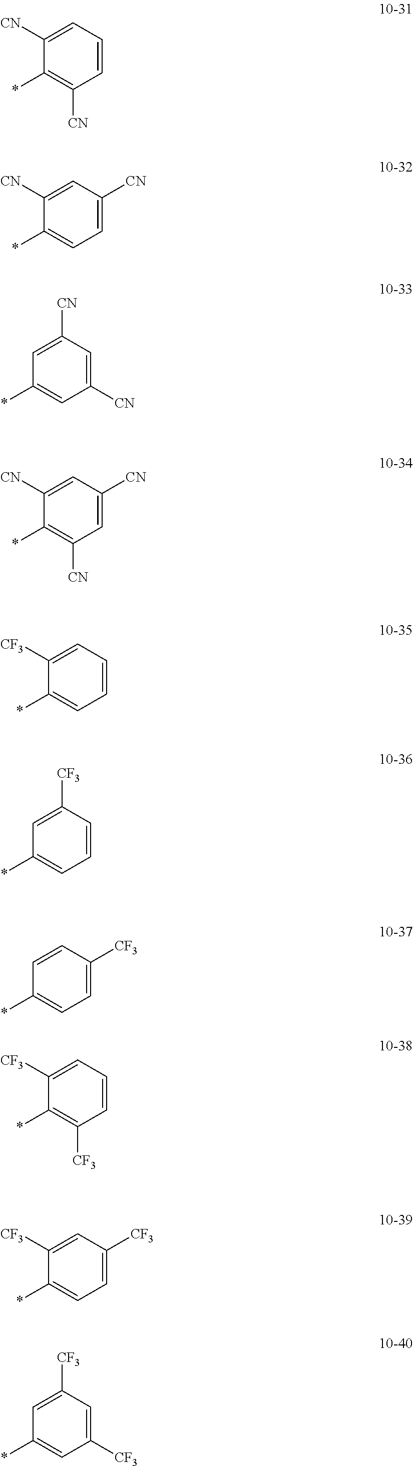

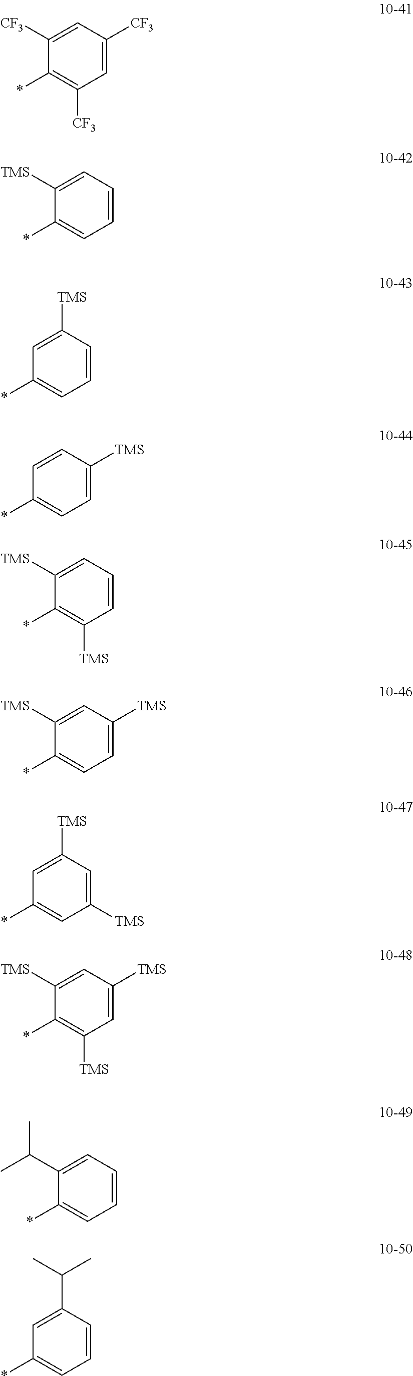

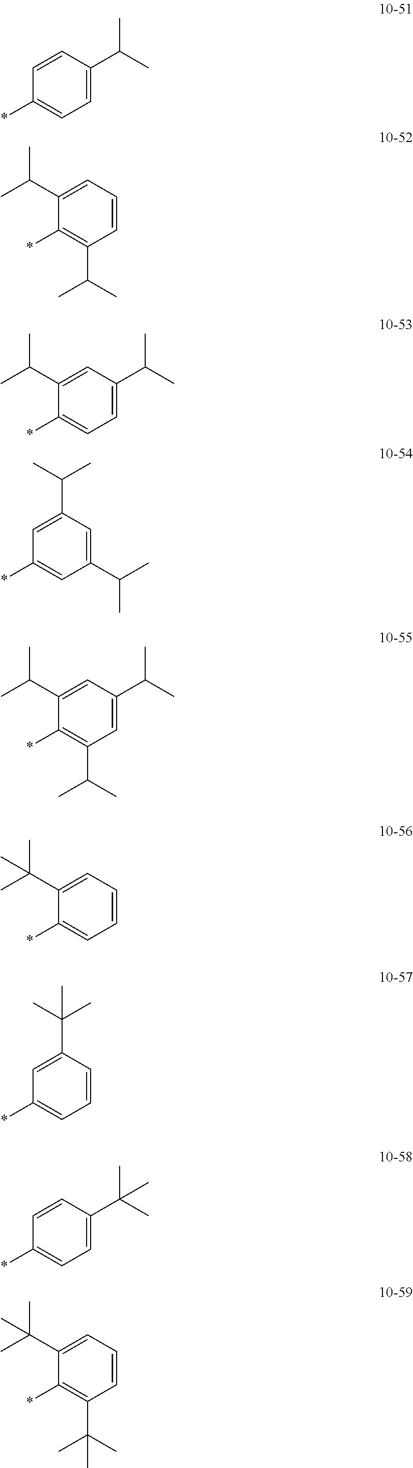

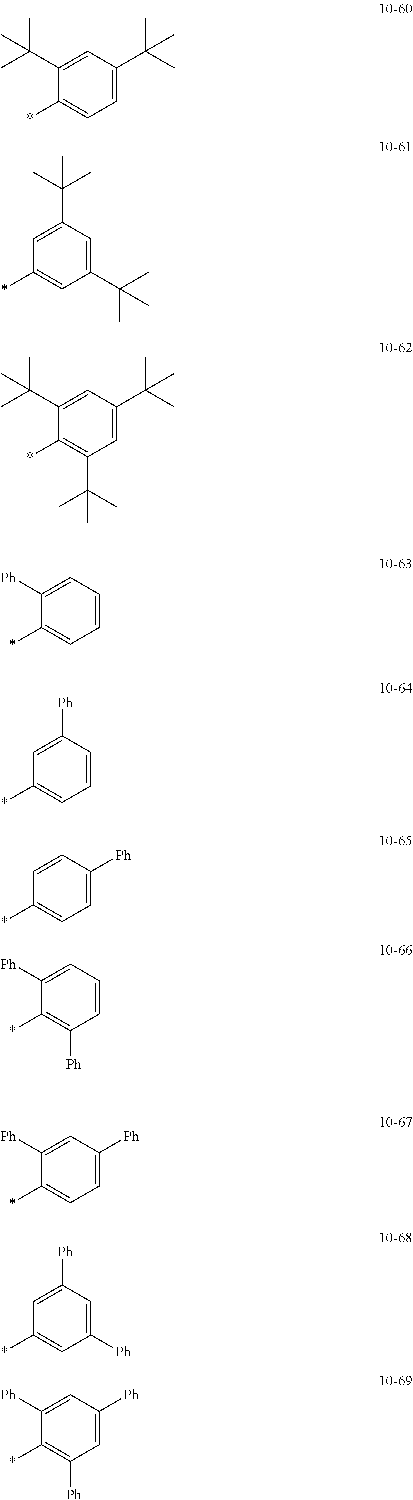

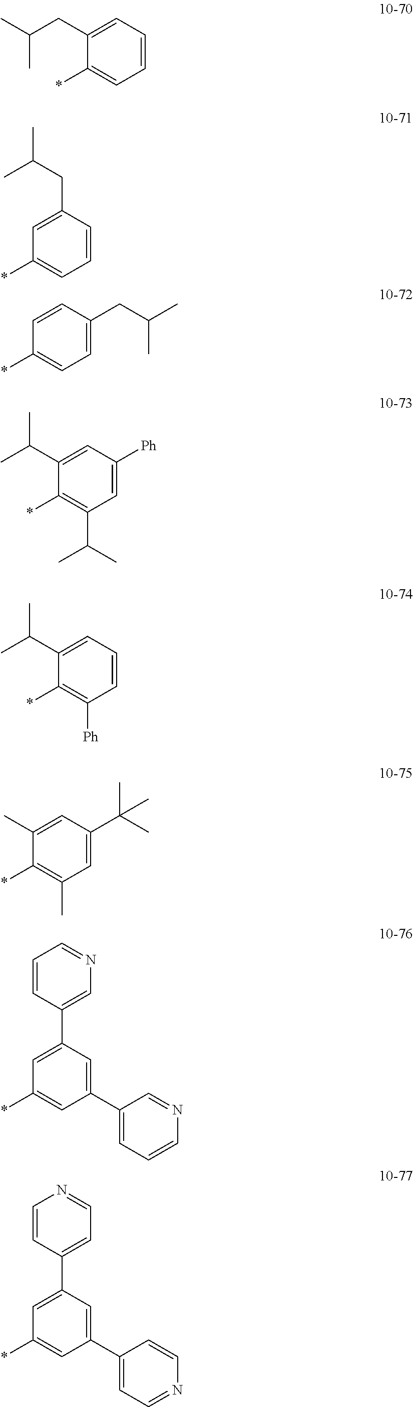

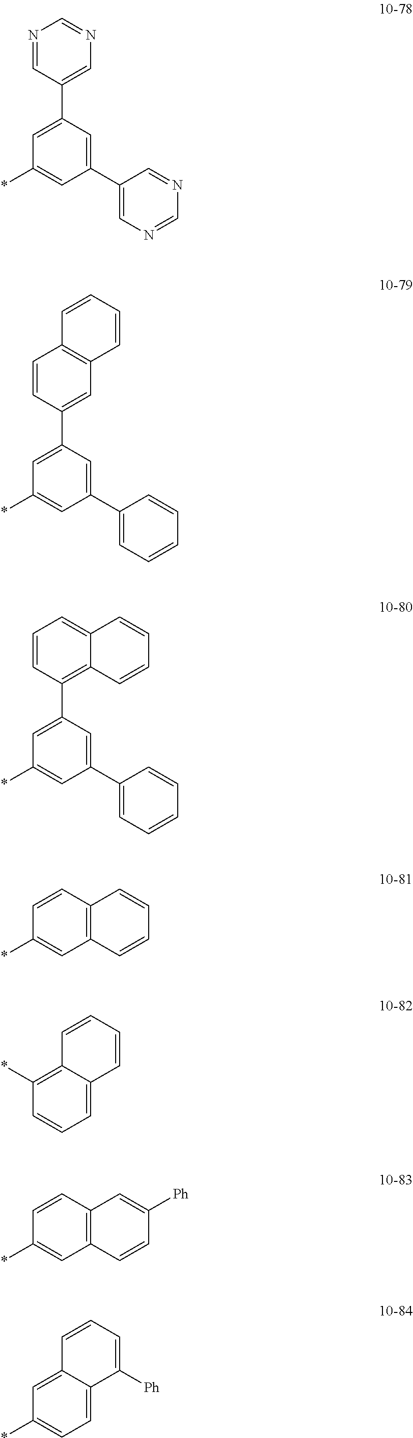

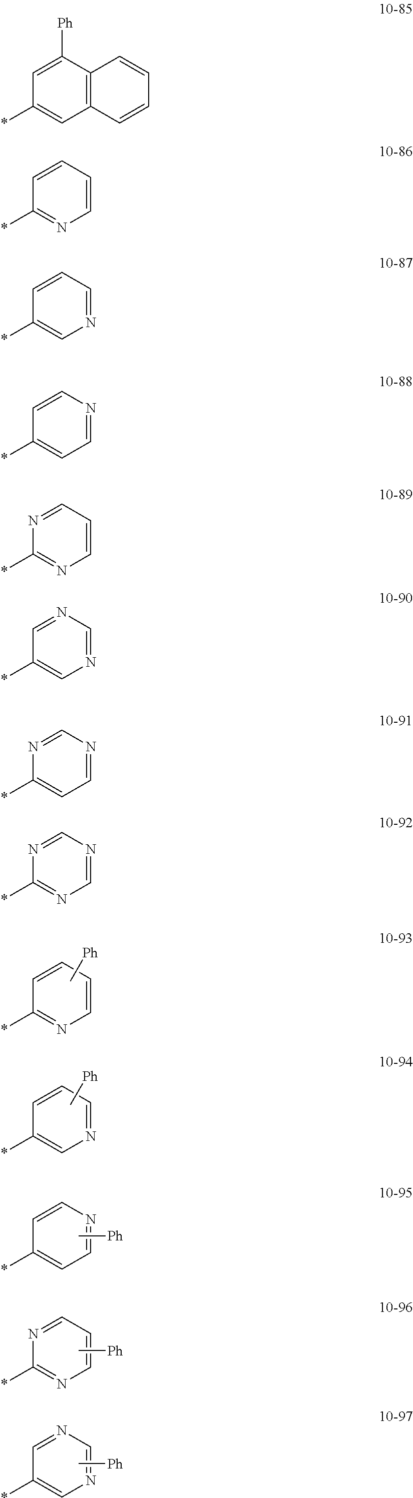

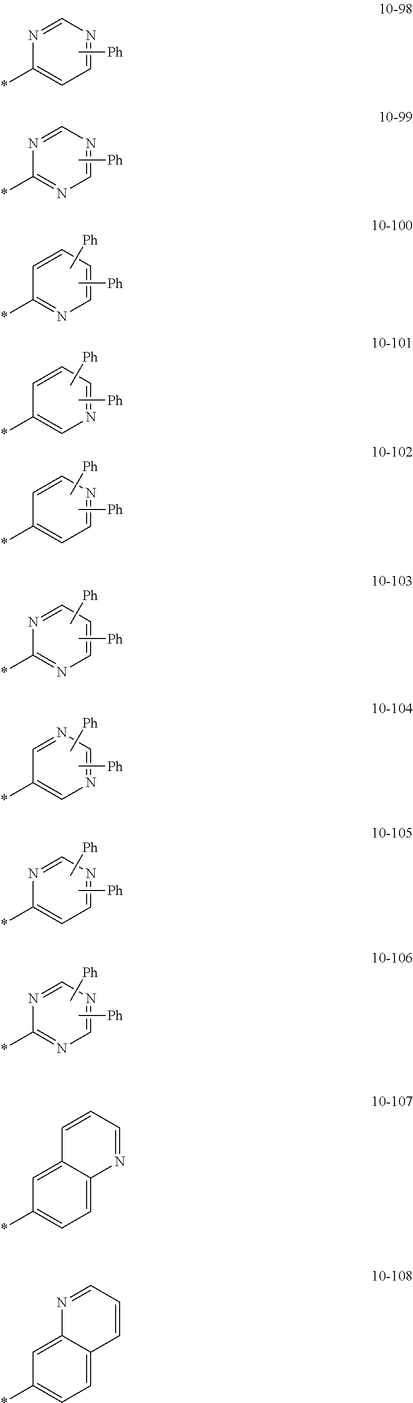

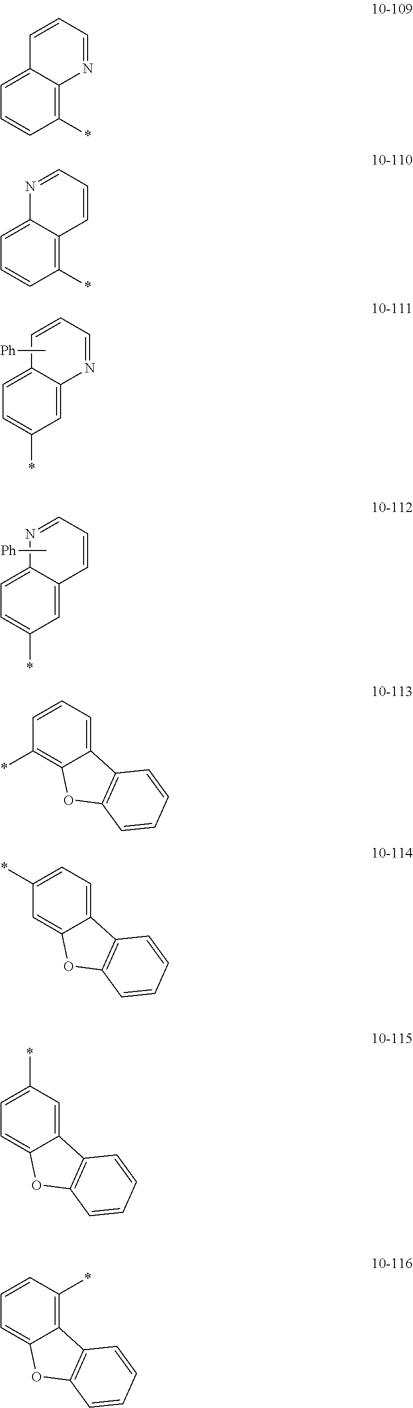

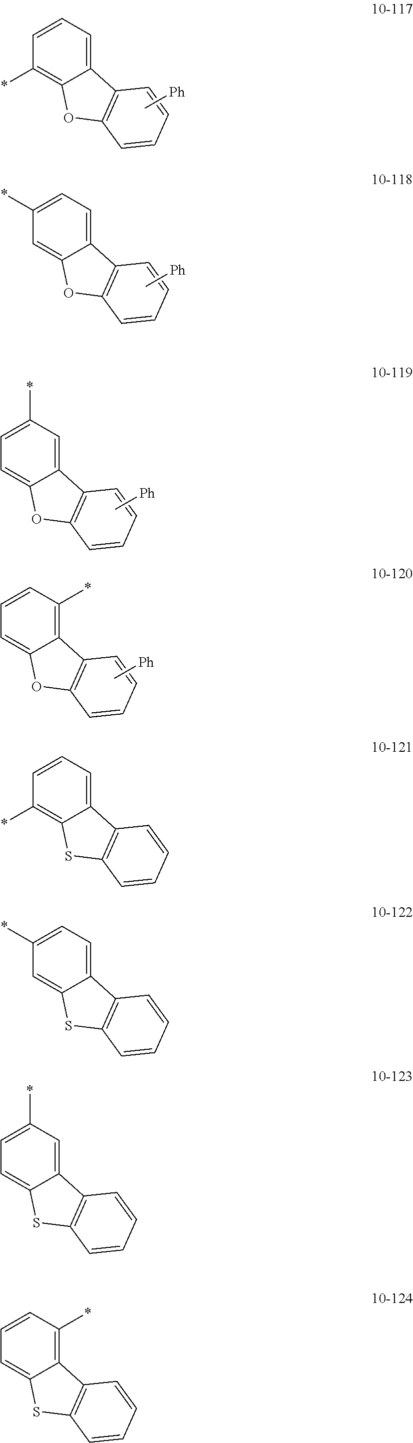

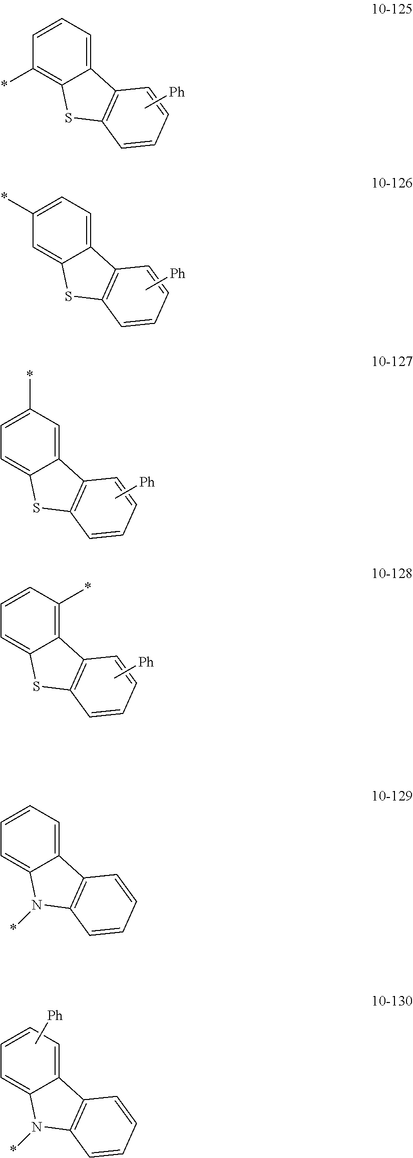

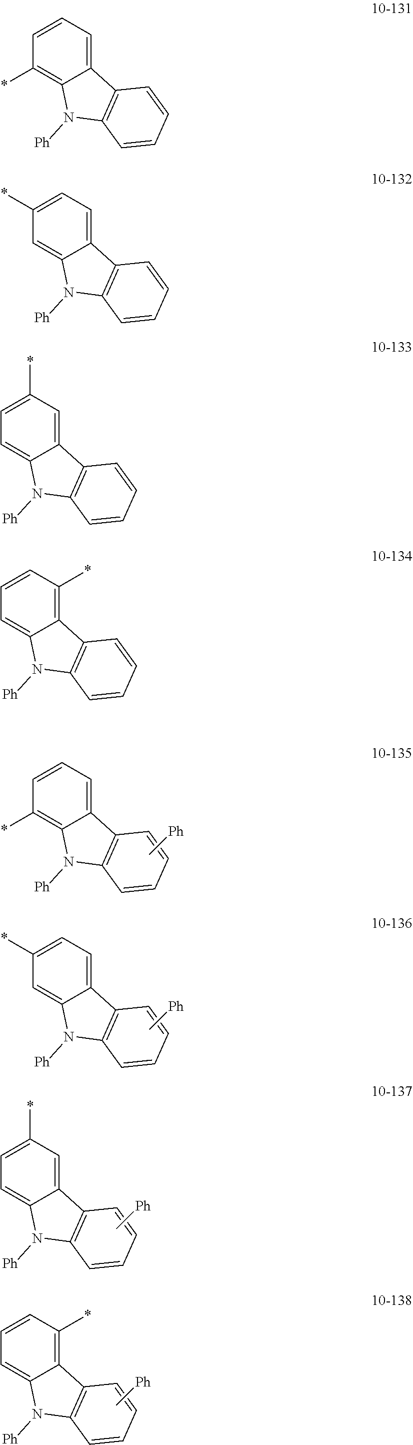

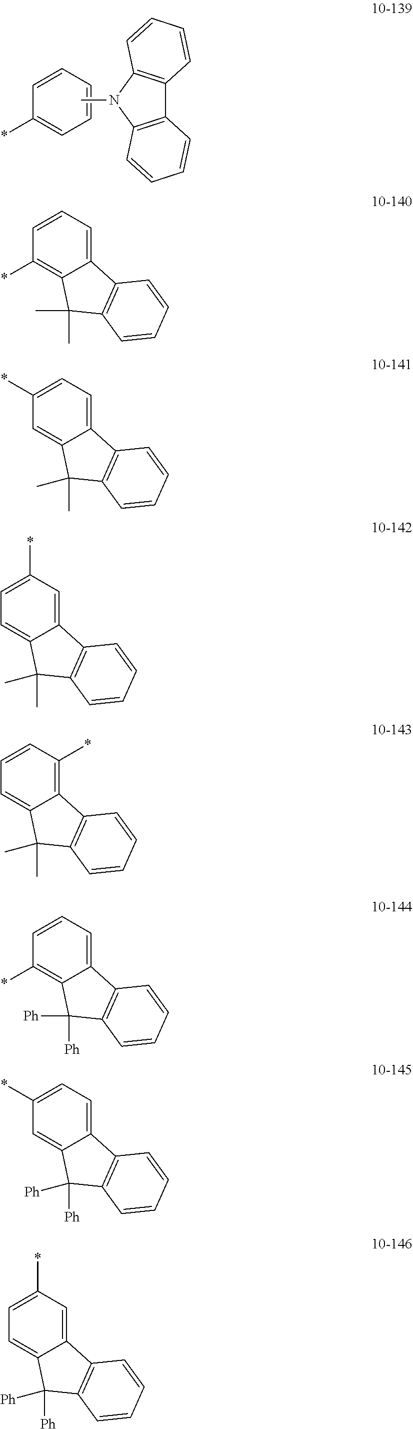

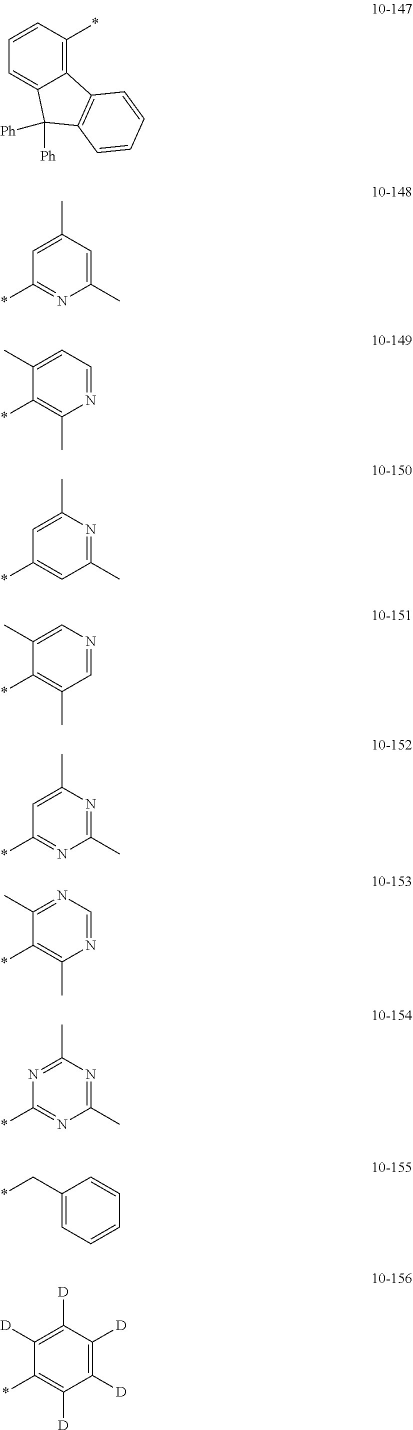

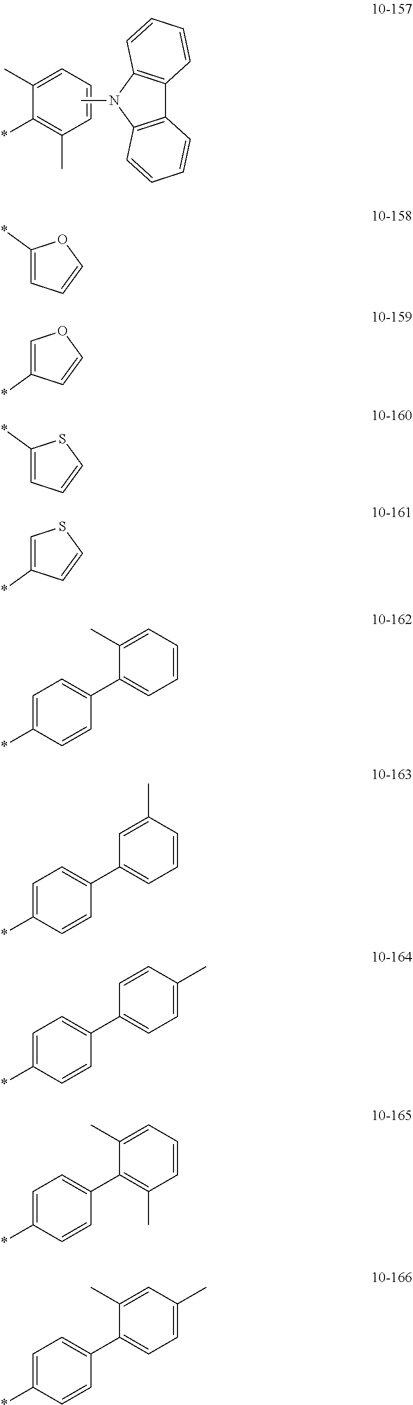

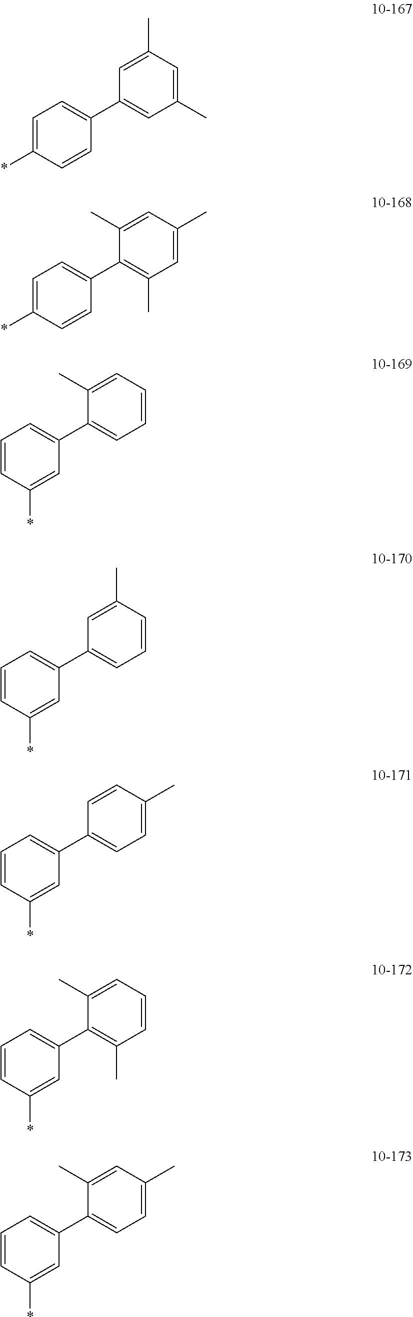

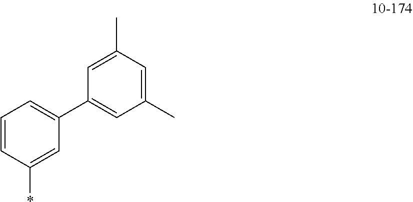 [SMILES: *c1cccc(-c2cc(C)cc(C)c2)c1]

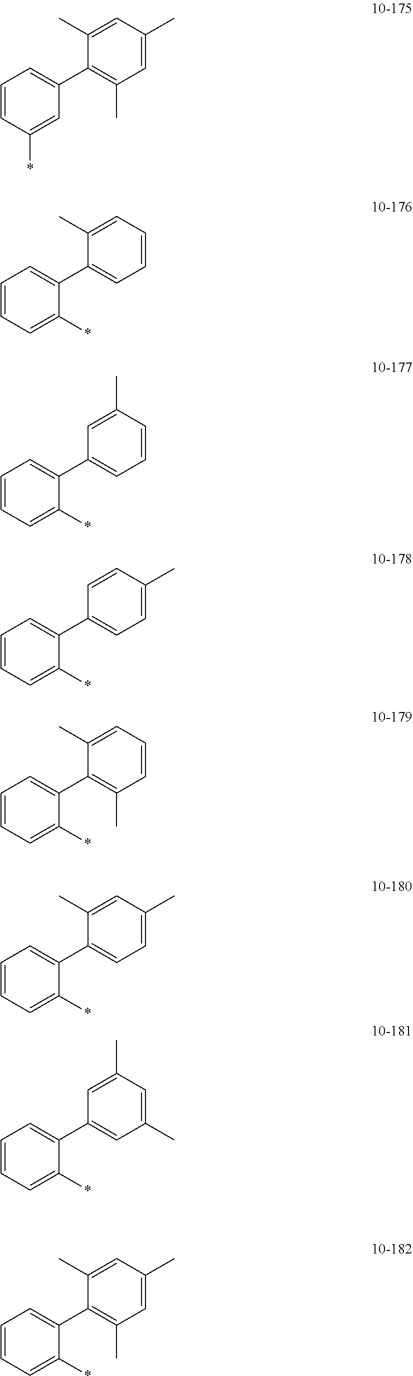

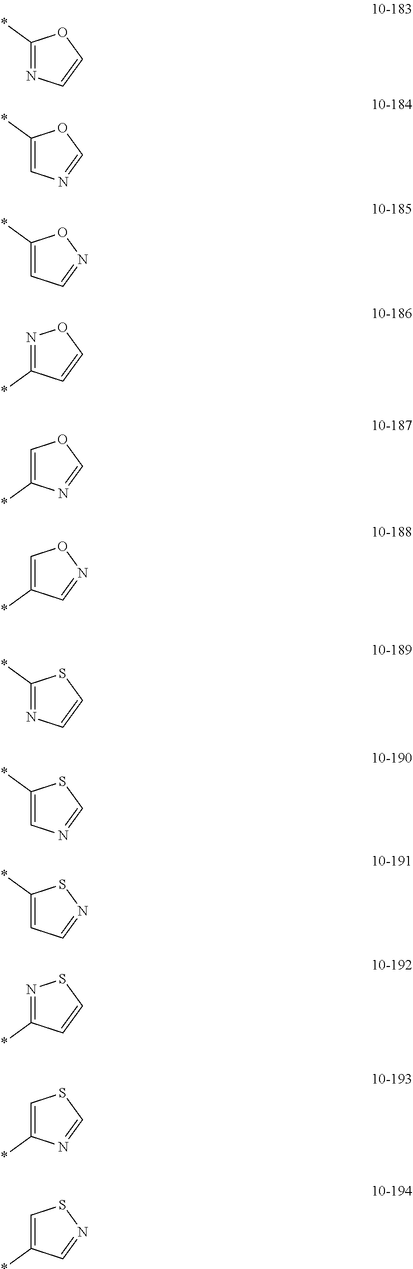

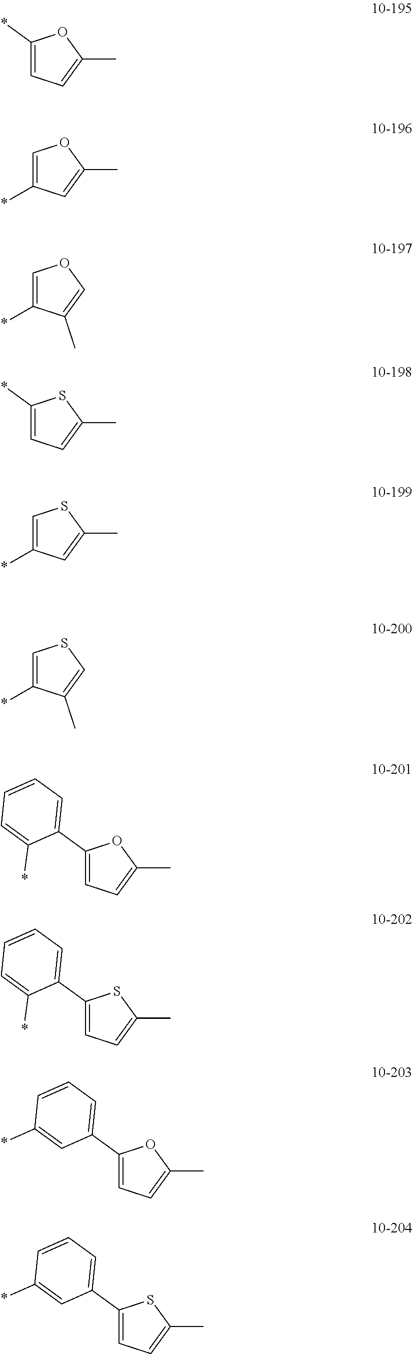

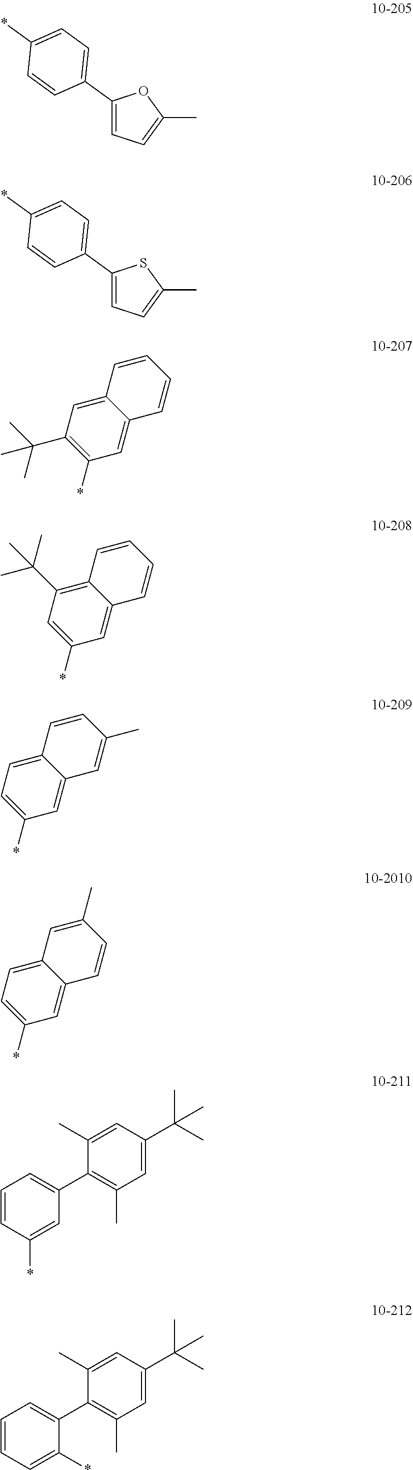

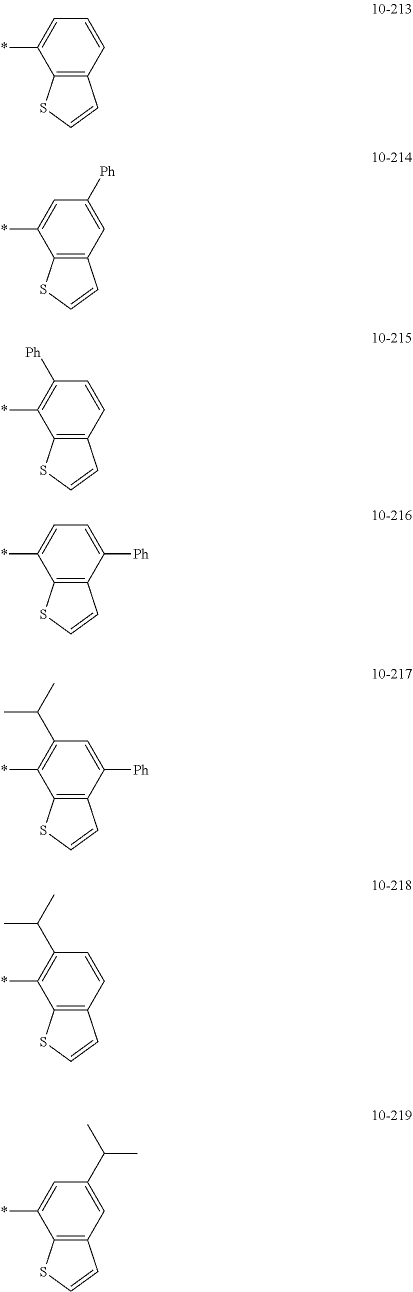

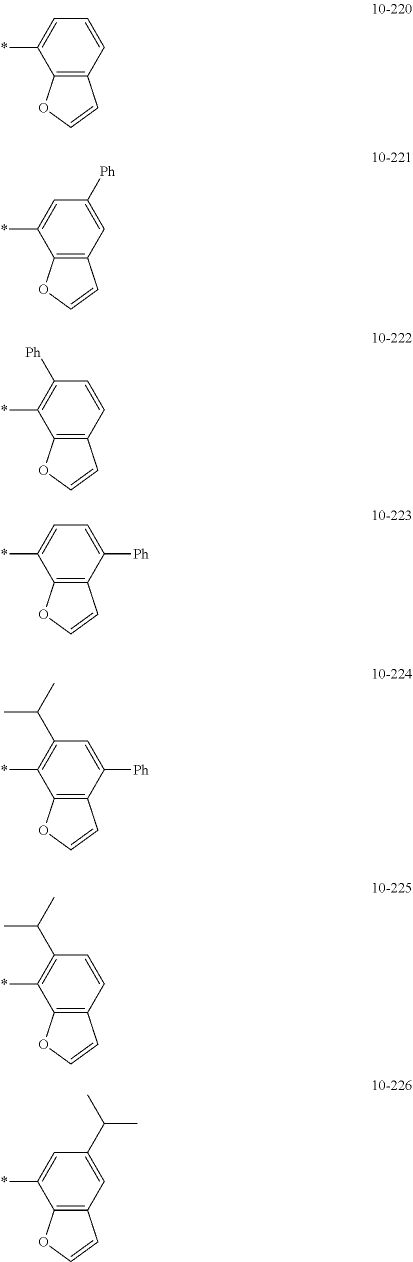

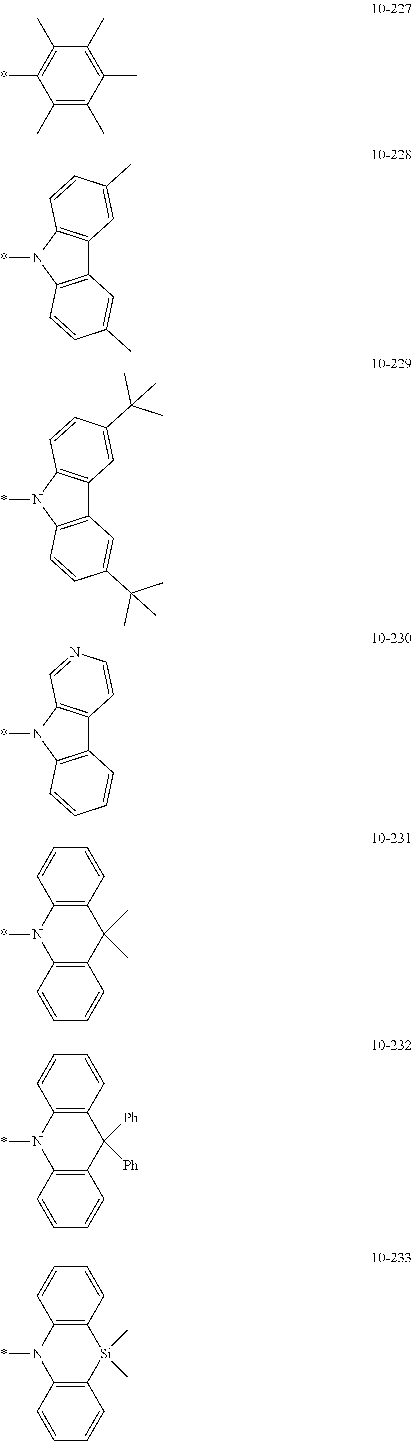

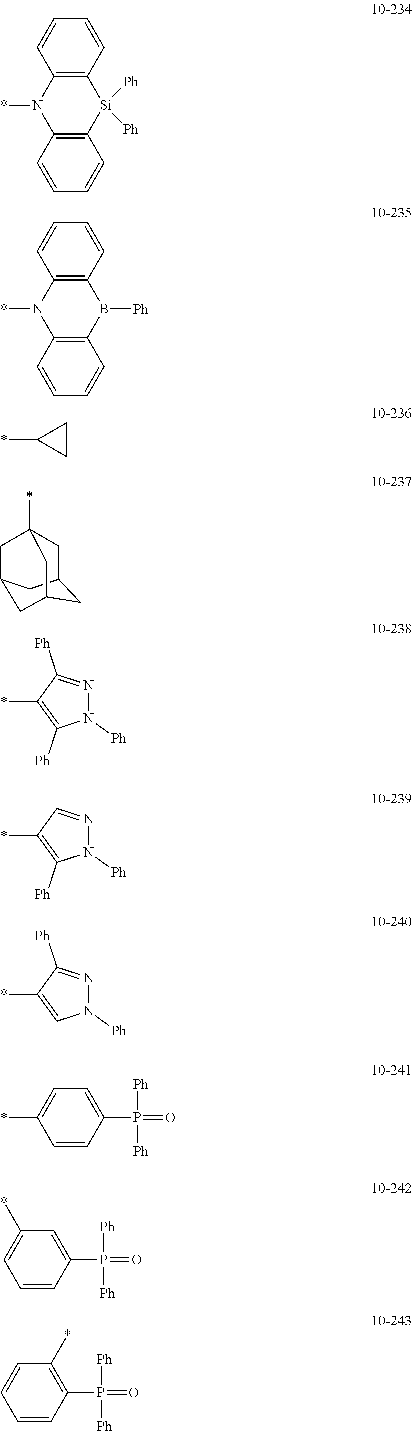

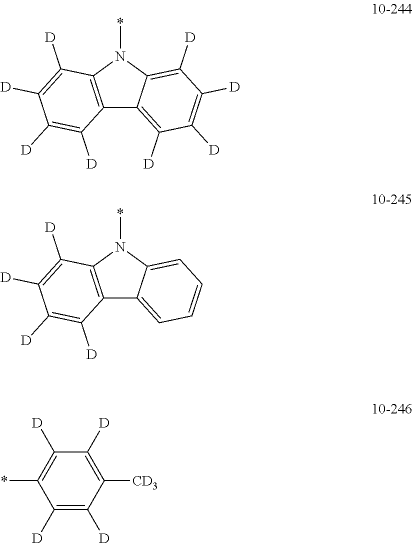 [SMILES: *n1c2c([2H])c([2H])c([2H])c([2H])c2c2c([2H])c([2H])c([2H])c([2H])c21 ; *n1c2ccccc2c2c([2H])c([2H])c([2H])c([2H])c21 ; *c1c([2H])c([2H])c(C([2H])([2H])[2H])c([2H])c1[2H]]

In Formulae 9-1 to 9-19 and 10-1 to 10-246, * indicates a binding site to a neighboring atom, “Ph” represents a phenyl group, and “TMS” represents a trimethylsilyl group.

In Formulae 20-1 to 20-5, a71 to a74 respectively indicate the number of R₇₁(s) to the number of R₇₄(s), and may each independently be an integer from 0 to 20. When a71 is 2 or more, two or more of R₇₁(s) may be identical to or different from each other, when a72 is 2 or more, two or more of R₇₂(s) may be identical to or different from each other, when a73 is 2 or more, two or more of R₇₃(s) may be identical to or different from each other, and when a74 is 2 or more, two or more of R₇₄(s) may be identical to or different from each other. In embodiment, a71 to a74 may each independently be an integer from 0 to 8.

In an embodiment, in Formula 30, a group represented by *-(L₅₁)_{b51}-R₅₁ and a group represented by *-(L₅₂)_{b52}-R₅₂ may each not be a phenyl group.

In an embodiment, in Formula 30, a group represented by *-(L₅₁)_{b51}-R₅₁ and a group represented by *-(L₅₂)_{b52}-R₅₂ may be identical to each other.

In an embodiment, in Formula 30, a group represented by *-(L₅₁)_{b51}-R₅₁ and a group represented by *-(L₅₂)_{b52}-R₅₂ may be different from each other.

In an embodiment, in Formula 30, b51 and b52 may each independently be 1, 2, or 3, and L₅₁ and L₅₂ may each independently be a benzene group, a pyridine group, a pyrimidine group, a pyridazine group, a pyrazine group, or a triazine group, each unsubstituted or substituted with at least one R₁₀ₐ.

In an embodiment, in Formula 30, R₅₁ and R₅₂ may each independently be: a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —C(Q₁)(Q₂)(Q₃), or —Si(Q₁)(Q₂)(Q₃), and

Q₁ to Q₃ may each independently be a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof.

In an embodiment, in Formula 30,

a group represented by *-(L₅₁)_{b51}-R₅₁ may be a group represented by one of Formulae CY51-1 to CY51-26, and/or

a group represented by *-(L₅₂)_{b52}-R₅₂ may be a group represented by one of Formulae CY52-1 to CY52-26, and/or

a group represented by *-(L₅₃)_{b53}-R₅₃ may be a group represented by one of Formulae CY53-1 to CY53-27, —C(Q₁)(Q₂)(Q₃), or —Si(Q₁)(Q₂)(Q₃), wherein Q₁ to Q₃ may each be the same as described herein:

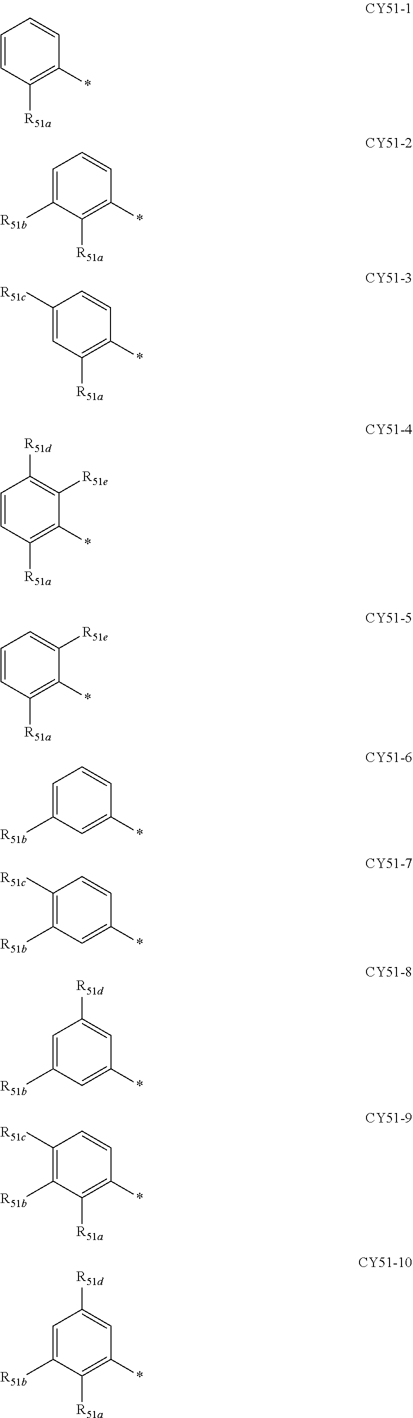

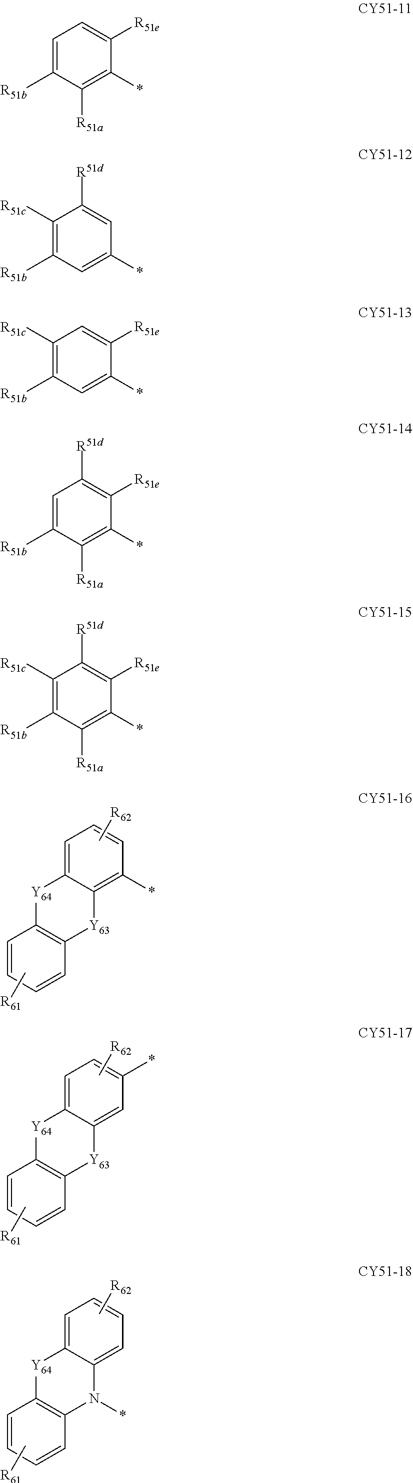

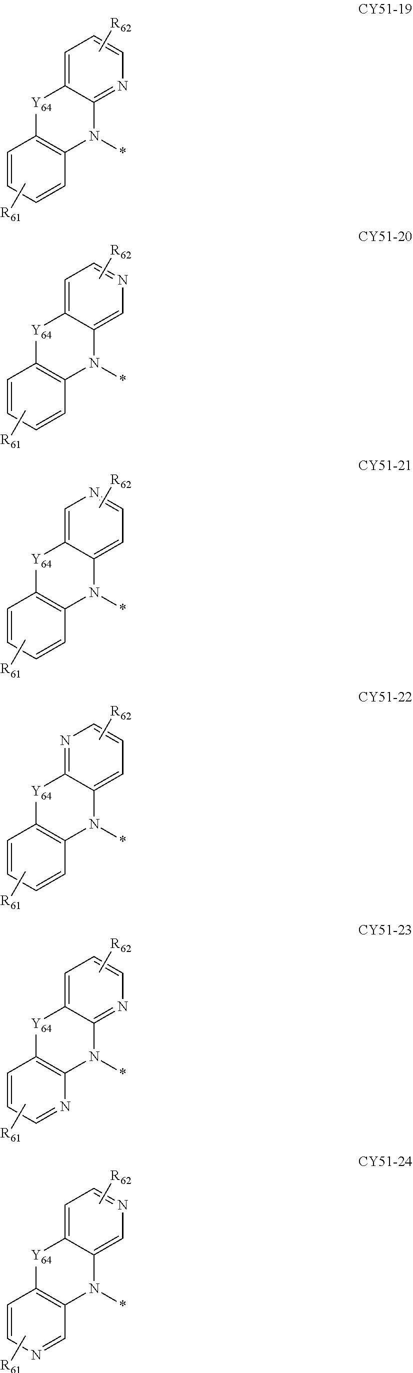

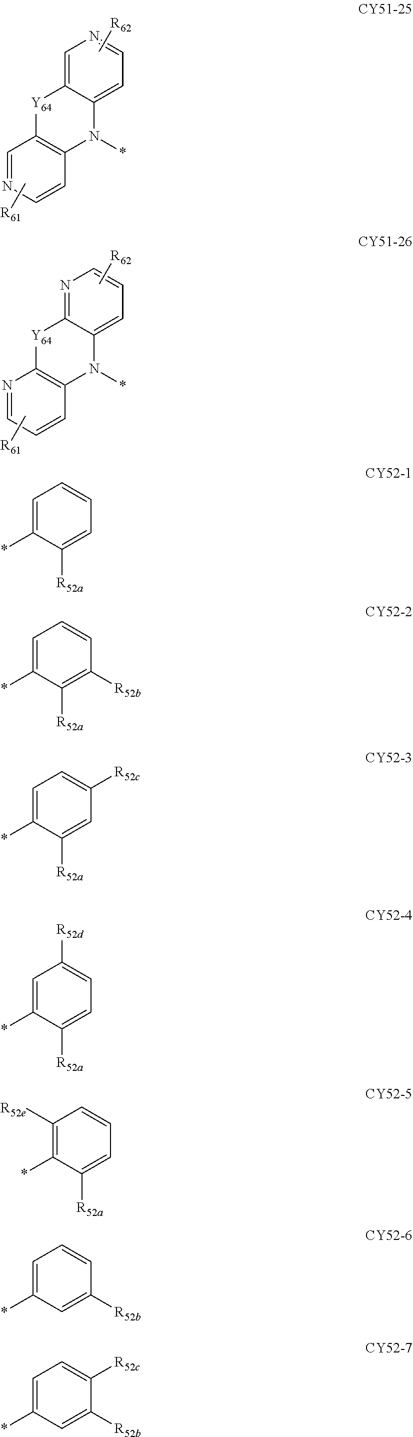

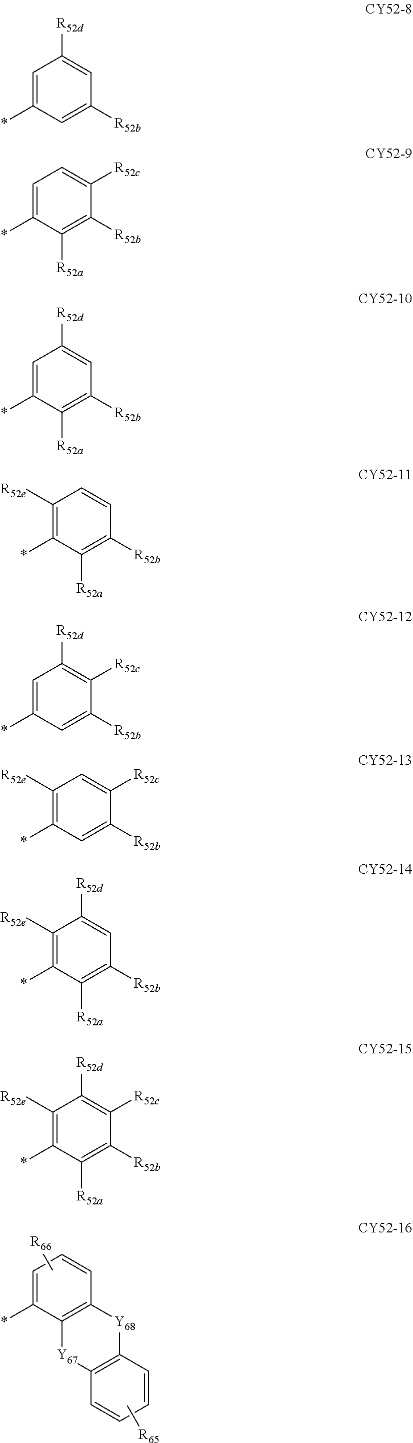

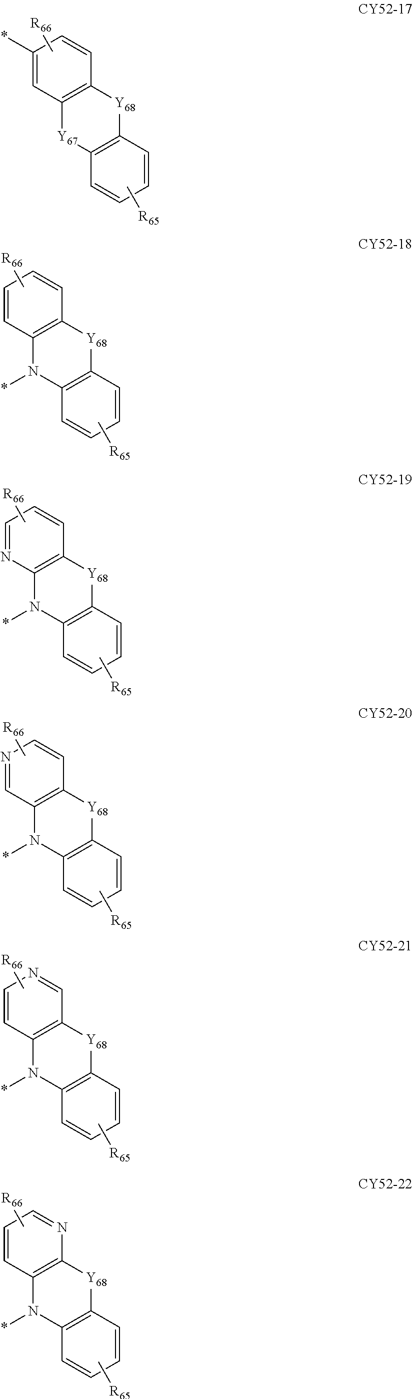

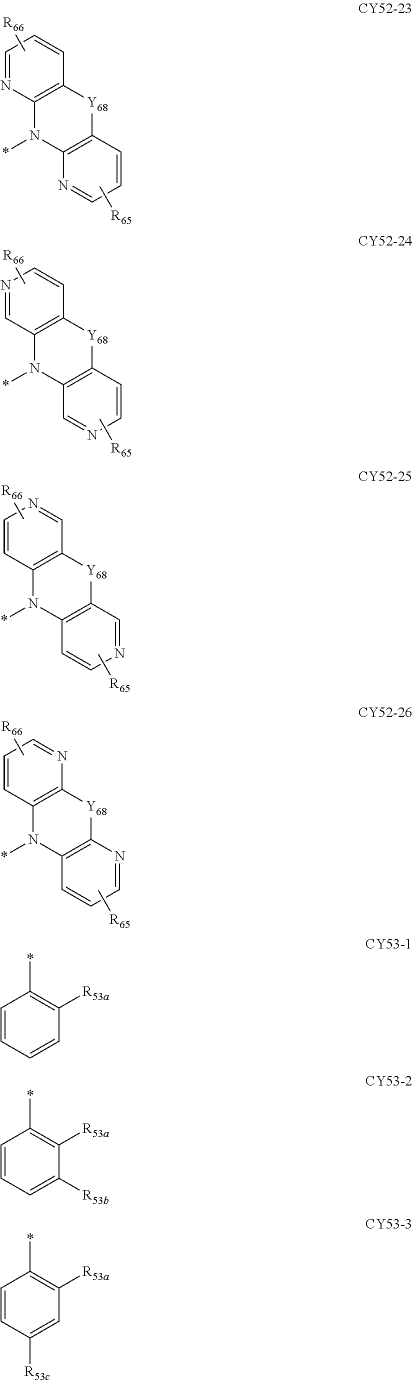

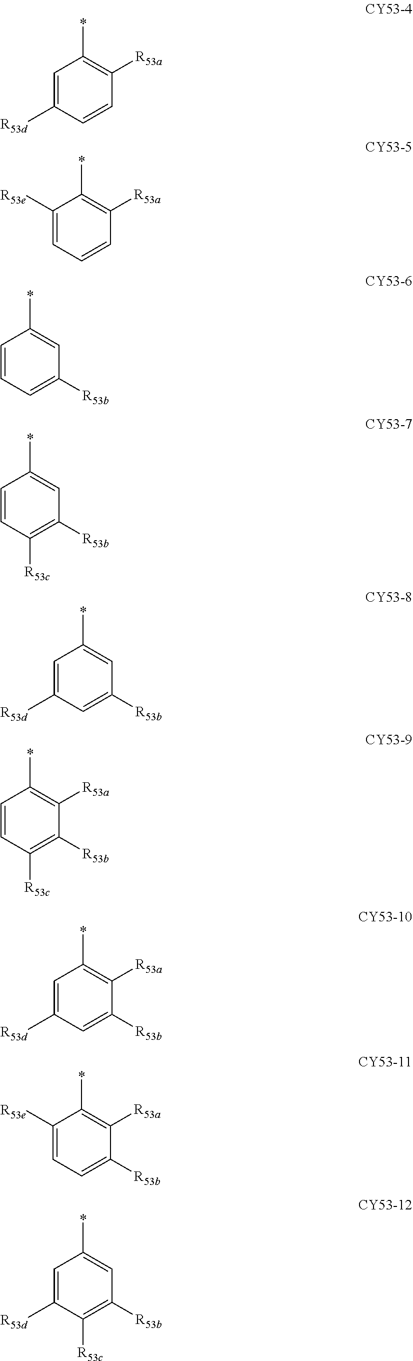

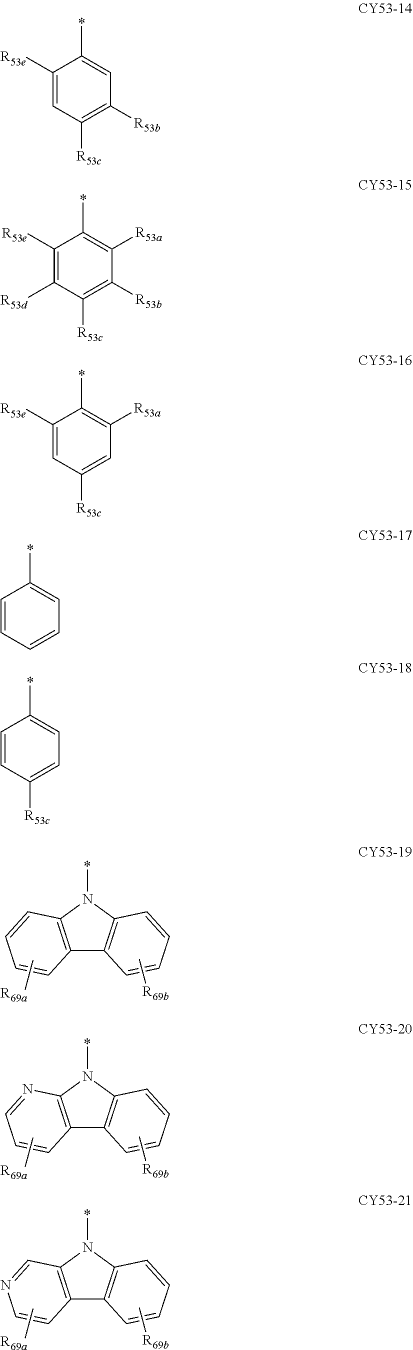

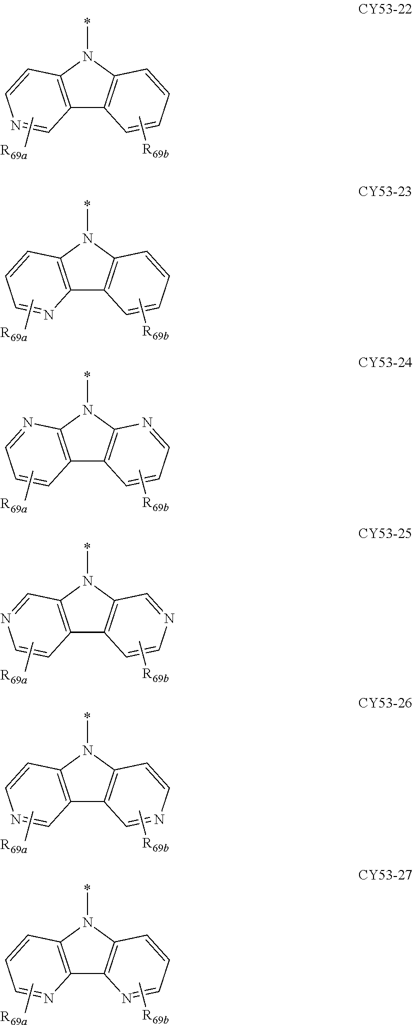

In Formulae CY51-1 to CY51-26, CY52-1 to CY52-26, and CY53-1 to CY53-27,

Y₆₃ may be a single bond, O, S, N(R₆₃), B(R₆₃), C(R₆₃ₐ)(R_{63b}), or Si(R₆₃ₐ)(R_{63b}),

Y₆₄ may be a single bond, O, S, N(R₆₄), B(R₆₄), C(R₆₄ₐ)(R_{64b}), or Si(R₆₄ₐ)(R_{64b}),

Y₆₇ may be a single bond, O, S, N(R₆₇), B(R₆₇), C(R₆₇ₐ)(R_{67b}), or Si(R₆₇ₐ)(R_{67b}),

Y₆₈ may be a single bond, O, S, N(R₆₈), B(R₆₈), C(R₆₈ₐ)(R_{68b}), or Si(R₆₈ₐ)(R_{68b}),

Y₆₃ and Y₆₄ in Formulae CY51-16 and CY51-17 may not each be a single bond at the same time,

Y₆₇ and Y₆₈ in Formulae CY52-16 and CY52-17 may not each be a single bond at the same time,

R₅₁ₐ to R₅₁ₑ, R₆₁ to R₆₄, R₆₃ₐ, R_{63b}, R₆₄ₐ, and R_{64b} may each independently be the same as described in connection with R₅₁, wherein R₅₁ₐ to R₅₁ₑ may not each be hydrogen,

R₅₂ₐ to R₅₂ₑ, R₆₅ to R₆₈, R₆₇ₐ, R_{67b}, R₆₈ₐ, and R_{68b} may each independently be the same as described in connection with R₅₂, wherein R₅₂ₐ to R₅₂ₑ may not each be hydrogen,

R₅₃ₐ to R₅₃ₑ, R₆₉ₐ, and R_{69b} may each independently be the same as described in connection with R₅₃, wherein R₅₃ₐ to R₅₃ₑ may not each be hydrogen, and

* indicates a binding site to a neighboring atom.

In embodiments, in Formulae CY51-1 to CY51-26 and Formulae CY52-1 to 52-26, R₅₁ₐ to R₅₁ₑ and R₅₂ₐ to R₅₂ₑ may each independently be:

a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, an azafluorenyl group, an azadibenzosilolyl group, or a group represented by Formula 91, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, a C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a phenyl group, a biphenyl group, a C₁-C₁₀ alkylphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, an isobenzothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, or any combination thereof; or

—C(Q₁)(Q₂)(Q₃) or —Si(Q₁)(Q₂)(Q₃),

wherein Q₁ to Q₃ may each independently be a phenyl group, a naphthyl group, a pyridinyl group, a pyrimidinyl group, a pyridazinyl group, a pyrazinyl group, or a triazinyl group, each unsubstituted or substituted with deuterium, a C₁-C₁₀ alkyl group, a phenyl group, a biphenyl group, a pyridinyl group, a pyrimidinyl group, a pyridazinyl group, a pyrazinyl group, a triazinyl group, or any combination thereof,

in Formulae CY51-16 and CY51-17, Y₆₃ may be O or S and Y₆₄ may be Si(R₆₄ₐ)(R_{64b}); or Y₆₃ may be Si(R₆₃ₐ)(R_{63b}) and Y₆₄ may be O or S, and

in Formulae CY52-16 and CY52-17, Y₆₇ may be O or S, and Yes may be Si(R₆₈ₐ)(R_{68b}); or Y₆₇ may be Si(R₆₇ₐ)(R_{67b}), and Yes may be O or S.

In an embodiment, in Formulae 20-1 to 20-5, L₈₁ to L₈₅ may each independently be:

a single bond; or

*—C(Q₄)(Q₅)*′ or *—Si(Q₄)(Q₅)-*′; or

a benzene group, a naphthalene group, an anthracene group, a phenanthrene group, a triphenylene group, a pyrene group, a chrysene group, a cyclopentadiene group, a furan group, a thiophene group, a silole group, an indene group, a fluorene group, an indole group, a carbazole group, a benzofuran group, a dibenzofuran group, a benzothiophene group, a dibenzothiophene group, a benzosilole group, a dibenzosilole group, an azafluorene group, an azacarbazole group, an azadibenzofuran group, an azadibenzothiophene group, an azadibenzosilole group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isooxazole group, a thiazole group, an isothiazole group, an oxadiazole group, a thiadiazole group, a benzopyrazole group, a benzimidazole group, a benzoxazole group, a benzothiazole group, a benzoxadiazole group, or a benzothiadiazole group, each unsubstituted or substituted with deuterium, —F, —Cl, —Br, —I, a hydroxyl group, a cyano group, a nitro group, a C₁-C₂₀ alkyl group, a C₁-C₂₀ alkoxy group, a phenyl group, a naphthyl group, a pyridinyl group, a pyrimidinyl group, a triazinyl group, a fluorenyl group, a dimethylfluorenyl group, a diphenylfluorenyl group, a carbazolyl group, a phenylcarbazolyl group, a dibenzofuranyl group, a dibenzothiophenyl group, a dibenzosilolyl group, a dimethyldibenzosilolyl group, a diphenyldibenzosilolyl group, —O(Q₃₁), —S(Q₃₁), —Si(Q₃₁)(Q₃₂)(Q₃₃), —N(Q₃₁)(Q₃₂), —B(Q₃₁)(Q₃₂), —P(Q₃₁)(Q₃₂), —C(═O)(Q₃₁), —S(═O)₂(Q₃₁), —P(═O)(Q₃₁)(Q₃₂), or any combination thereof,

wherein Q₄, Q₅, and Q₃₁ to Q₃₃ may each independently be hydrogen, deuterium, a C₁-C₂₀ alkyl group, a C₁-C₂₀ alkoxy group, a phenyl group, a biphenyl group, a terphenyl group, a pyridinyl group, a pyrimidinyl group, a pyridazinyl group, a pyrazinyl group, or a triazinyl group.

For example, in Formula 402, X₄₀₁ may be nitrogen and X₄₀₂ may be carbon, or each of X₄₀₁ and X₄₀₂ may be nitrogen.

In embodiments, in Formula 401, when xc1 is 2 or more, two ring A₄₀₁(s) in two or more of L₄₀₁(s) may optionally be bonded to each other via T₄₀₂, which is a linking group, and two ring A₄₀₂(s) in two or more of L₄₀₁(s) may optionally be bonded to each other via T₄₀₃, which is a linking group (see Compounds PD1 to PD4 and PD7). T₄₀₂ and T₄₀₃ may each independently be the same as described in connection with T₄₀₁.

In Formula 401, L₄₀₂ may be an organic ligand. For example, L₄₀₂ may include a halogen group, a diketone group (for example, an acetylacetonate group), a carboxylic acid group (for example, a picolinate group), —C(═O), an isonitrile group, a —CN group, a phosphorus group (for example, a phosphine group, a phosphite group, etc.), or any combination thereof.

### Detailed Examples of Second Compound to Fourth Compound

In an embodiment, the second compound may include at least one of Compounds HTH1 to HTH53:

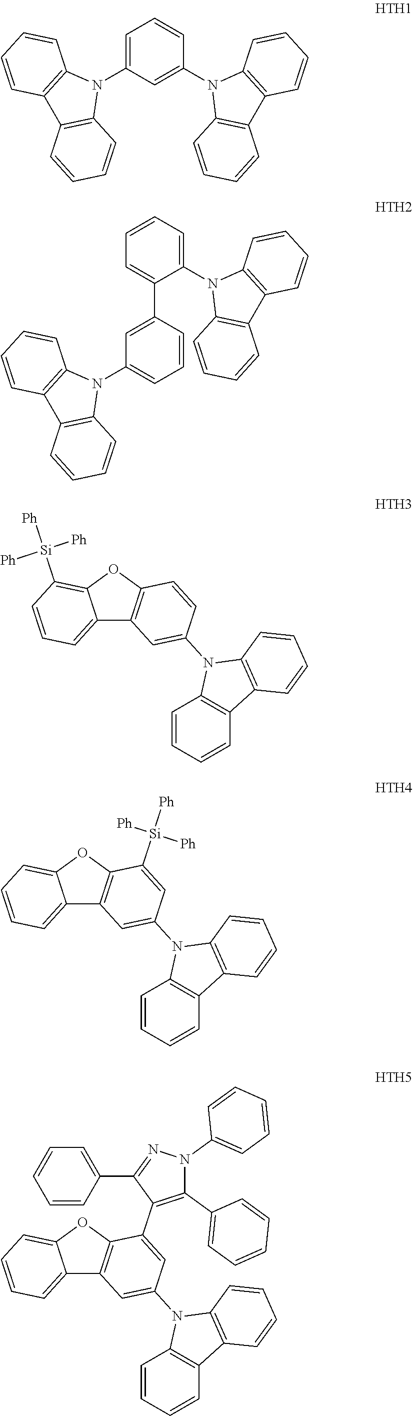 [SMILES: c1cc(-n2c3ccccc3c3ccccc32)cc(-n2c3ccccc3c3ccccc32)c1 ; c1cc(-c2ccccc2-n2c3ccccc3c3ccccc32)cc(-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1 ; c1ccc(-c2nn(-c3ccccc3)c(-c3ccccc3)c2-c2cc(-n3c4ccccc4c4ccccc43)cc3c2oc2ccccc23)cc1]

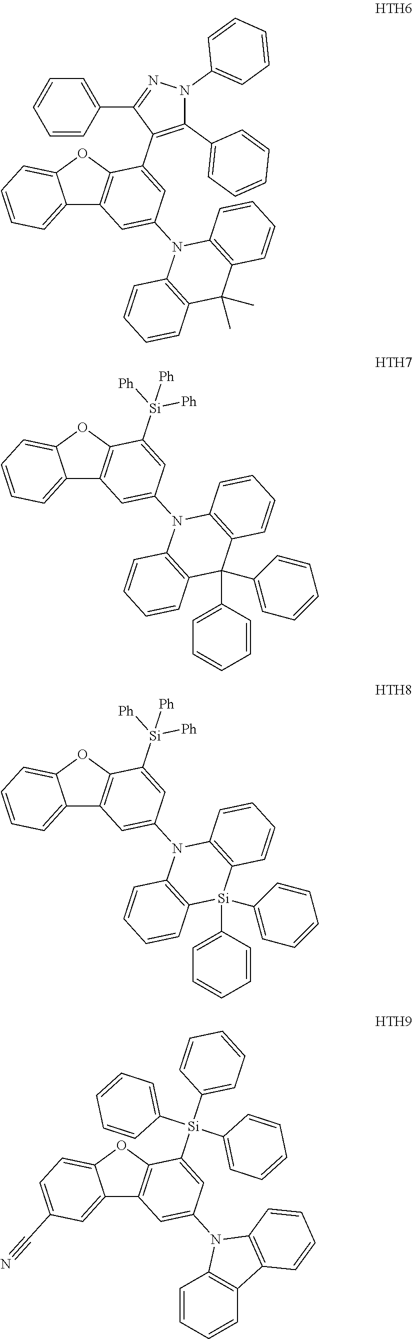

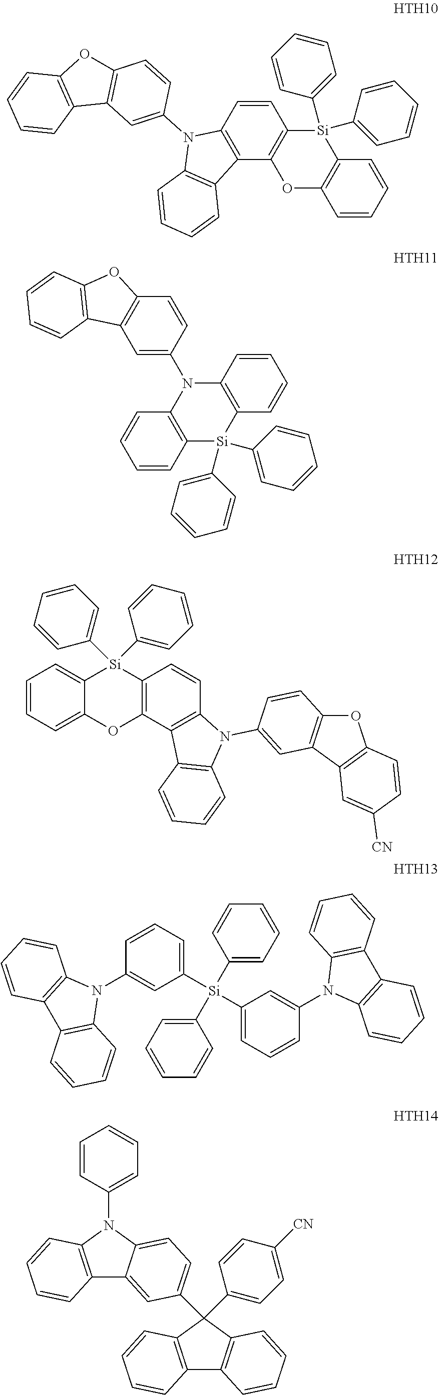

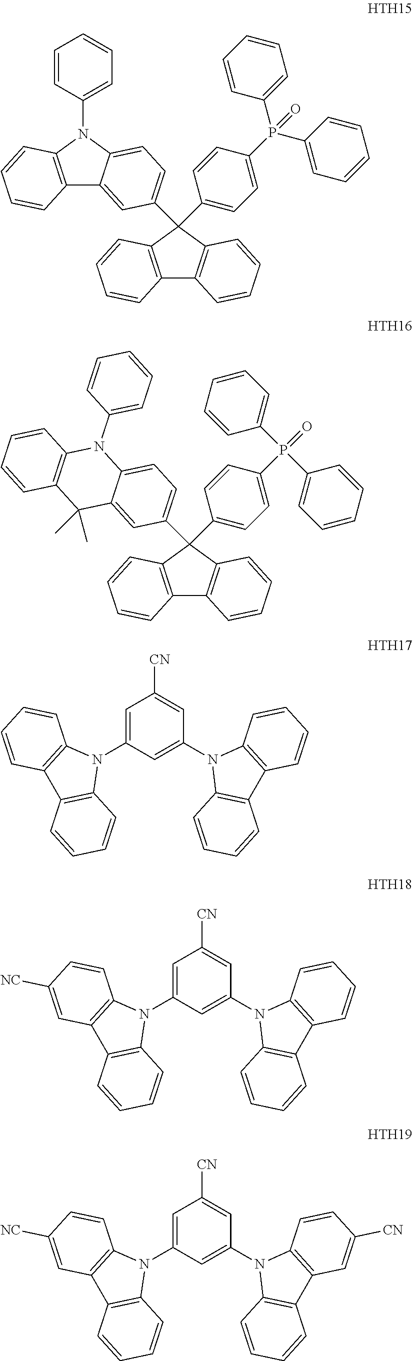

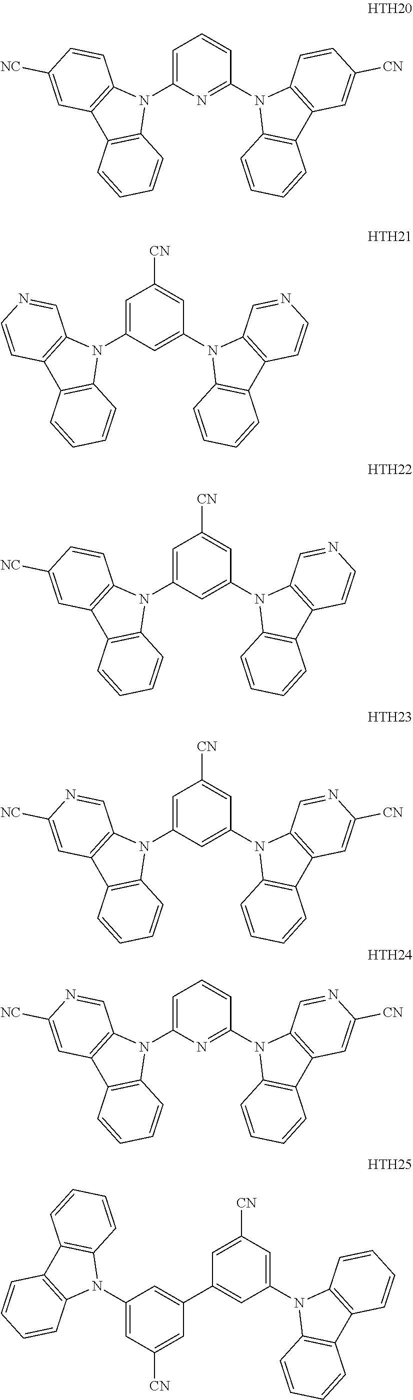 [SMILES: N#Cc1ccc2c(c1)c1ccccc1n2-c1cccc(-n2c3ccccc3c3cc(C#N)ccc32)n1 ; N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1 ; N#Cc1cc(-c2cc(C#N)cc(-n3c4ccccc4c4ccccc43)c2)cc(-n2c3ccccc3c3ccccc32)c1]

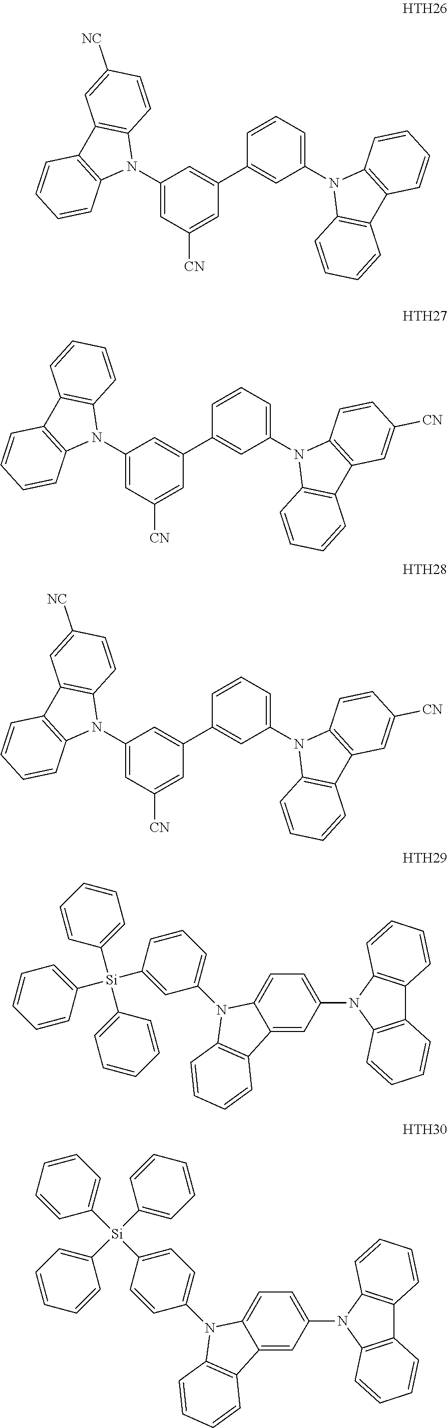 [SMILES: N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1 ; c1ccc([Si](c2ccccc2)(c2ccccc2)c2cccc(-n3c4ccccc4c4cc(-n5c6ccccc6c6ccccc65)ccc43)c2)cc1 ; c1ccc([Si](c2ccccc2)(c2ccccc2)c2ccc(-n3c4ccccc4c4cc(-n5c6ccccc6c6ccccc65)ccc43)cc2)cc1]

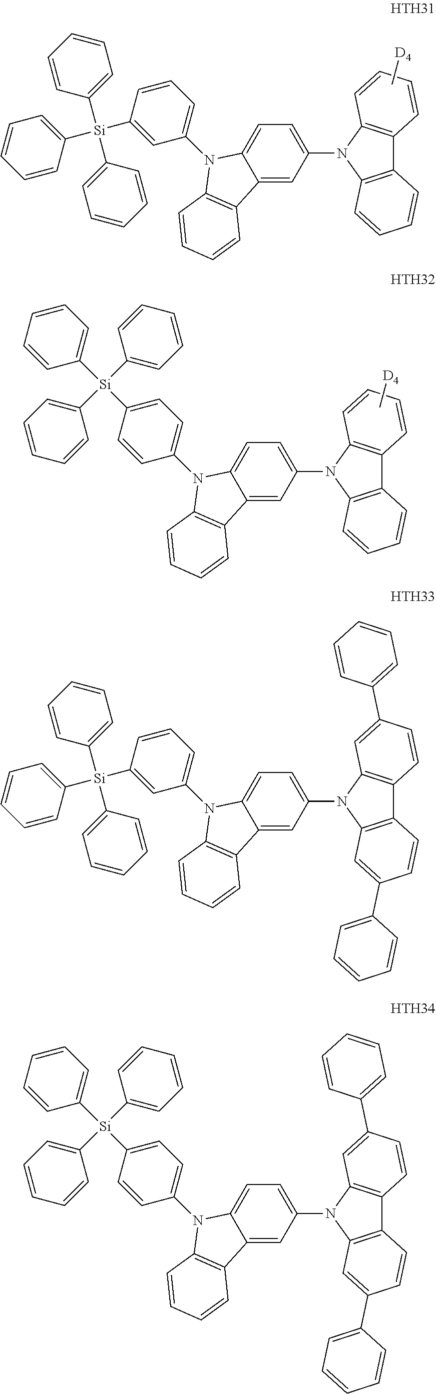

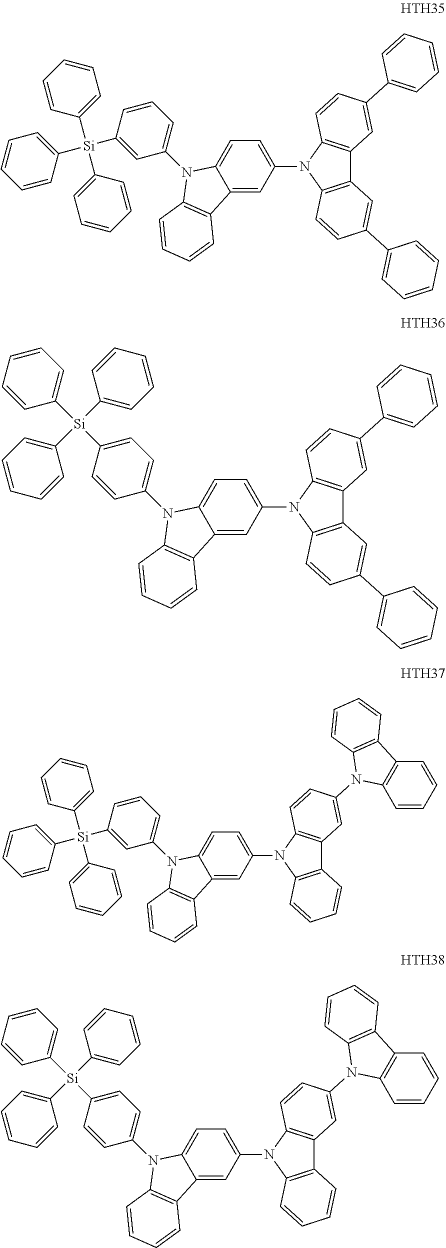 [SMILES: c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1 ; c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1]

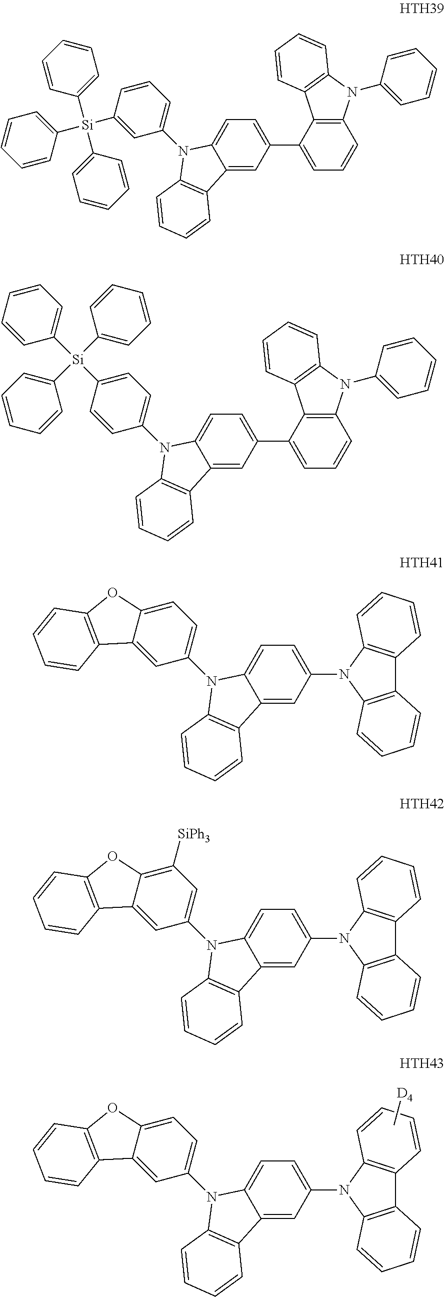

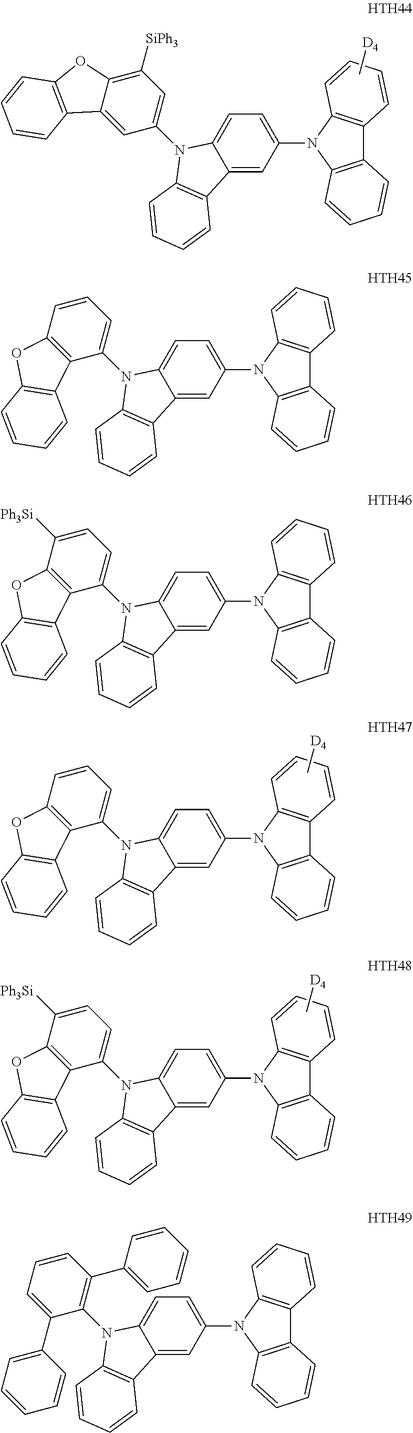

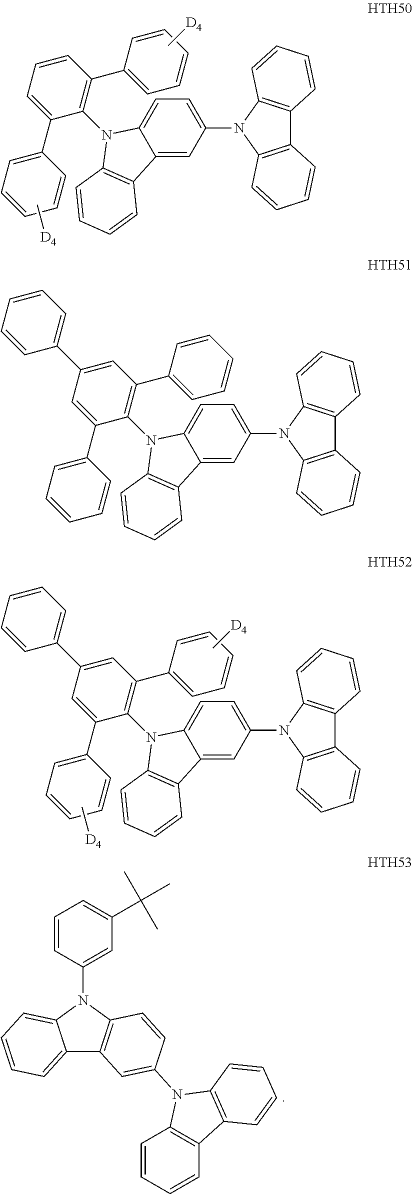

In an embodiment, the third compound may include at least one of Compounds ETH1 to ETH85:

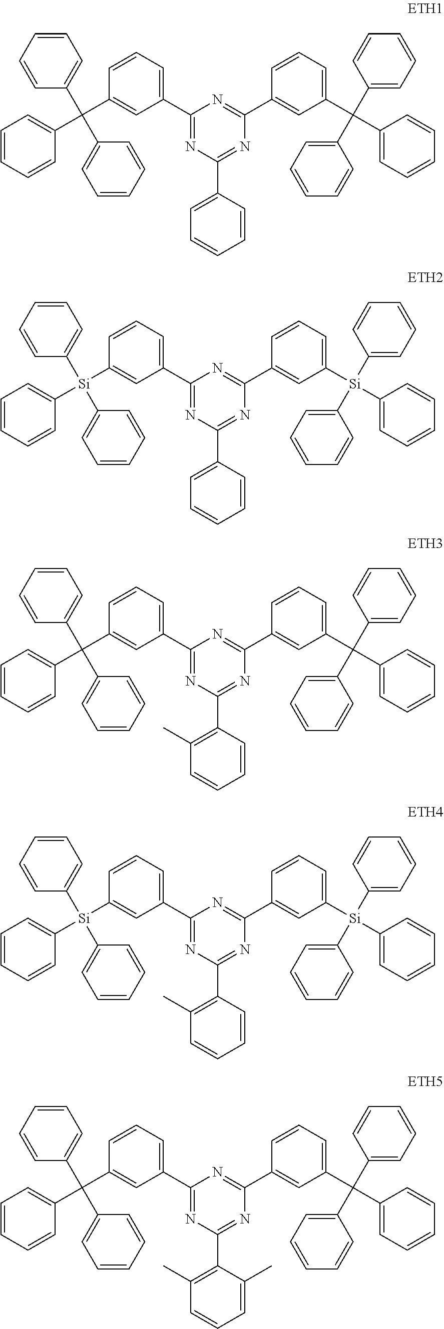

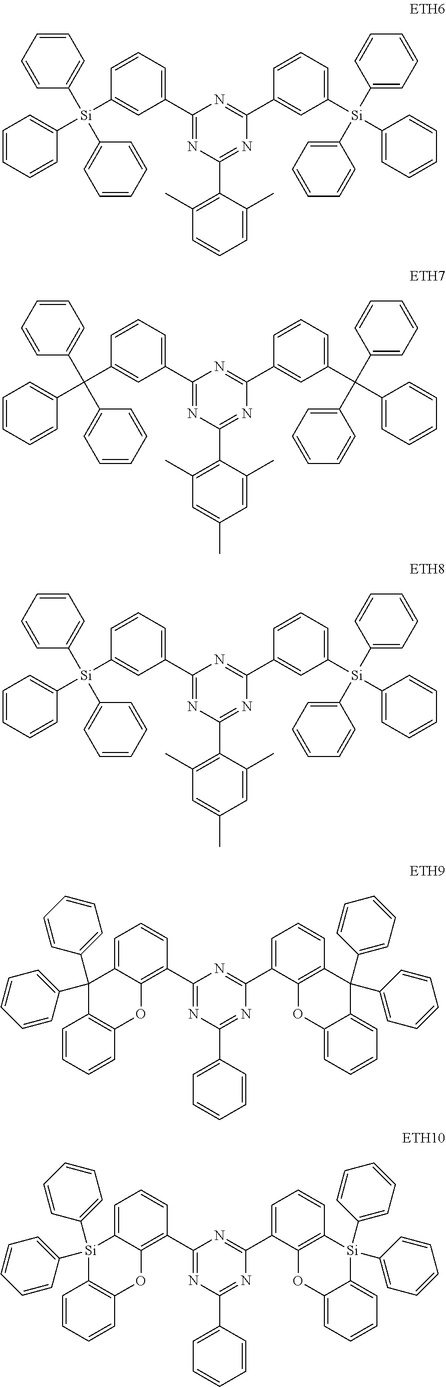

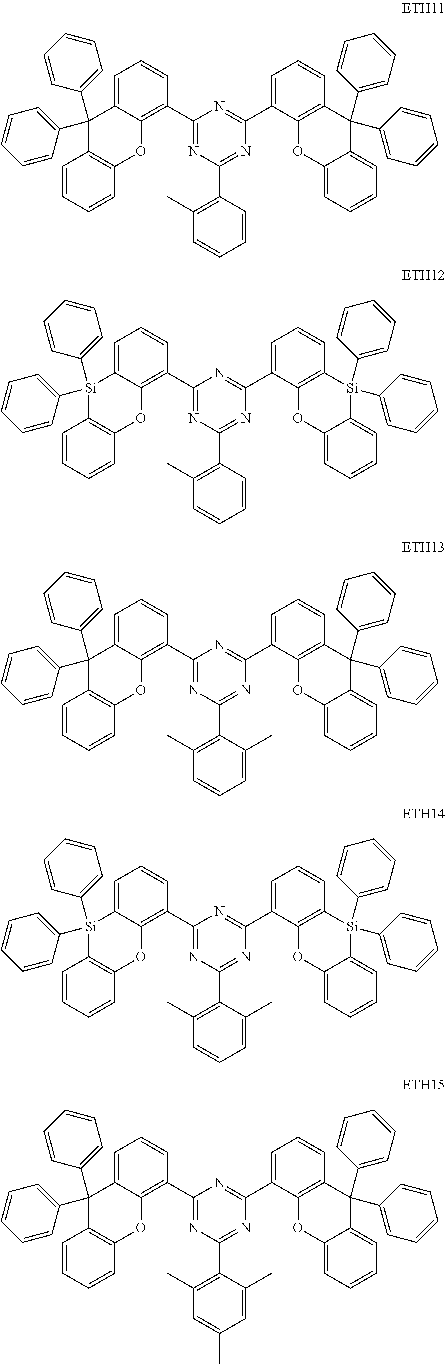

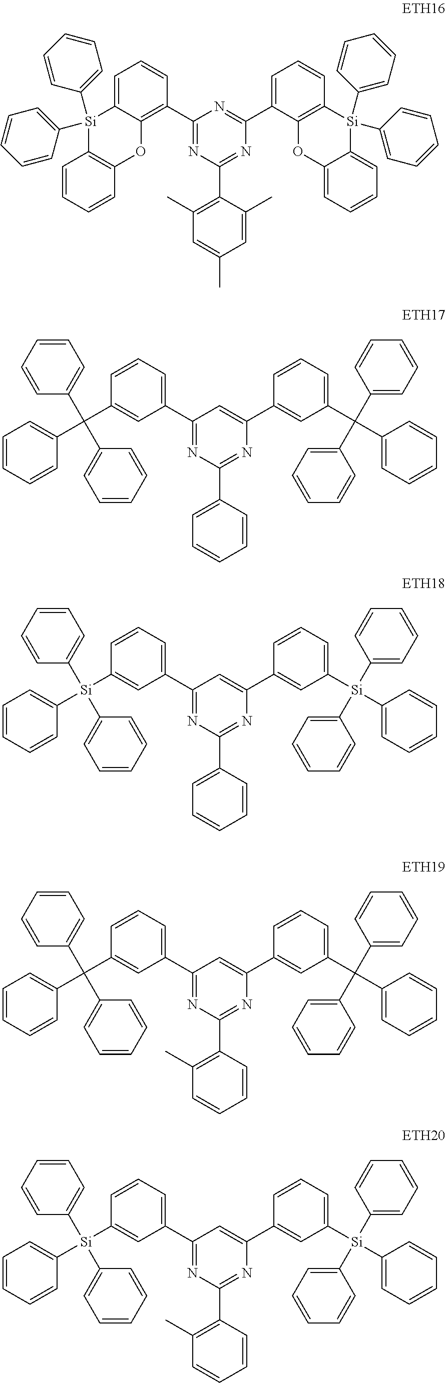

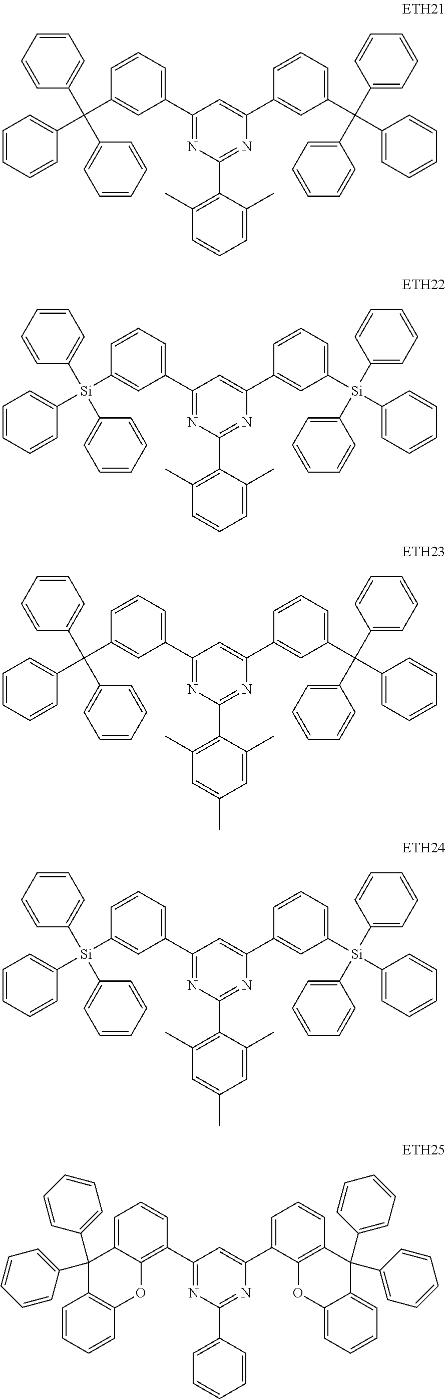

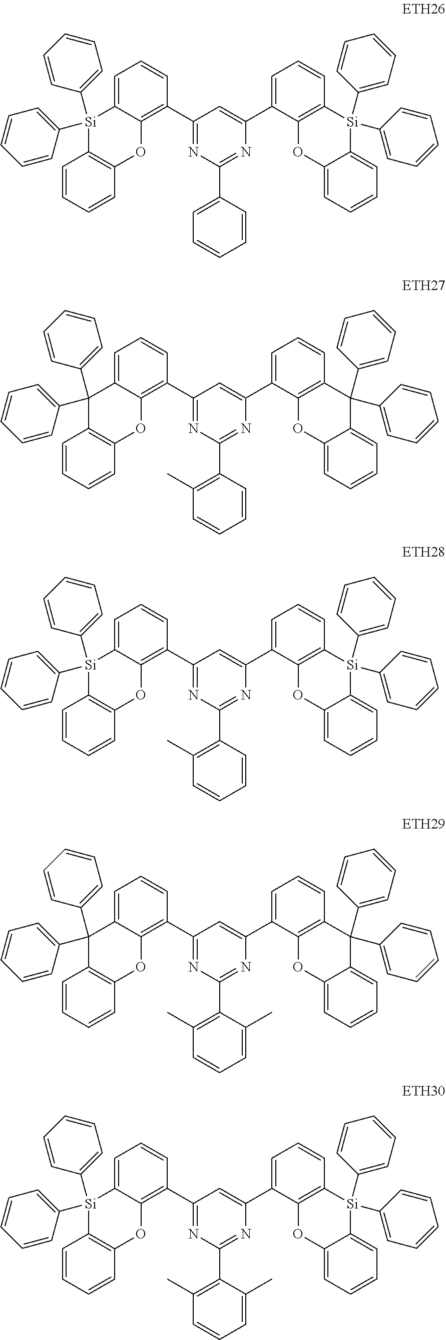

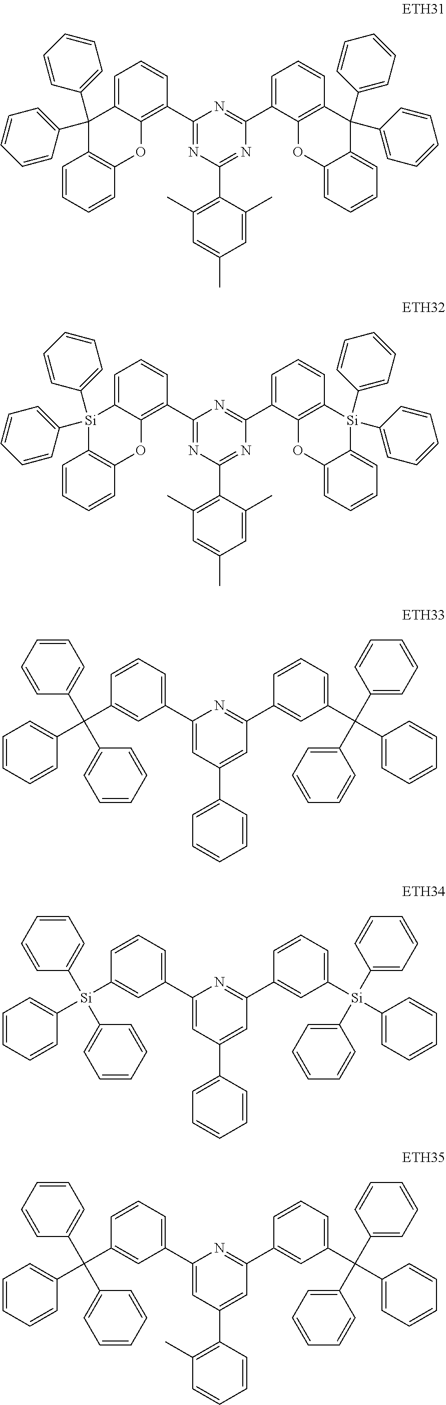

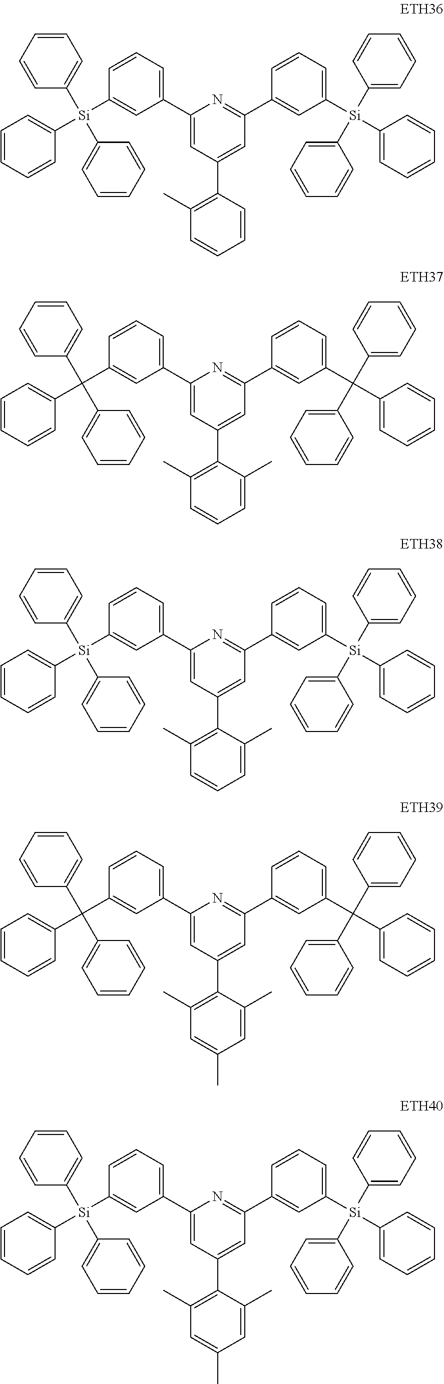

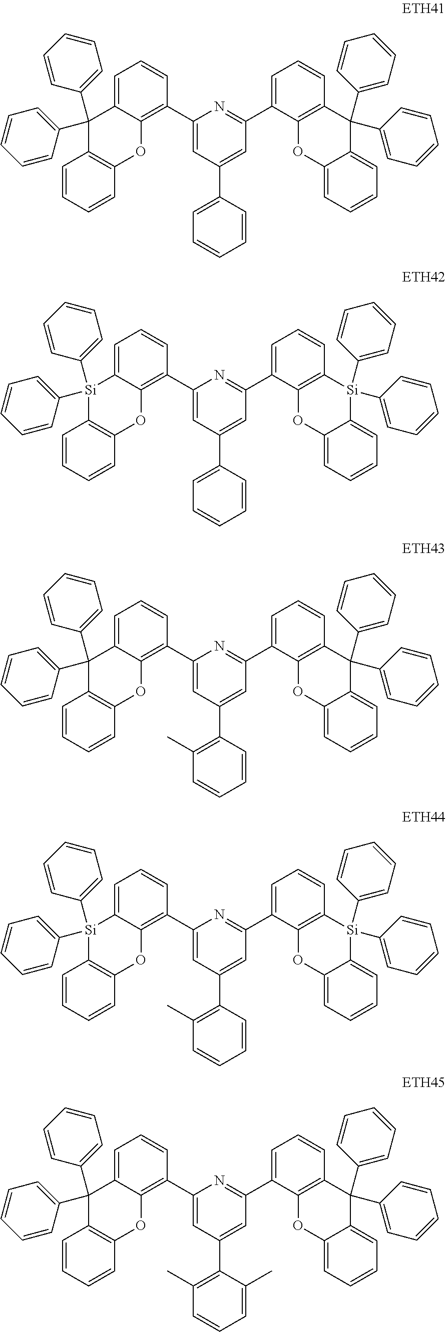

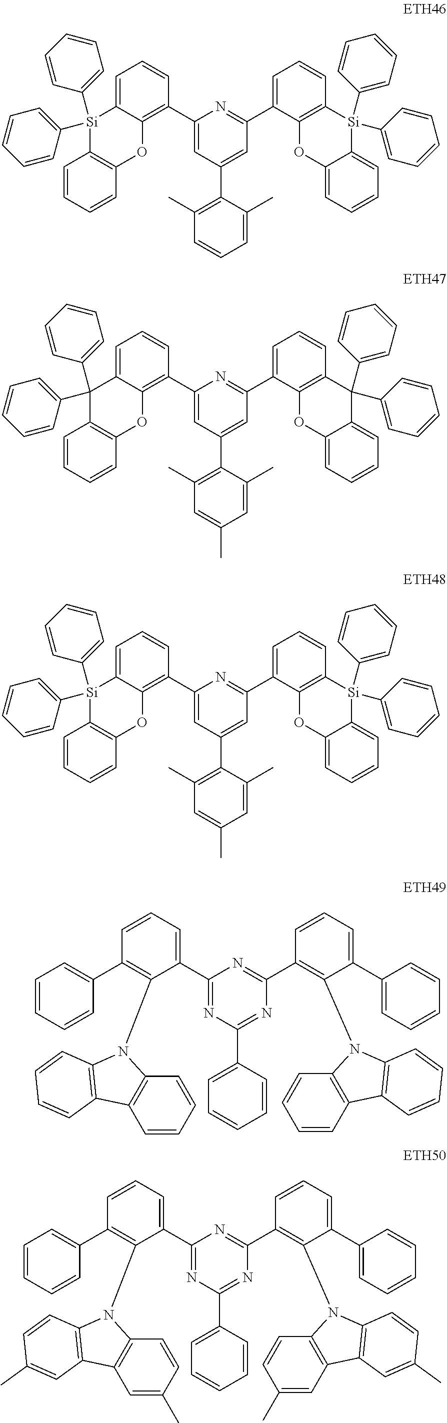

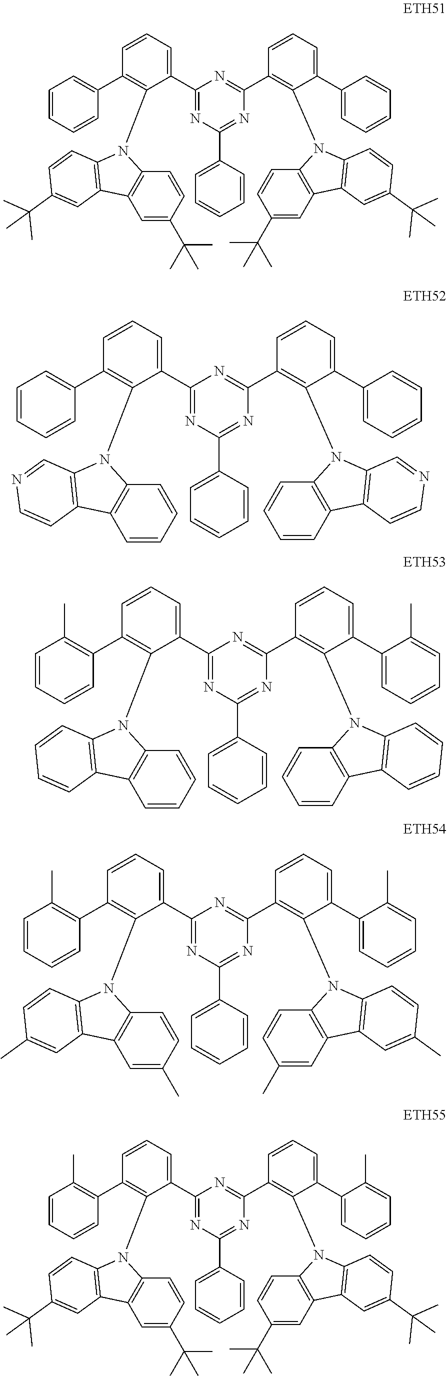

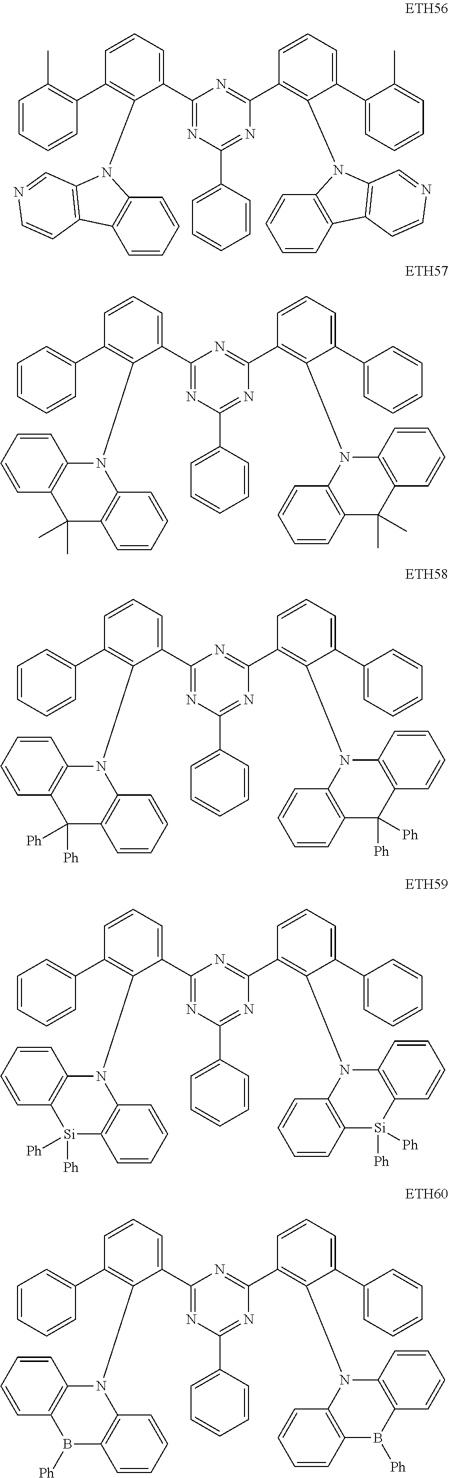

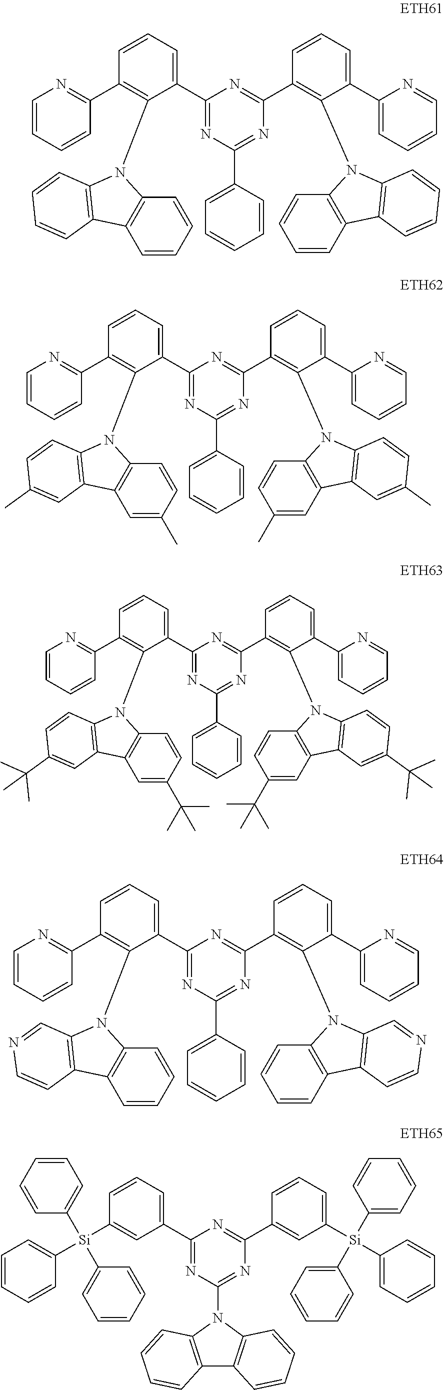

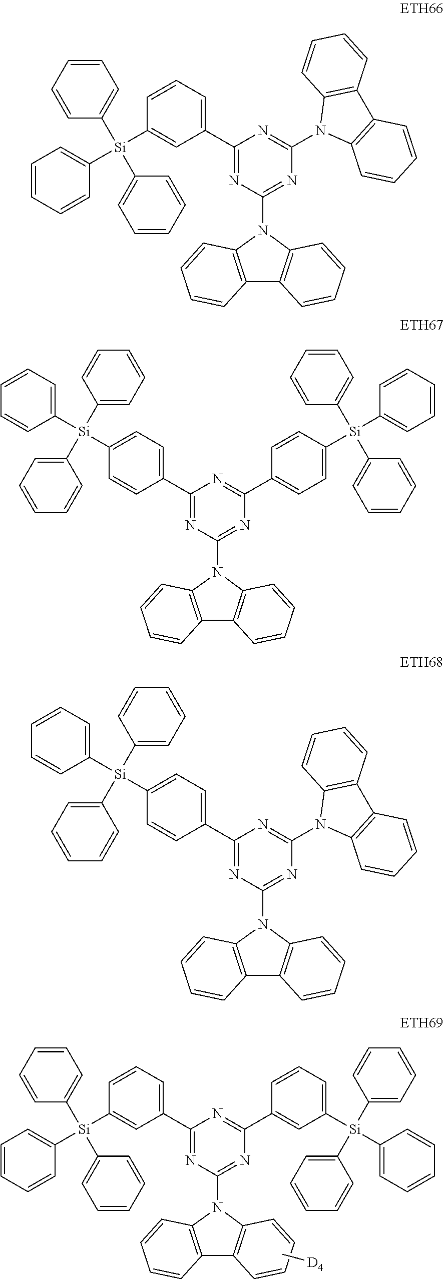

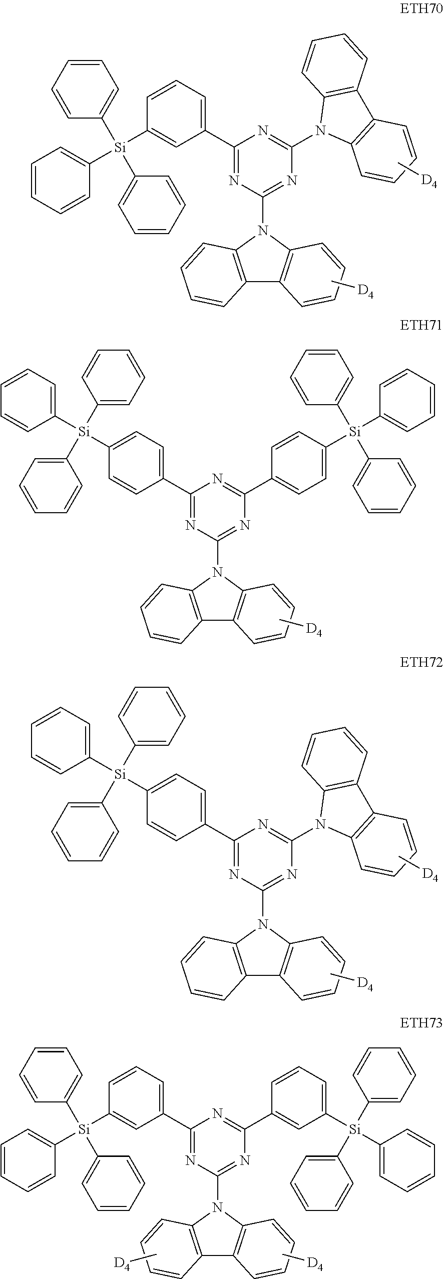

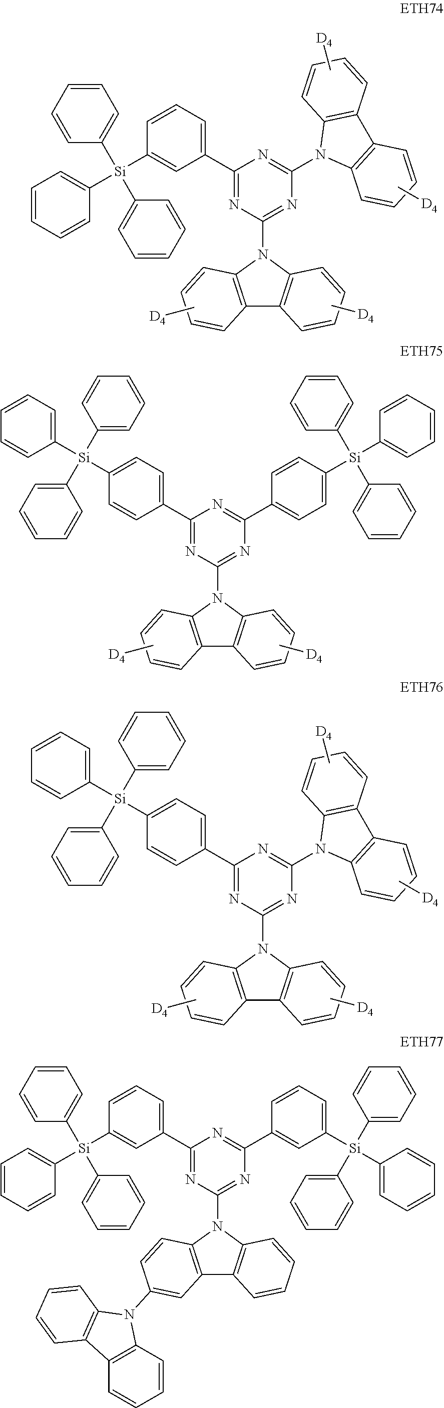

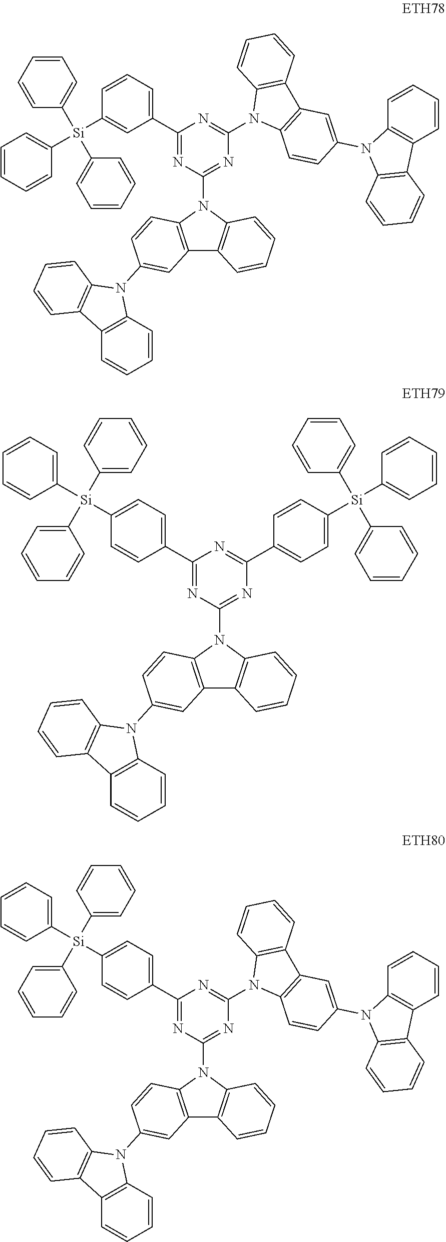 [SMILES: c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

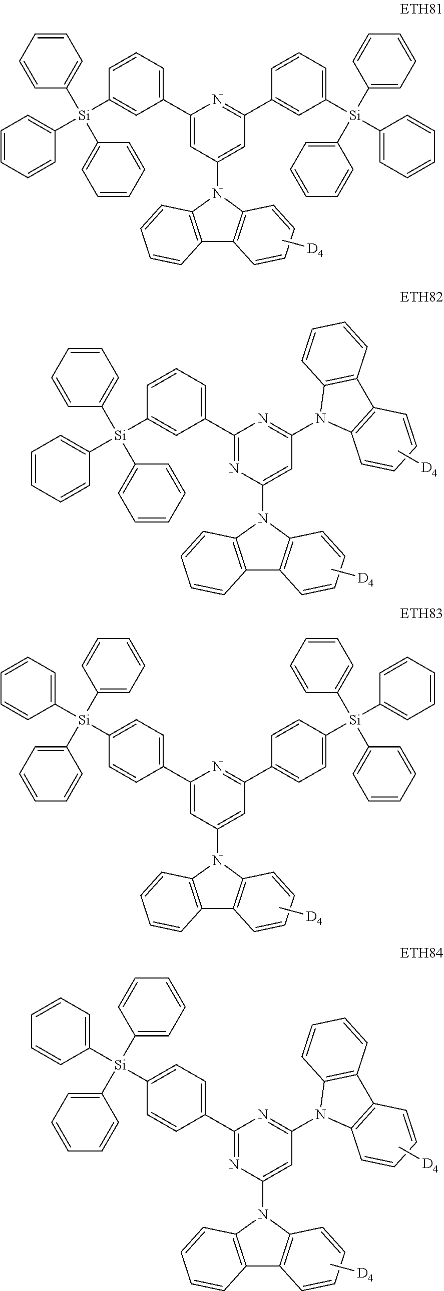

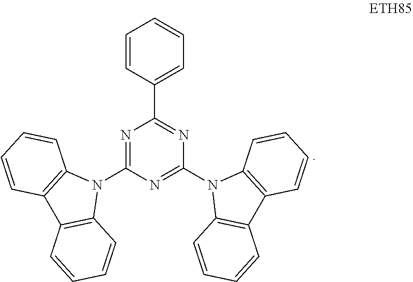 [SMILES: c1ccc(-c2nc(-n3c4ccccc4c4ccccc43)nc(-n3c4ccccc4c4ccccc43)n2)cc1]

In an embodiment, the fourth compound may include at least one of Compounds PD1 to PD40:

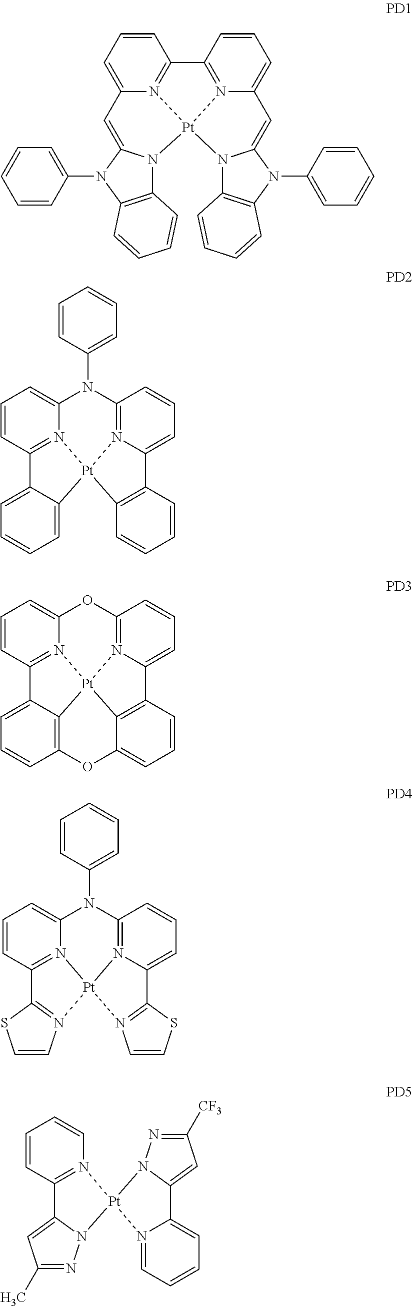

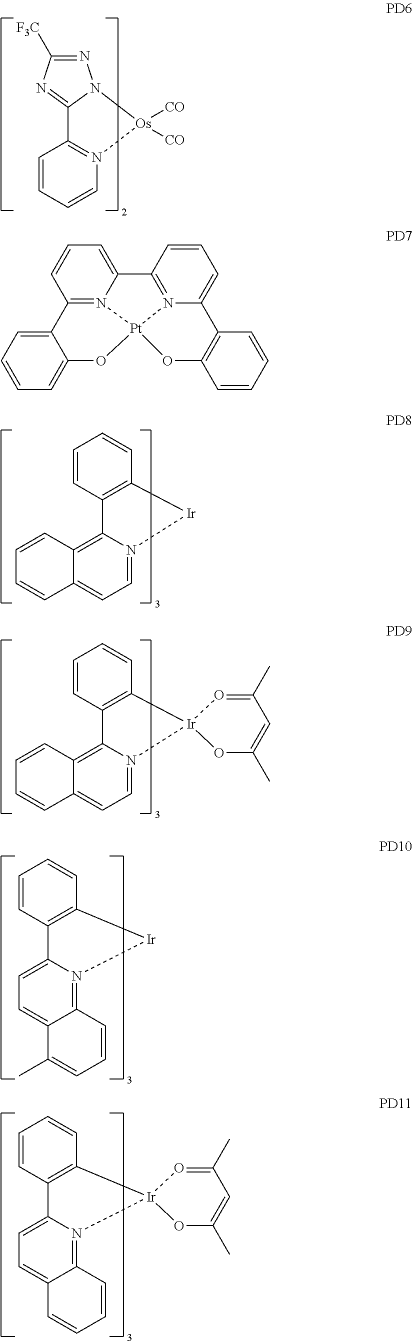

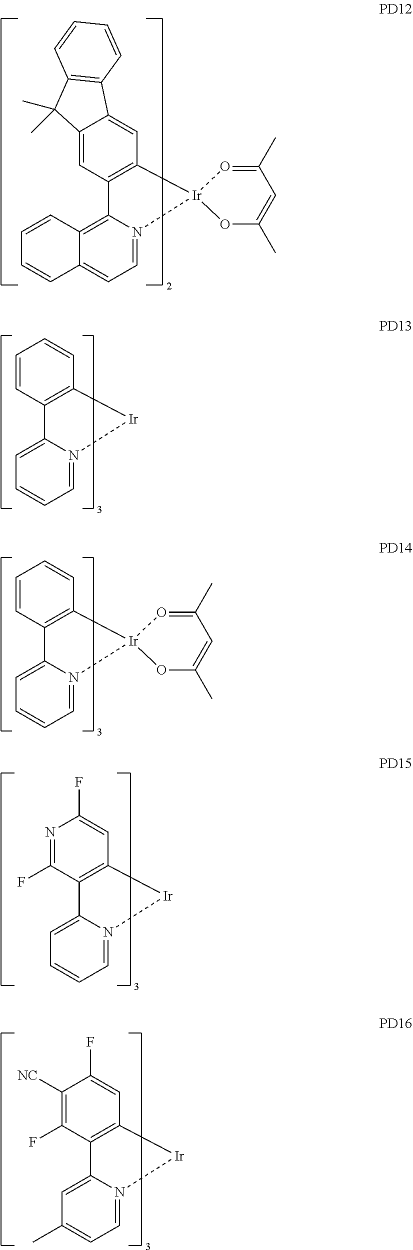

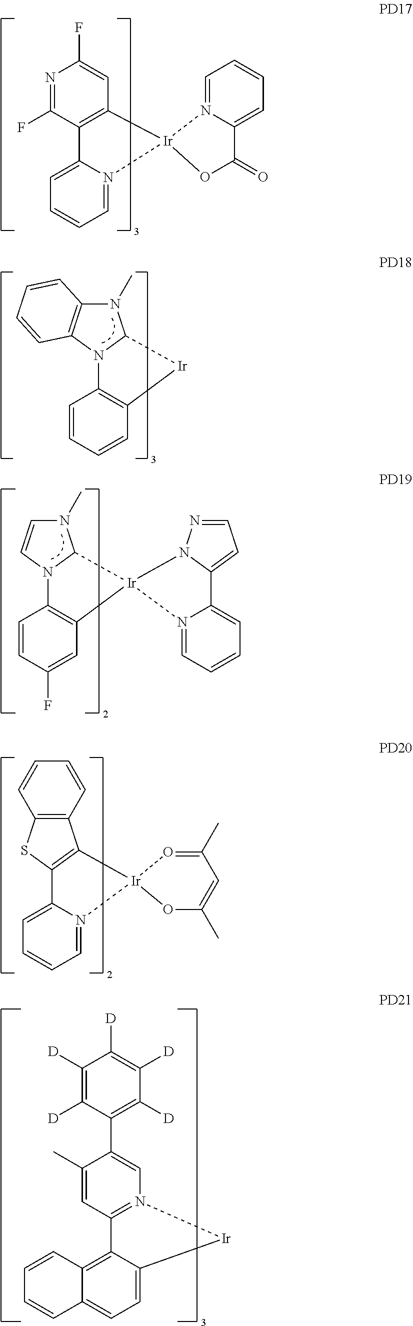

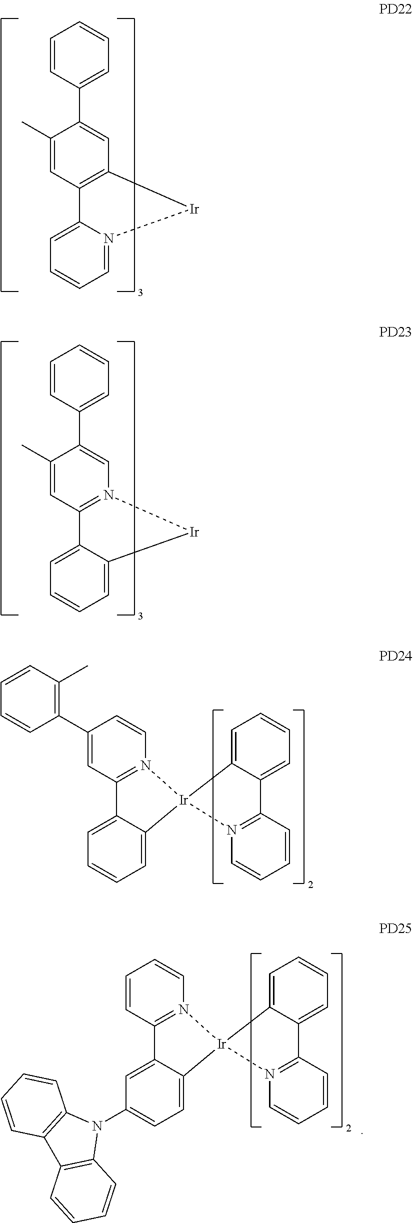

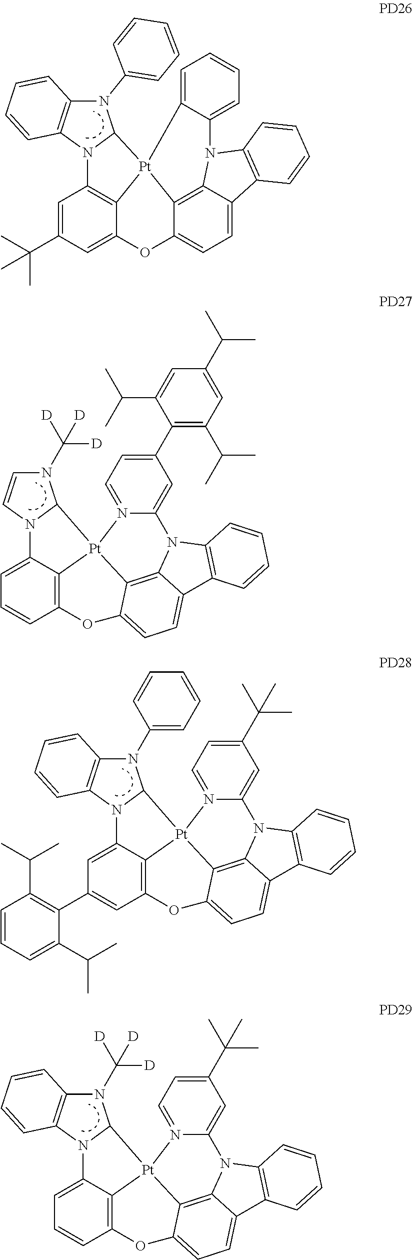

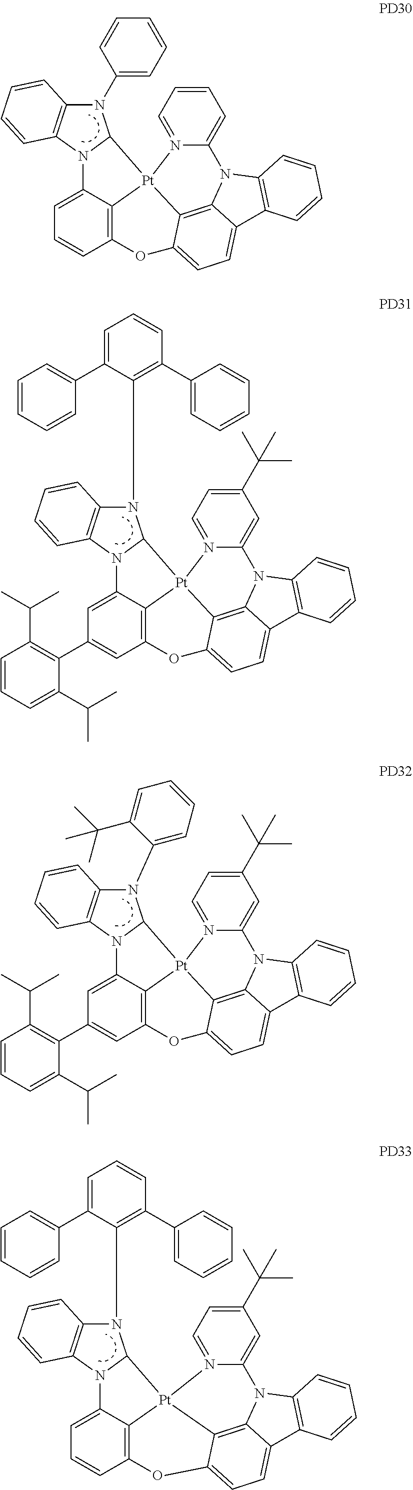

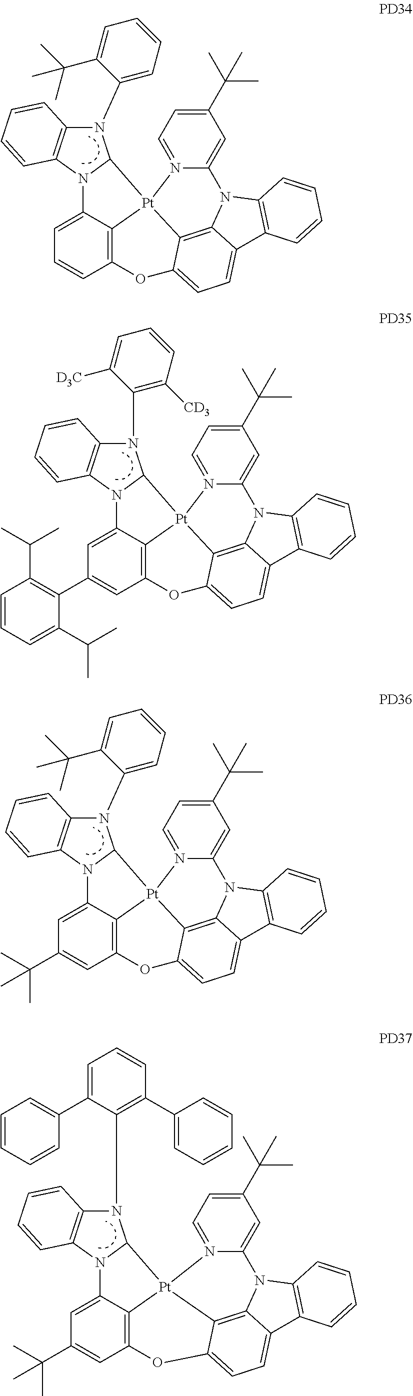

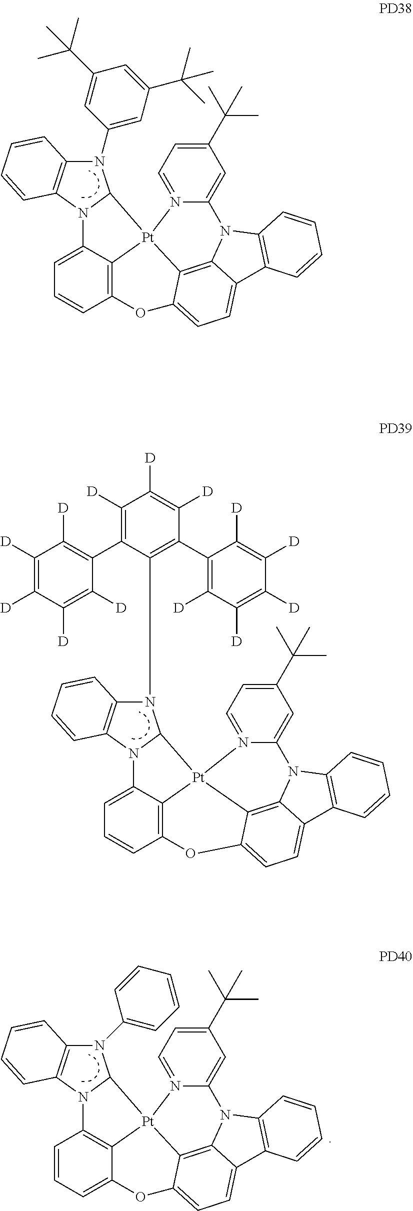

In Compounds HTH1 to HTH53 and ETH1 to ETH85, “Ph” represents a phenyl group, “D₅” represents substitution with five deuterium atoms, and “D₄” represents substitution with four deuterium atoms.

In an embodiment, the light-emitting device may satisfy at least one of Conditions 1 to 4:

### Condition 1

Lowest unoccupied molecular orbital (LUMO) energy level (eV) of the second compound >LUMO energy level (eV) of the fourth compound;

### Condition 2

LUMO energy level (eV) of the fourth compound >LUMO energy level (eV) of the third compound;

### Condition 3

Highest occupied molecular orbital (HOMO) energy level (eV) of the fourth compound>HOMO energy level (eV) of the second compound; and

### Condition 4

HOMO energy level (eV) of the second compound >HOMO energy level (eV) of the third compound.

A HOMO energy level and a LUMO energy level of each of the first compound, the second compound, and the third compound may each be a negative value, and may be measured according to a method of the related art.

In an embodiment, an absolute value of a difference between the LUMO energy level of the fourth compound and the LUMO energy level of the third compound may be in a range of about 0.1 eV to about 1.0 eV, an absolute value of a difference between the LUMO energy level of the fourth compound and the LUMO energy level of the second compound may be in a range of about 0.1 eV to about 1.0 eV, an absolute value of a difference between the HOMO energy level of the fourth compound and the HOMO energy level of the third compound may be equal to or less than about 1.25 eV (for example, in a range of about 0.2 eV to about 1.25 eV), and an absolute value of a difference between the HOMO energy level of the fourth compound and the HOMO energy level of the second compound may be equal to or less than about 1.25 eV (for example, in a range of about 0.2 eV to about 1.25 eV).

When the relationships between LUMO energy levels and HOMO energy levels satisfy the conditions as described above, a balance between holes and electrons injected into the emission layer can be achieved.

The light-emitting device may have a structure of a first embodiment or a second embodiment:

### Description of First Embodiment

According to a first embodiment, the first compound may be included in the emission layer of the interlayer in the light-emitting device, wherein the emission layer may further include a host, the first compound may be different from the host, and the emission layer may emit phosphorescence or fluorescence from the first compound.

For example, according to the first embodiment, the first compound may be a dopant or an emitter. For example, the first compound may be a phosphorescent dopant or a phosphorescence emitter.

Phosphorescence or fluorescence emitted from the first compound may be blue light.

The emission layer may further include an auxiliary dopant. The auxiliary dopant may effectively transfer energy to the first compound which serves as a dopant or an emitter, and in this regard, the auxiliary dopant may serve as a sensitizer that improves luminescence efficiency of the first compound.

The auxiliary dopant may be different from the first compound and the host.

For example, the auxiliary dopant may be a phosphorescent dopant.

### Description of Second Embodiment

According to a second embodiment, the first compound may be included in the emission layer of the interlayer in the light-emitting device, wherein the emission layer may further include a host and a dopant, the first compound, the host, and the dopant may be different from one another, and the emission layer may emit photoluminescence or fluorescence (e.g., delayed fluorescence) emitted from the dopant.

In an embodiment, the first compound in the second embodiment may serve not as a dopant, but may serve as an auxiliary dopant that transfers energy to a dopant (or to an emitter).

In embodiments, the first compound in the second embodiment may serve as an emitter and also as an auxiliary dopant that transfers energy to a dopant (or to an emitter).

For example, phosphorescence or fluorescence emitted from the dopant (or the emitter) in the second embodiment may be blue phosphorescence or blue fluorescence (e.g., blue delayed fluorescence).

The dopant (or the emitter) of the second embodiment may be a phosphorescent dopant material (for example, an organometallic compound represented by Formula 401) or a fluorescent dopant material (for example, in the specification, the condensed cyclic compound represented by Formula 1, a compound represented by Formula 501, or any combination thereof).

In the first embodiment and the second embodiment, the blue light may be blue light having a maximum emission wavelength in a range of about 390 nm to about 500 nm. For example, the blue light may have a maximum emission wavelength in a range of about 410 nm to about 490 nm. For example, the blue light may have a maximum emission wavelength in a range of about 430 nm to about 480 nm. For example, the blue light may have a maximum emission wavelength in a range of about 440 nm to about 475 nm. For example, the blue light may have a maximum emission wavelength in a range of about 455 nm to about 470 nm.

In the first embodiment, the auxiliary dopant may include, for example, a compound represented by Formula 401.

The host in the first embodiment and in the second embodiment may be any host material (e.g., a compound represented by Formula 301, a compound represented by 301-1, a compound represented by Formula 301-2, or any combination thereof).

In an embodiment, the host in the first embodiment and in the second embodiment may be the second compound, the third compound, or any combination thereof.

Another aspect of the disclosure provides an electronic apparatus which may include the light-emitting device. The electronic apparatus may further include a thin-film transistor. For example, in an embodiment, the electronic apparatus may further include a thin-film transistor including a source electrode and a drain electrode, wherein the first electrode of the light-emitting device may be electrically connected to the source electrode or the drain electrode. In an embodiment, the electronic apparatus may further include a color filter, a color conversion layer, a touch screen layer, a polarizing layer, or any combination thereof. The electronic apparatus may be the same as described herein.

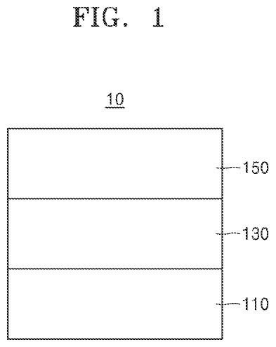

### Description of FIG. 1

FIG. 1 is a schematic cross-sectional view of a light-emitting device 10 according to an embodiment. The light-emitting device 10 includes a first electrode 110, an interlayer 130, and a second electrode 150.

Hereinafter, the structure of the light-emitting device 10 according to an embodiment and a method of manufacturing the light-emitting device 10 will be described with reference to FIG. 1.

### First Electrode 110

In FIG. 1, a substrate may be further included under the first electrode 110 or on the second electrode 150. In an embodiment, the substrate may be a glass substrate or a plastic substrate. In embodiments, the substrate may be a flexible substrate, and for example, may include plastics with excellent heat resistance and durability, such as polyimide, polyethylene terephthalate (PET), polycarbonate, polyethylene naphthalate, polyarylate (PAR), polyetherimide, or any combination thereof.

The first electrode 110 may be formed by, for example, depositing or sputtering a material for forming the first electrode 110 on the substrate. When the first electrode 110 is an anode, a material for forming the first electrode 110 may be a high-work function material that facilitates injection of holes.

The first electrode 110 may be a reflective electrode, a semi-transmissive electrode, or a transmissive electrode. In an embodiment, when the first electrode 110 is a transmissive electrode, a material for forming the first electrode 110 may include indium tin oxide (ITO), indium zinc oxide (IZO), tin oxide (SnO₂), zinc oxide (ZnO), or any combination thereof. In embodiments, when the first electrode 110 is a semi-transmissive electrode or a reflective electrode, a material for forming the first electrode 110 may include magnesium (Mg), silver (Ag), aluminum (Al), aluminum-lithium (Al—Li), calcium (Ca), magnesium-indium (Mg—In), magnesium-silver (Mg—Ag), or any combination thereof.

The first electrode 110 may have a structure consisting of a single layer or a structure including multiple layers. For example, the first electrode 110 may have a three-layered structure of ITO/Ag/ITO.

### Interlayer 130

The interlayer 130 is arranged on the first electrode 110. The interlayer 130 may include an emission layer.

The interlayer 130 may further include a hole transport region between the first electrode 110 and the emission layer, and an electron transport region between the emission layer and the second electrode 150.

In an embodiment, the interlayer 130 may further include, in addition to various organic materials, a metal-containing compound such as an organometallic compound, an inorganic material such as quantum dots, and the like.

In embodiments, the interlayer 130 may include two or more emitting units stacked between the first electrode 110 and the second electrode 150, and at least one charge generation layer between the two or more emitting units. When the interlayer 130 includes the two or more emitting units and the at least one charge generation layer, the light-emitting device 10 may be a tandem light-emitting device.

### Hole Transport Region in Interlayer 130

The hole transport region may have a structure consisting of a layer consisting of a single material, a structure consisting of a layer consisting of different materials, or a structure including multiple layers including different materials.

The hole transport region may include a hole injection layer, a hole transport layer, an emission auxiliary layer, an electron blocking layer, or any combination thereof.

For example, the hole transport region may have a multi-layered structure including a hole injection layer/hole transport layer structure, a hole injection layer/hole transport layer/emission auxiliary layer structure, a hole injection layer/emission auxiliary layer structure, a hole transport layer/emission auxiliary layer structure, or a hole injection layer/hole transport layer/electron blocking layer structure, wherein the layers of each structure may be stacked from the first electrode 110 in its respective stated order, but the structure of the hole transport region is not limited thereto.

The hole transport region may include a compound represented by Formula 201, a compound represented by Formula 202, or any combination thereof:

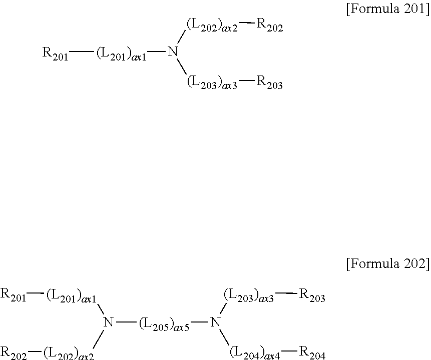

In Formulae 201 and 202,

L₂₀₁ to L₂₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

L₂₀₅ may be *—O—*′, *—S—*′, *—N(Q₂₀₁)-*′, a C₁-C₂₀ alkylene group unsubstituted or substituted with at least one R₁₀ₐ, a C₂-C₂₀ alkenylene group unsubstituted or substituted with at least one R₁₀ₐ, a C₃-C₆₀ carbocyclic group unsubstituted or substituted with at least one R₁₀ₐ, or a C₁-C₆₀ heterocyclic group unsubstituted or substituted with at least one R₁₀ₐ,

xa1 to xa4 may each independently be an integer from 0 to 5,

xa5 may be an integer from 1 to 10,

R₂₀₁ to R₂₀₄ and Q₂₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

R₂₀₁ and R₂₀₂ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group (for example, a carbazole group, etc.) unsubstituted or substituted with at least one R₁₀ₐ (for example, Compound HT16, etc.),

R₂O₃ and R₂₀₄ may optionally be bonded to each other via a single bond, a C₁-C₅ alkylene group unsubstituted or substituted with at least one R₁₀ₐ, or a C₂-C₅ alkenylene group unsubstituted or substituted with at least one R₁₀ₐ, to form a C₈-C₆₀ polycyclic group unsubstituted or substituted with at least one R₁₀ₐ, and

na1 may be an integer from 1 to 4.

In embodiments, each of Formulae 201 and 202 may include at least one of groups represented by Formulae CY201 to CY217:

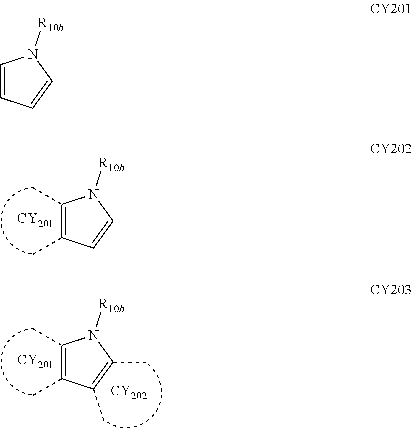

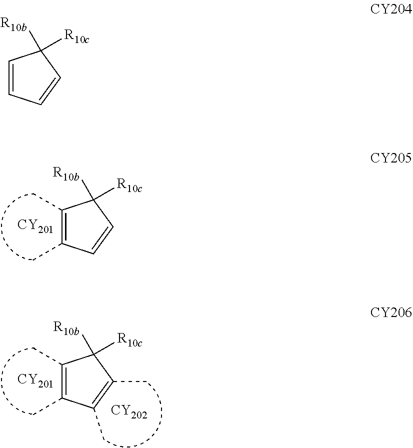

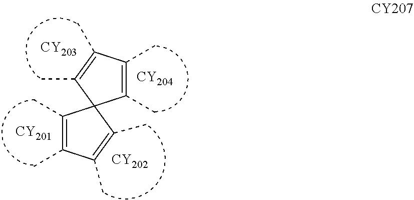

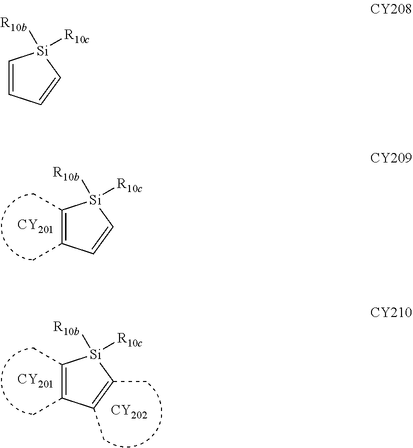

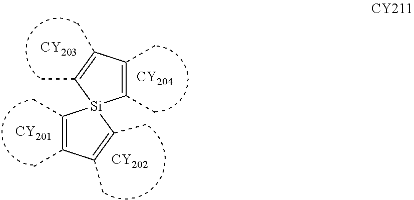

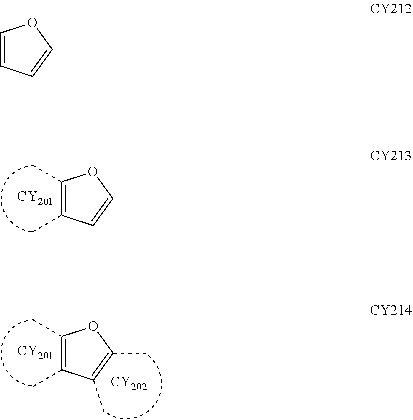

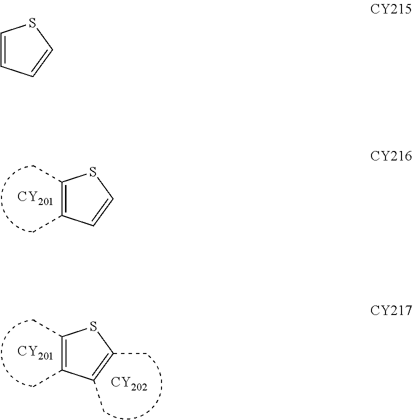

In Formulae CY201 to CY217, R_{10b} and R_{10c} may each independently be the same as described in connection with R₁₀ₐ, ring CY201 to ring CY204 may each independently be a C₃-C₂₀ carbocyclic group or a C₁-C₂₀ heterocyclic group, and at least one hydrogen in Formulae CY201 to CY217 may be unsubstituted or substituted with R₁₀ₐ as described herein.

In an embodiment, in Formulae CY201 to CY217, ring CY201 to ring CY204 may each independently be a benzene group, a naphthalene group, a phenanthrene group, or an anthracene group.

In embodiments, each of Formulae 201 and 202 may include at least one of groups represented by Formulae CY201 to CY203.

In embodiments, a compound represented by Formula 201 may include at least one of groups represented by Formulae CY201 to CY203 and at least one of groups represented by Formulae CY204 to CY217.

In embodiments, in Formula 201, xa1 may be 1, R₂₀₁ may be one of groups represented by Formulae CY201 to CY203, xa2 may be 0, and R₂₀₂ may be one of groups represented by Formulae CY204 to CY207.

In embodiments, each of Formulae 201 and 202 may not include groups represented by Formulae CY201 to CY203.

In embodiments, each of Formulae 201 and 202 may not include groups represented by Formulae CY201 to CY203, and may include at least one of groups represented by Formulae CY204 to CY217.

In embodiments, each of Formulae 201 and 202 may not include the groups represented by Formulae CY201 to CY217.

For example, the hole transport region may include one of Compounds HT1 to HT46, m-MTDATA, TDATA, 2-TNATA, NPB(NPD), β-NPB, TPD, Spiro-TPD, Spiro-NPB, methylated NPB, TAPC, HMTPD, 4,4′,4″-tris(N-carbazolyl)triphenylamine (TCTA), polyaniline/dodecylbenzenesulfonic acid (PANI/DBSA), poly(3,4-ethylenedioxythiophene)/poly(4-styrenesulfonate) (PEDOT/PSS), polyaniline/camphor sulfonic acid (PANI/CSA), polyaniline/poly(4-styrenesulfonate) (PANI/PSS), or any combination thereof:

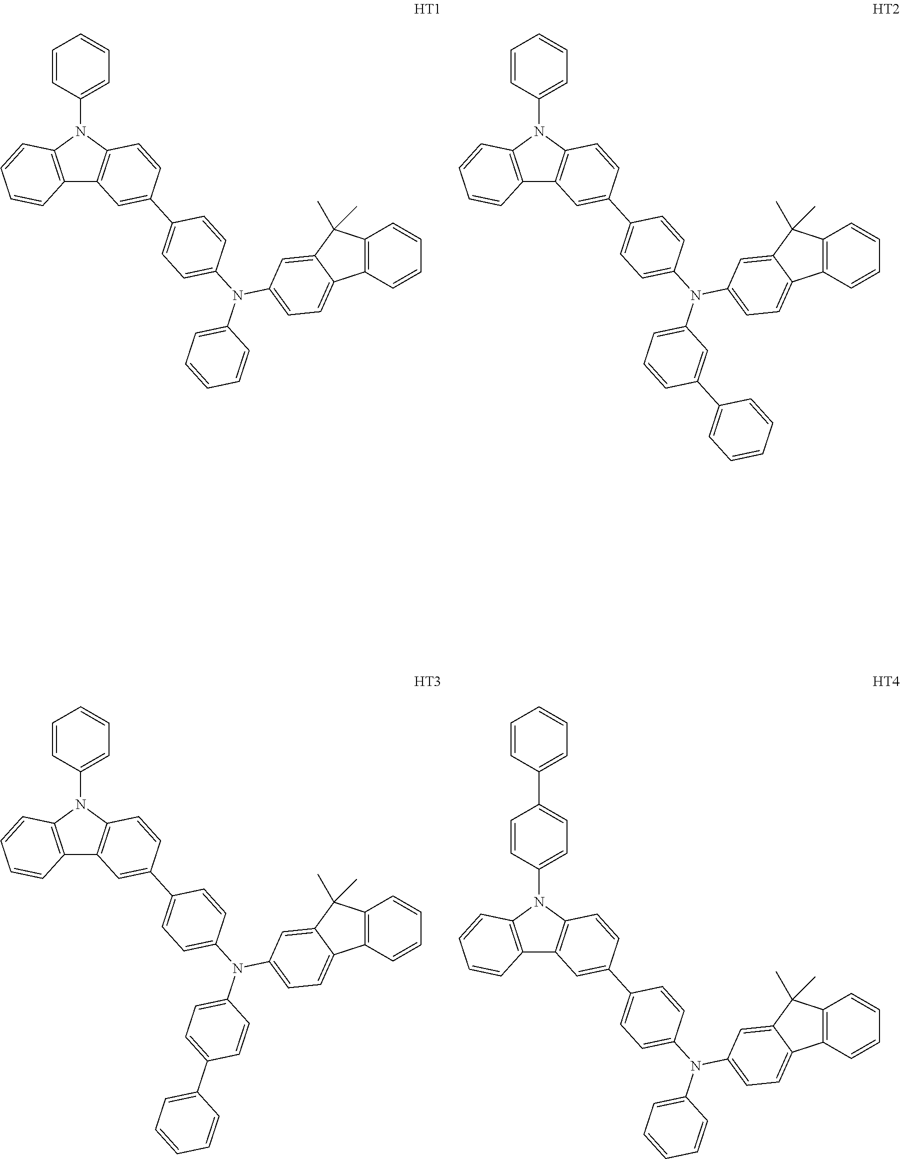

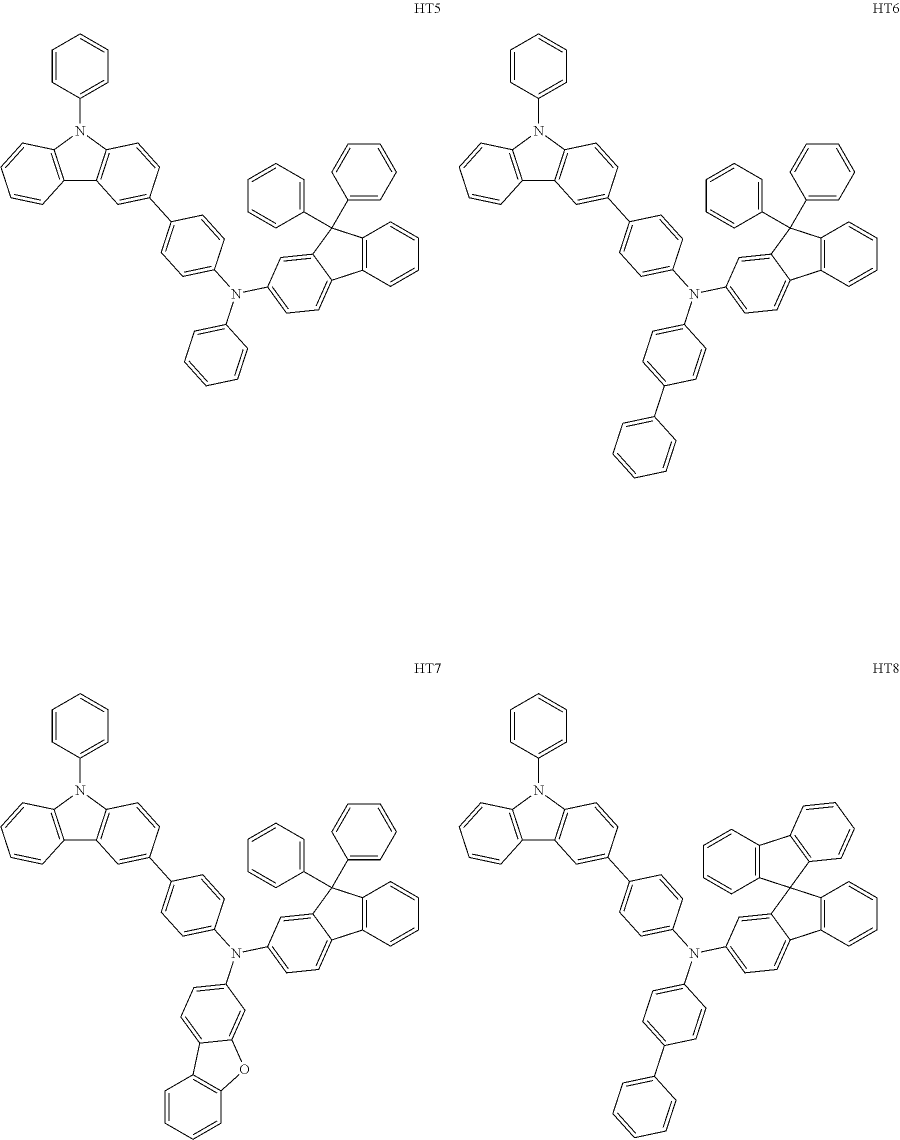 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

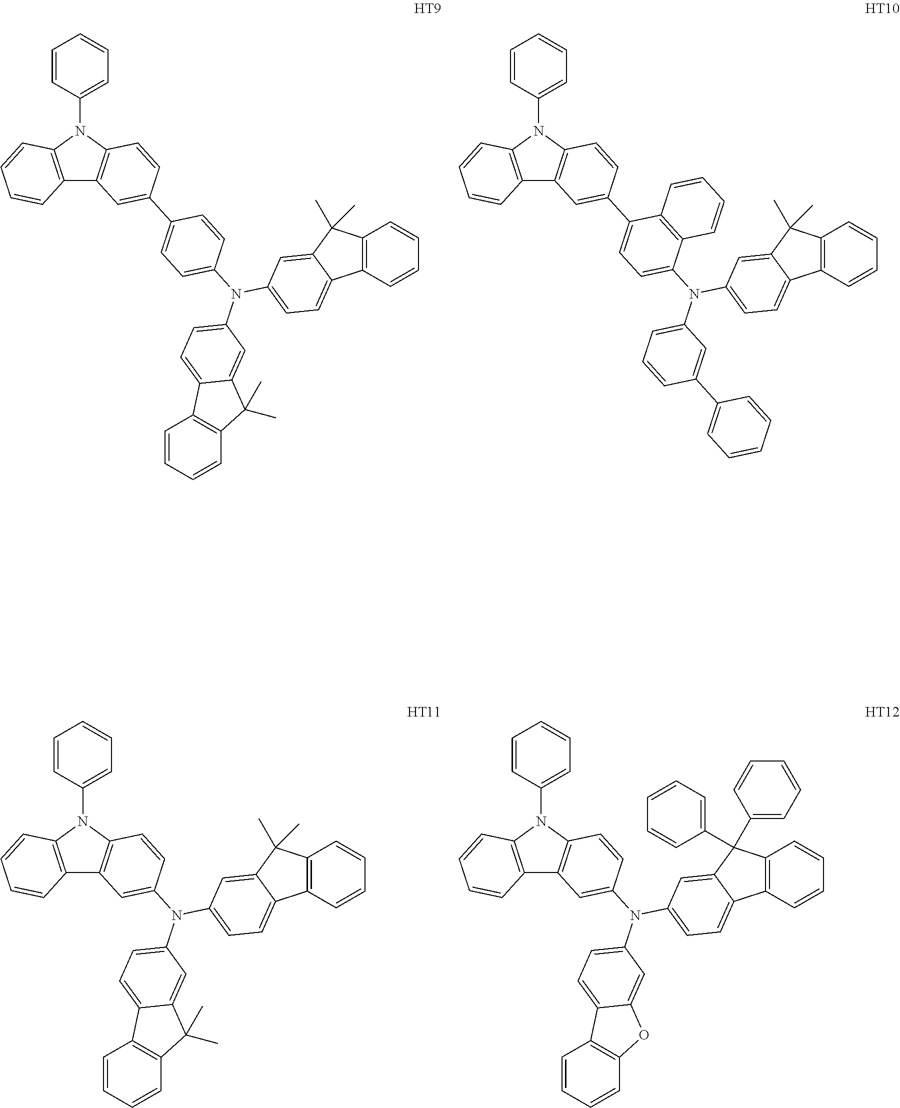 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

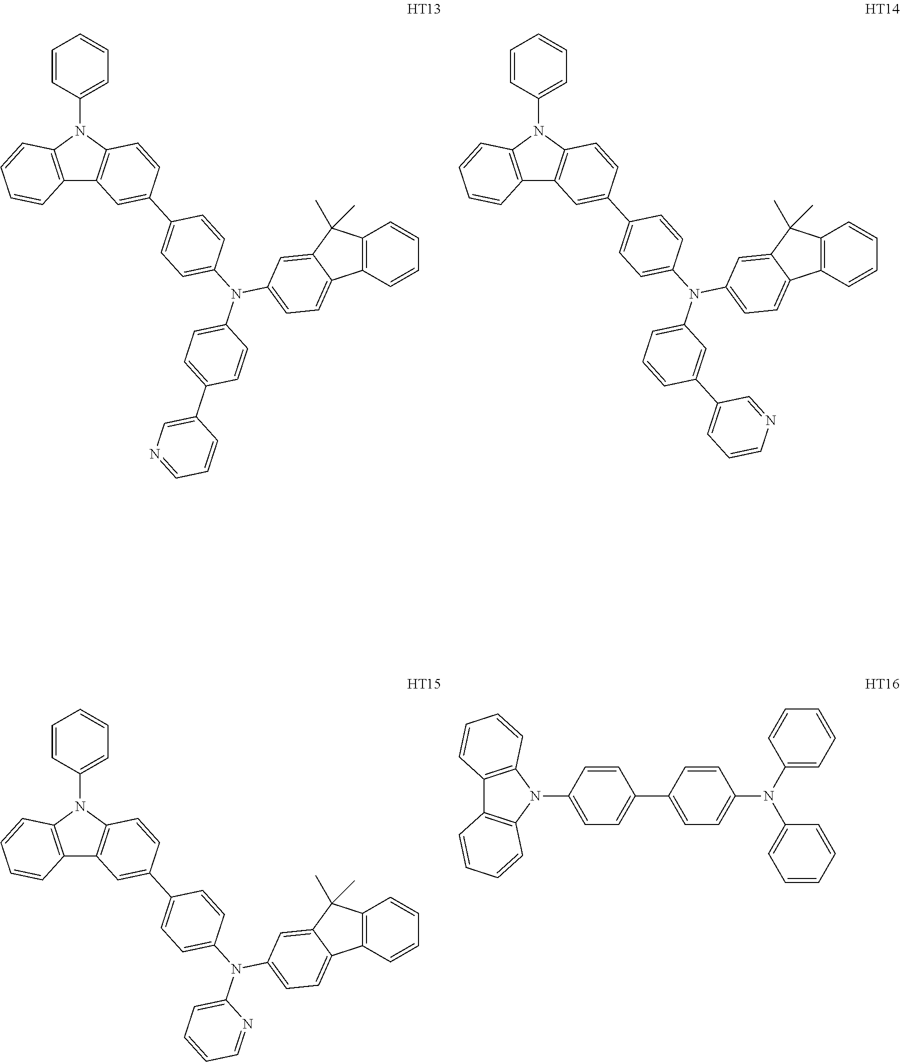 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

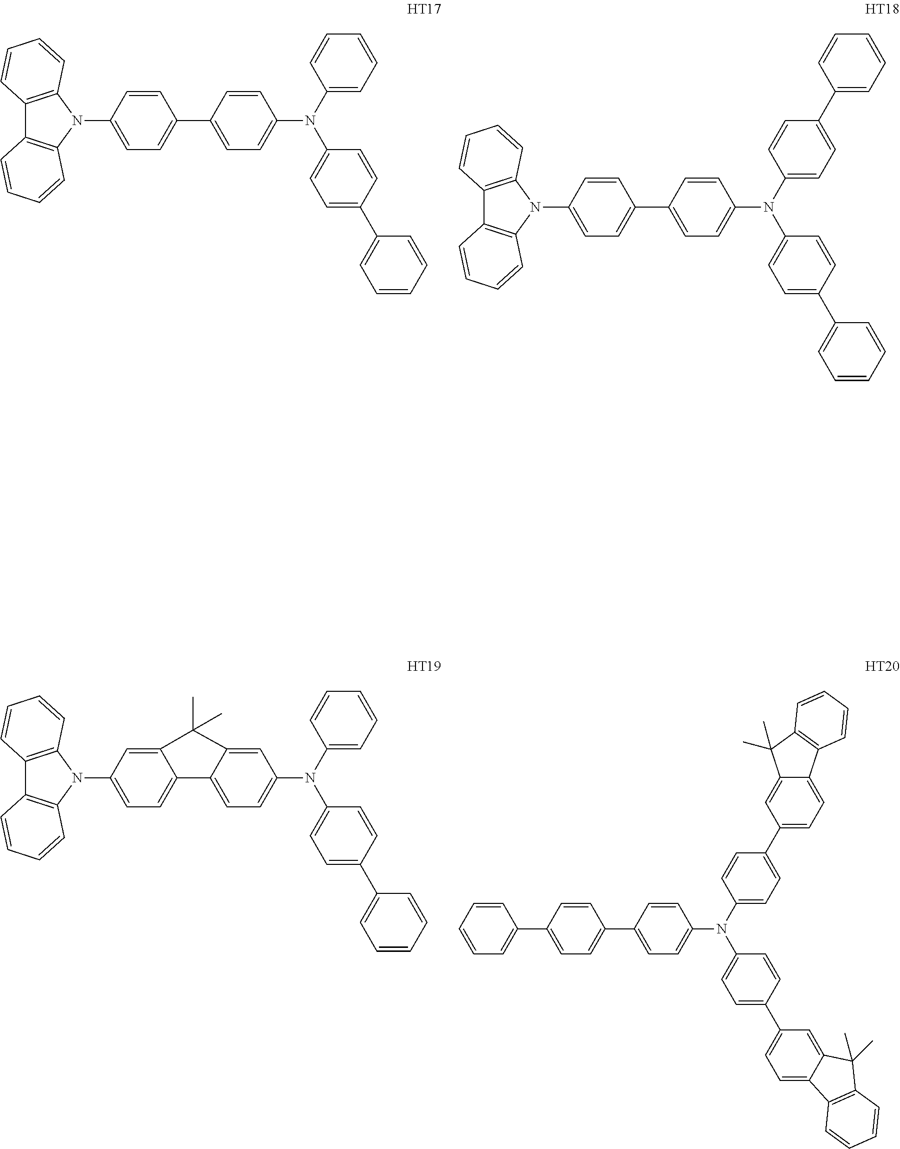

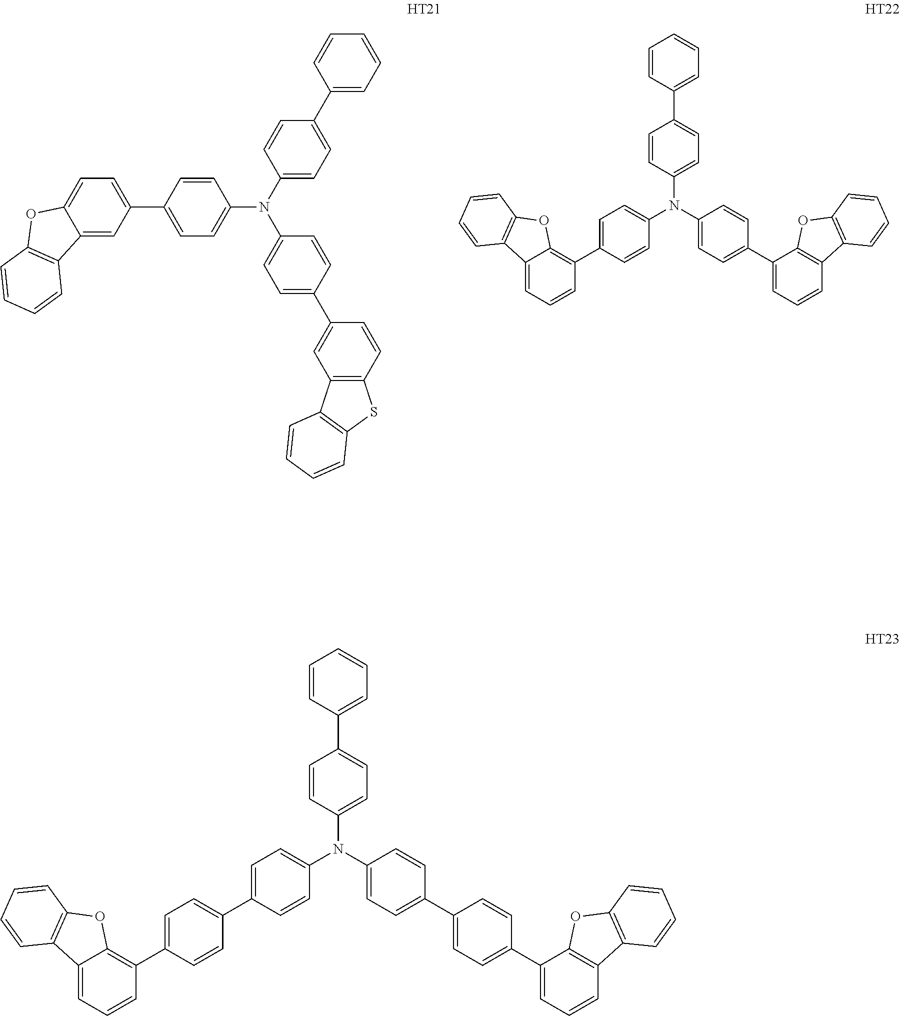 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

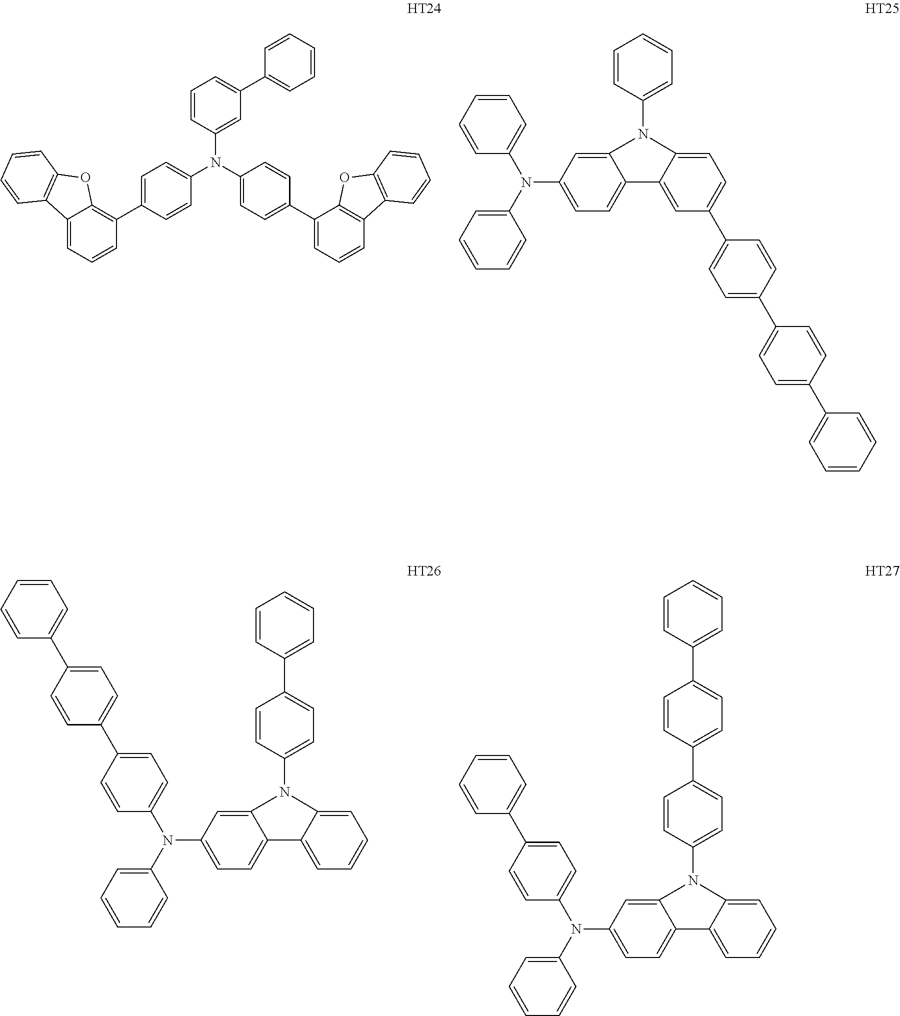 [SMILES: c1ccc(-c2cccc(N(c3ccc(-c4cccc5c4oc4ccccc45)cc3)c3ccc(-c4cccc5c4oc4ccccc45)cc3)c2)cc1 ; c1ccc(-c2ccc(-c3ccc(-c4ccc5c(c4)c4ccc(N(c6ccccc6)c6ccccc6)cc4n5-c4ccccc4)cc3)cc2)cc1 ; c1ccc(-c2ccc(-c3ccc(N(c4ccccc4)c4ccc5c6ccccc6n(-c6ccc(-c7ccccc7)cc6)c5c4)cc3)cc2)cc1 ; c1ccc(-c2ccc(-c3ccc(-n4c5ccccc5c5ccc(N(c6ccccc6)c6ccc(-c7ccccc7)cc6)cc54)cc3)cc2)cc1]

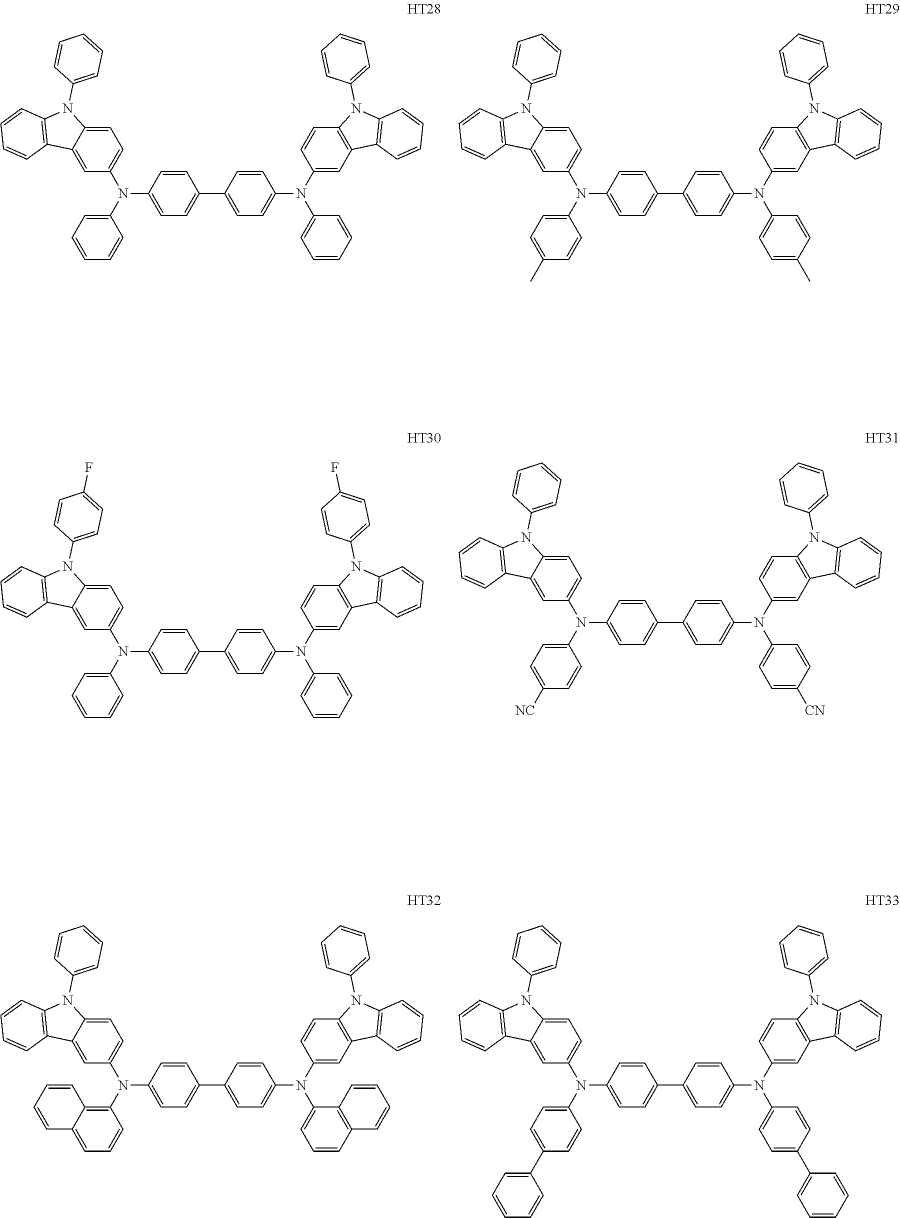

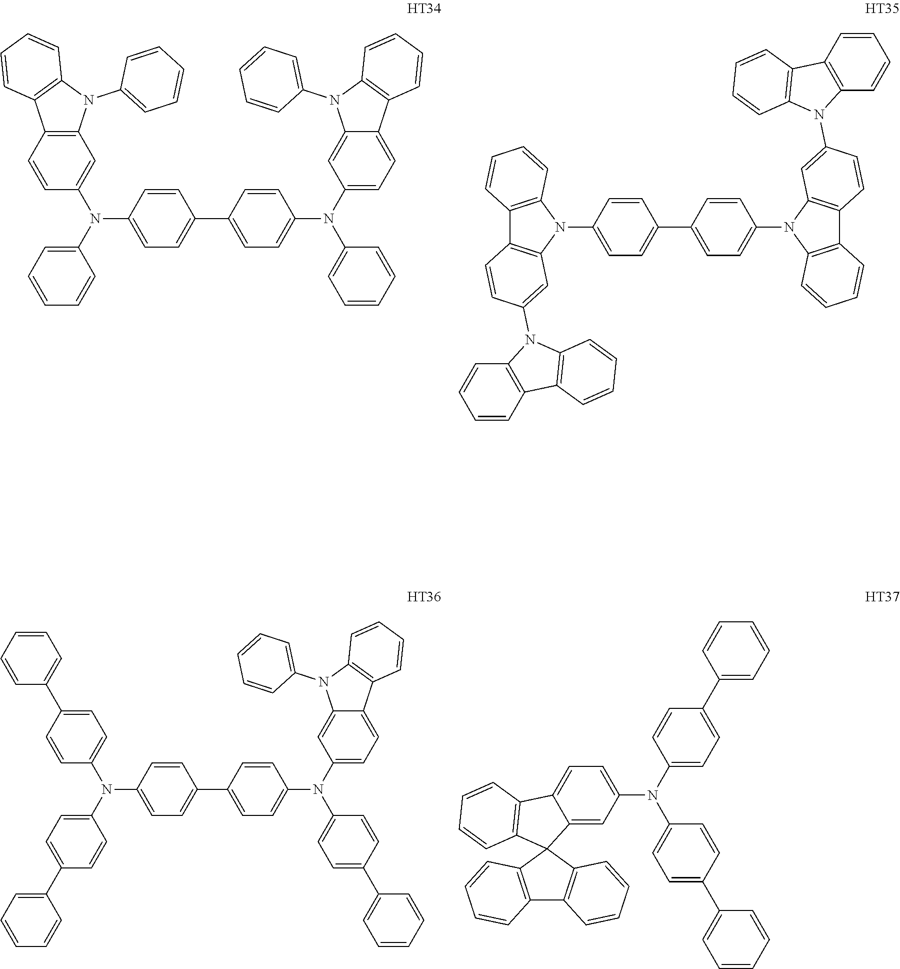 [SMILES: c1ccc(N(c2ccc(-c3ccc(N(c4ccccc4)c4ccc5c6ccccc6n(-c6ccccc6)c5c4)cc3)cc2)c2ccc3c4ccccc4n(-c4ccccc4)c3c2)cc1 ; c1ccc2c(c1)c1ccccc1n2-c1ccc2c3ccccc3n(-c3ccc(-c4ccc(-n5c6ccccc6c6ccc(-n7c8ccccc8c8ccccc87)cc65)cc4)cc3)c2c1 ; c1ccc(-c2ccc(N(c3ccc(-c4ccccc4)cc3)c3ccc(-c4ccc(N(c5ccc(-c6ccccc6)cc5)c5ccc6c7ccccc7n(-c7ccccc7)c6c5)cc4)cc3)cc2)cc1 ; c1ccc(-c2ccc(N(c3ccc(-c4ccccc4)cc3)c3ccc4c(c3)C3(c5ccccc5-c5ccccc53)c3ccccc3-4)cc2)cc1]

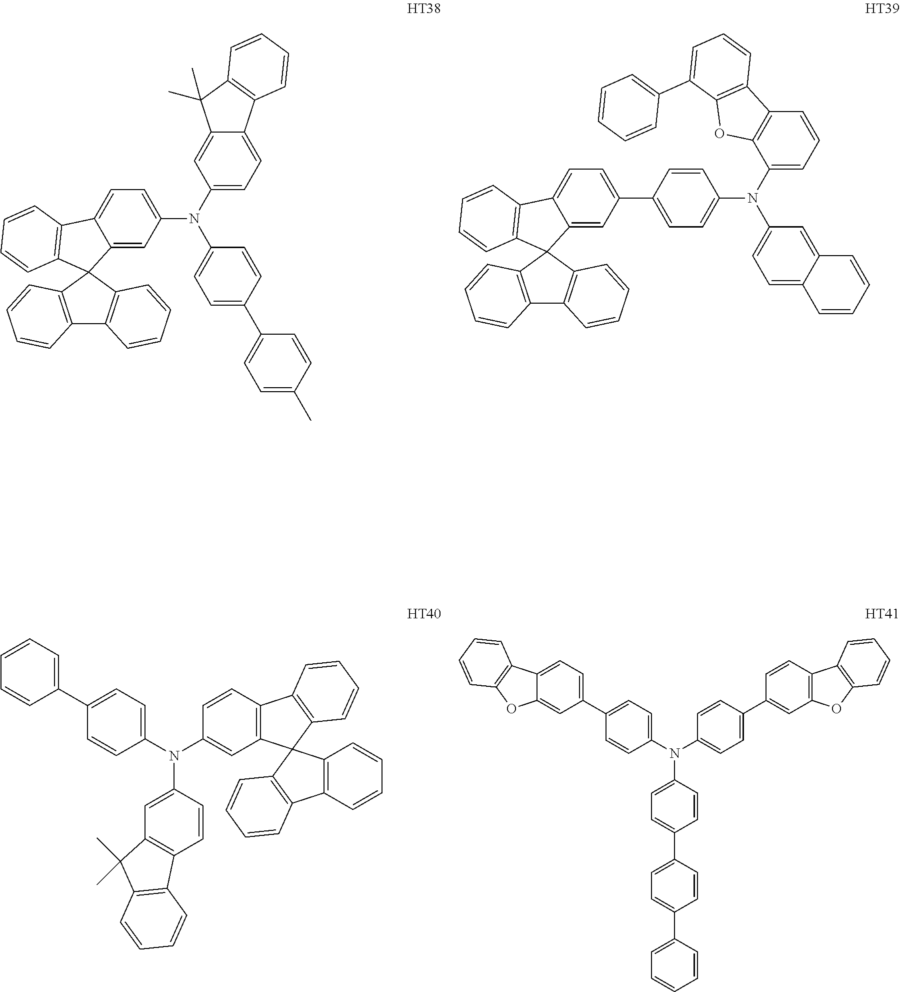 [SMILES: Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(-c3ccc(N(c4ccc(-c5ccc6c(c5)oc5ccccc56)cc4)c4ccc(-c5ccc6c(c5)oc5ccccc56)cc4)cc3)cc2)cc1]

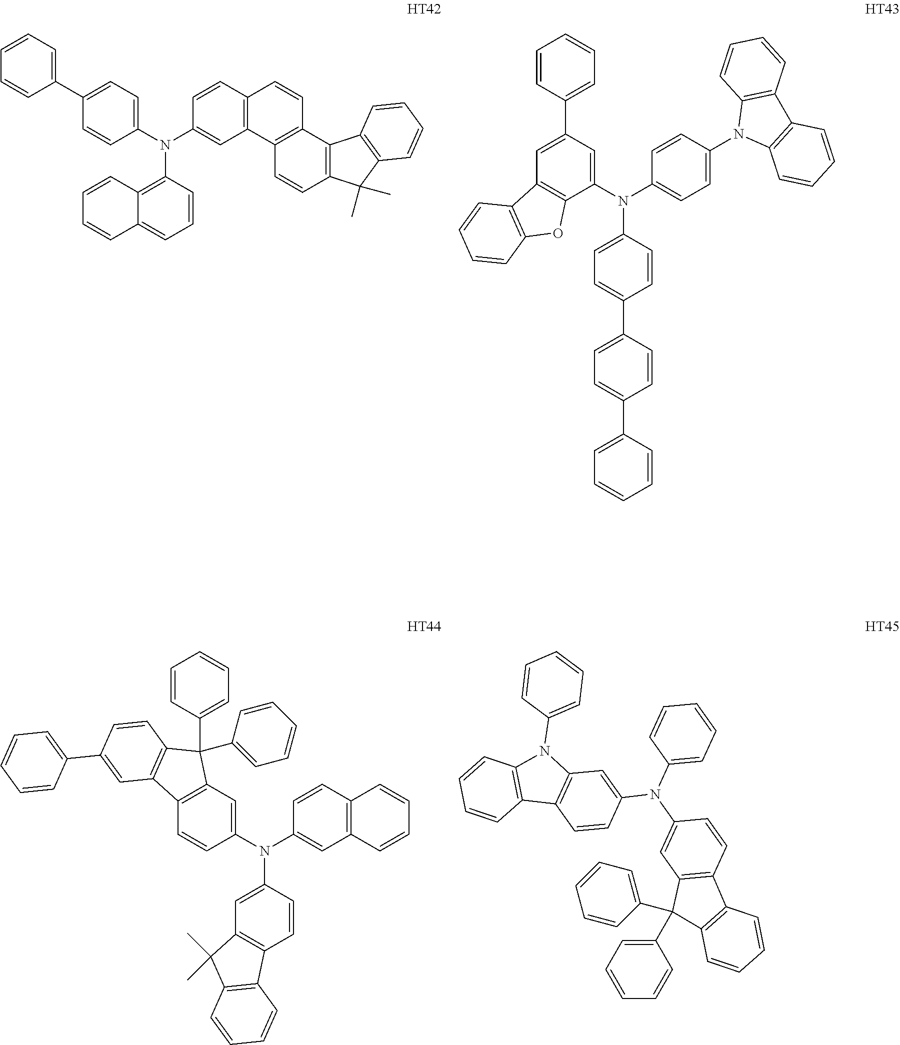 [SMILES: CC1(C)c2ccccc2-c2c1ccc1c2ccc2ccc(N(c3ccc(-c4ccccc4)cc3)c3cccc4ccccc34)cc21 ; c1ccc(-c2ccc(-c3ccc(N(c4ccc(-n5c6ccccc6c6ccccc65)cc4)c4cc(-c5ccccc5)cc5c4oc4ccccc45)cc3)cc2)cc1 ; CC1(C)c2ccccc2-c2ccc(N(c3ccc4c(c3)C(c3ccccc3)(c3ccccc3)c3ccc(-c5ccccc5)cc3-4)c3ccc4ccccc4c3)cc21 ; c1ccc(N(c2ccc3c(c2)C(c2ccccc2)(c2ccccc2)c2ccccc2-3)c2ccc3c4ccccc4n(-c4ccccc4)c3c2)cc1]

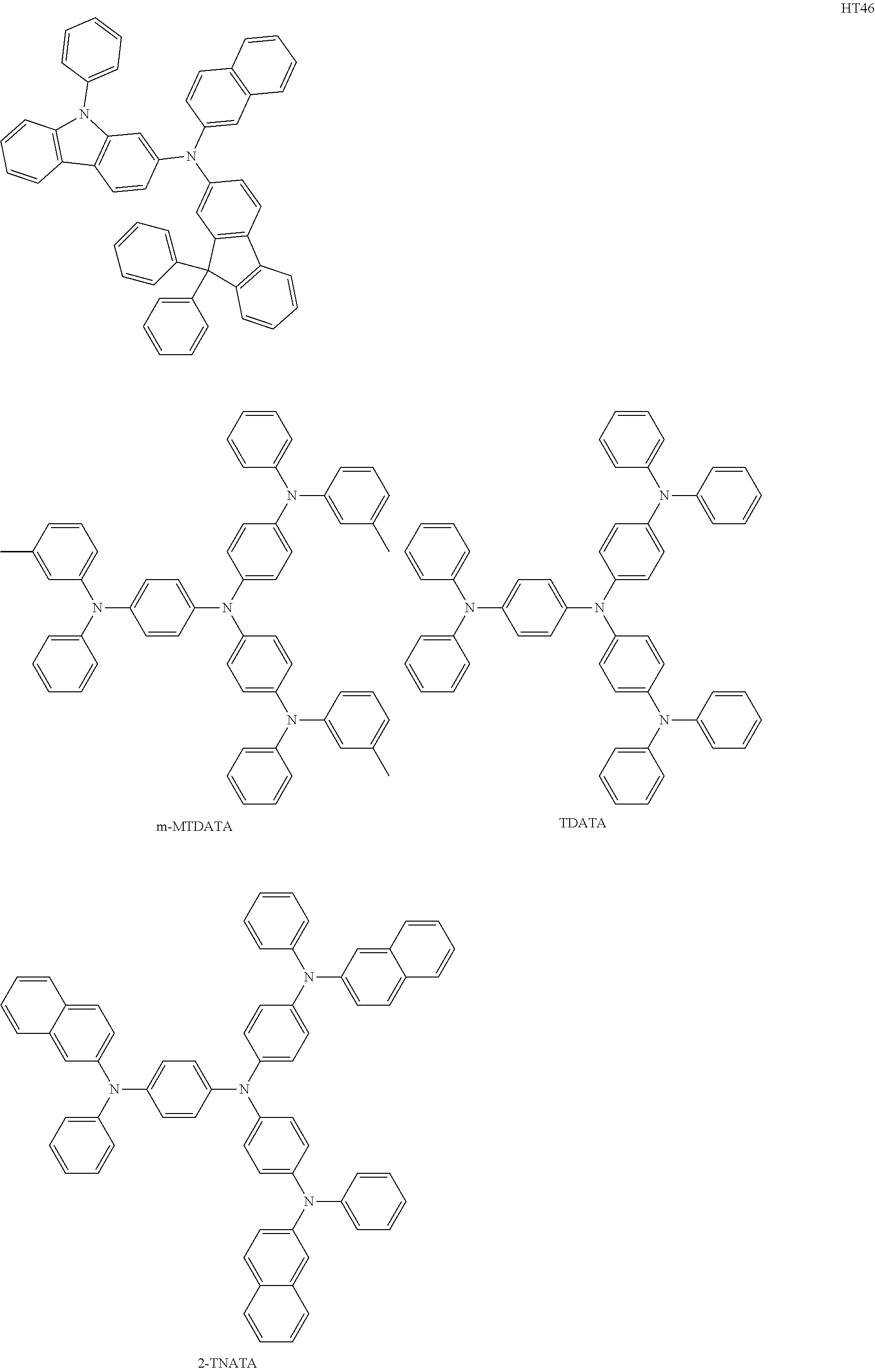

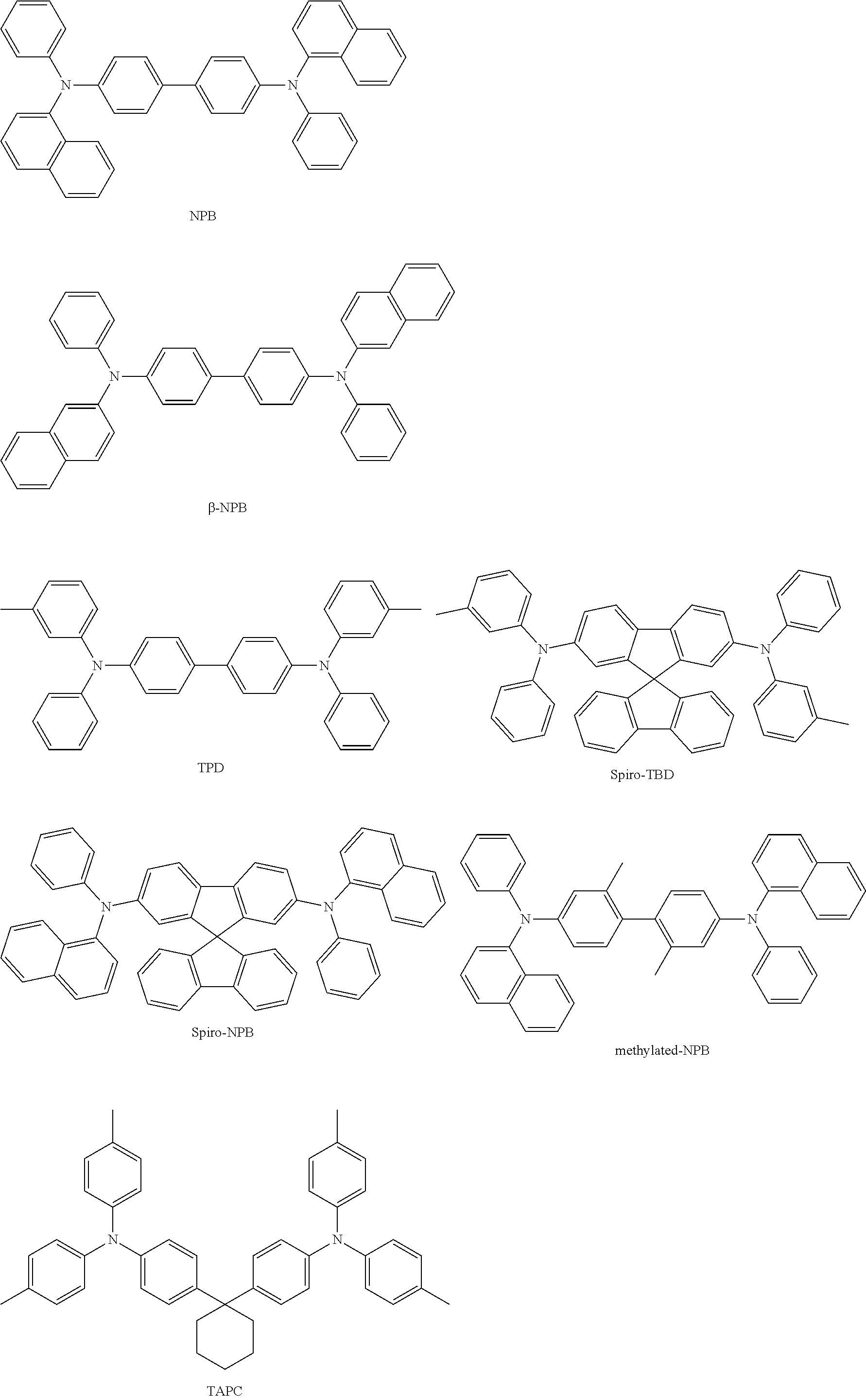

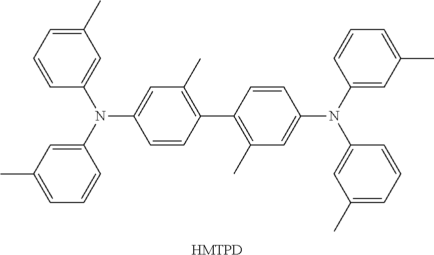

A thickness of the hole transport region may be in a range of about 50 Å to about 10,000 Å. For example, the thickness of the hole transport region may be in a range of about 100 Å to about 4,000 Å. When the hole transport region includes a hole injection layer, a hole transport layer, or any combination thereof, a thickness of the hole injection layer may be in a range of about 100 Å to about 9,000 Å, and a thickness of the hole transport layer may be in a range of about 50 Å to about 2,000 Å. For example, the thickness of the hole injection layer may be in a range of about 100 Å to about 1,000 Å. For example, the thickness of the hole transport layer may be in a range of about 100 Å to about 1,500 Å. When the thicknesses of the hole transport region, the hole injection layer, and the hole transport layer are within these ranges, satisfactory hole transporting characteristics may be obtained without a substantial increase in driving voltage.

The emission auxiliary layer may increase light-emission efficiency by compensating for an optical resonance distance according to a wavelength of light emitted by the emission layer, and the electron blocking layer may block the leakage of electrons from the emission layer to the hole transport region. Materials that may be included in the hole transport region may be included in the emission auxiliary layer and the electron blocking layer.

### p-Dopant

The hole transport region may further include, in addition to these materials, a charge-generation material for the improvement of conductive properties. The charge-generation material may be uniformly or non-uniformly dispersed in the hole transport region (for example, in the form of a single layer consisting of a charge-generation material).

The charge-generation material may be, for example, a p-dopant.

For example, the p-dopant may have a lowest unoccupied molecular orbital (LUMO) energy level equal to or less than about −3.5 eV.

In an embodiment, the p-dopant may include a quinone derivative, a cyano group-containing compound, a compound including element EL1 and element EL2, or any combination thereof.

Examples of the quinone derivative may include TCNQ, F4-TCNQ, and the like.

Examples of the cyano group-containing compound may include HAT-CN, a compound represented by Formula 221, and the like:

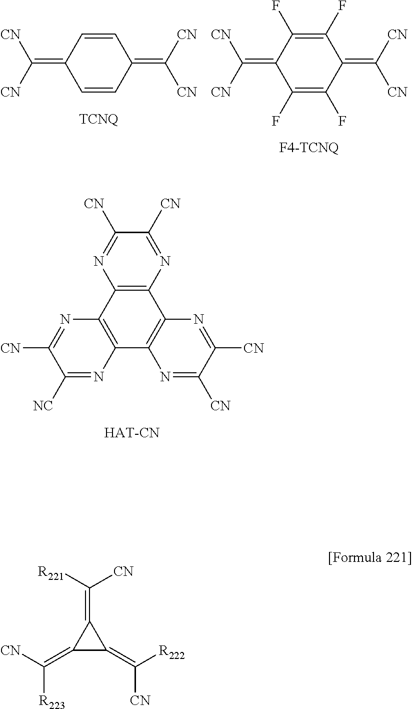

In Formula 221,

R₂₂₁ to R₂₂₃ may each independently be a C₃-C₆₀ carbocyclic group unsubstituted or substituted with at least one R₁₀ₐ or a C₁-C₆₀ heterocyclic group unsubstituted or substituted with at least one R₁₀ₐ, and

at least one of R₂₂₁ to R₂₂₃ may each independently be a C₃-C₆₀ carbocyclic group or a C₁-C₆₀ heterocyclic group, each substituted with: a cyano group; —F; —Cl; —Br;-A; a C₁-C₂₀ alkyl group substituted with a cyano group, —F, —Cl, —Br, —I, or any combination thereof; or any combination thereof.

In the compound including element EL1 and element EL2, element EL1 may be a metal, a metalloid, or any combination thereof, and element EL2 may be a non-metal, a metalloid, or any combination thereof.

Examples of the metal may include: an alkali metal (for example, lithium (Li), sodium (Na), potassium (K), rubidium (Rb), cesium (Cs), etc.); an alkaline earth metal (for example, beryllium (Be), magnesium (Mg), calcium (Ca), strontium (Sr), barium (Ba), etc.); a transition metal (for example, titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), etc.); a post-transition metal (for example, zinc (Zn), indium (In), tin (Sn), etc.); a lanthanide metal (for example, lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), etc.); and the like.

Examples of the metalloid may include silicon (Si), antimony (Sb), tellurium (Te), and the like.

Examples of the non-metal may include oxygen (O), a halogen (for example, F, Cl, Br, I, etc.), and the like.

Examples of the compound including element EL1 and element EL2 may include a metal oxide, a metal halide (for example, a metal fluoride, a metal chloride, a metal bromide, a metal iodide, etc.), a metalloid halide (for example, a metalloid fluoride, a metalloid chloride, a metalloid bromide, a metalloid iodide, etc.), a metal telluride, or any combination thereof.

Examples of the metal oxide may include tungsten oxide (for example, WO, W₂O₃, WO₂, WO₃, W₂O₅, etc.), vanadium oxide (for example, VO, V₂O₃, VO₂, V₂O₅, etc.), molybdenum oxide (MoO, Mo₂O₃, MoO₂, MoO₃, Mo₂O₅, etc.), rhenium oxide (for example, ReO₃, etc.), and the like.

Examples of the metal halide may include an alkali metal halide, an alkaline earth metal halide, a transition metal halide, a post-transition metal halide, a lanthanide metal halide, and the like.

Examples of the alkali metal halide may include LiF, NaF, KF, RbF, CsF, LiCl, NaCl, KCl, RbCl, CsCl, LiBr, NaBr, KBr, RbBr, CsBr, LiI, NaI, KI, RbI, CsI, and the like.

Examples of the alkaline earth metal halide may include BeF₂, MgF₂, CaF₂, SrF₂, BaF₂, BeCl₂, MgCl₂, CaCl₂), SrCl₂, BaCl₂, BeBr₂, MgBr₂, CaBr₂, SrBr₂, BaBr₂, BeI₂, MgI₂, CaI₂, SrI₂, BaI₂, and the like.

Examples of the transition metal halide may include a titanium halide (for example, TiF₄, TiCl₄, TiBr₄, TiI₄, etc.), a zirconium halide (for example, ZrF₄, ZrCl₄, ZrBr₄, ZrI₄, etc.), a hafnium halide (for example, HfF₄, HfCl₄, HfBr₄, HfI₄, etc.), a vanadium halide (for example, VF₃, VCl₃, VBr₃, VI₃, etc.), a niobium halide (for example, NbF₃, NbCl₃, NbBr₃, NbI₃, etc.), a tantalum halide (for example, TaF₃, TaCl₃, TaBr₃, TaI₃, etc.), a chromium halide (for example, CrF₃, CrCl₃, CrBr₃, CrI₃, etc.), a molybdenum halide (for example, MoF₃, MoCl₃, MoBr₃, MoI₃, etc.), a tungsten halide (for example, WF₃, WCl₃, WBr₃, WI₃, etc.), a manganese halide (for example, MnF₂, MnCl₂, MnBr₂, MnI₂, etc.), a technetium halide (for example, TcF₂, TcCl₂, TcBr₂, TcI₂, etc.), a rhenium halide (for example, ReF₂, ReCl₂, ReBr₂, ReI₂, etc.), an iron halide (for example, FeF₂, FeCl₂, FeBr₂, FeI₂, etc.), a ruthenium halide (for example, RuF₂, RuCl₂, RuBr₂, RuI₂, etc.), an osmium halide (for example, OsF₂, OSCl₂, OsBr₂, OSI₂, etc.), a cobalt halide (for example, CoF₂, CoCl₂, CoBr₂, C₀₁₂, etc.), a rhodium halide (for example, RhF₂, RhCl₂, RhBr₂, RhI₂, etc.), an iridium halide (for example, IrF₂, IrCl₂, IrBr₂, IrI₂, etc.), a nickel halide (for example, NiF₂, NiCl₂, NiBr₂, NiI₂, etc.), a palladium halide (for example, PdF₂, PdCl₂, PdBr₂, PdI₂, etc.), a platinum halide (for example, PtF₂, PtCl₂, PtBr₂, PtI₂, etc.), a copper halide (for example, CuF, CuCl, CuBr, CuI, etc.), a silver halide (for example, AgF, AgCl, AgBr, AgI, etc.), a gold halide (for example, AuF, AuCl, AuBr, AuI, etc.), and the like.

Examples of the post-transition metal halide may include a zinc halide (for example, ZnF₂, ZnCl₂, ZnBr₂, ZnI₂, etc.), an indium halide (for example, InI₃, etc.), a tin halide (for example, SnI₂, etc.), and the like.

Examples of the lanthanide metal halide may include YbF, YbF₂, YbF₃, SmF₃, YbCl, YbCl₂, YbCl₃, SmCl₃, YbBr, YbBr₂, YbBr₃ SmBr₃, YbI, YbI₂, YbI₃, SmI₃, and the like.

Examples of the metalloid halide may include an antimony halide (for example, SbCl₅, etc.) and the like.

Examples of the metal telluride may include an alkali metal telluride (for example, Li₂Te, a Na₂Te, K₂Te, Rb₂Te, Cs₂Te, etc.), an alkaline earth metal telluride (for example, BeTe, MgTe, CaTe, SrTe, BaTe, etc.), a transition metal telluride (for example, TiTe₂, ZrTe₂, HfTe₂, V₂Te₃, Nb₂Te₃, Ta₂Te₃, Cr₂Te₃, Mo₂Te₃, W₂Te₃, MnTe, TcTe, ReTe, FeTe, RuTe, OsTe, CoTe, RhTe, IrTe, NiTe, PdTe, PtTe, Cu₂Te, CuTe, Ag₂Te, AgTe, Au₂Te, etc.), a post-transition metal telluride (for example, ZnTe, etc.), a lanthanide metal telluride (for example, LaTe, CeTe, PrTe, NdTe, PmTe, EuTe, GdTe, TbTe, DyTe, HoTe, ErTe, TmTe, YbTe, LuTe, etc.), and the like.

### Emission Layer in Interlayer 130

When the light-emitting device 10 is a full-color light-emitting device, the emission layer may be patterned into a red emission layer, a green emission layer, and/or a blue emission layer, according to a subpixel. In an embodiment, the emission layer may have a stacked structure of two or more layers of a red emission layer, a green emission layer, and a blue emission layer, in which the two or more layers may contact each other or may be separated from each other to emit white light. In embodiments, the emission layer may include two or more materials of a red light-emitting material, a green light-emitting material, and a blue light-emitting material, in which the two or more materials may be mixed with each other in a single layer to emit white light. For example, the emission layer may emit blue light.

In an embodiment, the emission layer may include the condensed cyclic compound represented by Formula 1 as described in the specification.

The emission layer may include a host and a dopant.

In an embodiment, the dopant may include the condensed cyclic compound represented by Formula 1 as described in the specification. In this regard, the dopant may include, in addition to the condensed cyclic compound represented by Formula 1, a phosphorescent dopant, a fluorescent dopant, or any combination thereof. In addition to the condensed cyclic compound represented by Formula 1, the emission layer may further include a phosphorescent dopant, a fluorescent dopant, or the like, and the phosphorescent dopant and the fluorescent dopant will be described later.

In the emission layer, an amount of the dopant may be in a range of about 0.01 parts by weight to about 15 parts by weight, based on 100 parts by weight of the host.

In embodiments, the emission layer may include a quantum dot.

In embodiments, the emission layer may include a delayed fluorescence material. The delayed fluorescence material may serve as a host or as a dopant in the emission layer.

A thickness of the emission layer may be in a range of about 100 Å to about 1,000 Å. For example, the thickness of the emission layer may be in a range of about 200 Å to about 600 Å. When the thickness of the emission layer is within these ranges, excellent luminescence characteristics may be obtained without a substantial increase in driving voltage.

### Host

The host in the emission layer may include the second compound or the third compound described in the specification, or any combination thereof.

In an embodiment, the host may include a compound represented by Formula 301:

[Formula 301][Ar₃₀₁]_{xb11}-[(L₃₀₁)_{xb1}-R₃₀₁]_{xb21}

In Formula 301,

Ar₃₀₁ and L₃₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xb11 may be 1, 2, or 3,

xb1 may be an integer from 0 to 5,

R₃₀₁ may be hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₃₀₁)(Q₃₀₂)(Q₃₀₃), —N(Q₃₀₁)(Q₃₀₂), —B(Q₃₀₁)(Q₃₀₂), —C(═O)(Q₃₀₁), —S(═O)₂(Q₃₀₁), or —P(═O)(Q₃₀₁)(Q₃₀₂),

xb21 may be an integer from 1 to 5, and

Q₃₀₁ to Q₃₀₃ may independently each be the same as described in connection with Q₁.

In an embodiment, in Formula 301, when xb11 is 2 or more, two or more of Ar₃₀₁(s) may be bonded to each other via a single bond.

In embodiments, the host may include a compound represented by Formula 301-1, a compound represented by Formula 301-2, or any combination thereof:

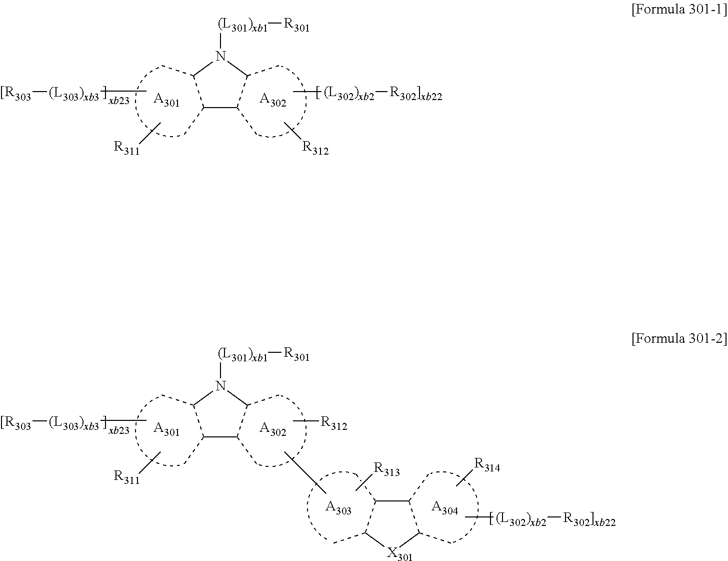

In Formulae 301-1 and 301-2,

ring A₃₀₁ to ring A₃₀₄ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

X₃₀₁ may be O, S, N-[(L₃₀₄)_{xb4}-R₃₀₄], C(R₃₀₄)(R₃₀₅), or Si(R₃₀₄)(R₃₀₅),

xb22 and xb23 may each independently be 0, 1, or 2,

L₃₀₁, xb1, and R₃₀₁ may each be the same as described herein,

L₃₀₂ to L₃₀₄ may each independently be the same as described in connection with L₃₀₁,

xb2 to xb4 may each independently be the same as described in connection with xb1, and

R₃₀₂ to R₃₀₅ and R₃₁₁ to R₃₁₄ may each independently be the same as described in connection with R₃₀₁.

In embodiments, the host may include an alkali earth metal complex, a post-transition metal complex, or any combination thereof. For example, the host may include a Be complex (for example, Compound H55), an Mg complex, a Zn complex, or any combination thereof.

In embodiments, the host may include one of Compounds H1 to H124, 9,10-di(2-naphthyl)anthracene (ADN), 2-methyl-9,10-bis(naphthalen-2-yl)anthracene (MADN), 9,10-di-(2-naphthyl)-2-t-butyl-anthracene (TBADN), 4,4′-bis(N-carbazolyl)-1,1′-biphenyl (CBP), 1,3-di-9-carbazolylbenzene (mCP), 1,3,5-tri(carbazol-9-yl)benzene (TCP), or any combination thereof:

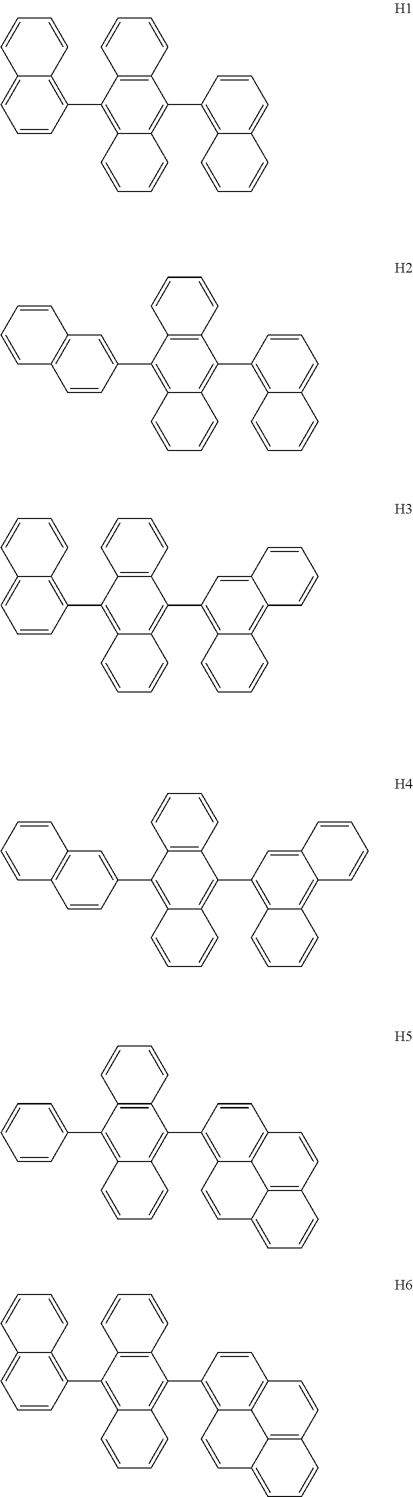

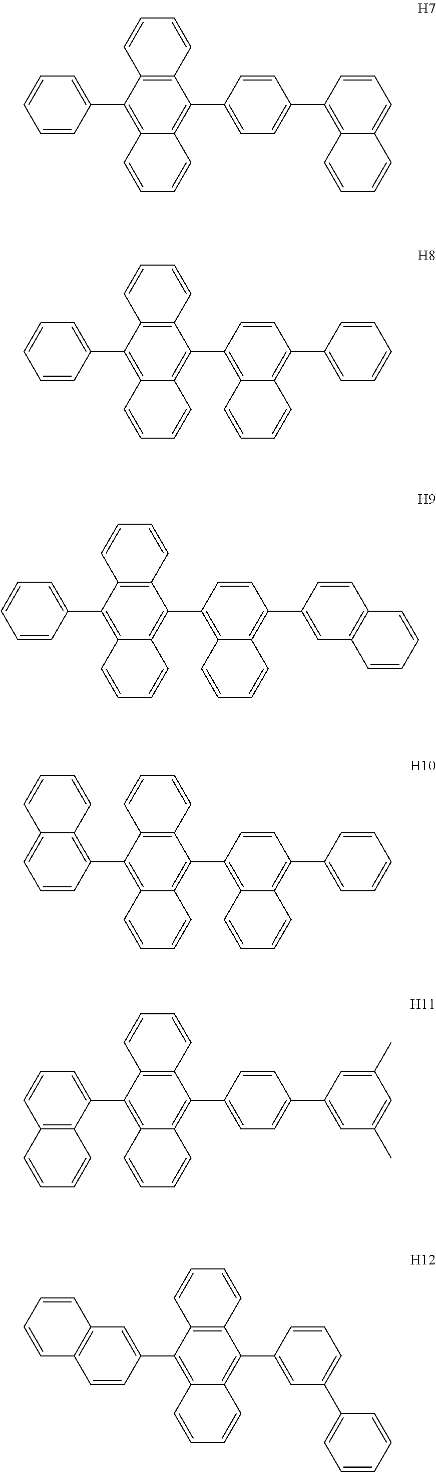

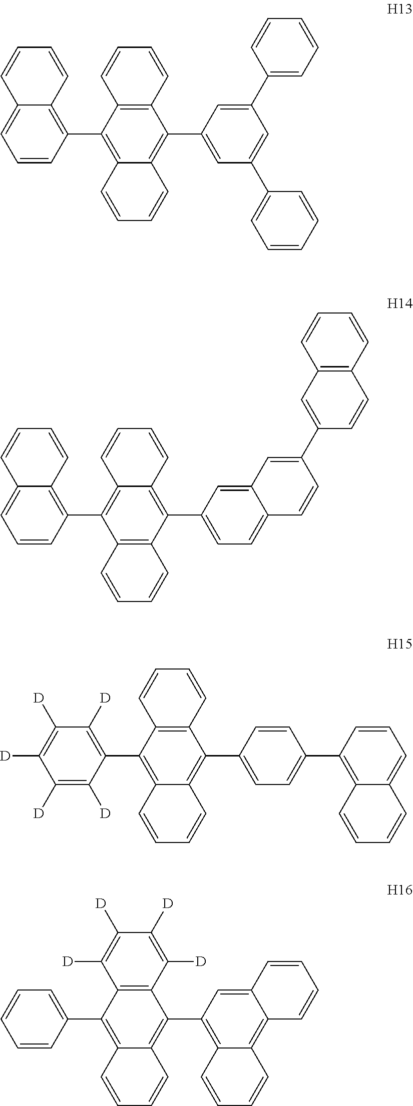

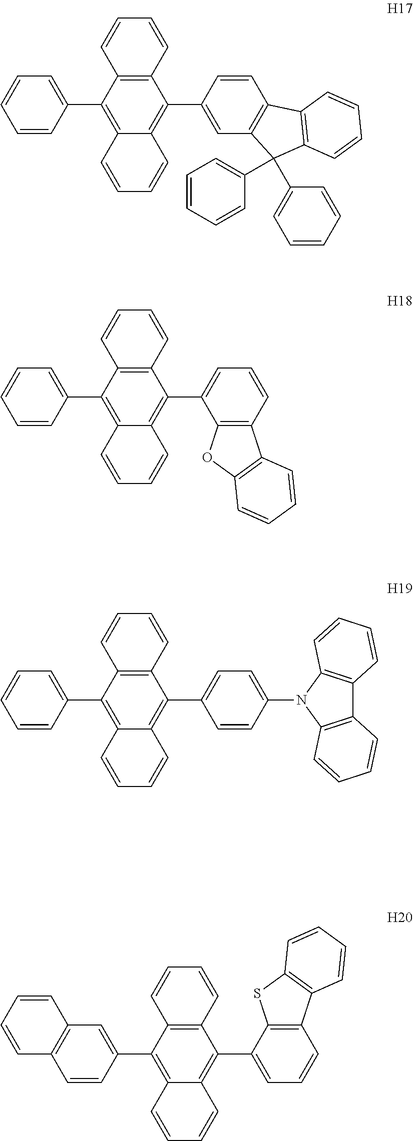

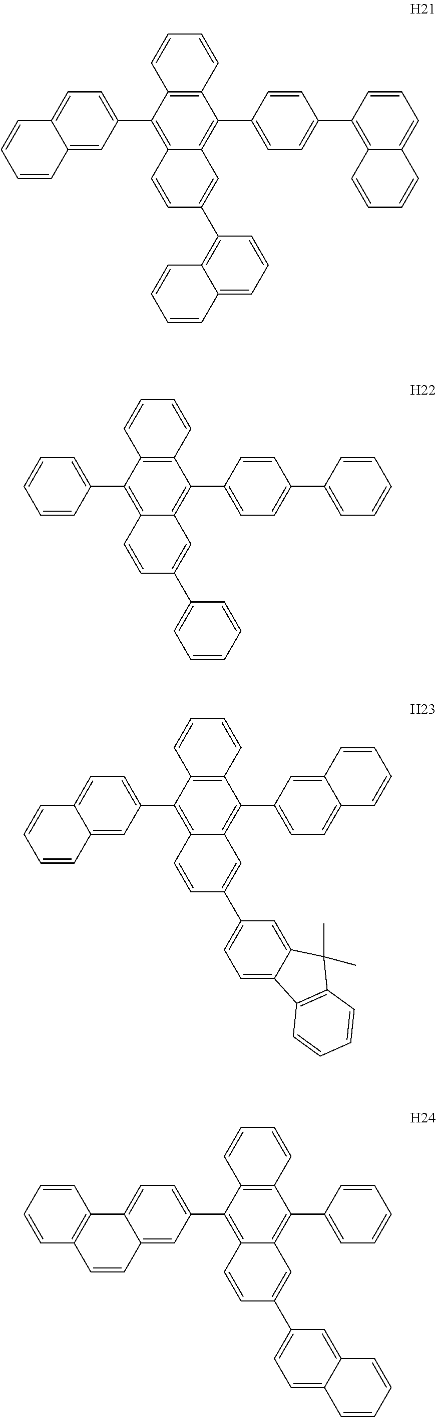

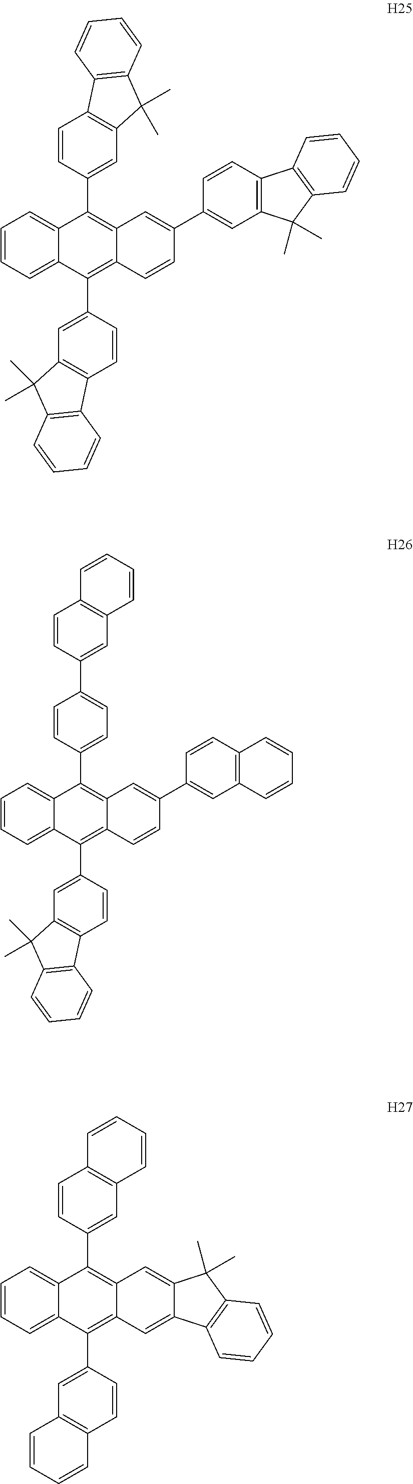

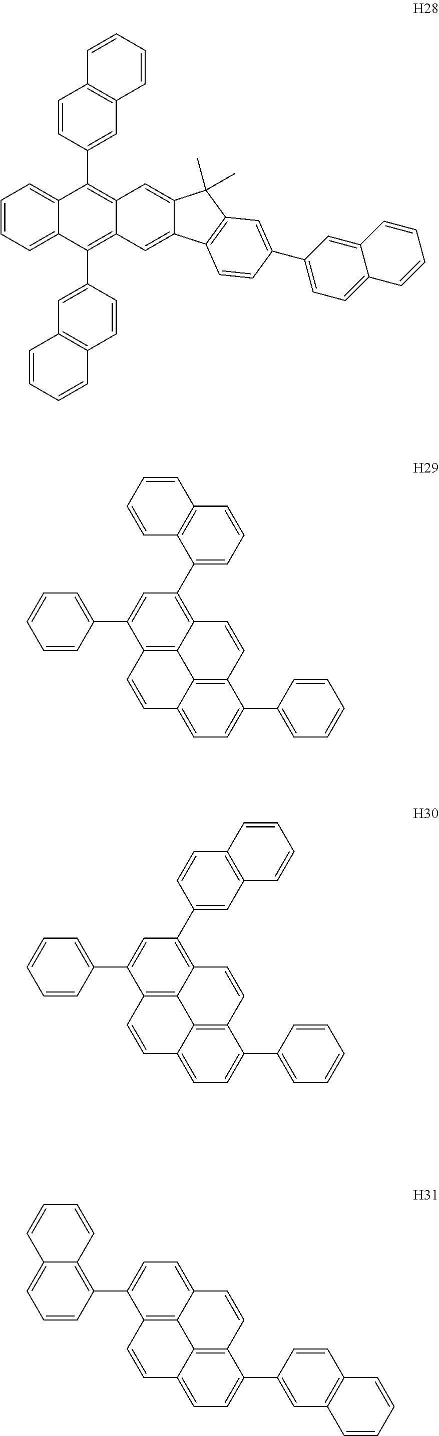

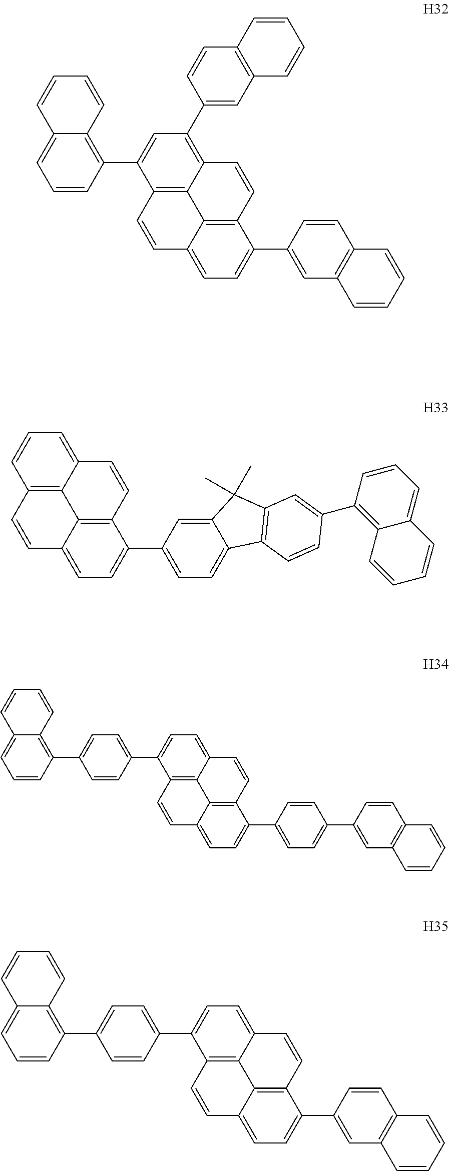

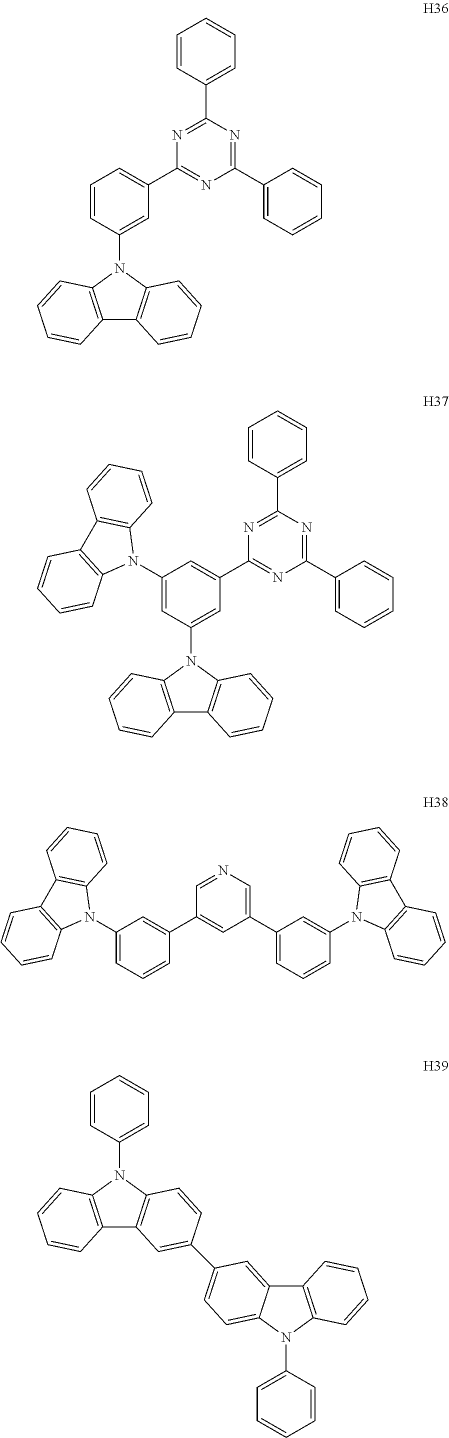 [SMILES: c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1 ; c1ccc(-n2c3ccccc3c3cc(-c4ccc5c(c4)c4ccccc4n5-c4ccccc4)ccc32)cc1]

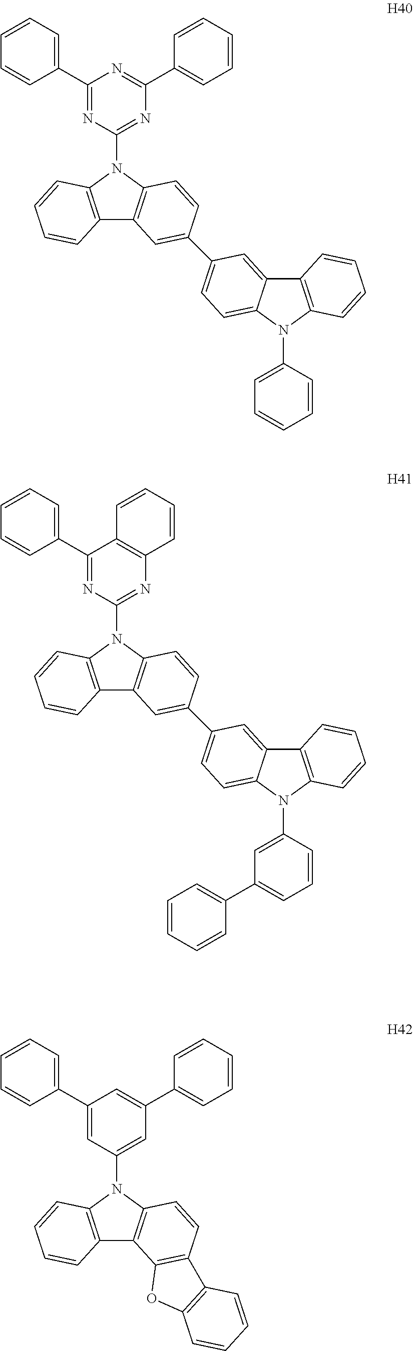 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5nc(-c6ccccc6)c6ccccc6n5)ccc43)c2)cc1 ; c1ccc(-c2cc(-c3ccccc3)cc(-n3c4ccccc4c4c5oc6ccccc6c5ccc43)c2)cc1]

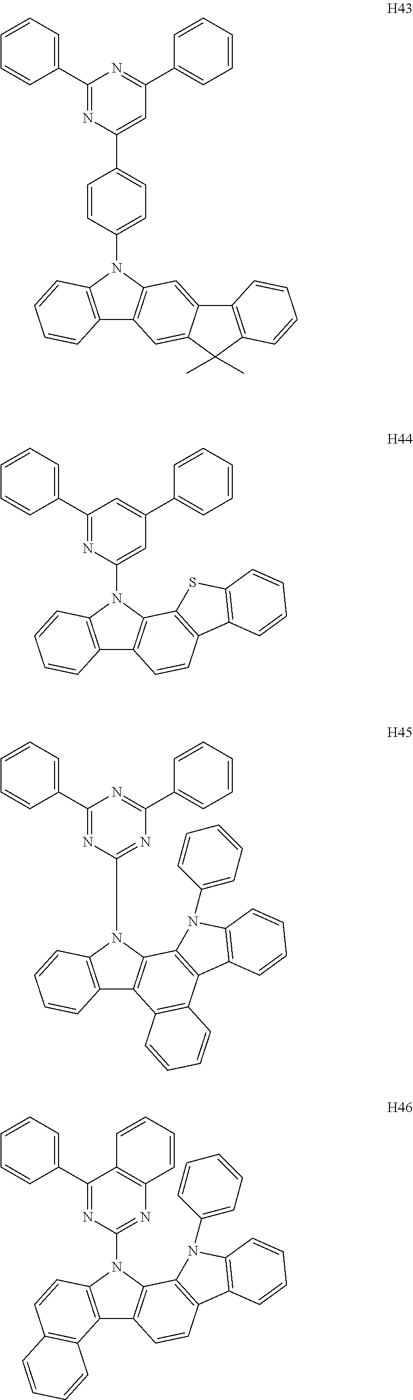 [SMILES: CC1(C)c2ccccc2-c2cc3c(cc21)c1ccccc1n3-c1ccc(-c2cc(-c3ccccc3)nc(-c3ccccc3)n2)cc1 ; c1ccc(-c2cc(-c3ccccc3)nc(-n3c4ccccc4c4ccc5c6ccccc6sc5c43)c2)cc1 ; c1ccc(-c2nc(-c3ccccc3)nc(-n3c4ccccc4c4c5ccccc5c5c6ccccc6n(-c6ccccc6)c5c43)n2)cc1 ; c1ccc(-c2nc(-n3c4ccc5ccccc5c4c4ccc5c6ccccc6n(-c6ccccc6)c5c43)nc3ccccc23)cc1]

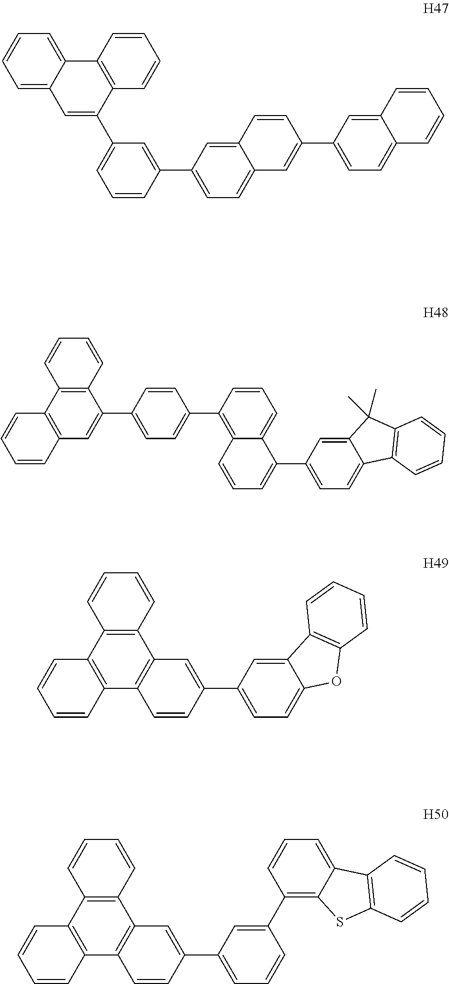

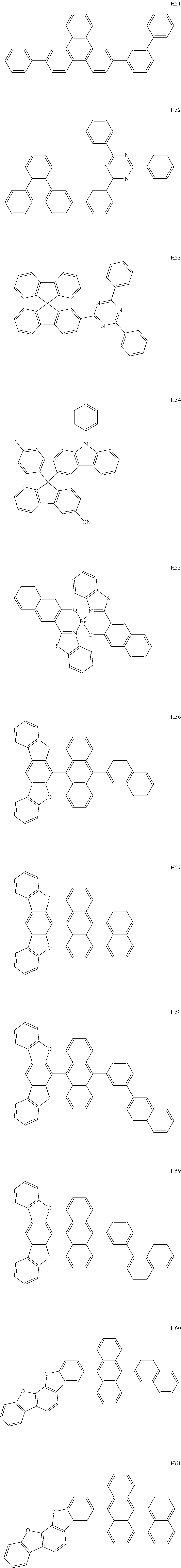

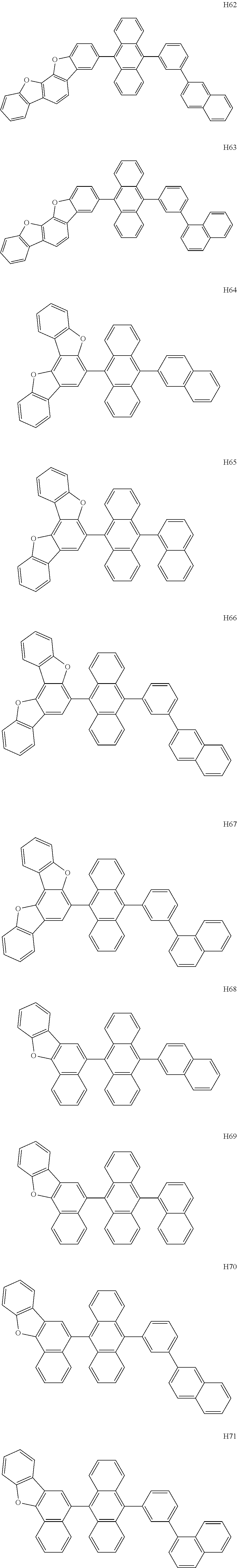

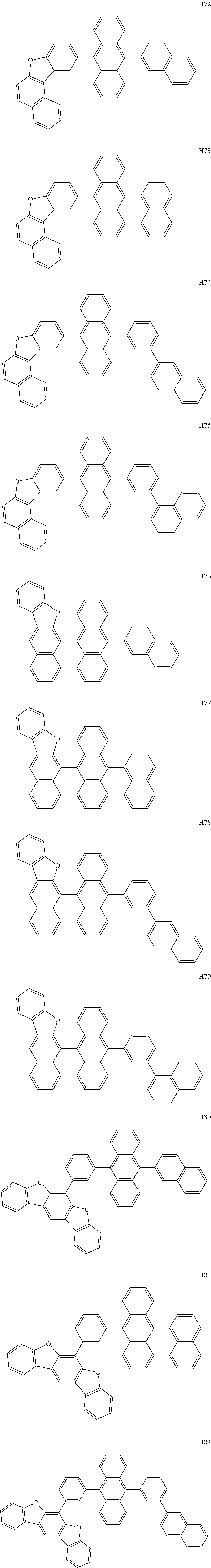

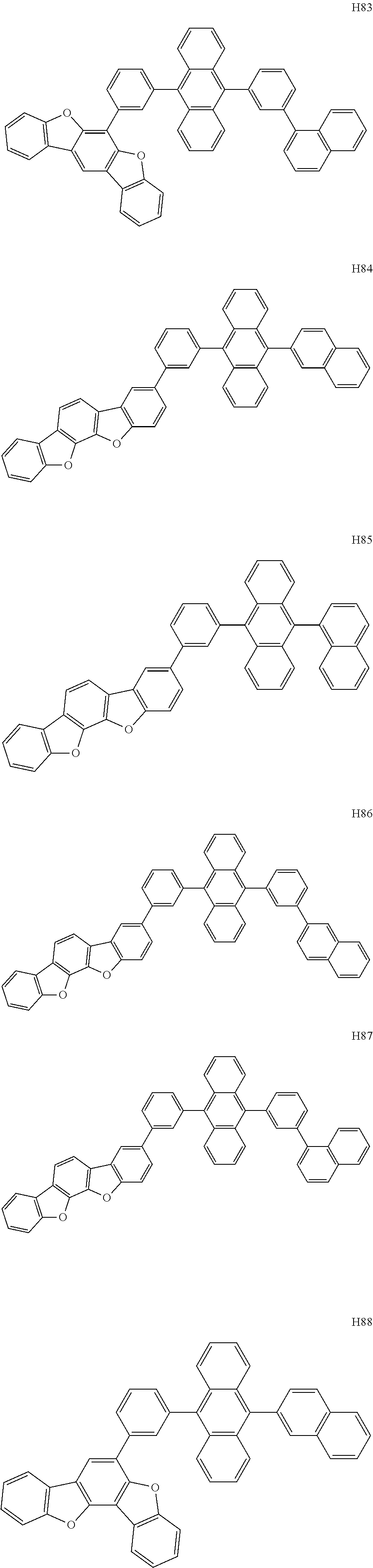

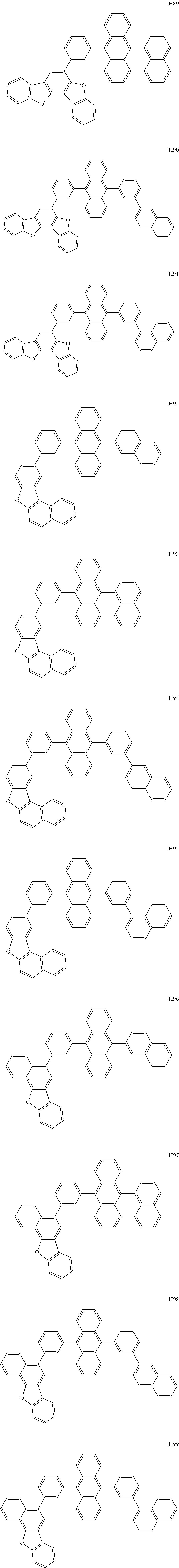

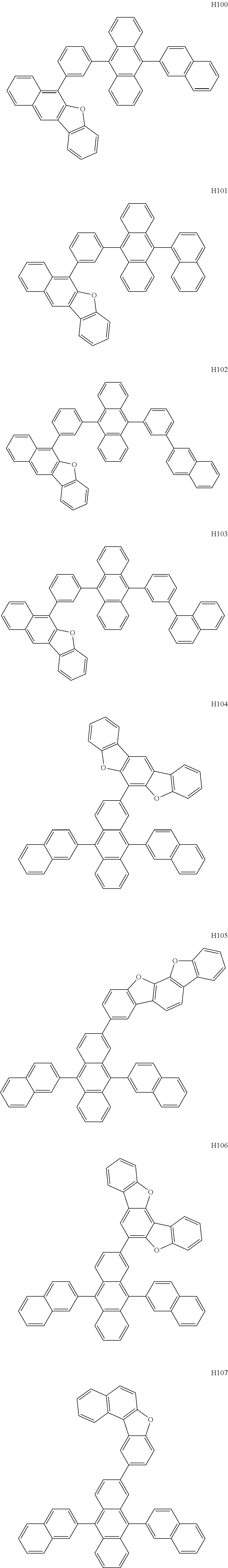

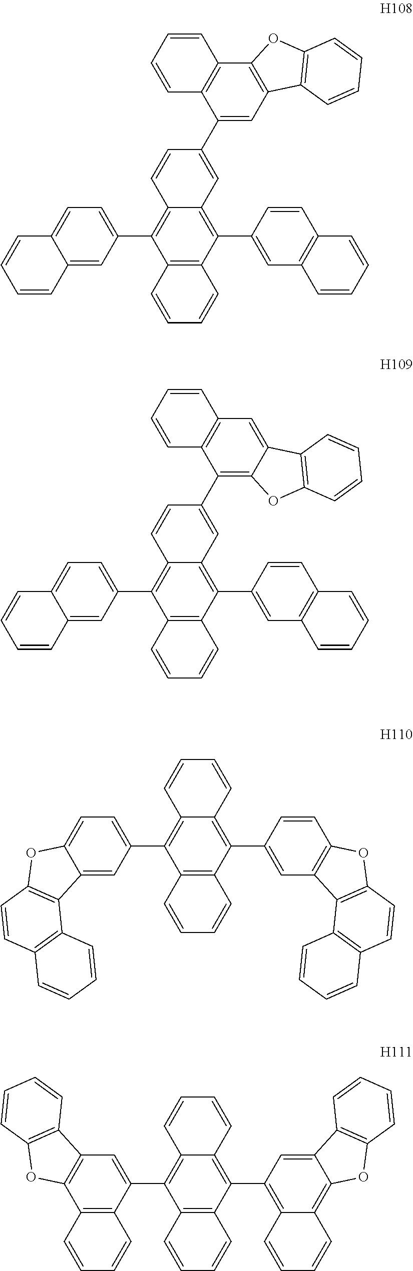 [SMILES: c1ccc2cc(-c3c4ccccc4c(-c4ccc5ccccc5c4)c4cc(-c5cc6c7ccccc7oc6c6ccccc56)ccc34)ccc2c1 ; c1ccc2cc(-c3c4ccccc4c(-c4ccc5ccccc5c4)c4cc(-c5c6ccccc6cc6c5oc5ccccc56)ccc34)ccc2c1 ; c1ccc2c(c1)ccc1oc3ccc(-c4c5ccccc5c(-c5ccc6oc7ccc8ccccc8c7c6c5)c5ccccc45)cc3c12 ; c1ccc2c(c1)oc1c3ccccc3c(-c3c4ccccc4c(-c4cc5c6ccccc6oc5c5ccccc45)c4ccccc34)cc21]

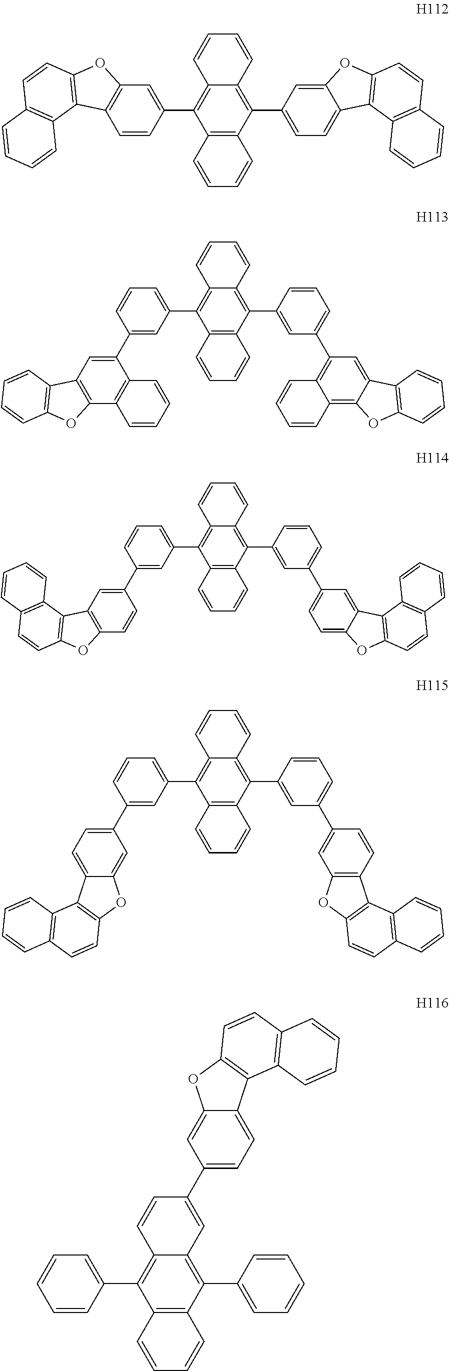 [SMILES: c1ccc2c(c1)ccc1oc3cc(-c4c5ccccc5c(-c5ccc6c(c5)oc5ccc7ccccc7c56)c5ccccc45)ccc3c12 ; c1cc(-c2c3ccccc3c(-c3cccc(-c4cc5c6ccccc6oc5c5ccccc45)c3)c3ccccc23)cc(-c2cc3c4ccccc4oc3c3ccccc23)c1 ; c1cc(-c2ccc3oc4ccc5ccccc5c4c3c2)cc(-c2c3ccccc3c(-c3cccc(-c4ccc5oc6ccc7ccccc7c6c5c4)c3)c3ccccc23)c1 ; c1cc(-c2ccc3c(c2)oc2ccc4ccccc4c23)cc(-c2c3ccccc3c(-c3cccc(-c4ccc5c(c4)oc4ccc6ccccc6c45)c3)c3ccccc23)c1 ; c1ccc(-c2c3ccccc3c(-c3ccccc3)c3cc(-c4ccc5c(c4)oc4ccc6ccccc6c45)ccc23)cc1]

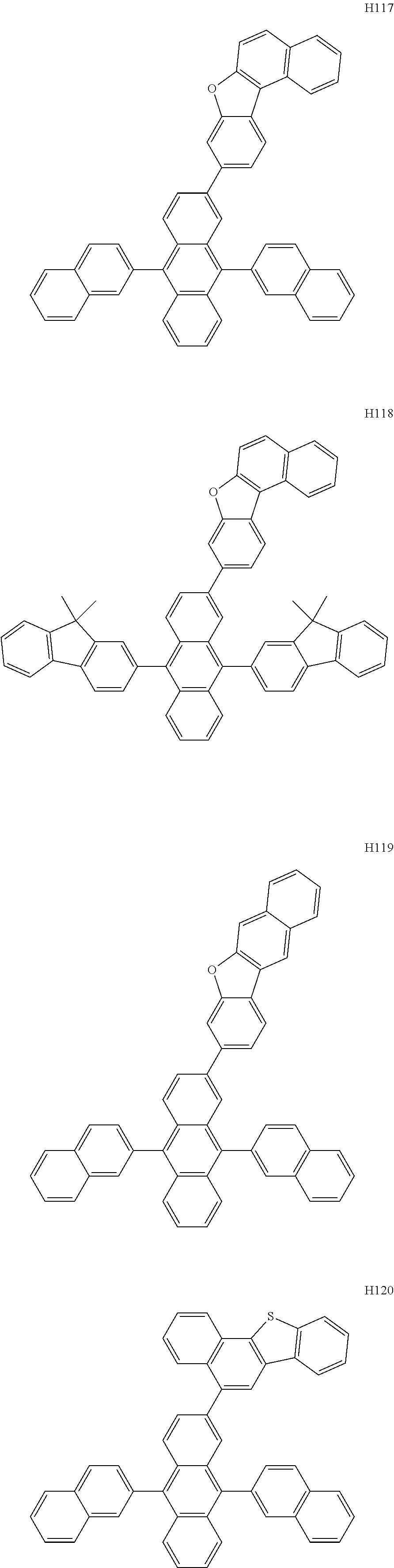 [SMILES: c1ccc2cc(-c3c4ccccc4c(-c4ccc5ccccc5c4)c4cc(-c5ccc6c(c5)oc5ccc7ccccc7c56)ccc34)ccc2c1 ; CC1(C)c2ccccc2-c2ccc(-c3c4ccccc4c(-c4ccc5c(c4)C(C)(C)c4ccccc4-5)c4cc(-c5ccc6c(c5)oc5ccc7ccccc7c56)ccc34)cc21 ; c1ccc2cc(-c3c4ccccc4c(-c4ccc5ccccc5c4)c4cc(-c5ccc6c(c5)oc5cc7ccccc7cc56)ccc34)ccc2c1 ; c1ccc2cc(-c3c4ccccc4c(-c4ccc5ccccc5c4)c4cc(-c5cc6c7ccccc7sc6c6ccccc56)ccc34)ccc2c1]

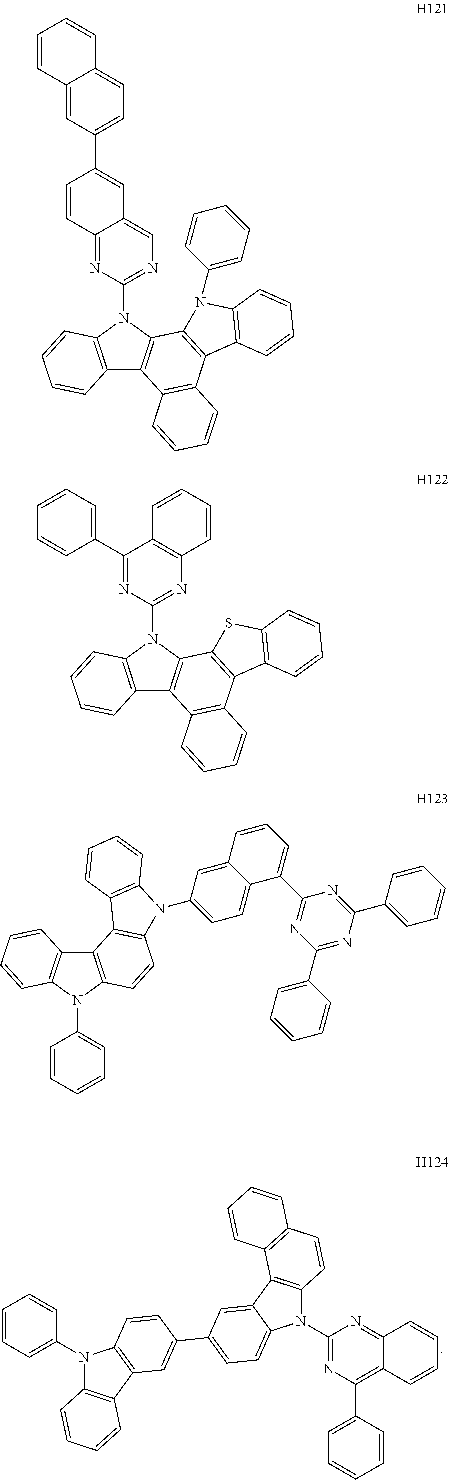

### Phosphorescent Dopant

The phosphorescent dopant may include at least one transition metal as a central metal.

The phosphorescent dopant may include a monodentate ligand, a bidentate ligand, a tridentate ligand, a tetradentate ligand, a pentadentate ligand, a hexadentate ligand, or any combination thereof.

The phosphorescent dopant may be electrically neutral.

In embodiments, the phosphorescent dopant may include an organometallic compound represented by Formula 401:

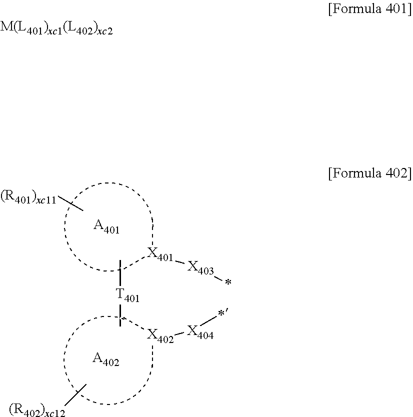

Formulae 401 and 402 may each be the same as described herein.

The phosphorescent dopant may include, for example, one of Compounds PD1 to PD40, or any combination thereof.

### Fluorescent Dopant

The fluorescent dopant may include an amine group-containing compound, a styryl group-containing compound, or any combination thereof.

In embodiments, the fluorescent dopant may include a compound represented by Formula 501:

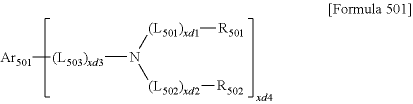

In Formula 501,

Ar₅₀₁, L₅₀₁ to L₅₀₃, R₅₀₁, and R₅₀₂ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xd1 to xd3 may each independently be 0, 1, 2, or 3, and

xd4 may be 1, 2, 3, 4, 5, or 6.

In an embodiment, in Formula 501, Ar₅₀₁ may be a condensed cyclic group (for example, an anthracene group, a chrysene group, a pyrene group, etc.) in which three or more monocyclic groups are condensed together.

In an embodiment, in Formula 501, xd4 may be 2.

For example, the fluorescent dopant may include one of Compounds FD1 to FD36, DPVBi, DPAVBi, or any combination thereof:

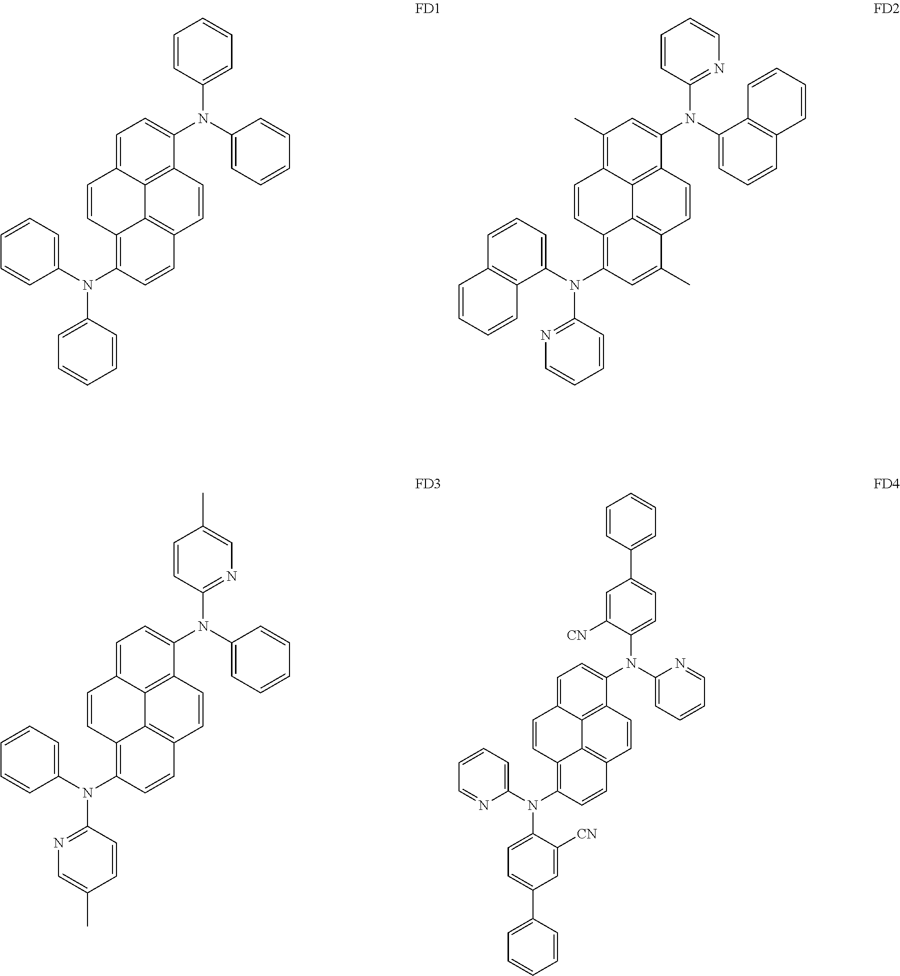

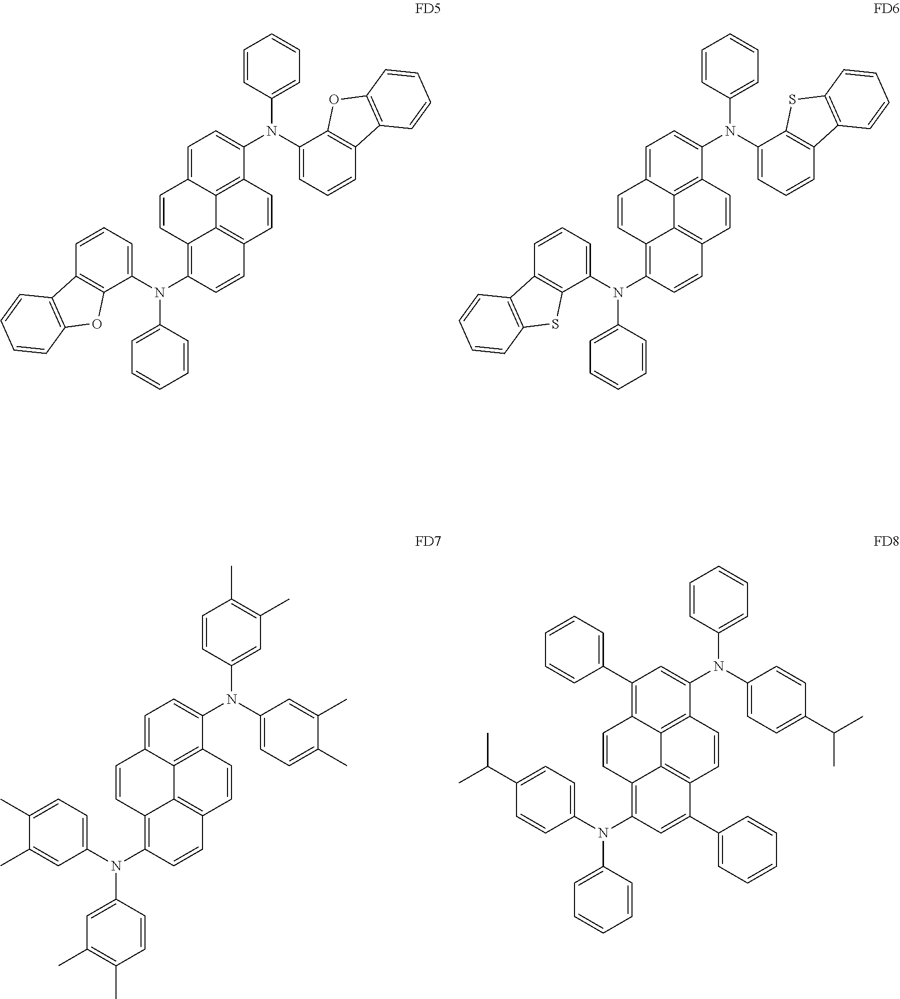

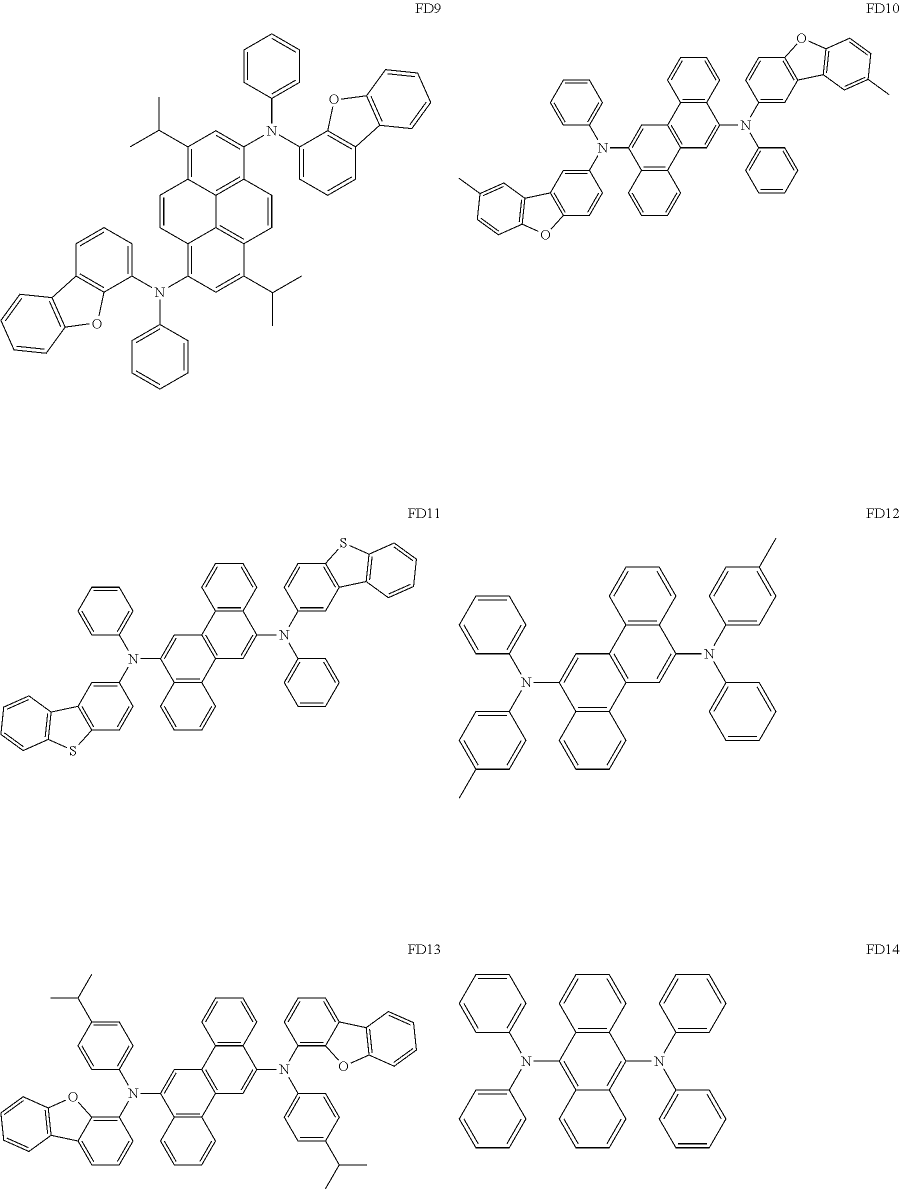

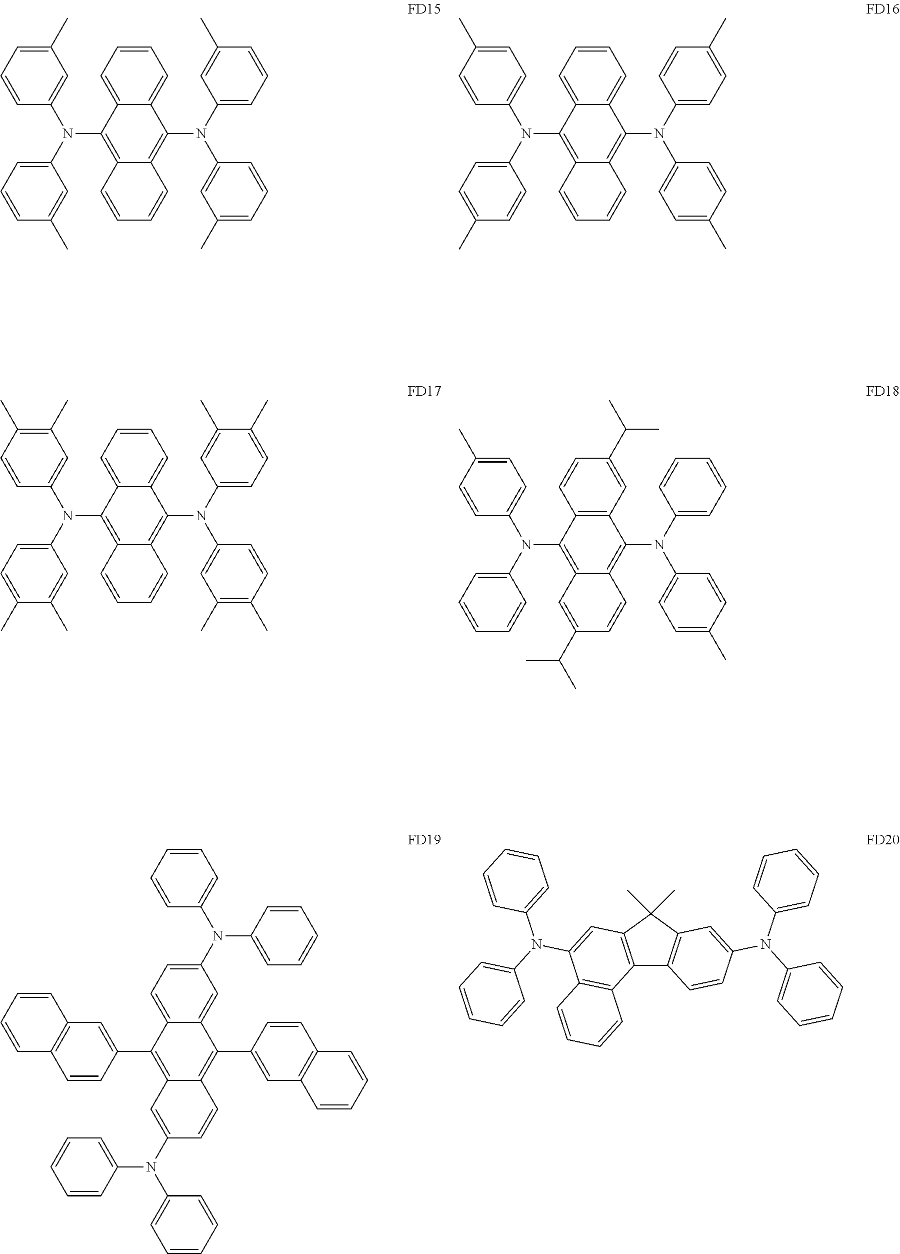 [SMILES: Cc1cccc(N(c2cccc(C)c2)c2c3ccccc3c(N(c3cccc(C)c3)c3cccc(C)c3)c3ccccc23)c1 ; Cc1ccc(N(c2ccc(C)cc2)c2c3ccccc3c(N(c3ccc(C)cc3)c3ccc(C)cc3)c3ccccc23)cc1 ; Cc1ccc(N(c2ccc(C)c(C)c2)c2c3ccccc3c(N(c3ccc(C)c(C)c3)c3ccc(C)c(C)c3)c3ccccc23)cc1C ; Cc1ccc(N(c2ccccc2)c2c3ccc(C(C)C)cc3c(N(c3ccccc3)c3ccc(C)cc3)c3ccc(C(C)C)cc23)cc1 ; c1ccc(N(c2ccccc2)c2ccc3c(-c4ccc5ccccc5c4)c4cc(N(c5ccccc5)c5ccccc5)ccc4c(-c4ccc5ccccc5c4)c3c2)cc1 ; CC1(C)c2cc(N(c3ccccc3)c3ccccc3)ccc2-c2c1cc(N(c1ccccc1)c1ccccc1)c1ccccc21]

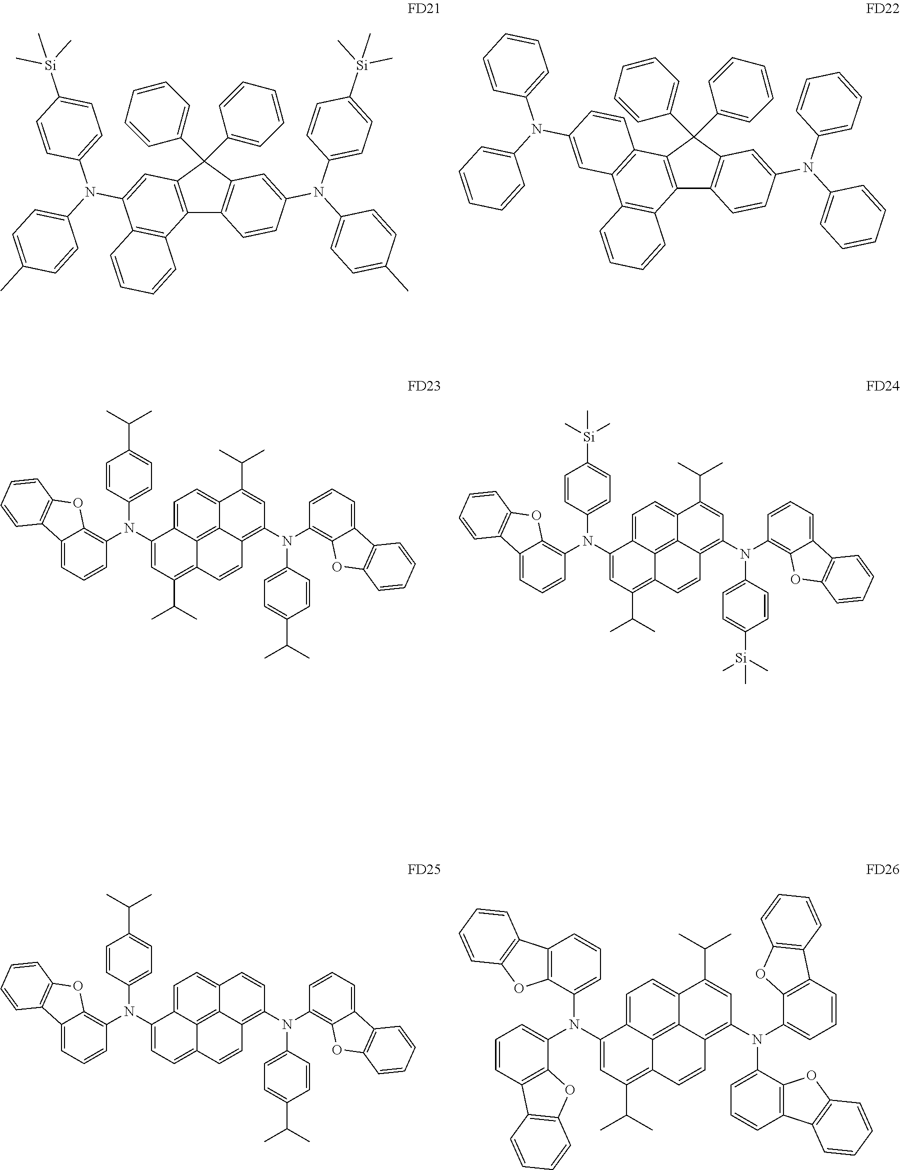

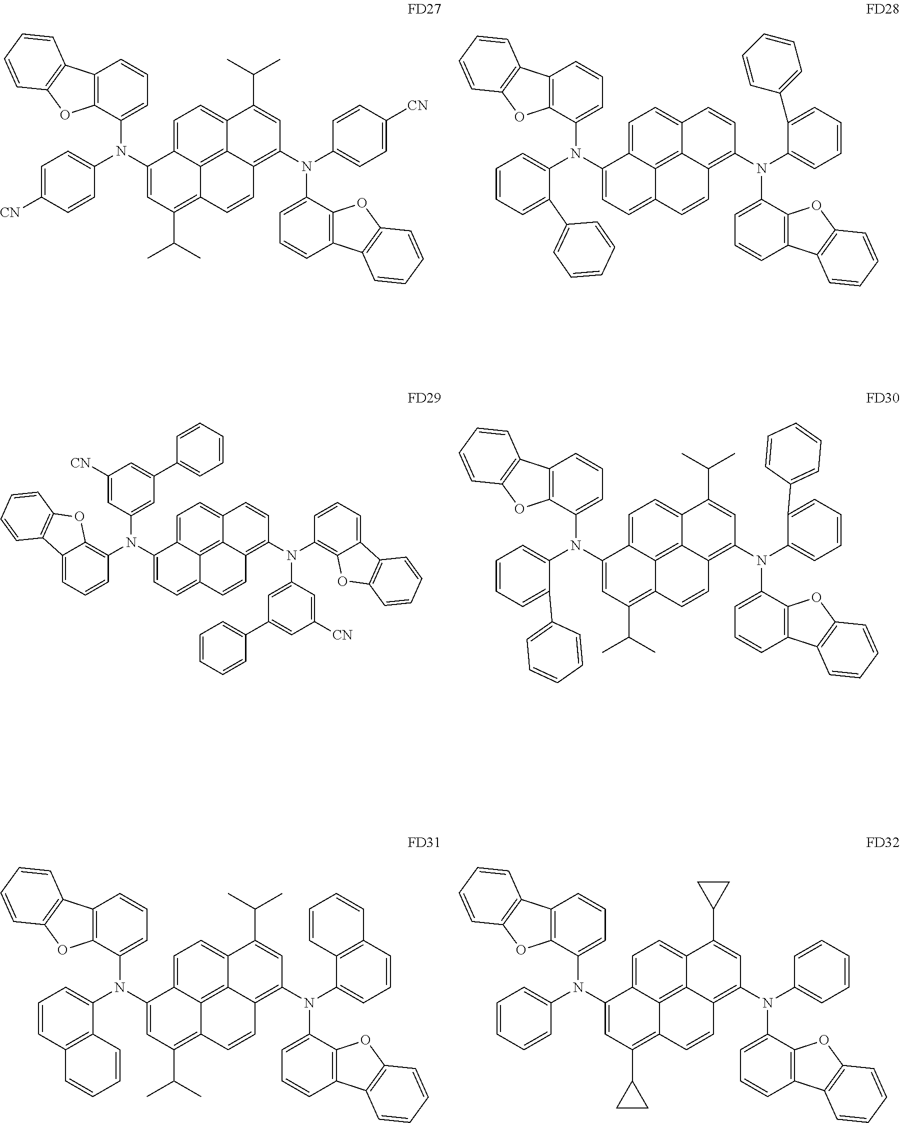

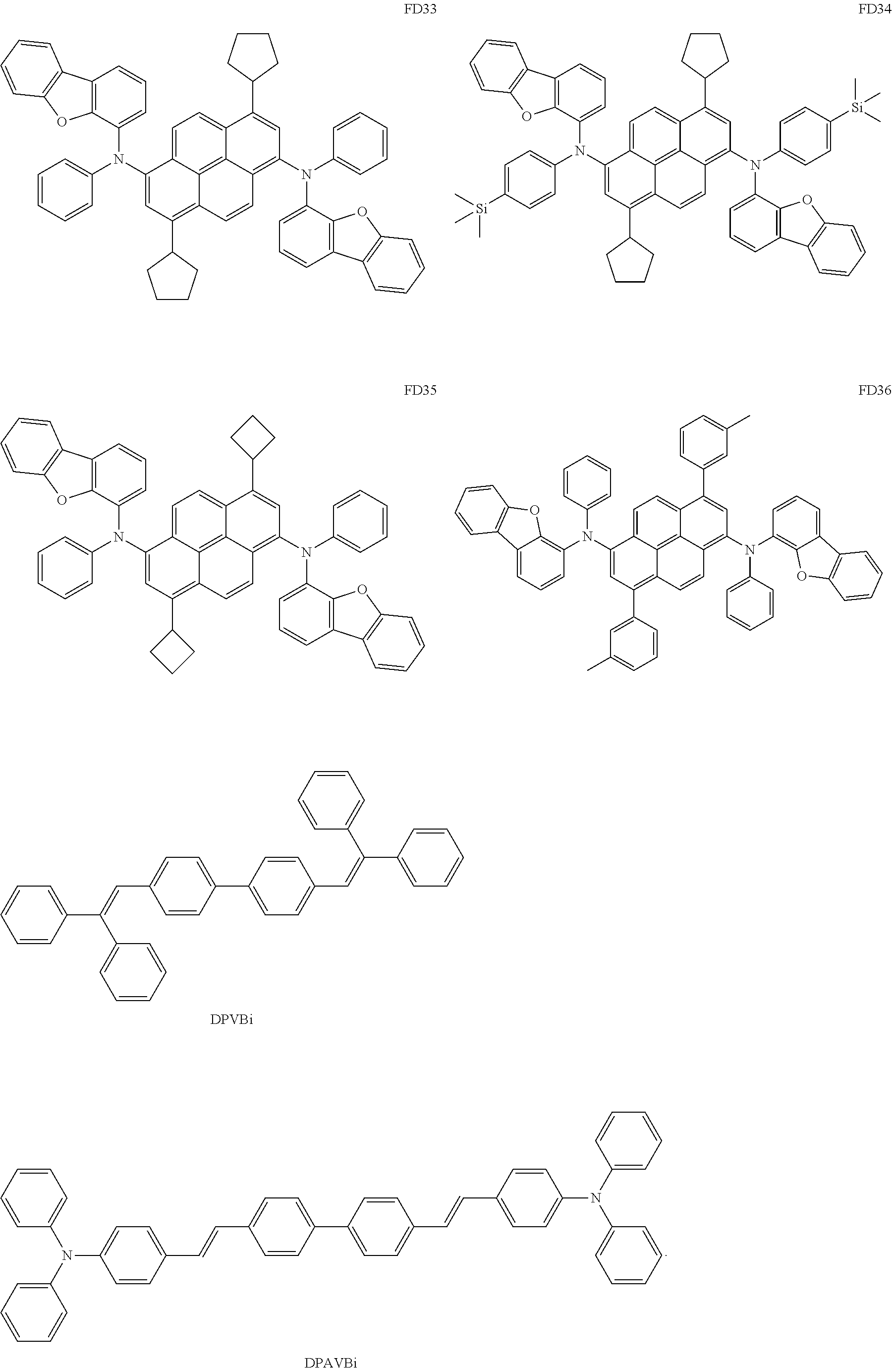

### Quantum Dot

The emission layer may include a quantum dot.

In the specification, a quantum dot may be a crystal of a semiconductor compound, and may include any material capable of emitting light of various emission wavelengths according to a size of the crystal.

A diameter of the quantum dot may be, for example, in a range of about 1 nm to about 10 nm.

The quantum dot may be synthesized by a wet chemical process, a metal organic chemical vapor deposition process, a molecular beam epitaxy process, or any process similar thereto.

The wet chemical process is a method that includes mixing a precursor material with an organic solvent and growing quantum dot particle crystals. When the crystal grows, the organic solvent naturally acts as a dispersant coordinated on the surface of the quantum dot crystal and controls the growth of the crystal so that the growth of quantum dot particles can be controlled through a process which costs lower, and may be more readily performed than vapor deposition methods, such as metal organic chemical vapor deposition (MOCVD) or molecular beam epitaxy (MBE).

The quantum dot may include a Group II-VI semiconductor compound, a Group III-V semiconductor compound, a Group III-VI semiconductor compound, a Group I-III-VI semiconductor compound, a Group IV-VI semiconductor compound, a Group IV element or compound, or any combination thereof.

Examples of the Group II-VI semiconductor compound may include: a binary compound, such as CdS, CdSe, CdTe, ZnS, ZnSe, ZnTe, ZnO, HgS, HgSe, HgTe, MgSe, MgS, and the like; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and the like; a quaternary compound, such as CdZnSeS, CdZnSeTe, CdZnSTe, CdHgSeS, CdHgSeTe, CdHgSTe, HgZnSeS, HgZnSeTe, HgZnSTe, and the like; or any combination thereof.

Examples of the Group III-V semiconductor compound may include: a binary compound, such as GaN, GaP, GaAs, GaSb, AlN, AlP, AlAs, AlSb, InN, InP, InAs, InSb, or the like; a ternary compound, such as GaNP, GaNAs, GaNSb, GaPAs, GaPSb, AlNP, AlNAs, AlNSb, AlPAs, AlPSb, InGaP, InNP, InAlP, InNAs, InNSb, InPAs, InPSb, GaAlNP, or the like; a quaternary compound, such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, or the like; or any combination thereof. In an embodiment, the Group III-V semiconductor compound may further include a Group II element. Examples of the Group III-V semiconductor compound further including the Group II element may include InZnP, InGaZnP, InAlZnP, and the like.

Examples of the Group III-VI semiconductor compound may include: a binary compound, such as GaS, GaSe, Ga₂Se₃, GaTe, InS, InSe, In₂S₃, In₂Se₃, InTe, and the like; a ternary compound, such as InGaS₃, InGaSe₃, and the like; or any combination thereof.

Examples of the Group I-III-VI semiconductor compound may include: a ternary compound, such as AgInS, AgInS₂, CuInS, CuInS₂, CuGaO₂, AgGaO₂, AgAlO₂, and the like; or any combination thereof.

Examples of the Group IV-VI semiconductor compound may include: a binary compound, such as SnS, SnSe, SnTe, PbS, PbSe, PbTe, and the like; a ternary compound, such as SnSeS, SnSeTe, SnSTe, PbSeS, PbSeTe, PbSTe, SnPbS, SnPbSe, SnPbTe, and the like; a quaternary compound, such as SnPbSSe, SnPbSeTe, SnPbSTe, and the like; or any combination thereof.

Examples of the Group IV element or compound may include: a single element material, such as Si, Ge, and the like; a binary compound, such as SiC, SiGe, and the like; or any combination thereof.

Each element included in a multi-element compound, such as a binary compound, a ternary compound, or a quaternary compound, may be present in a particle at a uniform concentration or at a non-uniform concentration.

In an embodiment, the quantum dot may have a single structure in which the concentration of each element in the quantum dot may be uniform, or the quantum dot may have a core-shell structure. For example, when the quantum dot has a core-shell structure, a material included in the core and a material included in the shell may be different from each other.

The shell of the quantum dot may serve as a protective layer which prevents chemical denaturation of the core to maintain semiconductor characteristics, and/or may serve as a charging layer which imparts electrophoretic characteristics to the quantum dot. The shell may be a single layer or a multi-layer. An interface between the core and the shell may have a concentration gradient in which the concentration of a material that is present in the shell decreases toward the core.

Examples of the shell of the quantum dot may include a metal oxide, a metalloid oxide, a non-metal oxide, a semiconductor compound, or any combination thereof. Examples of the metal oxide, the metalloid oxide, or the non-metal oxide may include: a binary compound, such as SiO₂, Al₂O₃, TiO₂, ZnO, MnO, Mn₂O₃, Mn₃O₄, CuO, FeO, Fe₂O₃, Fe₃O₄, CoO, CO₃O₄, NiO, and the like; a ternary compound, such as MgAl₂O₄, CoFe₂O₄, NiFe₂O₄, CoMn₂O₄, and the like; or any combination thereof.

Examples of the semiconductor compound may include, as described herein, a Group II-VI semiconductor compound, a Group III-V semiconductor compound, a Group III-VI semiconductor compound, a Group I-III-VI semiconductor compound, a Group IV-VI semiconductor compound, or any combination thereof. Examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or any combination thereof.

The quantum dot may have a full width of half maximum (FWHM) of an emission wavelength spectrum equal to or less than about 45 nm. For example, the quantum dot may have a FWHM of an emission wavelength spectrum equal to or less than about 40 nm. For example, the quantum dot may have a FWHM of an emission wavelength spectrum equal to or less than about 30 nm. When the FWHM of the quantum dot is within these ranges, the quantum dot may have improved color purity or color reproducibility. Light emitted through the quantum dot may be emitted in all directions, so that a wide viewing angle may be improved.

The quantum dot may be in the form of a spherical particle, a pyramidal particle, a multi-arm particle, a cubic nanoparticle, a nanotube particle, a nanowire particle, a nanofiber particle, or a nanoplate particle.

Since the energy band gap may be adjusted by controlling the size of the quantum dot, light having various wavelength bands may be obtained from the quantum dot emission layer. Accordingly, by using quantum dots of different sizes, a light-emitting device that emits light of various wavelengths may be implemented. In an embodiment, the size of the quantum dot may be selected to emit red, green, and/or blue light. For example, the size of the quantum dot may be configured to emit white light by combination of light of various colors.

### Electron Transport Region in Interlayer 130

The electron transport region may have a structure consisting of a layer consisting of a single material, a structure consisting of a layer consisting of different materials, or a structure including multiple layers including different materials.

The electron transport region may include a buffer layer, a hole blocking layer, an electron control layer, an electron transport layer, an electron injection layer, or any combination thereof.

For example, the electron transport region may have an electron transport layer/electron injection layer structure, a hole blocking layer/electron transport layer/electron injection layer structure, an electron control layer/electron transport layer/electron injection layer structure, or a buffer layer/electron transport layer/electron injection layer structure, wherein the layers of each structure are may be stacked from an emission layer in its respective stated order, but the structure of the electron transport region is not limited thereto.

In an embodiment, the electron transport region (for example, the buffer layer, the hole blocking layer, the electron control layer, or the electron transport layer in the electron transport region) may include a metal-free compound including at least one rr electron-deficient nitrogen-containing C₁-C₆₀ cyclic group.

For example, the electron transport region may include a compound represented by Formula 601:

[Ar₆₀₁]ₓₑ₁₁-[(L₆₀₁)ₓₑ₁-R₆₀₁]ₓₑ₂₁ [Formula 601]

In Formula 601,

Ar₆₀₁ and L₆₀₁ may each independently be a C₃-C₆₀ carbocyclic group unsubstituted or substituted with at least one R₁₀ₐ or a C₁-C₆₀ heterocyclic group unsubstituted or substituted with at least one R₁₀ₐ,

xe11 may be 1, 2, or 3,

xe1 may be 0, 1, 2, 3, 4, or 5,

R₆₀₁ may be a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₆₀₁)(Q₆₀₂)(Q₆₀₃), —C(═O)(Q₆₀₁), —S(═O)₂(Q₆₀₁), or —P(═O)(Q₆₀₁)(Q₆₀₂),

Q₆₀₁ to Q₆₀₃ may each independently be the same as described in connection with Q₁,

xe21 may be 1, 2, 3, 4, or 5, and

at least one of Ar₆₀₁, L₆₀₁, and R₆₀₁ may each independently be a π electron-deficient nitrogen-containing C₁-C₆₀ cyclic group unsubstituted or substituted with at least one R₁₀ₐ.

In an embodiment, in Formula 601, when xe11 is 2 or more, two or more of Ar₆₀₁(s) may be bonded to each other via a single bond.

In an embodiment, in Formula 601, Ar₆₀₁ may be a substituted or unsubstituted anthracene group.

In embodiments, the electron transport region may include a compound represented by Formula 601-1:

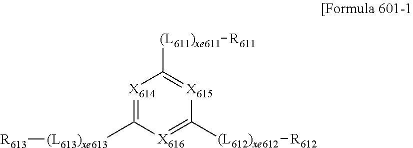

In Formula 601-1,

X₆₁₄ may be N or C(R₆₁₄), X₆₁₅ may be N or C(R₆₁₅), X₆₁₆ may be N or C(R₆₁₆), and at least one of X₆₁₄ to X₆₁₆ may be N,

L₆₁₁ to L₆₁₃ may each independently be the same as described in connection with L₆₀₁,

xe611 to xe613 may each independently be the same as described in connection with xe1,

R₆₁₁ to R₆₁₃ may each independently be the same as described in connection with R₆₀₁, and

R₆₁₄ to R₆₁₆ may each independently be hydrogen, deuterium, —F, —Cl, —Br, —I, a hydroxyl group, a cyano group, a nitro group, a C₁-C₂₀ alkyl group, a C₁-C₂₀ alkoxy group, a C₃-C₆₀ carbocyclic group unsubstituted or substituted with at least one R₁₀ₐ, or a C₁-C₆₀ heterocyclic group unsubstituted or substituted with at least one R₁₀ₐ.

In an embodiment, in Formulae 601 and 601-1, xe1 and xe611 to xe613 may each independently be 0, 1, or 2.

The electron transport region may include one of Compounds ET1 to ET45, 2,9-dimethyl-4,7-diphenyl-1,10-phenanthroline (BCP), 4,7-diphenyl-1,10-phenanthroline (Bphen), Alq₃, BAlq, TAZ, NTAZ, or any combination thereof:

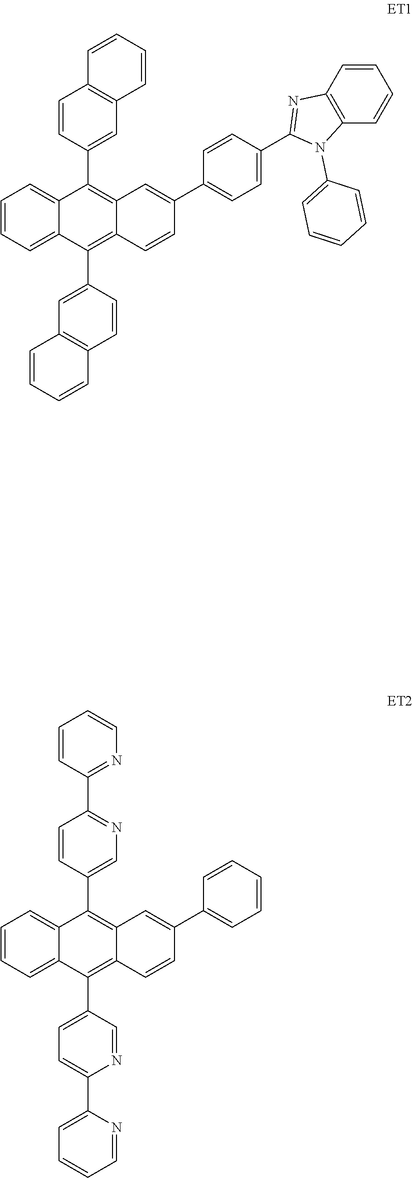 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1]

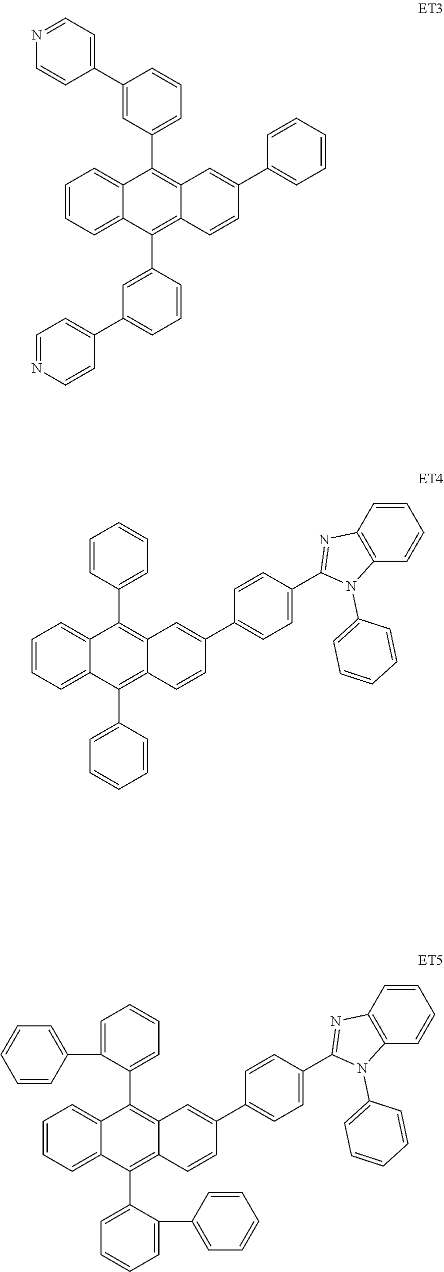 [SMILES: c1ccc(-c2ccc3c(-c4cccc(-c5ccncc5)c4)c4ccccc4c(-c4cccc(-c5ccncc5)c4)c3c2)cc1 ; c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1]

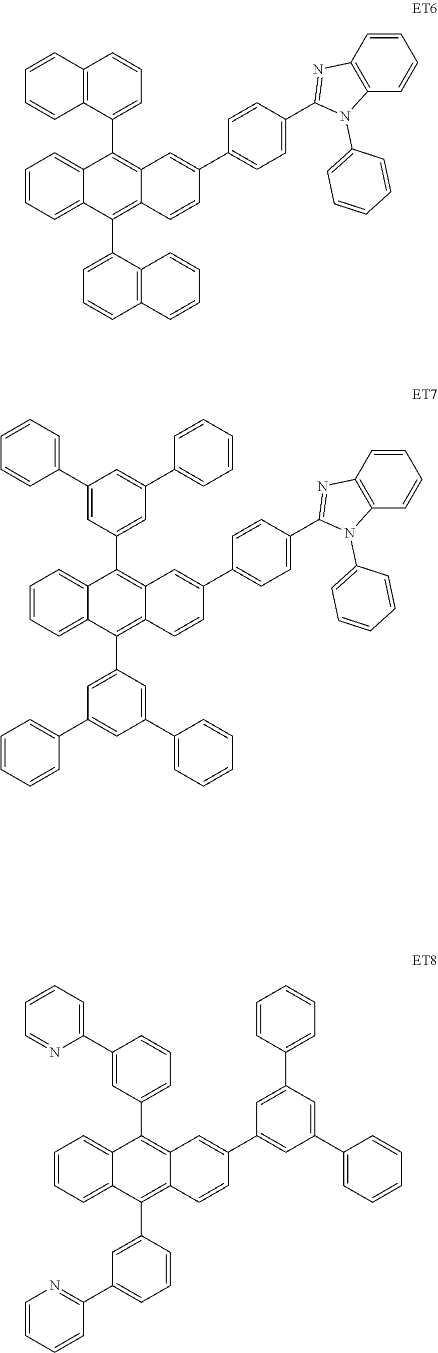 [SMILES: c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1 ; c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1]

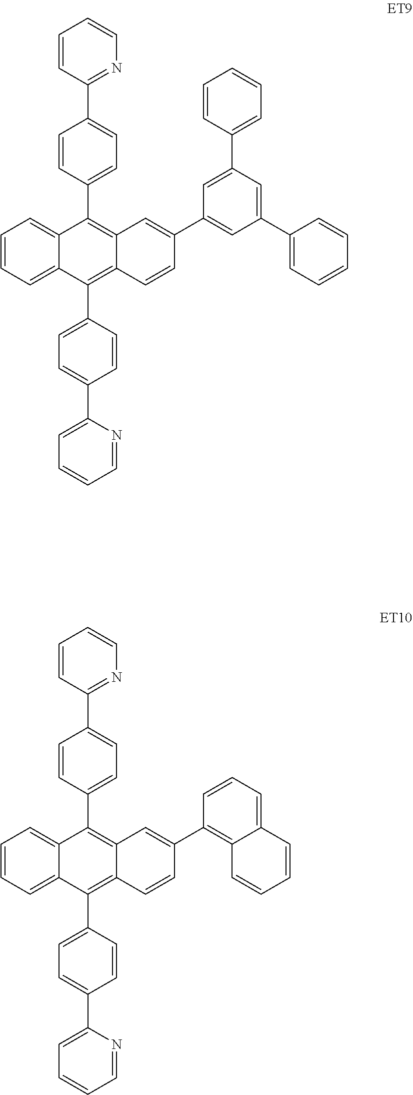 [SMILES: c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

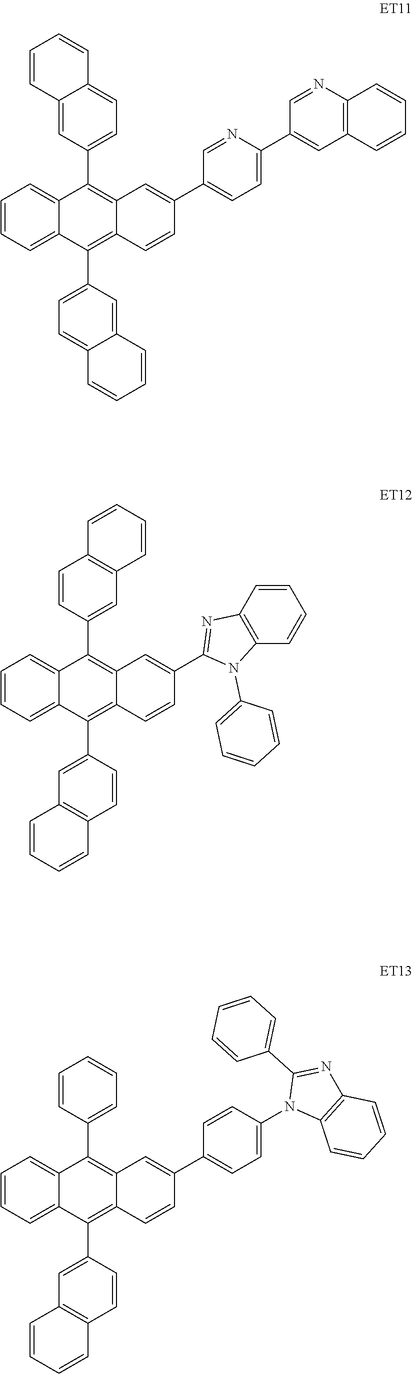 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

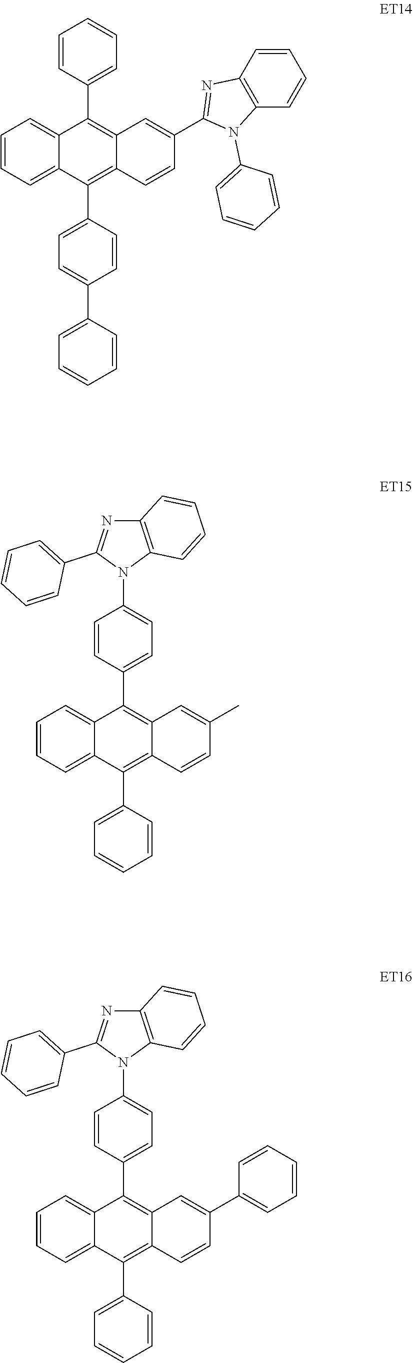 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

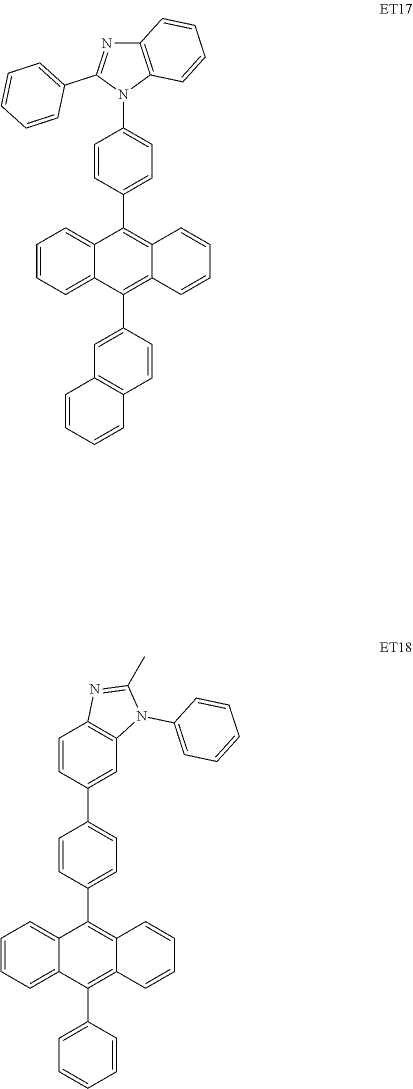 [SMILES: c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

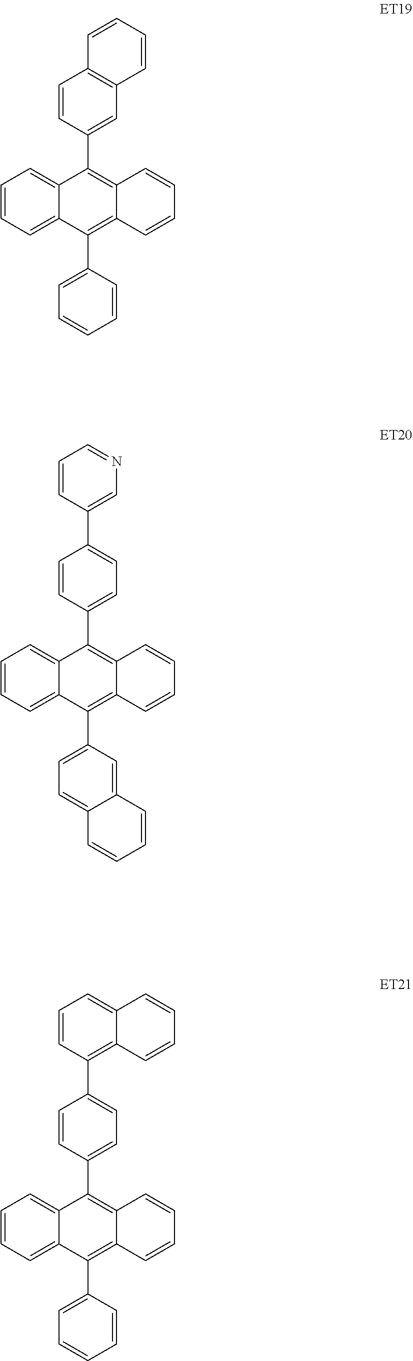

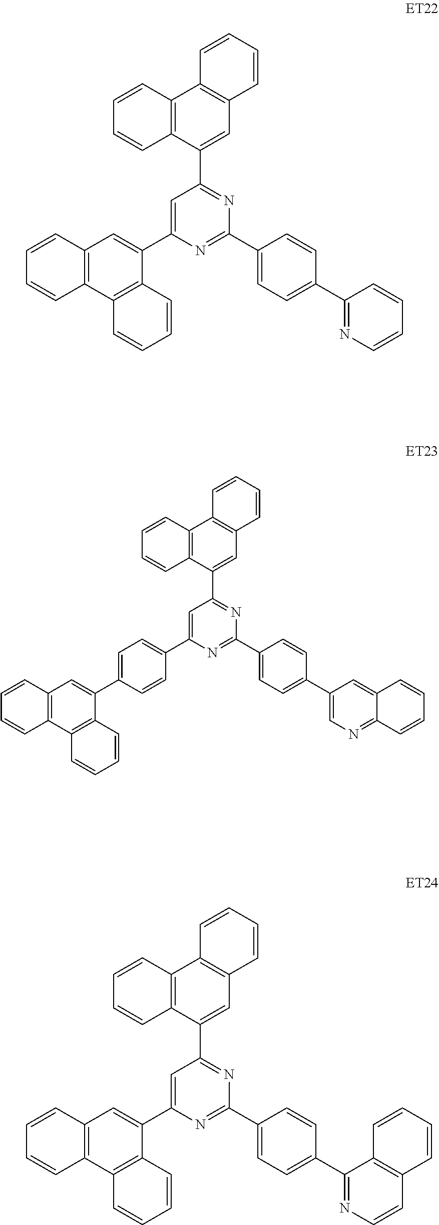 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

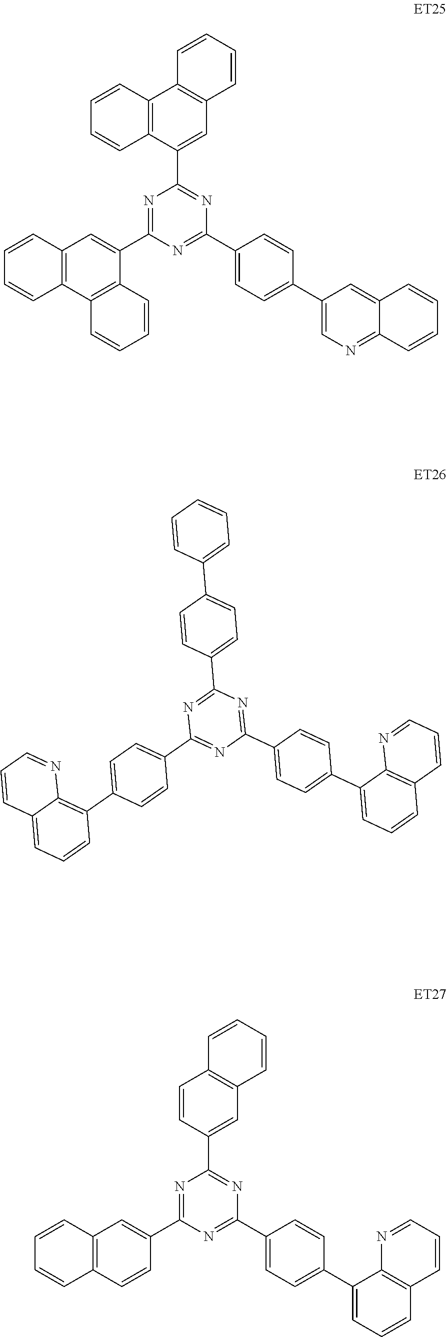 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

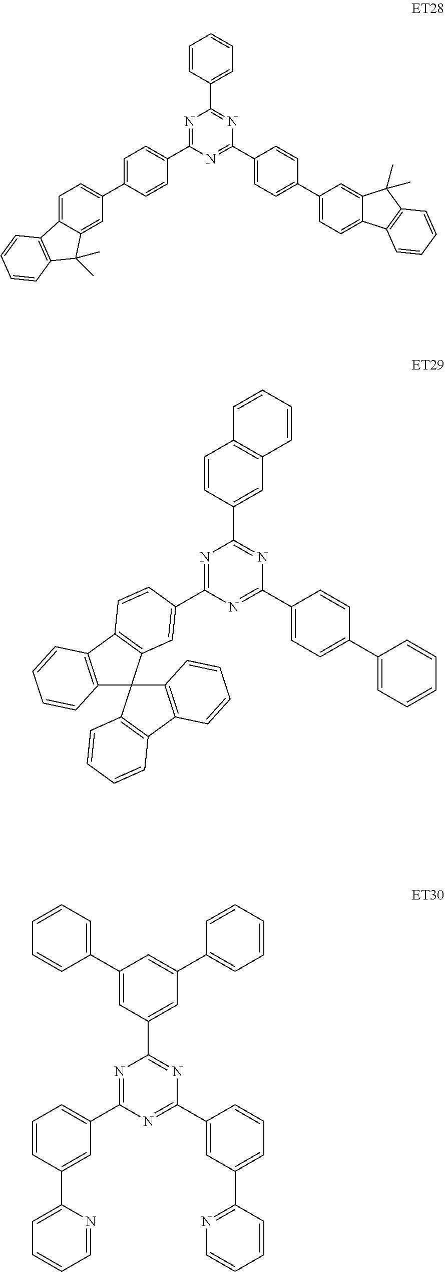 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3nc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

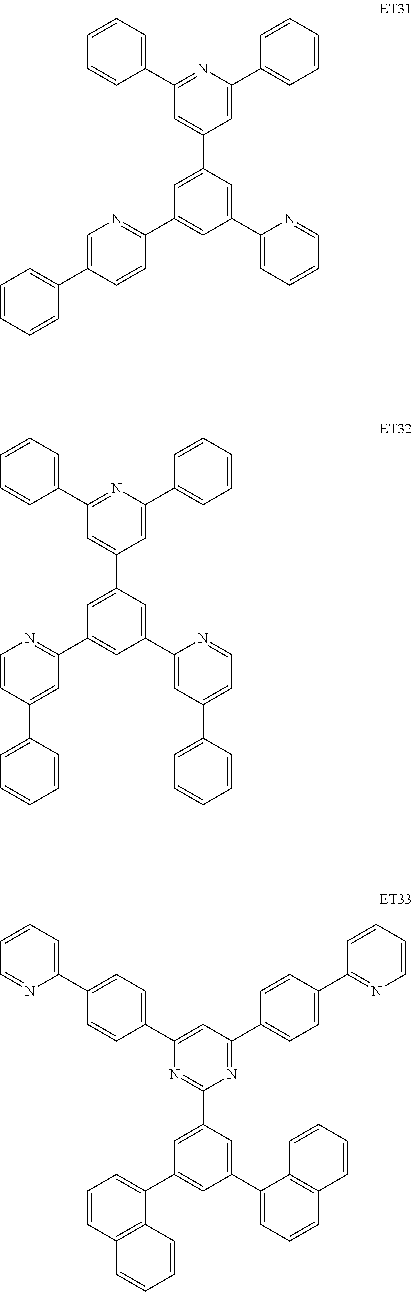 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

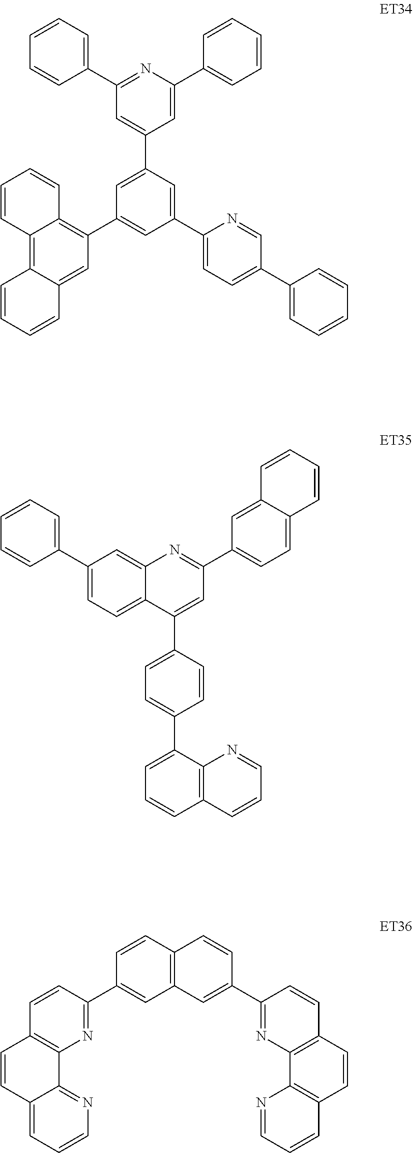 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12]

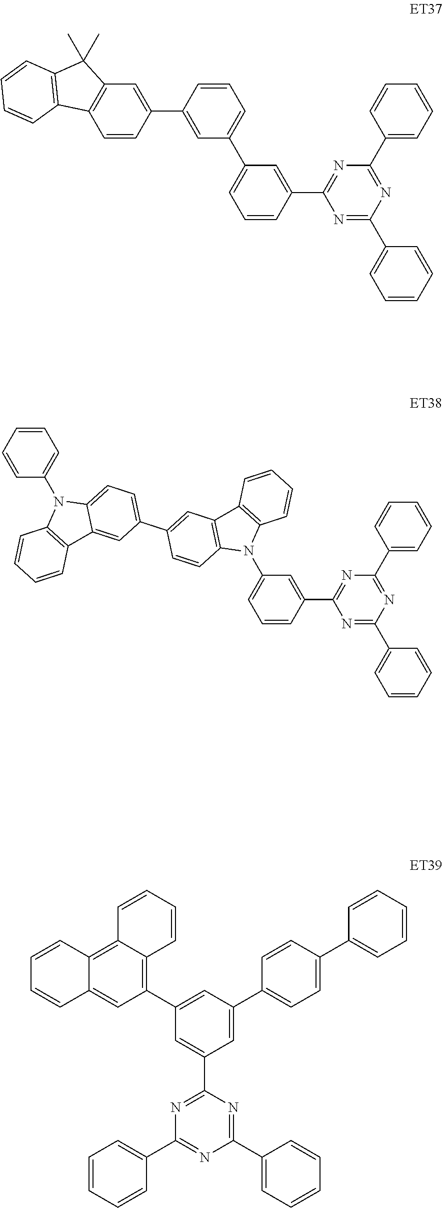 [SMILES: CC1(C)c2ccccc2-c2ccc(-c3cccc(-c4cccc(-c5nc(-c6ccccc6)nc(-c6ccccc6)n5)c4)c3)cc21 ; c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1 ; c1ccc(-c2ccc(-c3cc(-c4nc(-c5ccccc5)nc(-c5ccccc5)n4)cc(-c4cc5ccccc5c5ccccc45)c3)cc2)cc1]

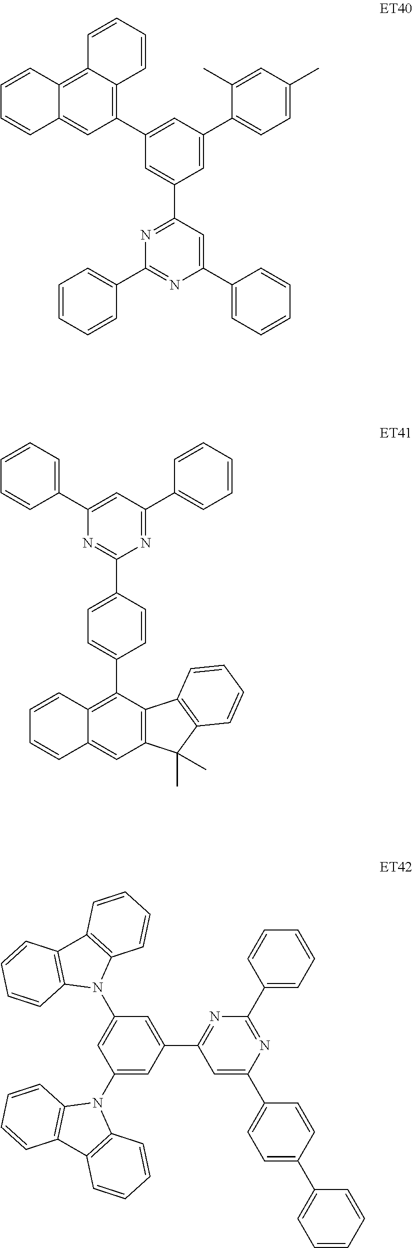 [SMILES: Cc1ccc(-c2cc(-c3cc(-c4ccccc4)nc(-c4ccccc4)n3)cc(-c3cc4ccccc4c4ccccc34)c2)c(C)c1 ; CC1(C)c2ccccc2-c2c1cc1ccccc1c2-c1ccc(-c2nc(-c3ccccc3)cc(-c3ccccc3)n2)cc1 ; c1ccc(-c2ccc(-c3cc(-c4cc(-n5c6ccccc6c6ccccc65)cc(-n5c6ccccc6c6ccccc65)c4)nc(-c4ccccc4)n3)cc2)cc1]

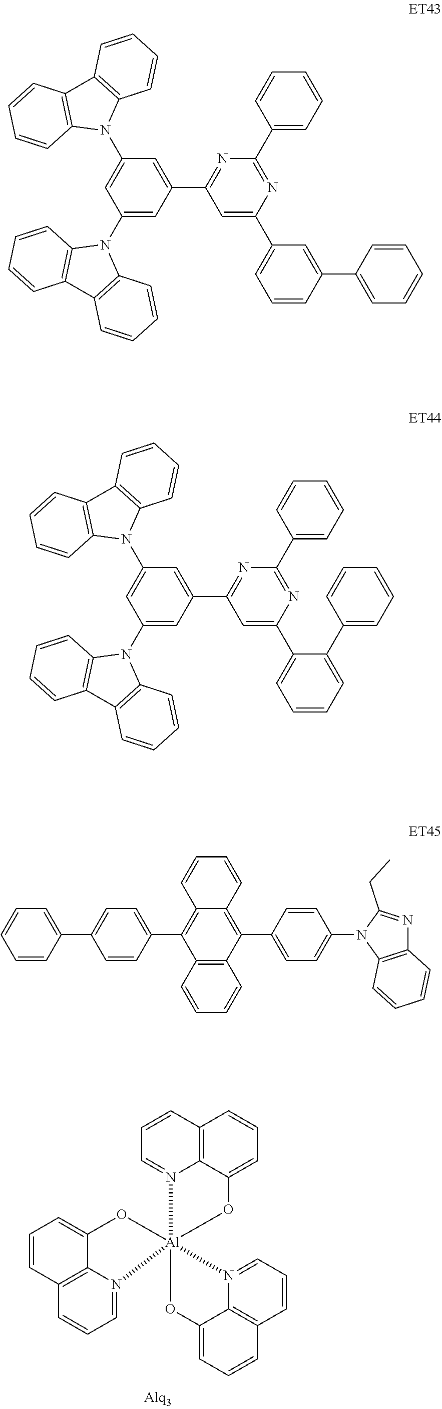

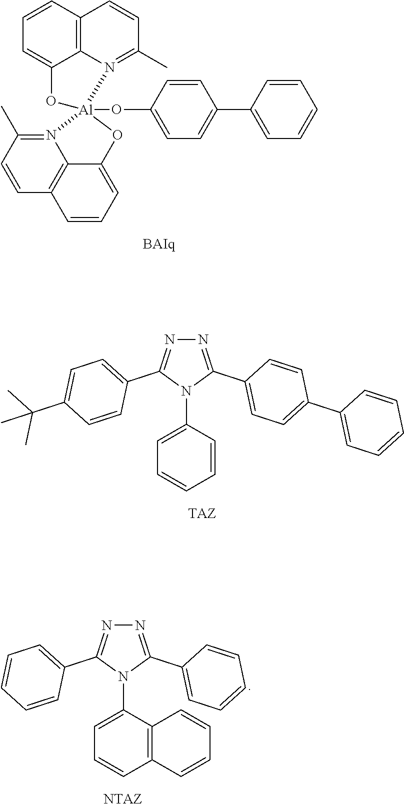

A thickness of the electron transport region may be in a range of about 100 Å to about 5,000 Å. For example, the thickness of the electron transport region may be in a range of about 160 Å to about 4,000 Å. When the electron transport region includes a buffer layer, a hole blocking layer, an electron control layer, an electron transport layer, or any combination thereof, a thickness of the buffer layer, the hole blocking layer, or the electron control layer may each independently be in a range of about 20 Å to about 1,000 Å, and a thickness of the electron transport layer may be in a range of about 100 Å to about 1,000 Å. For example, the thickness of the buffer layer, the hole blocking layer, or the electron control layer may each independently be in a range of about 30 Å to about 300 Å. For example, the thickness of the electron transport layer may be in a range of about 150 Å to about 500 Å. When the thicknesses of the buffer layer, the hole blocking layer, the electron control layer, the electron transport layer, and/or the electron transport region are within these ranges, satisfactory electron transporting characteristics may be obtained without a substantial increase in driving voltage.

The electron transport region (for example, the electron transport layer in the electron transport region) may further include, in addition to the materials described above, a metal-containing material.

The metal-containing material may include an alkali metal complex, an alkaline earth metal complex, or any combination thereof. A metal ion of an alkali metal complex may be a Li ion, a Na ion, a K ion, a Rb ion, or a Cs ion, and a metal ion of an alkaline earth metal complex may be a Be ion, a Mg ion, a Ca ion, a Sr ion, or a Ba ion. A ligand coordinated with the metal ion of the alkali metal complex or with the metal ion of the alkaline earth-metal complex may each independently include a hydroxyquinoline, a hydroxyisoquinoline, a hydroxybenzoquinoline, a hydroxyacridine, a hydroxyphenanthridine, a hydroxyphenyloxazole, a hydroxyphenylthiazole, a hydroxyphenyloxadiazole, a hydroxyphenylthiadiazole, a hydroxyphenylpyridine, a hydroxyphenylbenzimidazole, a hydroxyphenylbenzothiazole, a bipyridine, a phenanthroline, a cyclopentadiene, or any combination thereof.

In an embodiment, the metal-containing material may include a Li complex. The Li complex may include, for example, Compound ET-D1 (LiQ) or Compound ET-D2:

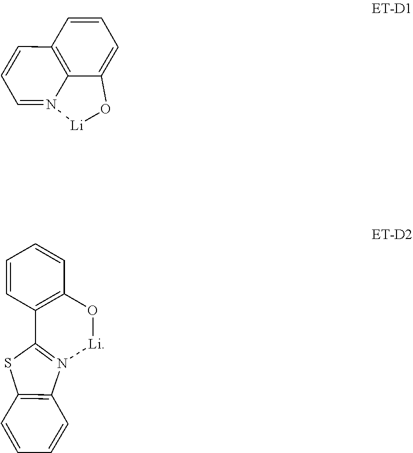

The electron transport region may include an electron injection layer that facilitates the injection of electrons from the second electrode 150. The electron injection layer may directly contact the second electrode 150.

The electron injection layer may have a structure consisting of a layer consisting of a single material, a structure consisting of a layer consisting of different materials, or a structure including multiple layers including different materials.

The electron injection layer may include an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof.

The alkali metal may include Li, Na, K, Rb, Cs, or any combination thereof.

The alkaline earth metal may include Mg, Ca, Sr, Ba, or any combination thereof. The rare earth metal may include Sc, Y, Ce, Tb, Yb, Gd, or any combination thereof.

The alkali metal-containing compound, the alkaline earth metal-containing compound, and the rare earth metal-containing compound may include oxides, halides (for example, fluorides, chlorides, bromides, iodides, etc.), or tellurides of the alkali metal, the alkaline earth metal, and the rare earth metal, or any combination thereof.

The alkali metal-containing compound may include: an alkali metal oxide, such as Li₂O, Cs₂₀, K₂O, and the like; alkali metal halides, such as LiF, NaF, CsF, KF, LiI, NaI, CsI, KI, and the like; or any combination thereof. The alkaline earth metal-containing compound may include an alkaline earth metal oxide, such as BaO, SrO, CaO, BaₓSr₁₋ₓO (wherein x is a real number satisfying 0<x<₁), BaₓCa₁₋ₓO (wherein x is a real number satisfying 0<x<₁), and the like. The rare earth metal-containing compound may include YbF₃, ScF₃, Sc₂O₃, Y₂O₃, Ce₂O₃, GdF₃, TbF₃, YbI₃, ScI₃, TbI₃, or any combination thereof. In an embodiment, the rare earth metal-containing compound may include a lanthanide metal telluride. Examples of the lanthanide metal telluride may include LaTe, CeTe, PrTe, NdTe, PmTe, SmTe, EuTe, GdTe, TbTe, DyTe, HoTe, ErTe, TmTe, YbTe, LuTe, La₂Te₃, Ce₂Te₃, Pr₂Te₃, Nd₂Te₃, Pm₂Te₃, Sm₂Te₃, Eu₂Te₃, Gd₂Te₃, Tb₂Te₃, Dy₂Te₃, Ho₂Te₃, Er₂Te₃, Tm₂Te₃, Yb₂Te₃, Lu₂Te₃, and the like.

The alkali metal complex, the alkaline earth-metal complex, and the rare earth metal complex may include one of ions of the alkali metal, ions of the alkaline earth metal, and ions of the rare earth metal, and a ligand bonded to the metal ion (for example, hydroxyquinoline, hydroxyisoquinoline, hydroxybenzoquinoline, hydroxyacridine, hydroxyphenanthridine, hydroxyphenyloxazole, hydroxyphenylthiazole, hydroxyphenyloxadiazole, hydroxyphenylthiadiazole, hydroxyphenylpyridine, hydroxyphenyl benzimidazole, hydroxyphenylbenzothiazole, bipyridine, phenanthroline, cyclopentadiene, or any combination thereof).

In an embodiment, the electron injection layer may consist of an alkali metal, an alkaline earth metal, a rare earth metal, an alkali metal-containing compound, an alkaline earth metal-containing compound, a rare earth metal-containing compound, an alkali metal complex, an alkaline earth metal complex, a rare earth metal complex, or any combination thereof, as described above. In embodiments, the electron injection layer may further include an organic material (for example, a compound represented by Formula 601).

In an embodiment, the electron injection layer may consist of an alkali metal-containing compound (for example, an alkali metal halide); or the electron injection layer may consist of an alkali metal-containing compound (for example, alkali metal halide), and an alkali metal, an alkaline earth metal, a rare earth metal, or any combination thereof. For example, the electron injection layer may be a KI:Yb co-deposited layer, an RbI:Yb co-deposited layer, or the like.

When the electron injection layer further includes an organic material, an alkali metal, an alkaline earth metal, a rare earth metal, an alkali metal-containing compound, an alkaline earth metal-containing compound, a rare earth metal-containing compound, an alkali metal complex, an alkaline earth-metal complex, a rare earth metal complex, or any combination thereof may be uniformly or non-uniformly dispersed in a matrix including the organic material.

A thickness of the electron injection layer may be in a range of about 1 Å to about 100 Å. For example, the thickness of the electron injection layer may be in a range of about 3 Å to about 90 Å. When the thickness of the electron injection layer is within the ranges described above, satisfactory electron injection characteristics may be obtained without a substantial increase in driving voltage.

### Second Electrode 150

The second electrode 150 may be arranged on the interlayer 130 having a structure as described herein. The second electrode 150 may be a cathode, which is an electron injection electrode. The second electrode 150 may include a material having a low-work function, for example, a metal, an alloy, an electrically conductive compound, or any combination thereof.

The second electrode 150 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or any combination thereof. The second electrode 150 may be a transmissive electrode, a semi-transmissive electrode, or a reflective electrode.

The second electrode 150 may have a single-layered structure or a multi-layered structure.

### Capping Layer

The light-emitting device 10 may include a first capping layer outside the first electrode 110, and/or a second capping layer outside the second electrode 150. For example, the light-emitting device 10 may have a structure in which the first capping layer, the first electrode 110, the interlayer 130, and the second electrode 150 are stacked in this stated order, a structure in which the first electrode 110, the interlayer 130, the second electrode 150, and the second capping layer are stacked in this stated order, or a structure in which the first capping layer, the first electrode 110, the interlayer 130, the second electrode 150, and the second capping layer are stacked in this stated order.

Light generated in an emission layer of the interlayer 130 of the light-emitting device 10 may be extracted toward the outside through the first electrode 110, which may be a semi-transmissive electrode or a transmissive electrode, and through the first capping layer. Light generated in an emission layer of the interlayer 130 of the light-emitting device 10 may be extracted toward the outside through the second electrode 150, which may be a semi-transmissive electrode or a transmissive electrode, and through the second capping layer.

The first capping layer and the second capping layer may each increase external emission efficiency according to the principle of constructive interference. Accordingly, the light extraction efficiency of the light-emitting device 10 is increased, so that the luminescence efficiency of the light-emitting device 10 may be improved.

The first capping layer and the second capping layer may each include a material having a refractive index equal to or greater than about 1.6 (with respect to a wavelength of about 589 nm).

The first capping layer and the second capping layer may each independently be an organic capping layer including an organic material, an inorganic capping layer including an inorganic material, or an organic-inorganic composite capping layer including an organic material and an inorganic material.

At least one of the first capping layer and the second capping layer may each independently include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may optionally be substituted with a substituent including O, N, S, Se, Si, F, Cl, Br, I, or any combination thereof.

In an embodiment, at least one of the first capping layer and the second capping layer may each independently include an amine group-containing compound.

In embodiments, at least one of the first capping layer and the second capping layer may each independently include a compound represented by Formula 201, a compound represented by Formula 202, or any combination thereof.

In embodiments, at least one of the first capping layer and the second capping layer may each independently include one of Compounds HT28 to HT33, one of Compounds CP1 to CP6, p-NPB, or any combination thereof:

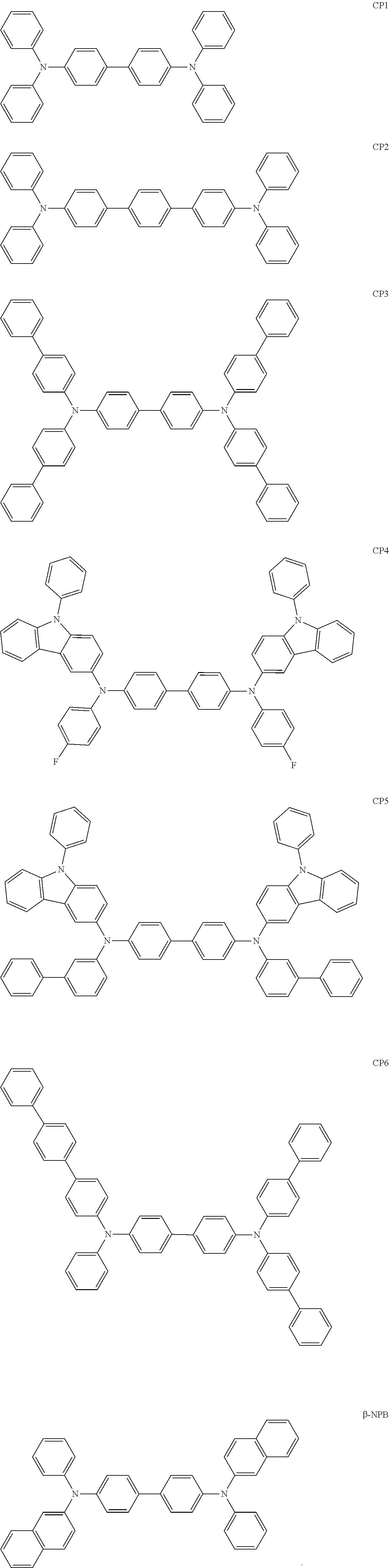

### Film

The condensed cyclic compound represented by Formula 1 may be included in various films. Accordingly, another aspect provides a film including the condensed cyclic compound represented by Formula 1. The film may be, for example, an optical member (or a light control means) (for example, a color filter, a color conversion member, a capping layer, a light extraction efficiency enhancement layer, a selective light absorbing layer, a polarizing layer, a quantum dot-containing layer, or like), a light-blocking member (for example, a light reflective layer, a light absorbing layer, or the like), or a protective member (for example, an insulating layer, a dielectric layer, or the like).

### Electronic Apparatus

The light-emitting device may be included in various electronic apparatuses.

For example, the electronic apparatus including the light-emitting device may be a light-emitting apparatus, an authentication apparatus, or the like.

The electronic apparatus (for example, a light-emitting apparatus) may further include, in addition to the light-emitting device, a color filter, a color conversion layer, or a color filter and a color conversion layer. The color filter and/or the color conversion layer may be arranged in at least one traveling direction of light emitted from the light-emitting device. For example, the light emitted from the light-emitting device may be blue light or white light. The light-emitting device may be the same as defined herein.

In an embodiment, the color conversion layer may include a quantum dot. The quantum dot may be, for example, a quantum dot as described herein.

The electronic apparatus may include a first substrate. The first substrate may include subpixels, the color filter may include color filter areas respectively corresponding to the subpixels, and the color conversion layer may include color conversion areas respectively corresponding to the subpixels.

A pixel-defining film may be arranged between the subpixels to define each subpixel.

The color filter may further include color filter areas and light-shielding patterns arranged between the color filter areas, and the color conversion layer may further include color conversion areas and light-shielding patterns arranged between the color conversion areas.

The color filter areas (or the color conversion areas) may include a first area emitting first color light, a second area emitting second color light, and/or a third area emitting third color light, wherein the first color light, the second color light, and/or the third color light may have different maximum emission wavelengths from one another. For example, the first color light may be red light, the second color light may be green light, and the third color light may be blue light. In embodiments, the color filter areas (or the color conversion areas) may include quantum dots. For example, the first area may include a red quantum dot, the second area may include a green quantum dot, and the third area may not include a quantum dot. The quantum dot may be the same as described herein. The first area, the second area, and/or the third area may each include a scatterer.

For example, the light-emitting device may emit first light, the first area may absorb the first light to emit first-first color light, the second area may absorb the first light to emit second-first color light, and the third area may absorb the first light to emit third-first color light. The first-first color light, the second-first color light, and the third-first color light may have different maximum emission wavelengths from one another.

For example, the first light may be blue light, the first-first color light may be red light, the second-first color light may be green light, and the third-first color light may be blue light.

The electronic apparatus may further include a thin-film transistor, in addition to the light-emitting device as described herein. The thin-film transistor may include a source electrode, a drain electrode, and an active layer, wherein any one of the source electrode and the drain electrode may be electrically connected to any one of the first electrode and the second electrode of the light-emitting device.

The thin-film transistor may further include a gate electrode, a gate insulating film, or the like.

The active layer may include crystalline silicon, amorphous silicon, an organic semiconductor, an oxide semiconductor, or the like.

The electronic apparatus may further include a sealing portion for sealing the light-emitting device. The sealing portion may be arranged between the color filter and/or the color conversion layer, and the light-emitting device. The sealing portion may allow light from the light-emitting device to be extracted to the outside, and may simultaneously prevent ambient air and moisture from penetrating into the light-emitting device. The sealing portion may be a sealing substrate including a transparent glass substrate or a plastic substrate. The sealing portion may be a thin-film encapsulation layer including an organic layer and/or an inorganic layer. When the sealing portion is a thin-film encapsulation layer, the electronic apparatus may be flexible.

Various functional layers may be further included on the sealing portion, in addition to the color filter and/or the color conversion layer, according to the use of the electronic apparatus. Examples of the functional layers may include a touch screen layer, a polarizing layer, an authentication apparatus, and the like. The touch screen layer may be a pressure-sensitive touch screen layer, a capacitive touch screen layer, or an infrared touch screen layer. The authentication apparatus may be, for example, a biometric authentication apparatus that authenticates an individual by using biometric information of a living body (for example, fingertips, pupils, etc.).

The authentication apparatus may further include, in addition to the light-emitting device as described herein, a biometric information collector.

The electronic apparatus may be applied to various displays, light sources, lighting, personal computers (for example, a mobile personal computer), mobile phones, digital cameras, electronic organizers, electronic dictionaries, electronic game machines, medical instruments (for example, electronic thermometers, sphygmomanometers, blood glucose meters, pulse measurement devices, pulse wave measurement devices, electrocardiogram displays, ultrasonic diagnostic devices, or endoscope displays), fish finders, various measuring instruments, meters (for example, meters for a vehicle, an aircraft, and a vessel), projectors, and the like.

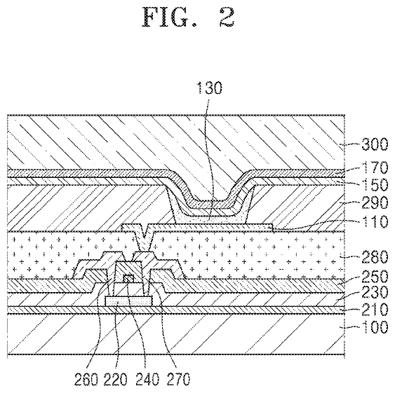

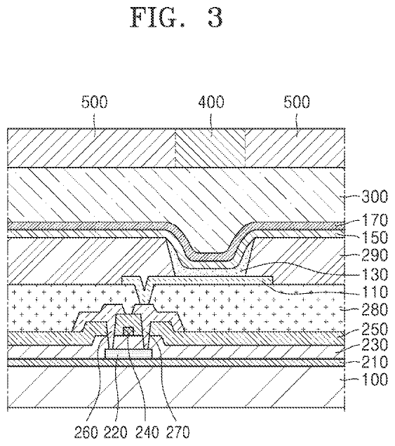

### Description of FIGS. 2 and 3

FIG. 2 is a schematic cross-sectional view showing an electronic apparatus according to an embodiment.

The electronic apparatus of FIG. 2 includes a substrate 100, a thin-film transistor (TFT), a light-emitting device, and an encapsulation portion 300 that seals the light-emitting device.

The substrate 100 may be a flexible substrate, a glass substrate, or a metal substrate. A buffer layer 210 may be arranged on the substrate 100. The buffer layer 210 may prevent penetration of impurities through the substrate 100 and may provide a flat surface on the substrate 100.

A TFT may be arranged on the buffer layer 210. The TFT may include an active layer 220, a gate electrode 240, a source electrode 260, and a drain electrode 270.

The active layer 220 may include an inorganic semiconductor such as silicon or polysilicon, an organic semiconductor, or an oxide semiconductor, and may include a source region, a drain region, and a channel region.

A gate insulating film 230 for insulating the active layer 220 from the gate electrode 240 may be arranged on the active layer 220, and the gate electrode 240 may be arranged on the gate insulating film 230.

An interlayer insulating film 250 may be arranged on the gate electrode 240.

The interlayer insulating film 250 may be arranged between the gate electrode 240 and the source electrode 260 to insulate the gate electrode 240 from the source electrode 260 and between the gate electrode 240 and the drain electrode 270 to insulate the gate electrode 240 from the drain electrode 270.

The source electrode 260 and the drain electrode 270 may be arranged on the interlayer insulating film 250. The interlayer insulating film 250 and the gate insulating film 230 may expose the source region and the drain region of the active layer 220, and the source electrode 260 and the drain electrode 270 may respectively contact the exposed portions of the source region and the drain region of the active layer 220.

The TFT may be electrically connected to a light-emitting device to drive the light-emitting device, and may be covered and protected by a passivation layer 280.

The passivation layer 280 may include an inorganic insulating film, an organic insulating film, or any combination thereof. A light-emitting device may be provided on the passivation layer 280. The light-emitting device may include a first electrode 110, an interlayer 130, and a second electrode 150.

The first electrode 110 may be arranged on the passivation layer 280. The passivation layer 280 does not fully cover the drain electrode 270 and may expose a portion of the drain electrode 270, and the first electrode 110 may be electrically connected to the exposed portion of the drain electrode 270.

A pixel defining layer 290 including an insulating material may be arranged on the first electrode 110. The pixel defining layer 290 may expose a region of the first electrode 110, and an interlayer 130 may be formed in the exposed region of the first electrode 110. The pixel defining layer 290 may be a polyimide or polyacrylic organic film. Although not shown in FIG. 2, at least some layers of the interlayer 130 may extend beyond the upper portion of the pixel defining layer 290 to be provided in the form of a common layer.

The second electrode 150 may be arranged on the interlayer 130, and a capping layer 170 may be further included on the second electrode 150. The capping layer 170 may cover the second electrode 150.

The encapsulation portion 300 may be arranged on the capping layer 170.

The encapsulation portion 300 may be arranged on a light-emitting device to protect the light-emitting device from moisture and/or oxygen. The encapsulation portion 300 may include: an inorganic film including silicon nitride (SiNx), silicon oxide (SiOx), indium tin oxide, indium zinc oxide, or any combination thereof; an organic film including polyethylene terephthalate, polyethylene naphthalate, polycarbonate, polyimide, polyethylene sulfonate, polyoxymethylene, polyarylate, hexamethyldisiloxane, an acrylic resin (for example, polymethyl methacrylate, polyacrylic acid, or the like), an epoxy-based resin (for example, aliphatic glycidyl ether (AGE), or the like), or any combination thereof; or any combination of the inorganic films and the organic films.

FIG. 3 is a schematic cross-sectional view showing an electronic apparatus according to another embodiment.

The electronic apparatus of FIG. 3 may differ from the electronic apparatus of FIG. 2, at least in that a light-shielding pattern 500 and a functional region 400 are further included on the encapsulation portion 300. The functional region 400 may be a color filter area, a color conversion area, or a combination of the color filter area and the color conversion area. In an embodiment, the light-emitting device included in the electronic apparatus of FIG. 3 may be a tandem light-emitting device.

### Manufacturing Method

Respective layers included in the hole transport region, the emission layer, and respective layers included in the electron transport region may be formed in a certain region by using one or more suitable methods selected from vacuum deposition, spin coating, casting, Langmuir-Blodgett (LB) deposition, ink-jet printing, laser-printing, laser-induced thermal imaging, and the like.

When respective layers included in the hole transport region, the emission layer, and respective layers included in the electron transport region are formed by vacuum deposition, the deposition may be performed at a deposition temperature of about 100° C. to about 500° C., a vacuum degree of about 10⁻⁸ torr to about 10⁻³ torr, and a deposition speed of about 0.01 Å/sec to about 100 Å/sec, depending on a material to be included in a layer to be formed and the structure of a layer to be formed.

### Definitions of Terms

The term “C₃-C₆₀ carbocyclic group” as used herein a cyclic group consisting of carbon as the only ring-forming atoms and having three to sixty carbon atoms, and the term “C₁-C₆₀ heterocyclic group” as used herein may be a cyclic group that has one to sixty carbon atoms and further has, in addition to carbon, at least one heteroatom as a ring-forming atom. The C₃-C₆₀ carbocyclic group and the C₁-C₆₀ heterocyclic group may each be a monocyclic group consisting of one ring or a polycyclic group in which two or more rings are condensed with each other. For example, the number of ring-forming atoms of the C₁-C₆₀ heterocyclic group may be from 3 to 61.

The term “cyclic group” as used herein may include the C₃-C₆₀ carbocyclic group or the C₁-C₆₀ heterocyclic group.

The term “π electron-rich C₃-C₆₀ cyclic group” as used herein may be a cyclic group that has three to sixty carbon atoms and may not include *—N═*′ as a ring-forming moiety, and the term “π electron-deficient nitrogen-containing C₁-C₆₀ cyclic group” as used herein may be a heterocyclic group that has one to sixty carbon atoms and may include *—N═*′ as a ring-forming moiety.

In embodiments,

the C₃-C₆₀ carbocyclic group may be a T1 group, or a cyclic group in which two or more T1 groups are condensed with each other (for example, a cyclopentadiene group, an adamantane group, a norbornane group, a benzene group, a pentalene group, a naphthalene group, an azulene group, an indacene group, an acenaphthylene group, a phenalene group, a phenanthrene group, an anthracene group, a fluoranthene group, a triphenylene group, a pyrene group, a chrysene group, a perylene group, a pentaphene group, a heptalene group, a naphthacene group, a picene group, a hexacene group, a pentacene group, a rubicene group, a coronene group, an ovalene group, an indene group, a fluorene group, a spiro-bifluorene group, a benzofluorene group, an indenophenanthrene group, or an indenoanthracene group),

the C₁-C₆₀ heterocyclic group may be a T2 group, a cyclic group in which at least two T2 groups are condensed with each other, or a cyclic group in which at least one T2 group and at least one T1 group are condensed with each other (for example, a pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, or the like),

the π electron-rich C₃-C₆₀ cyclic group may be a T1 group, a cyclic group in which at least two T1 groups are condensed with each other, a T3 group, a cyclic group in which at least two T3 groups are condensed with each other, or a cyclic group in which at least one T3 group and at least one T1 group are condensed with each other (for example, a C₃-C₆₀ carbocyclic group, a 1H-pyrrole group, a silole group, a borole group, a 2H-pyrrole group, a 3H-pyrrole group, a thiophene group, a furan group, an indole group, a benzoindole group, a naphthoindole group, an isoindole group, a benzoisoindole group, a naphthoisoindole group, a benzosilole group, a benzothiophene group, a benzofuran group, a carbazole group, a dibenzosilole group, a dibenzothiophene group, a dibenzofuran group, an indenocarbazole group, an indolocarbazole group, a benzofurocarbazole group, a benzothienocarbazole group, a benzosilolocarbazole group, a benzoindolocarbazole group, a benzocarbazole group, a benzonaphthofuran group, a benzonaphthothiophene group, a benzonaphthosilole group, a benzofurodibenzofuran group, a benzofurodibenzothiophene group, a benzothienodibenzothiophene group, or the like),

the π electron-deficient nitrogen-containing C₁-C₆₀ cyclic group may be a T4 group, a cyclic group in which at least two T4 groups are condensed with each other, a cyclic group in which at least one T4 group and at least one T1 group are condensed with each other, a cyclic group in which at least one T4 group and at least one T3 group are condensed with each other, or a cyclic group in which at least one T4 group, at least one T1 group, and at least one T3 group are condensed with one another (for example, a pyrazole group, an imidazole group, a triazole group, an oxazole group, an isoxazole group, an oxadiazole group, a thiazole group, an isothiazole group, a thiadiazole group, a benzopyrazole group, a benzimidazole group, a benzoxazole group, a benzoisoxazole group, a benzothiazole group, a benzoisothiazole group, a pyridine group, a pyrimidine group, a pyrazine group, a pyridazine group, a triazine group, a quinoline group, an isoquinoline group, a benzoquinoline group, a benzoisoquinoline group, a quinoxaline group, a benzoquinoxaline group, a quinazoline group, a benzoquinazoline group, a phenanthroline group, a cinnoline group, a phthalazine group, a naphthyridine group, an imidazopyridine group, an imidazopyrimidine group, an imidazotriazine group, an imidazopyrazine group, an imidazopyridazine group, an azacarbazole group, an azafluorene group, an azadibenzosilole group, an azadibenzothiophene group, an azadibenzofuran group, and the like),

wherein the T1 group may be a cyclopropane group, a cyclobutane group, a cyclopentane group, a cyclohexane group, a cycloheptane group, a cyclooctane group, a cyclobutene group, a cyclopentene group, a cyclopentadiene group, a cyclohexene group, a cyclohexadiene group, a cycloheptene group, an adamantane group, a norbornane (or bicyclo[2.2.1]heptane) group, a norbornene group, a bicyclo[1.1.1]pentane group, a bicyclo[2.1.1]hexane group, a bicyclo[2.2.2]octane group, or a benzene group,

the T2 group may be a furan group, a thiophene group, a 1H-pyrrole group, a silole group, a borole group, a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, a tetrazine group, a pyrrolidine group, an imidazolidine group, a dihydropyrrole group, a piperidine group, a tetrahydropyridine group, a dihydropyridine group, a hexahydropyrimidine group, a tetrahydropyrimidine group, a dihydropyrimidine group, a piperazine group, a tetrahydropyrazine group, a dihydropyrazine group, a tetrahydropyridazine group, or a dihydropyridazine group,

the T3 group may be a furan group, a thiophene group, a 1H-pyrrole group, a silole group, or a borole group, and

the T4 group may be a 2H-pyrrole group, a 3H-pyrrole group, an imidazole group, a pyrazole group, a triazole group, a tetrazole group, an oxazole group, an isoxazole group, an oxadiazole group, a thiazole group, an isothiazole group, a thiadiazole group, an azasilole group, an azaborole group, a pyridine group, a pyrimidine group, a pyrazine group, a pyridazine group, a triazine group, or a tetrazine group.

The terms “cyclic group”, “C₃-C₆₀ carbocyclic group”, “C₁-C₆₀ heterocyclic group”, “π electron-rich C₃-C₆₀ cyclic group”, or “π electron-deficient nitrogen-containing C₁-C₆₀ cyclic group” as used herein may each be a group condensed to any cyclic group, a monovalent group, or a polyvalent group (for example, a divalent group, a trivalent group, a tetravalent group, etc.) according to the structure of a formula for which the corresponding term is used. For example, a “benzene group” may be a benzo group, a phenyl group, a phenylene group, or the like, which may be readily understood by one of ordinary skill in the art according to the structure of a formula including the “benzene group.”

Examples of the monovalent C₃-C₆₀ carbocyclic group and the monovalent C₁-C₆₀ heterocyclic group may include a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₁-C₆₀ heteroaryl group, a monovalent non-aromatic condensed polycyclic group, and a monovalent non-aromatic condensed heteropolycyclic group. Examples of the divalent C₃-C₆₀ carbocyclic group and the divalent C₁-C₆₀ heterocyclic group may include a C₃-C₁₀ cycloalkylene group, a C₁-C₁₀ heterocycloalkylene group, a C₃-C₁₀ cycloalkenylene group, a C₁-C₁₀ heterocycloalkenylene group, a C₆-C₆₀ arylene group, a C₁-C₆₀ heteroarylene group, a divalent non-aromatic condensed polycyclic group, and a divalent non-aromatic condensed heteropolycyclic group.

The term “C₁-C₆₀ alkyl group” as used herein may be a linear or branched aliphatic hydrocarbon monovalent group that has one to sixty carbon atoms, and examples thereof may include a methyl group, an ethyl group, an n-propyl group, an isopropyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, an n-hexyl group, an isohexyl group, a sec-hexyl group, a tert-hexyl group, an n-heptyl group, an isoheptyl group, a sec-heptyl group, a tert-heptyl group, an n-octyl group, an isooctyl group, a sec-octyl group, a tert-octyl group, an n-nonyl group, an isononyl group, a sec-nonyl group, a tert-nonyl group, an n-decyl group, an isodecyl group, a sec-decyl group, and a tert-decyl group. The term “C₁-C₆₀ alkylene group” as used herein may be a divalent group having a same structure as the C₁-C₆₀ alkyl group.

The term “C₂-C₆₀ alkenyl group” as used herein may be a monovalent hydrocarbon group having at least one carbon-carbon double bond in the middle or at a terminus of a C₂-C₆₀ alkyl group, and examples thereof may include an ethenyl group, a propenyl group, a butenyl group, and the like. The term “C₂-C₆₀ alkenylene group” as used herein may be a divalent group having a same structure as the C₂-C₆₀ alkenyl group.

The term “C₂-C₆₀ alkynyl group” as used herein may be a monovalent hydrocarbon group having at least one carbon-carbon triple bond in the middle or at a terminus of a C₂-C₆₀ alkyl group, and examples thereof may include an ethynyl group, a propynyl group, and the like. The term “C₂-C₆₀ alkynylene group” as used herein may be a divalent group having a same structure as the C₂-C₆₀ alkynyl group.

The term “C₁-C₆₀ alkoxy group” as used herein may be a monovalent group represented by —O(A₁₀₁) (wherein A₁₀₁ may be a C₁-C₆₀ alkyl group), and examples thereof may include a methoxy group, an ethoxy group, an isopropyloxy group, and the like.

The term “C₃-C₁₀ cycloalkyl group” as used herein may be a monovalent saturated hydrocarbon cyclic group having 3 to 10 carbon atoms, and examples thereof may include a cyclopropyl group, a cyclobutyl group, a cyclopentyl group, a cyclohexyl group, a cycloheptyl group, a cyclooctyl group, an adamantanyl group, a norbornanyl group (or bicyclo[2.2.1]heptyl group), a bicyclo[1.1.1]pentyl group, a bicyclo[2.1.1]hexyl group, a bicyclo[2.2.2]octyl group, and the like. The term “C₃-C₁₀ cycloalkylene group” as used herein may be a divalent group having a same structure as the C₃-C₁₀ cycloalkyl group.

The term “C₁-C₁₀ heterocycloalkyl group” as used herein may be a monovalent cyclic group of 1 to 10 carbon atoms, further including, in addition to carbon atoms, at least one heteroatom, as ring-forming atoms, and examples thereof may include a 1,2,3,4-oxatriazolidinyl group, a tetrahydrofuranyl group, a tetrahydrothiophenyl group, and the like. The term “C₁-C₁₀ heterocycloalkylene group” as used herein may be a divalent group having a same structure as the C₁-C₁₀ heterocycloalkyl group.

The term “C₃-C₁₀ cycloalkenyl group” as used herein may be a monovalent cyclic group that has three to ten carbon atoms and at least one carbon-carbon double bond in the ring thereof and no aromaticity, and examples thereof may include a cyclopentenyl group, a cyclohexenyl group, a cycloheptenyl group, and the like. The term “C₃-C₁₀ cycloalkenylene group” as used herein may be a divalent group having a same structure as the C₃-C₁₀ cycloalkenyl group.

The term “C₁-C₁₀ heterocycloalkenyl group” as used herein may be a monovalent cyclic group of 1 to 10 carbon atoms, further including, in addition to carbon atoms, at least one heteroatom, as ring-forming atoms, and having at least one carbon-carbon double bond in the cyclic structure thereof. Examples of the C₁-C₁₀ heterocycloalkenyl group may include a 4,5-dihydro-1,2,3,4-oxatriazolyl group, a 2,3-dihydrofuranyl group, a 2,3-dihydrothiophenyl group, and the like. The term “C₁-C₁₀ heterocycloalkenylene group” as used herein may be a divalent group having a same structure as the C₁-C₁₀ heterocycloalkenyl group.

The term “C₆-C₆₀ aryl group” as used herein may be a monovalent group having a carbocyclic aromatic system of 6 to 60 carbon atoms, and the term “C₆-C₆₀ arylene group” as used herein may be a divalent group having a carbocyclic aromatic system of 6 to 60 carbon atoms. Examples of the C₆-C₆₀ aryl group may include a phenyl group, a pentalenyl group, a naphthyl group, an azulenyl group, an indacenyl group, an acenaphthyl group, a phenalenyl group, a phenanthrenyl group, an anthracenyl group, a fluoranthenyl group, a triphenylenyl group, a pyrenyl group, a chrysenyl group, a perylenyl group, a pentaphenyl group, a heptalenyl group, a naphthacenyl group, a picenyl group, a hexacenyl group, a pentacenyl group, a rubicenyl group, a coronenyl group, an ovalenyl group, and the like. When the C₆-C₆₀ aryl group and the C₆-C₆₀ arylene group each include two or more rings, the respective rings may be condensed with each other.

The term “C₁-C₆₀ heteroaryl group” as used herein may be a monovalent group having a heterocyclic aromatic system of 1 to 60 carbon atoms, further including, in addition to carbon atoms, at least one heteroatom, as ring-forming atoms. The term “C₁-C₆₀ heteroarylene group” as used herein may be a divalent group having a heterocyclic aromatic system of 1 to 60 carbon atoms, further including, in addition to carbon atoms, at least one heteroatom, as ring-forming atoms. Examples of the C₁-C₆₀ heteroaryl group may include a pyridinyl group, a pyrimidinyl group, a pyrazinyl group, a pyridazinyl group, a triazinyl group, a quinolinyl group, a benzoquinolinyl group, an isoquinolinyl group, a benzoisoquinolinyl group, a quinoxalinyl group, a benzoquinoxalinyl group, a quinazolinyl group, a benzoquinazolinyl group, a cinnolinyl group, a phenanthrolinyl group, a phthalazinyl group, and a naphthyridinyl group. When the C₁-C₆₀ heteroaryl group and the C₁-C₆₀ heteroarylene group each include two or more rings, the respective rings may be condensed with each other.

The term “monovalent non-aromatic condensed polycyclic group” as used herein may be a monovalent group (for example, having 8 to 60 carbon atoms) having two or more rings condensed to each other, only carbon atoms as ring-forming atoms, and no aromaticity in its entire molecular structure. Examples of the monovalent non-aromatic condensed polycyclic group may include an indenyl group, a fluorenyl group, a spiro-bifluorenyl group, a benzofluorenyl group, an indenophenanthrenyl group, an indeno anthracenyl group, and the like. The term “divalent non-aromatic condensed polycyclic group” as used herein may be a divalent group having a same structure as the monovalent non-aromatic condensed polycyclic group described above.

The term “monovalent non-aromatic condensed heteropolycyclic group” as used herein may be a monovalent group (for example, having 1 to 60 carbon atoms) having two or more rings condensed to each other, further including, in addition to carbon atoms, at least one heteroatom, as ring-forming atoms, and having non-aromaticity in its entire molecular structure. Examples of the monovalent non-aromatic condensed heteropolycyclic group may include a pyrrolyl group, a thiophenyl group, a furanyl group, an indolyl group, a benzoindolyl group, a naphtho indolyl group, an isoindolyl group, a benzoisoindolyl group, a naphthoisoindolyl group, a benzosilolyl group, a benzothiophenyl group, a benzofuranyl group, a carbazolyl group, a dibenzosilolyl group, a dibenzothiophenyl group, a dibenzofuranyl group, an azacarbazolyl group, an azafluorenyl group, an azadibenzosilolyl group, an azadibenzothiophenyl group, an azadibenzofuranyl group, a pyrazolyl group, an imidazolyl group, a triazolyl group, a tetrazolyl group, an oxazolyl group, an isoxazolyl group, a thiazolyl group, an isothiazolyl group, an oxadiazolyl group, a thiadiazolyl group, a benzopyrazolyl group, a benzimidazolyl group, a benzoxazolyl group, a benzothiazolyl group, a benzoxadiazolyl group, a benzothiadiazolyl group, an imidazopyridinyl group, an imidazopyrimidinyl group, an imidazotriazinyl group, an imidazopyrazinyl group, an imidazopyridazinyl group, an indenocarbazolyl group, an indolocarbazolyl group, a benzofurocarbazolyl group, a benzothienocarbazolyl group, a benzosilolocarbazolyl group, a benzoindolocarbazolyl group, a benzocarbazolyl group, a benzonaphthofuranyl group, a benzonaphthothiophenyl group, a benzonaphthosilolyl group, a benzofurodibenzofuranyl group, a benzofurodibenzothiophenyl group, a benzothienodibenzothiophenyl group, and the like. The term “divalent non-aromatic condensed heteropolycyclic group” as used herein may be a divalent group having a same structure as the monovalent non-aromatic condensed heteropolycyclic group described above.

The term “C₆-C₆₀ aryloxy group” as used herein may be a group represented by —O(A₁₀₂) (wherein A₁₀₂ may be a C₆-C₆₀ aryl group), and the term “C₆-C₆₀ arylthio group” as used herein may be a group represented by —S(A₁₀₃) (wherein A₁₀₃ may be a C₆-C₆₀ aryl group).

The term “C₇-C₆₀ arylalkyl group” as used herein may be a group represented by -(A₁₀₄)(A₁₀₅) (wherein A₁₀₄ may be a C₁-C₅₄ alkylene group, and A₁₀₅ may be a C₆-C₅₉ aryl group), and the term “C₂-C₆₀ heteroarylalkyl group” as used herein may be a group represented by -(A₁₀₆)(A₁₀₇) (wherein A₁₀₆ may be a C₁-C₅₉ alkylene group, and A₁₀₇ may be a C₁-C₅₉ heteroaryl group).

The group R₁₀ₐ as used herein may be:

deuterium (-D), —F, —Cl, —Br, —I, a hydroxyl group, a cyano group, or a nitro group;

a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or any combination thereof;

a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or any combination thereof; or

—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂).

In the specification, Q₁ to Q₃, Q₁₁ to Q₁₃, Q₂₁ to Q₂₃, and Q₃₁ to Q₃₃ may each independently be: hydrogen; deuterium; —F; —Cl; —Br; —I; a hydroxyl group; a cyano group; a nitro group; a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or any combination thereof; a C₇-C₆₀ arylalkyl group, or a C₂-C₆₀ heteroarylalkyl group.

The term “heteroatom” as used herein may be any atom other than a carbon atom or a hydrogen atom. Examples of the heteroatom may include O, S, N, P, Si, B, Ge, Se, or any combination thereof.

The term “Ph” as used herein refers to a phenyl group, the term “Me” as used herein refers to a methyl group, the term “Et” as used herein refers to an ethyl group, the terms “tert-Bu” or “Bu^{t}” as used herein each refer to a tert-butyl group, and the term “OMe” as used herein refers to a methoxy group.

The term “biphenyl group” as used herein may be a “phenyl group substituted with a phenyl group.” For example, the “biphenyl group” may be a substituted phenyl group having a C₆-C₆₀ aryl group as a substituent.

The term “terphenyl group” as used herein may be a “phenyl group substituted with a biphenyl group.” For example, the “terphenyl group” may be a substituted phenyl group having, as a substituent, a C₆-C₆₀ aryl group substituted with a C₆-C₆₀ aryl group.

The symbols *, *′, and *″ as used herein, unless defined otherwise, each refer to a binding site to a neighboring atom in a corresponding formula or moiety.

Hereinafter, compounds according to embodiments and light-emitting devices according to embodiments will be described in detail with reference to the Synthesis Examples and Examples. The wording “B was used instead of A” used in describing Synthesis Examples means that an identical molar equivalent of B was used in place of A.

### EXAMPLES

### Synthesis Example 1: Synthesis of Compound 1

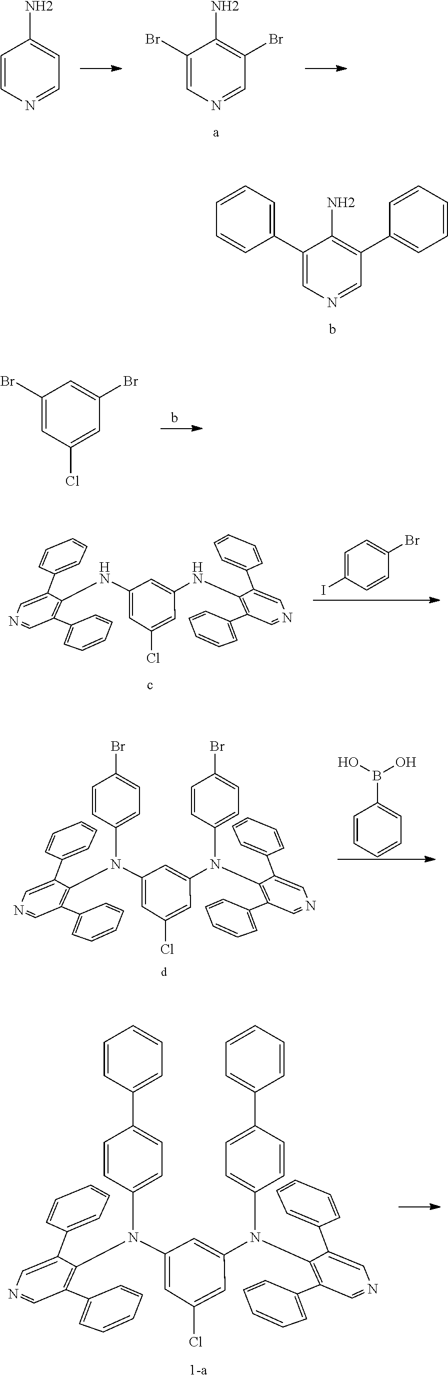

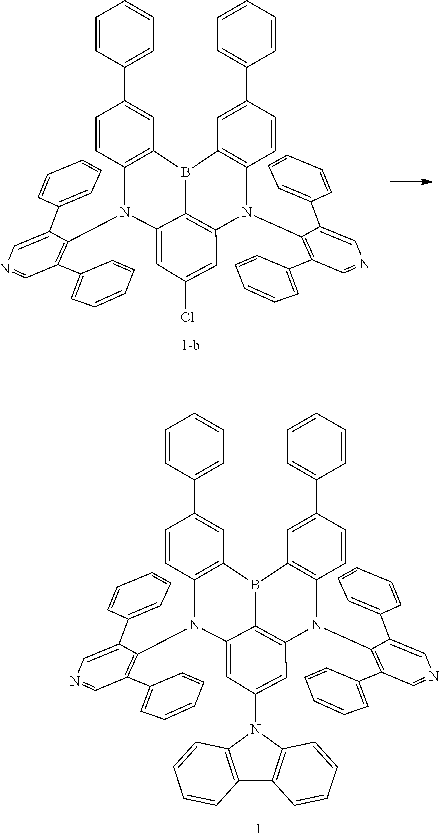 [SMILES: Clc1cc2c3c(c1)N(c1c(-c4ccccc4)cncc1-c1ccccc1)c1ccc(-c4ccccc4)cc1B3c1cc(-c3ccccc3)ccc1N2c1c(-c2ccccc2)cncc1-c1ccccc1 ; c1ccc(-c2ccc3c(c2)B2c4cc(-c5ccccc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1]

### Synthesis of Intermediate Compound a

Under argon conditions, 4-aminopyridine (7.5 g, 80 mmol) was dissolved in 800 mL of dichloromethane in a 2 L flask, and the reaction solution was cooled to 0° C. While stirring strongly, a solution in which 1-bromo-2,5-pyrrolidinedione (NBS, 32.8 g, 184 mmol) was dissolved in 200 ml of dichloromethane was added dropwise to the flask. The reaction temperature was raised to room temperature, and the resulting reaction solution was stirred for 24 hours. After completion of the reaction, the reaction solution was decompressed to remove the solvent therefrom, and the reaction product was purified by silica gel column chromatography by using ethyl acetate and hexane as developing solvents to obtain Intermediate compound a (white solid, 18.1 g, 72 mmol, 90%). By ESI-LCMS, the compound thus obtained was identified as Intermediate compound a.

ESI-LCMS: [M]⁺: C₅H₄Br₂N₂. 251.87.

### Synthesis of Intermediate Compound b

Under argon conditions, in a 2 L flask, Intermediate compound a (18.1 g, 72 mmol), phenyl boronic acid (21.9 g, 180 mmol), Pd(PPh₃)₄ (4.2 g, 3.6 mmol), and potassium carbonate (29.9 g, 216 mmol) were added and dissolved in 600 mL of toluene and 200 mL of H₂O. The reaction solution was stirred at 100° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound b (white solid, 14 g, 57 mmol, 79%). By ESI-LCMS, the compound thus obtained was identified as Intermediate compound b.

ESI-LCMS: [M]⁺: C₁₇H₁₄N₂. 246.12.

### Synthesis of Intermediate Compound c

Under argon conditions, in a 2 L flask, Intermediate compound b (14 g, 57 mmol), 1,3-dibromo-5-chlorobenzene (7.7 g, 29 mmol), Pd₂dba₃ (1.3 g, 1.5 mmol), tris-tert-butyl phosphine solution 50% in toluene (1.4 mL, 2.9 mmol), and sodium tert-butoxide (8.4 g, 87 mmol) were added and dissolved in 600 mL of o-xylene. The reaction solution was stirred at 140° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound c (white solid, 12.7 g, 21 mmol, 73%). By ESI-LCMS, the compound thus obtained was identified as Intermediate compound c.

ESI-LCMS: [M]⁺: C₄₀H₂₉ClN₄. 600.21.

### Synthesis of Intermediate Compound d

Under argon conditions, in a 2 L flask, Intermediate compound c (12.7 g, 21 mmol), 4-iodo-bromobenzene (29.7 g, 105 mmol), Pd₂dba₃ (1.0 g, 1.1 mmol), tris-tert-butyl phosphine solution 50% in toluene (1.0 mL, 2.1 mmol), and sodium tert-butoxide (6.1 g, 63 mmol) were added and dissolved in 300 mL of o-xylene. The reaction solution was stirred at 140° C. for 72 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound d (white solid, 11.5 g, 12.6 mmol, 60%). By ESI-LCMS, the compound thus obtained was identified as Intermediate compound d.

ESI-LCMS: [M]⁺: C₅₂H₃₅Br₂ClN₄. 910.09.

### Synthesis of Intermediate Compound 1-a

Under argon conditions, in a 2 L flask, Intermediate compound d (11.5 g, 13 mmol), phenyl boronic acid (3.1 g, 25 mmol), Pd(PPh₃)₄ (0.73 g, 0.63 mmol), and potassium carbonate (5.2 g, 38 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 1-a (white solid, 7.7 g, 8.5 mmol, 65%). By ESI-LCMS, the compound thus obtained was identified as Intermediate compound 1-a.

ESI-LCMS: [M]⁺: C₆₄H₄₅ClN₄. 904.33.

### Synthesis of Intermediate Compound 1-b

Under argon conditions, in a 500 mL flask, Intermediate compound 1-a (7.7 g, 8.5 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 1-b (yellow solid, 3.0 g, 3.2 mmol, 38%). By ESI-LCMS, the compound thus obtained was identified as Intermediate compound 1-b.

ESI-LCMS: [M]⁺: C₆₄H₄₂BClN₄. 912.33.

### Synthesis of Compound 1

Under argon conditions, in a 500 mL flask, Intermediate compound 1-b (3.0 g, 3.2 mmol), 9H-carbazole (0.6 g, 3.5 mmol), Pd₂dba₃ (0.15 g, 0.16 mmol), tris-tert-butyl phosphine solution 50% in toluene (0.15 mL, 0.3 mmol), and sodium tert-butoxide (0.62 g, 6.4 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 1 (yellow solid, 2.27 g, 2.18 mmol, 68%). By ¹H-NMR and ESI-LCMS, the compound thus obtained was identified as Compound 1.

¹H-NMR (400 MHz, CDCl₃): δ=9.38 (s, 2H), 8.80 (s, 4H), 8.13 (d, 2H), 7.85-7.79 (m, 14H), 7.64 (d, 4H), 7.58-7.51 (m, 8H), 7.47-7.42 (m, 6H), 7.29 (t, 2H), 7.20 (t, 2H), 7.14-7.12 (m, 4H), 6.54 (s, 2H)

ESI-LCMS: [M]⁺: C₇₆H₅₀BN₅. 1043.42.

### Synthesis Example 2: Synthesis of Compound 29

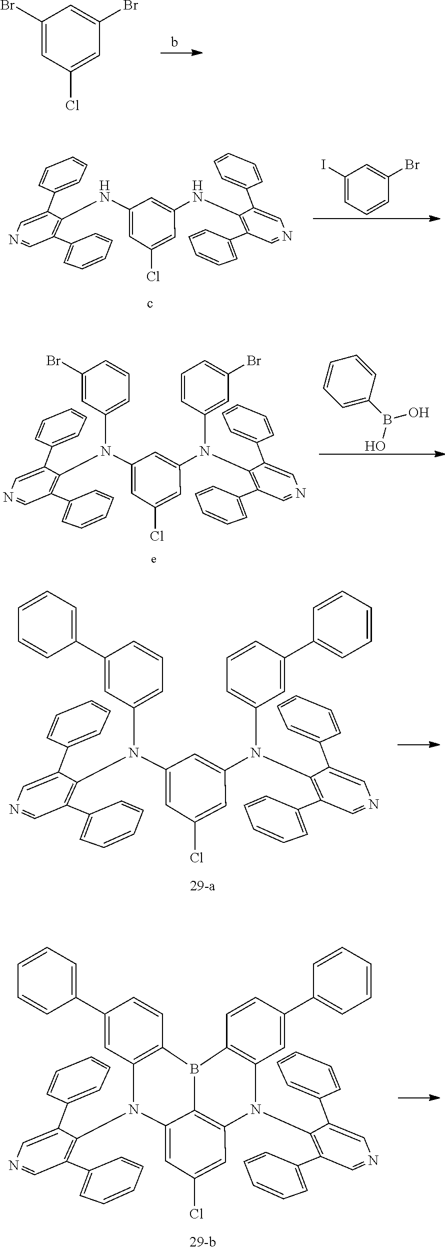

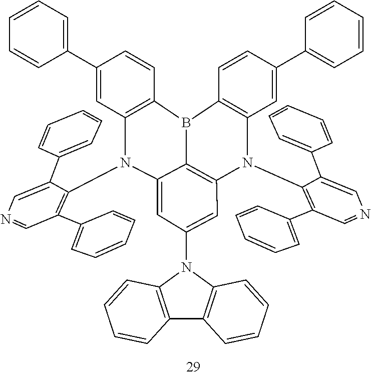 [SMILES: c1ccc(-c2ccc3c(c2)N(c2c(-c4ccccc4)cncc2-c2ccccc2)c2cc(-n4c5ccccc5c5ccccc54)cc4c2B3c2ccc(-c3ccccc3)cc2N4c2c(-c3ccccc3)cncc2-c2ccccc2)cc1]

### Synthesis of Intermediate Compound e

Under argon conditions, in a 1 L flask, Intermediate compound c (12.0 g, 20 mmol), 3-iodo-bromobenzene (28.3 g, 100 mmol), Pd₂dba₃ (0.9 g, 1.0 mmol), tris-tert-butyl phosphine solution 50% in toluene (0.9 mL, 2.0 mmol), and sodium tert-butoxide (5.8 g, 60 mmol) were added and dissolved in 300 mL of o-xylene. The reaction solution was stirred at 140° C. for 72 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound e (white solid, 12.0 g, 13.2 mmol, 66%). By ESI-LCMS, the compound thus obtained was identified as Intermediate compound e.

ESI-LCMS: [M]⁺: C₅₂H₃₅Br₂ClN₄. 910.09.

### Synthesis of Intermediate Compound 29-a

Under argon conditions, in a 500 mL flask, Intermediate compound e (12.0 g, 13 mmol), phenylboronic acid (3.96 g, 32.5 mmol), Pd(PPh₃)₄ (0.76 g, 0.66 mmol), and potassium carbonate (5.5 g, 40 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 29-a (white solid, 8.35 g, 9.23 mmol, 71%). By ESI-LCMS, the compound thus obtained was identified as Intermediate compound 29-a.

ESI-LCMS: [M]⁺: C₆₄H₄₅ClN₄. 904.33.

### Synthesis of Intermediate Compound 29-b

Under argon conditions, in a 500 mL flask, Intermediate compound 29-a (8.4 g, 9.2 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 29-b (yellow solid, 2.95 g, 3.23 mmol, 35%). By ESI-LCMS, the compound thus obtained was identified as Intermediate compound 29-b.

ESI-LCMS: [M]⁺: C₆₄H₄₂BClN₄. 912.32.

### Synthesis of Compound 29

Under argon conditions, in a 500 mL flask, Intermediate compound 29-b (3.0 g, 3.2 mmol), 9H-carbazole (0.59 g, 3.6 mmol), Pd₂dba₃ (0.15 g, 0.16 mmol), tris-tert-butyl phosphine solution 50% in toluene (0.15 mL, 0.32 mmol), and sodium tert-butoxide (0.62 g, 6.4 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 29 (yellow solid, 1.8 g, 1.8 mmol, 55%). By ¹H-NMR and ESI-LCMS, the compound thus obtained was identified as Compound 29.

¹H-NMR (400 MHz, CDCl₃): δ=9.35 (d, 2H), 8.72 (s, 4H), 8.10 (d, 2H), 7.86-7.79 (m, 14H), 7.60 (d, 4H), 7.51-7.49 (m, 8H), 7.48-7.44 (m, 6H), 7.30 (t, 2H), 7.25 (t, 2H), 7.16-7.12 (m, 4H), 6.50 (s, 2H)

ESI-LCMS: [M]⁺: C₇₆H₅₀BN₅. 1043.42.

### Synthesis Example 3: Synthesis of Compound 31

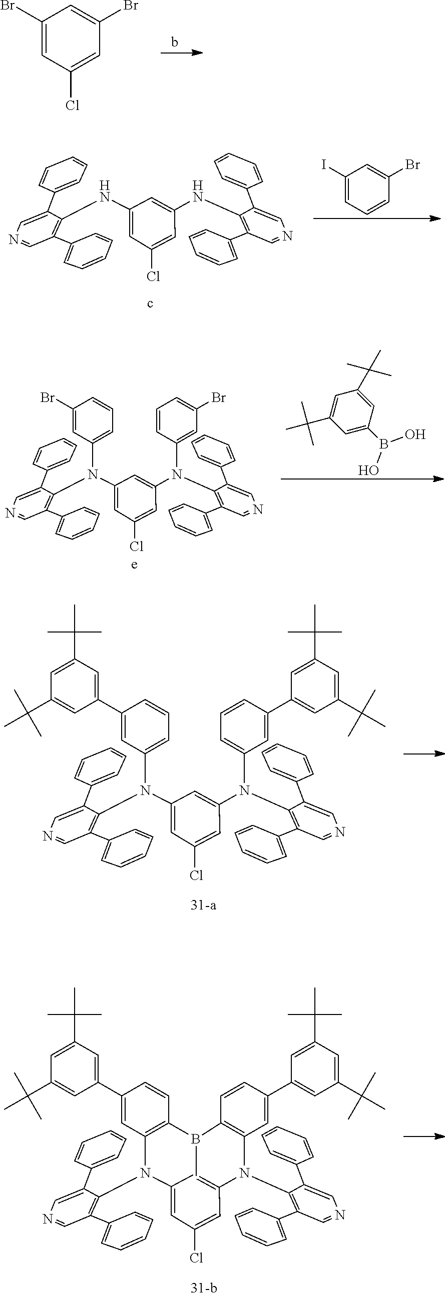

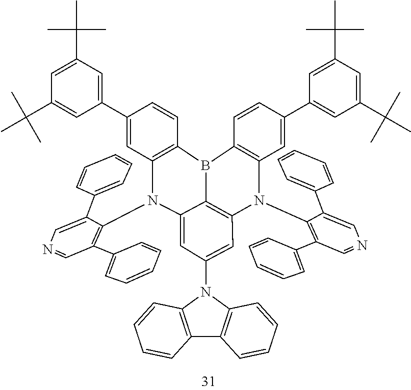 [SMILES: CC(C)(C)c1cc(-c2ccc3c(c2)N(c2c(-c4ccccc4)cncc2-c2ccccc2)c2cc(-n4c5ccccc5c5ccccc54)cc4c2B3c2ccc(-c3cc(C(C)(C)C)cc(C(C)(C)C)c3)cc2N4c2c(-c3ccccc3)cncc2-c2ccccc2)cc(C(C)(C)C)c1]

### Synthesis of Intermediate Compound e

Under argon conditions, in a 1 L flask, Intermediate compound c (12.0 g, 20 mmol), 3-iodo-bromobenzene (28.3 g, 100 mmol), Pd₂dba₃ (0.9 g, 1.0 mmol), tris-tert-butyl phosphine solution 50% in toluene (0.9 mL, 2.0 mmol), and sodium tert-butoxide (5.8 g, 60 mmol) were added and dissolved in 300 mL of o-xylene. The reaction solution was stirred at 140° C. for 72 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound c (white solid, 12.0 g, 13.2 mmol, 66%). By ESI-LCMS, the compound thus obtained was identified as Intermediate compound e.

ESI-LCMS: [M]⁺: C₅₂H₃₅Br₂ClN₄. 910.09.

### Synthesis of Intermediate Compound 31-a

Under argon conditions, in a 500 mL flask, Intermediate compound e (12.0 g, 13 mmol), (3,5-di-tert-butylphenyl)boronic acid (6.1 g, 26 mmol), Pd(PPh₃)₄ (0.76 g, 0.66 mmol), and potassium carbonate (5.5 g, 40 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 31-a (white solid, 8.5 g, 7.5 mmol, 58%). By ESI-LCMS, the compound thus obtained was identified as Intermediate compound 31-a.

ESI-LCMS: [M]⁺: C₈₀H₇₇ClN₄. 1128.59.

### Synthesis of Intermediate Compound 31-b

Under argon conditions, in a 500 mL flask, Intermediate compound 31-a (8.5 g, 7.5 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 31-b (yellow solid, 2.5 g, 2.2 mmol, 29%). By ESI-LCMS, the compound thus obtained was identified as Intermediate compound 31-b.

ESI-LCMS: [M]⁺: C₈₀H₇₄BClN₄. 1136.55.

### Synthesis of Compound 31

Under argon conditions, in a 500 mL flask, Intermediate compound 31-b (2.5 g, 2.2 mmol), 9H-carbazole (0.40 g, 2.4 mmol), Pd₂dba₃ (0.10 g, 0.11 mmol), tris-tert-butyl phosphine solution 50% in toluene (0.10 mL, 0.22 mmol), and sodium tert-butoxide (0.42 g, 4.4 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 31 (yellow solid, 1.7 g, 1.3 mmol, 60%). By ¹H-NMR and ESI-LCMS, the compound thus obtained was identified as Compound 31.

¹H-NMR (400 MHz, CDCl₃): δ=9.32 (d, 2H), 8.78 (s, 4H), 8.08 (d, 2H), 7.85-7.76 (m, 14H), 7.51 (d, 4H), 7.50-7.46 (m, 8H), 7.45-7.44 (m, 2H), 7.32 (t, 2H), 7.22 (t, 2H), 7.15-7.12 (m, 4H), 6.47 (s, 2H), 1.58 (s, 36H)

ESI-LCMS: [M]⁺: C₉₂H₈₂BN₅. 1267.65.

### Synthesis Example 4: Synthesis of Compound 34

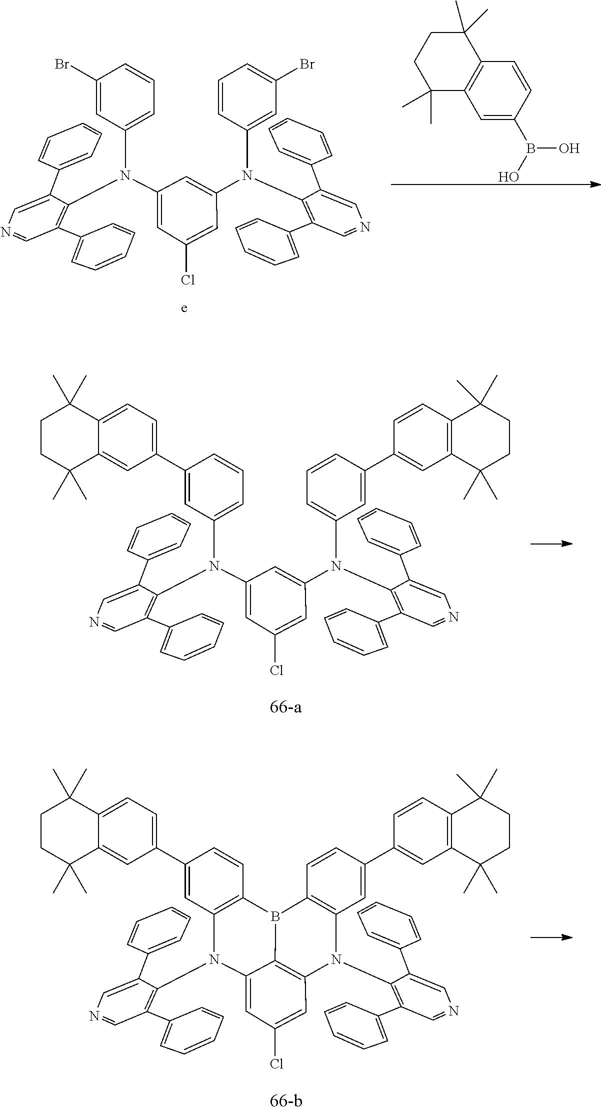 [SMILES: Clc1cc(N(c2cccc(Br)c2)c2c(-c3ccccc3)cncc2-c2ccccc2)cc(N(c2cccc(Br)c2)c2c(-c3ccccc3)cncc2-c2ccccc2)c1 ; CC1(C)CCC(C)(C)c2cc(B(O)O)ccc21 ; CC1(C)CCC(C)(C)c2cc(-c3cccc(N(c4cc(Cl)cc(N(c5cccc(-c6ccc7c(c6)C(C)(C)CCC7(C)C)c5)c5c(-c6ccccc6)cncc5-c5ccccc5)c4)c4c(-c5ccccc5)cncc4-c4ccccc4)c3)ccc21 ; CC1(C)CCC(C)(C)c2cc(-c3ccc4c(c3)N(c3c(-c5ccccc5)cncc3-c3ccccc3)c3cc(Cl)cc5c3B4c3ccc(-c4ccc6c(c4)C(C)(C)CCC6(C)C)cc3N5c3c(-c4ccccc4)cncc3-c3ccccc3)ccc21]

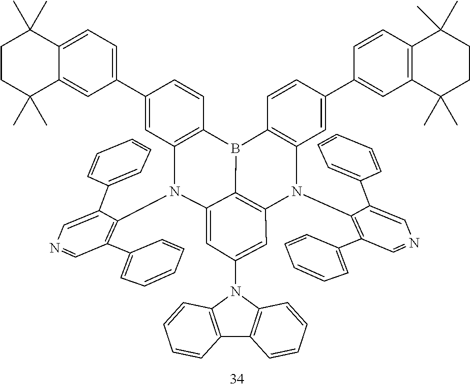 [SMILES: CC1(C)CCC(C)(C)c2cc(-c3ccc4c(c3)N(c3c(-c5ccccc5)cncc3-c3ccccc3)c3cc(-n5c6ccccc6c6ccccc65)cc5c3B4c3ccc(-c4ccc6c(c4)C(C)(C)CCC6(C)C)cc3N5c3c(-c4ccccc4)cncc3-c3ccccc3)ccc21]

### Synthesis of Intermediate Compound 66-a

Under argon conditions, in a 500 mL flask, intermediate compound e (15.0 g, 17 mmol), (5,5,8,8-tetramethyl-5,6,7,8-tetrahydronaphthalen-2-yl)boronic acid (7.7 g, 33 mmol), Pd(PPh₃)₄ (0.95 g, 0.83 mmol), and potassium carbonate (6.8 g, 50 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 66-a (white solid, 8.4 g, 7.4 mmol, 45%). By ESI-LCMS, the compound thus obtained was identified as Intermediate compound 66-a.

ESI-LCMS: [M]⁺: C₈₀H₇₃ClN₄. 1125.91.

### Synthesis of Intermediate Compound 66-b

Under argon conditions, in a 500 mL flask, Intermediate compound 66-a (8.4 g, 7.4 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 66-b (yellow solid, 2.1 g, 1.9 mmol, 25%). By ESI-LCMS, the obtained compound was identified as Intermediate compound 66-b.

ESI-LCMS: [M]⁺: C₈₀H₇₀BClN₄. 1132.55.

### Synthesis of Compound 34

Under argon conditions, in a 500 mL flask, Intermediate compound 66-b (2.38 g, 2.1 mmol), 9H-carbazole (0.39 g, 2.3 mmol), Pd₂dba₃ (0.10 g, 0.11 mmol), tris-tert-butyl phosphine solution 50% in toluene (0.10 mL, 0.21 mmol), and sodium tert-butoxide (0.40 g, 4.2 mmol) were added and dissolved in 100 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 34 (yellow solid, 1.5 g, 1.2 mmol, 55%). By ¹H-NMR and ESI-LCMS, the compound thus obtained was identified as Compound 34.

¹H-NMR (400 MHz, CDCl₃): δ=9.27 (d, 2H), 8.60 (s, 4H), 8.10 (d, 2H), 7.88-7.79 (m, 12H), 7.65-7.61 (m, 4H), 7.50-7.46 (m, 6H), 7.48-7.44 (m, 8H), 7.25 (d, 2H), 7.16-7.10 (m, 4H), 6.56 (s, 2H), 1.90-1.82 (m, 8H), 1.48 (s, 12H), 1.32 (s, 12H)

ESI-LCMS: [M]⁺: C₉₂H₇₈BN₅. 1263.64.

### Synthesis Example 5: Synthesis of Compound 37

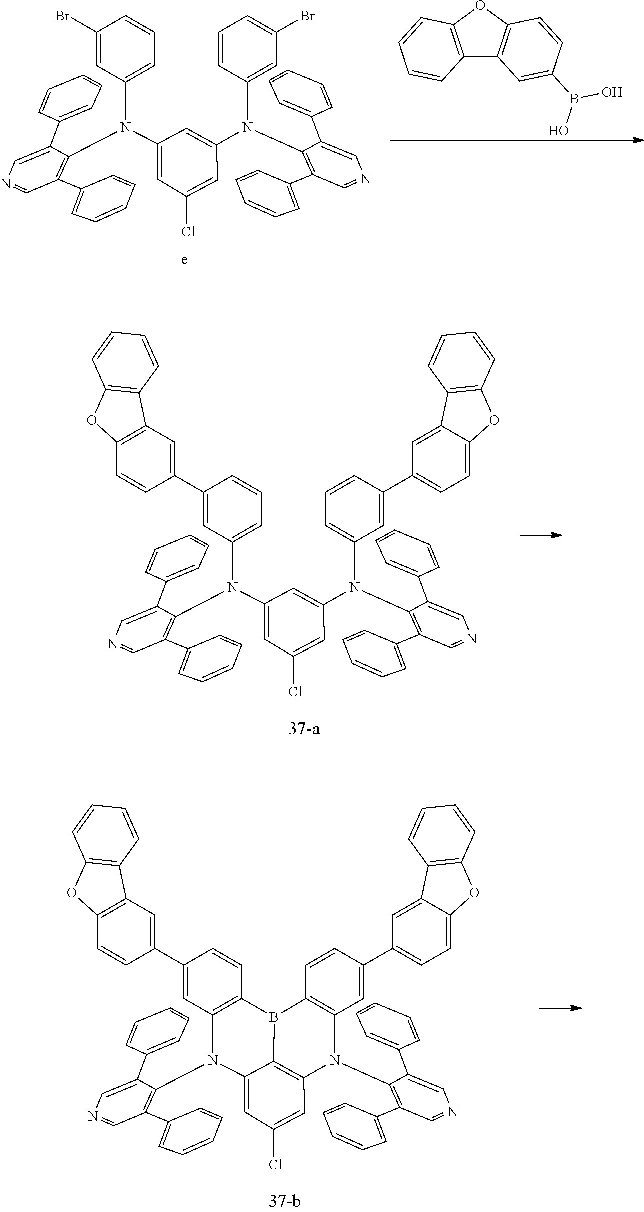 [SMILES: Clc1cc(N(c2cccc(Br)c2)c2c(-c3ccccc3)cncc2-c2ccccc2)cc(N(c2cccc(Br)c2)c2c(-c3ccccc3)cncc2-c2ccccc2)c1 ; OB(O)c1ccc2oc3ccccc3c2c1 ; Clc1cc(N(c2cccc(-c3ccc4oc5ccccc5c4c3)c2)c2c(-c3ccccc3)cncc2-c2ccccc2)cc(N(c2cccc(-c3ccc4oc5ccccc5c4c3)c2)c2c(-c3ccccc3)cncc2-c2ccccc2)c1 ; Clc1cc2c3c(c1)N(c1c(-c4ccccc4)cncc1-c1ccccc1)c1cc(-c4ccc5oc6ccccc6c5c4)ccc1B3c1ccc(-c3ccc4oc5ccccc5c4c3)cc1N2c1c(-c2ccccc2)cncc1-c1ccccc1]

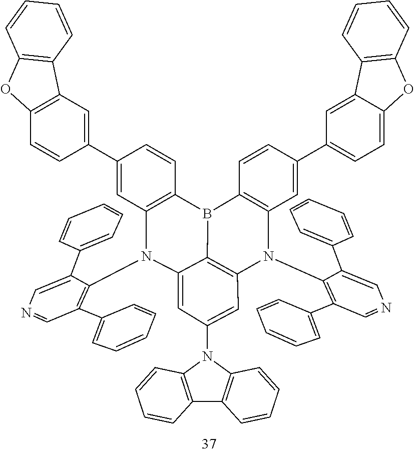 [SMILES: c1ccc(-c2cncc(-c3ccccc3)c2N2c3cc(-c4ccc5oc6ccccc6c5c4)ccc3B3c4ccc(-c5ccc6oc7ccccc7c6c5)cc4N(c4c(-c5ccccc5)cncc4-c4ccccc4)c4cc(-n5c6ccccc6c6ccccc65)cc2c43)cc1]

### Synthesis of Intermediate Compound 37-a

Under argon conditions, in a 500 mL flask, Intermediate compound e (12.0 g, 13 mmol), dibenzofuran-2-boronic acid (5.6 g, 26 mmol), Pd(PPh₃)₄ (0.76 g, 0.66 mmol), and potassium carbonate (5.5 g, 40 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 37-a (white solid, 7.8 g, 7.2 mmol, 55%). By ESI-LCMS, the compound thus obtained was identified as Intermediate compound 37-a.

ESI-LCMS: [M]⁺: C₇₆H₄₉ClN₄O₂. 1084.34.

### Synthesis of Intermediate Compound 37-b

Under argon conditions, in a 500 mL flask, Intermediate compound 37-a (7.8 g, 7.2 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 37-b (yellow solid, 1.7 g, 1.6 mmol, 22%). By ESI-LCMS, the compound thus obtained was identified as Intermediate compound 37-b.

ESI-LCMS: [M]⁺: C₇₆H₄₆BClN₄O₂. 1092.34.

### Synthesis of Compound 37

Under argon conditions, in a 500 mL flask, Intermediate compound 37-b (1.7 g, 1.6 mmol), 9H-carbazole (0.30 g, 1.8 mmol, Pd₂dba₃ (0.07 g, 0.08 mmol), tris-tert-butyl phosphine solution 50% in toluene (0.07 mL, 0.16 mmol), and sodium tert-butoxide (0.31 g, 3.2 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 37 (yellow solid, 1.3 g, 1.0 mmol, 65%). By ¹H-NMR and ESI-LCMS, the compound thus obtained was identified as Compound 37.

¹H-NMR (400 MHz, CDCl₃): δ=9.28 (d, 2H), 8.85 (s, 4H), 8.13 (d, 2H), 8.07-8.02 (m, 6H), 7.76-7.72 (m, 2H), 7.68-7.63 (m, 4H), 7.54-7.51 (m, 2H), 7.45-7.41 (m, 6H), 7.23 (dd, 2H), 7.14-7.12 (m, 2H), 7.07-7.02 (m, 12H), 6.99-6.93 (m, 8H), 6.64 (s, 2H)

ESI-LCMS: [M]⁺: C₈₈H₅₄BN₅O₂. 1223.45.

### Synthesis Example 6: Synthesis of Compound 66

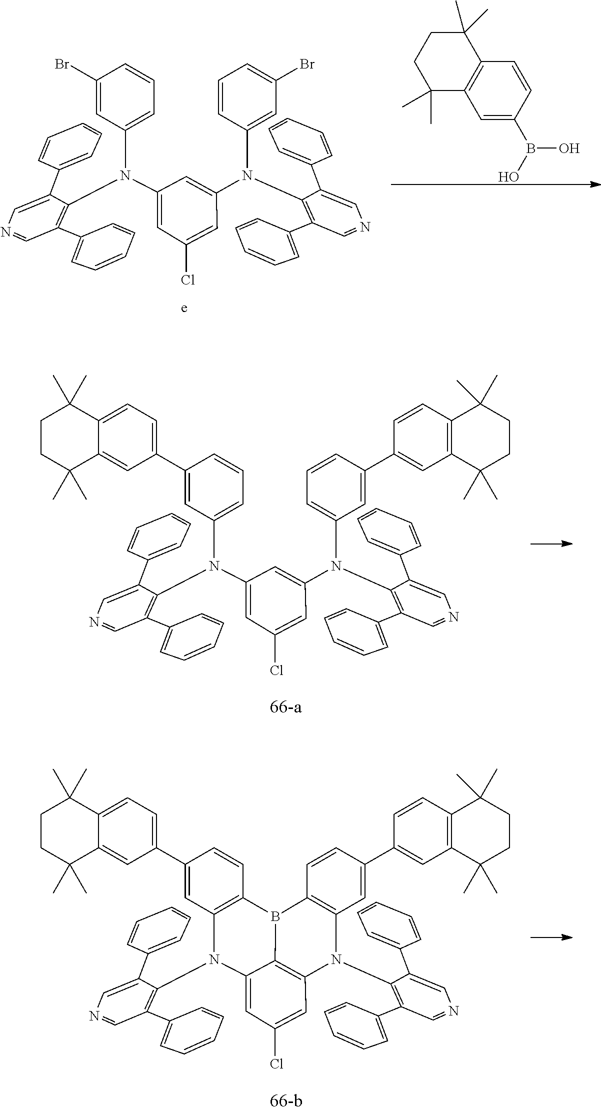 [SMILES: Clc1cc(N(c2cccc(Br)c2)c2c(-c3ccccc3)cncc2-c2ccccc2)cc(N(c2cccc(Br)c2)c2c(-c3ccccc3)cncc2-c2ccccc2)c1 ; CC1(C)CCC(C)(C)c2cc(B(O)O)ccc21 ; CC1(C)CCC(C)(C)c2cc(-c3cccc(N(c4cc(Cl)cc(N(c5cccc(-c6ccc7c(c6)C(C)(C)CCC7(C)C)c5)c5c(-c6ccccc6)cncc5-c5ccccc5)c4)c4c(-c5ccccc5)cncc4-c4ccccc4)c3)ccc21 ; CC1(C)CCC(C)(C)c2cc(-c3ccc4c(c3)N(c3c(-c5ccccc5)cncc3-c3ccccc3)c3cc(Cl)cc5c3B4c3ccc(-c4ccc6c(c4)C(C)(C)CCC6(C)C)cc3N5c3c(-c4ccccc4)cncc3-c3ccccc3)ccc21]

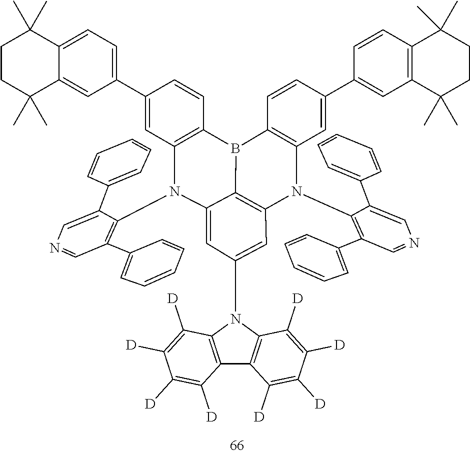 [SMILES: [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1cc(-c4ccc5c(c4)C(C)(C)CCC5(C)C)ccc1B3c1ccc(-c3ccc4c(c3)C(C)(C)CCC4(C)C)cc1N2c1c(-c2ccccc2)cncc1-c1ccccc1]

### Synthesis of Intermediate Compound 66-a

Under argon conditions, in a 500 mL flask, intermediate compound e (15.0 g, 17 mmol), (5,5,8,8-tetramethyl-5,6,7,8-tetrahydronaphthalen-2-yl)boronic acid (7.7 g, 33 mmol), Pd(PPh₃)₄ (0.95 g, 0.83 mmol), and potassium carbonate (6.8 g, 50 mmol) were added and dissolved in 150 mL of toluene and 50 mL of H₂O. The reaction solution was stirred at 100° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 66-a (white solid, 8.4 g, 7.4 mmol, 45%). By ESI-LCMS, the compound thus obtained was identified as Intermediate compound 66-a.

ESI-LCMS: [M]⁺: C₈₀H₇₃ClN₄. 1125.91.

### Synthesis of Intermediate Compound 66-b

Under argon conditions, in a 500 mL flask, Intermediate compound 66-a (8.4 g, 7.4 mmol) was added and dissolved in 160 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 66-b (yellow solid, 2.1 g, 1.9 mmol, 25%). By ESI-LCMS, the obtained compound was identified as Intermediate compound 66-b.

ESI-LCMS: [M]⁺: C₈₀H₇₀BClN₄. 1132.55.

### Synthesis of Compound 66

Under argon conditions, in a 500 mL flask, Intermediate compound 66-b (2.1 g, 1.9 mmol), 9H-carbazole-1,2,3,4,5,6,7,8-d8 (0.35 g, 2.0 mmol), Pd₂dba₃ (0.09 g, 0.10 mmol), tris-tert-butyl phosphine solution 50% in toluene (0.09 mL, 0.19 mmol), and sodium tert-butoxide (0.37 g, 3.8 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 66 (yellow solid, 1.7 g, 1.3 mmol, 71%). By ¹H-NMR and ESI-LCMS, the compound thus obtained was identified as Compound 66.

¹H-NMR (400 MHz, CDCl₃): δ=9.27 (d, 2H), 8.60 (s, 4H), 7.88-7.79 (m, 12H), 7.65-7.61 (m, 4H), 7.50-7.46 (m, 4H), 7.48-7.44 (m, 6H), 7.25 (d, 2H), 7.16-7.10 (m, 2H), 6.56 (s, 2H), 1.87-1.80 (m, 8H), 1.50 (s, 12H), 1.31 (s, 12H)

ESI-LCMS: [M]⁺: C₉₂H₇₀D₈BN₅. 1271.70.

### Synthesis Example 7: Synthesis of Compound 107

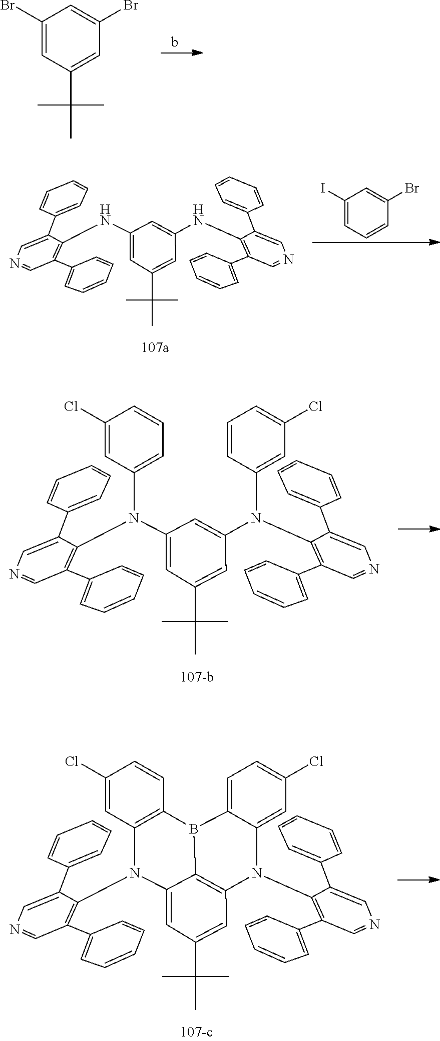 [SMILES: CC(C)(C)c1cc(Br)cc(Br)c1 ; CC(C)(C)c1cc(Nc2c(-c3ccccc3)cncc2-c2ccccc2)cc(Nc2c(-c3ccccc3)cncc2-c2ccccc2)c1 ; Brc1cccc(I)c1 ; CC(C)(C)c1cc(N(c2cccc(Cl)c2)c2c(-c3ccccc3)cncc2-c2ccccc2)cc(N(c2cccc(Cl)c2)c2c(-c3ccccc3)cncc2-c2ccccc2)c1 ; CC(C)(C)c1cc2c3c(c1)N(c1c(-c4ccccc4)cncc1-c1ccccc1)c1cc(Cl)ccc1B3c1ccc(Cl)cc1N2c1c(-c2ccccc2)cncc1-c1ccccc1]

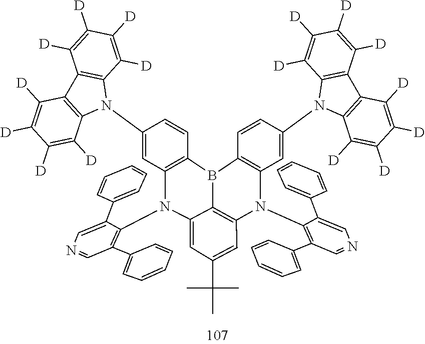 [SMILES: [2H]c1c([2H])c([2H])c2c(c1[2H])c1c([2H])c([2H])c([2H])c([2H])c1n2-c1ccc2c(c1)N(c1c(-c3ccccc3)cncc1-c1ccccc1)c1cc(C(C)(C)C)cc3c1B2c1ccc(-n2c4c([2H])c([2H])c([2H])c([2H])c4c4c([2H])c([2H])c([2H])c([2H])c42)cc1N3c1c(-c2ccccc2)cncc1-c1ccccc1]

### Synthesis of Intermediate Compound 107-a

Under argon conditions, in a 2 L flask, Intermediate compound b (17.2 g, 70 mmol), 1,3-dibromo-5-(tert-butyl)benzene (10.2 g, 35 mmol), Pd₂dba₃ (1.6 g, 1.75 mmol), tris-tert-butyl phosphine solution 50% in toluene (1.63 mL, 3.5 mmol), and sodium tert-butoxide (10.1 g, 105 mmol) were added and dissolved in 700 mL of o-xylene. The reaction solution was stirred at 140° C. for 12 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 107-a (white solid, 17.4 g, 28 mmol, 80%). By ESI-LCMS, the compound thus obtained was identified as Intermediate compound 107-a.

ESI-LCMS: [M]⁺: C₄₄H₃₈N₄. 622.31.

### Synthesis of Intermediate Compound 107-b

Under argon conditions, in a 1 L flask, Intermediate compound 107-a (17.4 g, 28 mmol), 1-chloro-3-iodobenzene (29.7 g, 140 mmol), pd₂dba₃ (1.3 g, 1.4 mmol), tris-tert-butyl phosphine solution 50% in toluene (1.3 mL, 2.8 mmol), and sodium tert-butoxide (8.1 g, 84 mmol) were added and dissolved in 300 mL of o-xylene. The reaction solution was stirred at 140° C. for 72 hours. After cooling, an extraction process was performed thereon by using water (500 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 107-b (white solid, 15.1 g, 17.9 mmol, 64%). By ESI-LCMS, the compound thus obtained was identified as Intermediate compound 107-b.

ESI-LCMS: [M]⁺: C₅₆H₄₄Cl₂N₄. 842.29.

### Synthesis of Intermediate Compound 107-c

Under argon conditions, in a 500 mL flask, Intermediate compound 107-b (15.1 g, 17.9 mmol) was added and dissolved in 300 mL of o-dichlorobenzene. After cooling using water-ice, and BBr₃ (5 equiv.) was slowly added dropwise thereto, and the reaction solution was stirred at 180° C. for 12 hours. After cooling again, triethylamine (5 equiv.) was added thereto to terminate the reaction. An extraction process was performed thereon by using water/CH₂Cl₂ to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Intermediate compound 107-c (yellow solid, 3.7 g, 4.3 mmol, 24%). By ESI-LCMS, the compound thus obtained was identified as Intermediate compound 107-c.

ESI-LCMS: [M]⁺: C₅₆H₄₁BCl₂N₄. 850.28.

### Synthesis of Compound 107

Under argon conditions, in a 500 mL flask, Intermediate compound 107-c (3.7 g, 4.3 mmol), 9H-carbazole-1,2,3,4,5,6,7,8-d8 (1.6 g, 9.0 mmol), Pd₂dba₃ (0.20 g, 0.22 mmol), tris-tert-butyl phosphine solution 50% in toluene (0.20 mL, 0.43 mmol), and sodium tert-butoxide (1.24 g, 12.9 mmol) were added and dissolved in 50 mL of o-xylene. The reaction solution was stirred at 140° C. for 12 hours. After cooling, an extraction process was performed thereon by using water (300 mL) and ethylacetate (300 ml) to collect an organic layer, which was dried by using MgSO₄ and filtered. The filtrate was decompressed to remove the solvent therefrom, and a solid thus obtained was subjected to silica gel column chromatography by using CH₂Cl₂ and hexane as developing solvents for purification and separation, so as to obtain Compound 107 (yellow solid, 3.2 g, 2.8 mmol, 65%). By ¹H-NMR and ESI-LCMS, the compound thus obtained was identified as Compound 107.

¹H-NMR (400 MHz, CDCl₃): δ=9.01 (d, 2H), 8.51 (s, 4H), 7.88-7.79 (m, 8H), 7.60-7.57 (m, 2H), 7.50-7.48 (m, 2H), 7.40-7.37 (m, 6H), 7.28 (d, 2H), 7.16-7.12 (m, 4H), 6.46 (s, 2H), 1.53 (s, 9H)

ESI-LCMS: [M]⁺: C₈₀H₄₁D₁₆BN₆. 1128.57.

### Evaluation Example 1

For each synthesized compound, S₁ and T₁ energy levels were measured, and results are shown in Table 1. The S₁ energy level was calculated based on a fluorescence spectrum measured at room temperature, and the Ti energy level was calculated based on a photoluminescence spectrum measured at a low temperature (at 77 K). In Table 1, ΔE_{ST} represents a difference between the S₁ energy level and the T₁ energy level.

TABLE 1

| Compound No. | S₁ (eV) | T₁ (eV) | ΔE_{ST} (eV) |
|---|---|---|---|
| 1 | 2.73 | 2.56 | 0.17 |
| 29 | 2.71 | 2.55 | 0.16 |
| 31 | 2.72 | 2.56 | 0.16 |
| 34 | 2.72 | 2.55 | 0.17 |
| 37 | 2.71 | 2.55 | 0.16 |
| 66 | 2.71 | 2.56 | 0.15 |
| 107 | 2.70 | 2.57 | 0.13 |

### Example 1

As an anode, a glass substrate (product of Corning Inc.) with a 15 Ω/cm² (1,200 Δ) ITO electrode formed thereon was cut to a size of 50 mm×50 mm×0.7 mm, sonicated using isopropyl alcohol and pure water each for 5 minutes, and cleaned by irradiation of ultraviolet rays and exposure of ozone thereto for 30 minutes. The resultant glass substrate was mounted on a vacuum deposition apparatus.

NPB was deposited on the anode to form a hole injection layer having a thickness of 300 Å, HT6 was deposited on the hole injection layer to form a hole transport layer having a thickness of 200 Å, and CzSi was deposited on the hole transport layer to form an emission auxiliary layer having a thickness of 100 Å.

On the emission auxiliary layer, a host compound in which a first host (HTH53) and a second host (ETH85) were mixed at a ratio of 1:1, a phosphorescent sensitizer (PD40), and Compound 1 were co-deposited at a weight ratio of 82:15:3 to form an emission layer having a thickness of 200 Å.

TSPO1 was deposited on the emission layer to form a hole blocking layer having a thickness of 200 Å, TPBI was deposited on the hole blocking layer to form an electron transport layer having a thickness of 300 Å, LiF was deposited on the electron transport layer to form an electron injection layer having a thickness of 10 Å, Al was deposited on the electron injection layer to form a cathode having a thickness of 3,000 Å, and HT28 was deposited on the cathode to form a capping layer having a thickness of 700 Å, thereby completing the manufacture of a light-emitting device.

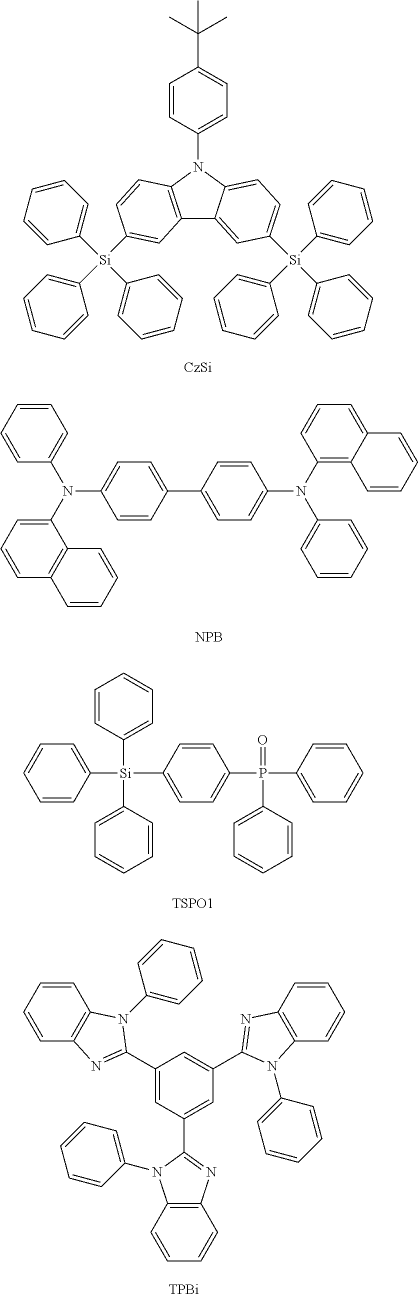

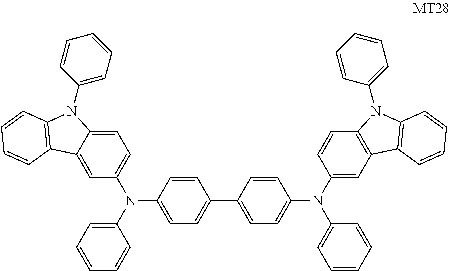 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1]

### Examples 2 to 7 and Comparative Examples 1 to 5

Light-emitting devices of Examples 2 to 7 and Comparative Examples 1 to 5 were manufactured in the same manner as in Example 1, except that compounds shown in Table 2 were used in forming an emission layer.

### Evaluation Example 2

To evaluate characteristics of the light-emitting devices manufactured according to Examples 1 to 7 and Comparative Examples 1 to 5, the driving voltage at a current density of 10 mA/cm² luminescence efficiency, and lifespan (T₉₅) thereof were measured, and results are shown in Table 2. The driving voltage of the light-emitting devices was measured using a source meter (Keithley Instrument Inc., 2400 series). In Table 2, the lifespan ratio represents the time taken for the luminance to become 95% compared to the initial luminance, based on Comparative Example 1.

TABLE 2

| | Host | | | | Driving | | Emission | Lifespan |
|---|---|---|---|---|---|---|---|---|
| | First | Second | | Luminescent | voltage | Efficiency | wavelength | ratio |
| | host | host | Sensitizer | material | (V) | (cd/A) | (nm) | (T₉₅) |
| Example1 | HTH53 | ETH85 | PD40 | 1 | 4.1 | 28.5 | 458 | 4.3 |
| Example 2 | HTH53 | ETH85 | PD40 | 29 | 4.0 | 30.5 | 457 | 5.1 |
| Example 3 | HTH53 | ETH85 | PD40 | 31 | 4.2 | 29.8 | 458 | 5.2 |
| Example 4 | HTH53 | ETH85 | PD40 | 34 | 4.2 | 31.2 | 459 | 4.9 |
| Example 5 | HTH53 | ETH85 | PD40 | 37 | 4.1 | 30.9 | 459 | 5.2 |
| Example 6 | HTH53 | ETH85 | PD40 | 66 | 4.3 | 30.1 | 458 | 5.1 |
| Example 7 | HTH53 | ETH85 | PD40 | 107 | 4.2 | 29.3 | 458 | 4.4 |
| Comparative | HTH53 | ETH85 | PD40 | Compound A | 4.8 | 19.2 | 457 | 1 |
| Example 1 | | | | | | | | |
| Comparative | HTH53 | ETH85 | PD40 | Compound B | 4.6 | 24.6 | 462 | 2.5 |
| Example 2 | | | | | | | | |
| Comparative | HTH53 | ETH85 | PD40 | Compound C | 4.7 | 20.1 | 460 | 1.2 |
| Example 3 | | | | | | | | |
| Comparative | HTH53 | ETH85 | PD40 | Compound D | 4.7 | 18.4 | 456 | 1.5 |
| Example 4 | | | | | | | | |
| Comparative | HTH53 | ETH85 | PD40 | Compound E | 4.6 | 20.0 | 456 | 1.8 |
| Example 5 | | | | | | | | |

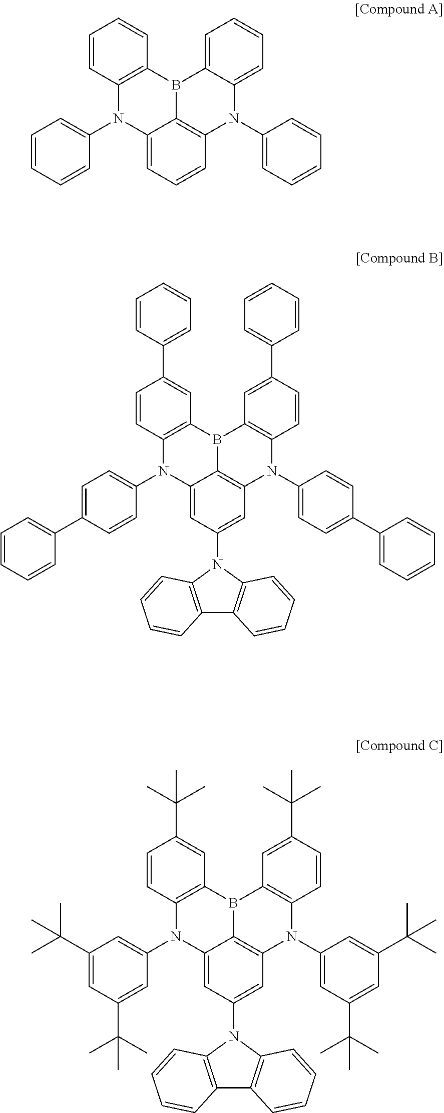 [SMILES: c1ccc(N2c3ccccc3B3c4ccccc4N(c4ccccc4)c4cccc2c43)cc1 ; c1ccc(-c2ccc(N3c4ccc(-c5ccccc5)cc4B4c5cc(-c6ccccc6)ccc5N(c5ccc(-c6ccccc6)cc5)c5cc(-n6c7ccccc7c7ccccc76)cc3c54)cc2)cc1 ; CC(C)(C)c1cc(N2c3ccc(C(C)(C)C)cc3B3c4cc(C(C)(C)C)ccc4N(c4cc(C(C)(C)C)cc(C(C)(C)C)c4)c4cc(-n5c6ccccc6c6ccccc65)cc2c43)cc(C(C)(C)C)c1]

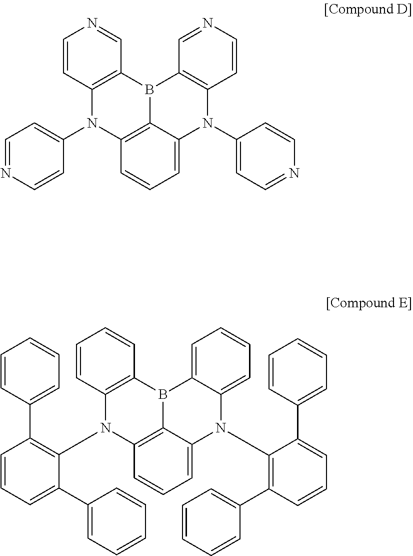 [SMILES: c1cc2c3c(c1)N(c1ccncc1)c1ccncc1B3c1cnccc1N2c1ccncc1 ; c1ccc(-c2cccc(-c3ccccc3)c2N2c3ccccc3B3c4ccccc4N(c4c(-c5ccccc5)cccc4-c4ccccc4)c4cccc2c43)cc1]

Referring to Table 2, it was confirmed that the light-emitting devices according to Examples 1 to 7 had excellent driving voltage, luminescence efficiency, and lifespan characteristics compared to those of the light-emitting devices according to Comparative Examples 1 to 5.

According to the embodiments, a light-emitting device may include a condensed cyclic compound represented by Formula 1, and accordingly may have excellent driving voltage, luminescence efficiency, and lifespan characteristics. In this regard, a high-quality electronic apparatus may be manufactured by using the light-emitting device.

Embodiments have been disclosed herein, and although terms are employed, they are used and are to be interpreted in a generic and descriptive sense only and not for purpose of limitation. In some instances, as would be apparent by one of ordinary skill in the art, features, characteristics, and/or elements described in connection with an embodiment may be used singly or in combination with features, characteristics, and/or elements described in connection with other embodiments unless otherwise specifically indicated. Accordingly, it will be understood by those of ordinary skill in the art that various changes in form and details may be made without departing from the spirit and scope of the disclosure as set forth in the claims.

What is claimed is:

1. A light-emitting device comprising:
a first electrode;
a second electrode facing the first electrode; and
an interlayer between the first electrode and the second electrode and comprising an emission layer, wherein
the emission layer comprises a condensed cyclic compound represented by Formula 1: 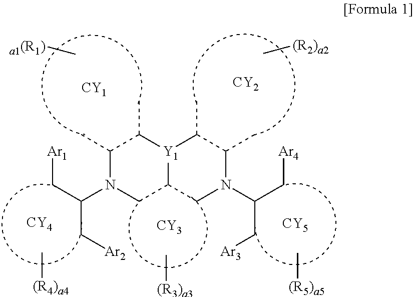
wherein in Formula 1,
Y₁ is boron (B), P(═O), or P(═S),
ring CY₁ to ring CY₃ are each independently a C₅-C₆₀ carbocyclic group or a C₁-C₆₀ heterocyclic group,
ring CY₄ and ring CY₅ are each independently a C₁-C₆₀ heterocyclic group including at least one nitrogen atom,
Ar₁ to Ar₄ are each independently a C₃-C₆₀ carbocyclic group unsubstituted or substituted with at least one R₁₀ₐ or a C₁-C₆₀ heterocyclic group unsubstituted or substituted with at least one R₁₀ₐ,
R₁ to R₅ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a5 are each independently an integer from 0 to 10,
two or more of R₁(s) in the number of a1 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₂(s) in the number of a2 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₃(s) in the number of a3 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, a pyridinyl group, a pyrimidinyl group, a pyridazinyl group, a pyrazinyl group, a triazinyl group, or a combination thereof.

2. The light-emitting device claim 1, wherein
a difference between a triplet energy level (eV) and a singlet energy level (eV) of the condensed cyclic compound represented by Formula 1 is equal to or less than about 0.2 eV.

3. The light-emitting device claim 1, wherein the emission layer emits light having a maximum emission wavelength in a range of about 430 nm to about 480 nm.

4. The light-emitting device claim 1, wherein
the emission layer comprises:
a first compound including the condensed cyclic compound represented by Formula 1; and
a second compound including a group represented by Formula 20, a third compound including at least one π electron-deficient nitrogen-containing C₁-C₆₀ cyclic group, a fourth compound including a transition metal, or a combination thereof, and
the first compound, the second compound, the third compound, and the fourth compound are different from each other: 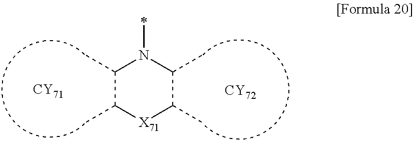
wherein in Formula 20,
ring CY₇₁ and ring CY₇₂ are each independently a π electron-rich C₃-C₆₀ cyclic group or a pyridine group,
X₇₁ is:
a single bond; or
a linking group including O, S, N, B, C, Si, or a combination thereof,
* indicates a binding site to a neighboring atom, and
CBP and mCBP are excluded from the second compound:

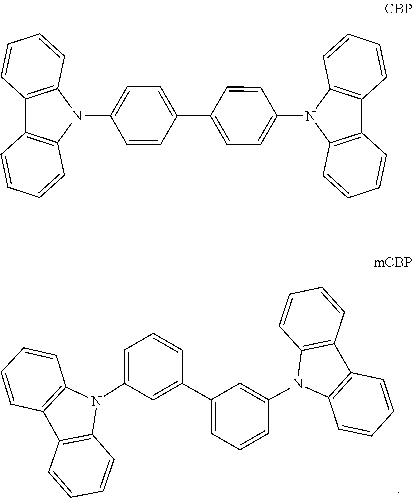 [SMILES: c1ccc2c(c1)c1ccccc1n2-c1ccc(-c2ccc(-n3c4ccccc4c4ccccc43)cc2)cc1 ; c1cc(-c2cccc(-n3c4ccccc4c4ccccc43)c2)cc(-n2c3ccccc3c3ccccc32)c1]

5. The light-emitting device of claim 4, wherein
the emission layer includes:
the first compound including the condensed cyclic compound represented by Formula 1; and
at least one of the second compound and the third compound, and
the emission layer optionally further comprises the fourth compound.

6. The light-emitting device of claim 4, wherein the third compound includes a pyridine group, a pyrimidine group, a pyrazine group, a pyridazine group, a triazine group, or a combination thereof.

7. The light-emitting device of claim 4, wherein the fourth compound includes a compound represented by Formula 401: 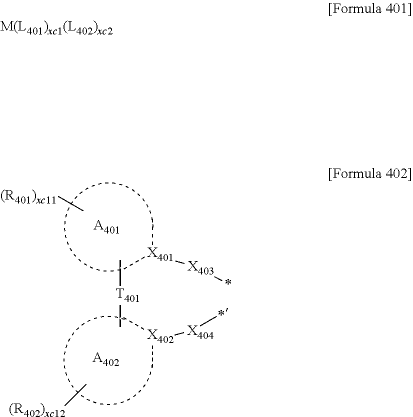
wherein in Formulae 401 and 402,
M is a transition metal,
L₄₀₁ is a ligand represented by Formula 402,
xc1 is 1, 2, or 3,
when xc1 is 2 or more, two or more of L₄₀₁(s) are identical to or different from each other,
L₄₀₂ is an organic ligand,
xc2 is 0, 1, 2, 3, or 4,
when xc2 is 2 or more, two or more of L₄₀₂(s) are identical to or different from each other,
X₄₀₁ and X₄₀₂ are each independently nitrogen or carbon,
ring A₄₀₁ and ring A₄₀₂ are each independently a C₃-C₆₀ carbocyclic group or a C₁-C₆₀ heterocyclic group,
T₄₀₁ is a single bond, *—O—*′, *—S*′, *—C(═O)—*′, *—N(Q₄₁₁)-*′, *—C(Q₄₁₁)(Q₄₁₂)-*′, *—C(Q₄₁₁)═C(Q₄₁₂)-*′, *—C(Q₄₁₁)=*′, or *=C═*′,
X₄₀₃ and X₄₀₄ are each independently a chemical bond, O, S, N(Q₄₁₃), B(Q₄₁₃), P(Q₄₁₃), C(Q₄₁₃)(Q₄₁₄), or Si(Q₄₁₃)(Q₄₁₄),
R₄₀₁ and R₄₀₂ are each independently hydrogen, deuterium, —F, —Cl, —Br, —I, a hydroxyl group, a cyano group, a nitro group, a C₁-C₂₀ alkyl group unsubstituted or substituted with at least one R₁₀ₐ, a C₁-C₂₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, —Si(Q₄₀₁)(Q₄₀₂)(Q₄₀₃), —N(Q₄₀₁)(Q₄₀₂), —B(Q₄₀₁)(Q₄₀₂), —C(═O)(Q₄₀₁), —S(═O)₂(Q₄₀₁), or —P(═O)(Q₄₀₁)(Q₄₀₂),
xc11 and xc12 are each independently an integer from 0 to 10,
Q₄₁₁ to Q₄₁₄ and Q₄₀₁ to Q₄₀₃ are each independently: hydrogen; deuterium; —F; —Cl; —Br; —I; a hydroxyl group; a cyano group; a nitro group; a C₁-C₆₀ alkyl group; a C₂-C₆₀ alkenyl group; a C₂-C₆₀ alkynyl group; a C₁-C₆₀ alkoxy group; a C₃-C₆₀ carbocyclic group or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof; a C₇-C₆₀ arylalkyl group; or a C₂-C₆₀ heteroarylalkyl group,
* and *′ in Formula 402 each indicate a binding site to M in Formula 401, and
R₁₀ₐ is the same as defined in Formula 1.

8. An electronic apparatus comprising the light-emitting device of claim 1.

9. The electronic apparatus of claim 8, further comprising a thin-film transistor, wherein
the thin-film transistor includes a source electrode and a drain electrode, and
the first electrode of the light-emitting device is electrically connected to the source electrode or the drain electrode.

10. A condensed cyclic compound represented by Formula 1: 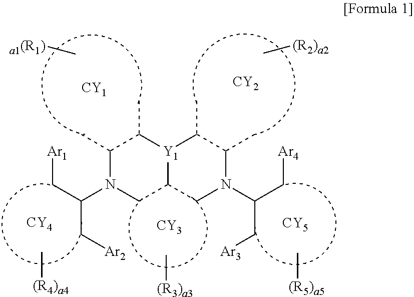
wherein in Formula 1,
Y₁ is boron (B), P(═O), or P(═S),
ring CY₁ to ring CY₃ are each independently a C₅-C₆₀ carbocyclic group or a C₁-C₆₀ heterocyclic group,
ring CY₄ and ring CY₅ are each independently a C₁-C₆₀ heterocyclic group including at least one nitrogen atom,
Ar₁ to Ar₄ are each a C₃-C₆₀ carbocyclic group unsubstituted or substituted with at least one R₁₀ₐ or a C₁-C₆₀ heterocyclic group unsubstituted or substituted with at least one R₁₀ₐ,
R₁ to R₅ are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
a1 to a5 are each independently an integer from 0 to 10,
two or more of R₁(s) in the number of a1 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₂(s) in the number of a2 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
two or more of R₃(s) in the number of a3 are optionally bonded to each other to form a C₃-C₆₀ carbocyclic group unsubstituted or substituted with at least one R₁₀ₐ or a C₁-C₆₀ heterocyclic group unsubstituted or substituted with at least one R₁₀ₐ,
R₁₀ₐ is:
deuterium, —F, —Cl, —Br, —I, a hydroxyl group, a cyano group, or a nitro group;
a C₁-C₆₀ alkyl group, a C₂-C₆₀ alkenyl group, a C₂-C₆₀ alkynyl group, or a C₁-C₆₀ alkoxy group, each unsubstituted or substituted with deuterium, —F, —Cl, —Br, —I, a hydroxyl group, a cyano group, a nitro group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₁₁)(Q₁₂)(Q₁₃), —N(Q₁₁)(Q₁₂), —B(Q₁₁)(Q₁₂), —C(═O)(Q₁₁), —S(═O)₂(Q₁₁), —P(═O)(Q₁₁)(Q₁₂), or a combination thereof;
a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, or a C₂-C₆₀ heteroarylalkyl group, each unsubstituted or substituted with deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, a C₁-C₆₀ heterocyclic group, a C₆-C₆₀ aryloxy group, a C₆-C₆₀ arylthio group, a C₇-C₆₀ arylalkyl group, a C₂-C₆₀ heteroarylalkyl group, —Si(Q₂₁)(Q₂₂)(Q₂₃), —N(Q₂₁)(Q₂₂), —B(Q₂₁)(Q₂₂), —C(═O)(Q₂₁), —S(═O)₂(Q₂₁), —P(═O)(Q₂₁)(Q₂₂), or a combination thereof; or
—Si(Q₃₁)(Q₃₂)(Q₃₃), —N(Q₃₁)(Q₃₂), —B(Q₃₁)(Q₃₂), —C(═O)(Q₃₁), —S(═O)₂(Q₃₁), or —P(═O)(Q₃₁)(Q₃₂), and
Q₁ to Q₃, Q₁₁ to Q₁₃, Q₂₁ to Q₂₃, and Q₃₁ to Q₃₃ are each independently hydrogen, deuterium, —F, —Cl, —Br, —I, a hydroxyl group, a cyano group, a nitro group, a C₁-C₆₀ alkyl group, a C₂-C₆₀ alkenyl group, a C₂-C₆₀ alkynyl group, a C₁-C₆₀ alkoxy group, a C₃-C₆₀ carbocyclic group, or a C₁-C₆₀ heterocyclic group, each unsubstituted or substituted with deuterium, —F, a cyano group, a C₁-C₆₀ alkyl group, a C₁-C₆₀ alkoxy group, a phenyl group, a biphenyl group, or a combination thereof.

11. The condensed cyclic compound of claim 10, wherein ring CY₁ to ring CY₃ do not include nitrogen.

12. The condensed cyclic compound of claim 10, wherein ring CY₄ and ring CY₅ are each independently a 6-membered ring including at least one nitrogen atom.

13. The condensed cyclic compound of claim 10, wherein the condensed cyclic compound represented by Formula 1 is represented by Formula 1-1 or Formula 1-2: 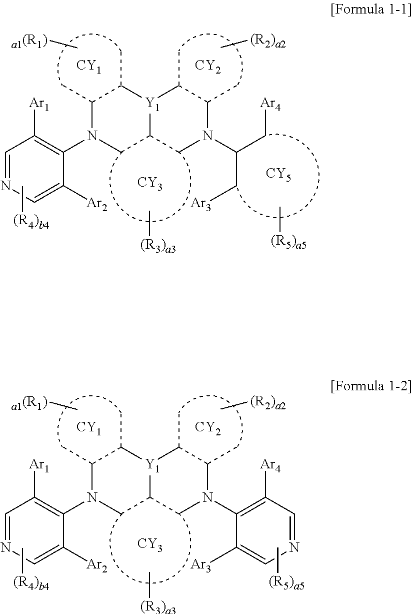
wherein in Formulae 1-1 and 1-2,
b4 and b5 are each independently an integer from 0 to 2, and
Y₁, ring CY₁ to ring CY₃, ring CY₅, Ar₁ to Ar₄, R₁ to R₅, a1 to a3, and a5 are each the same as defined in Formula 1.

14. The condensed cyclic compound of claim 10, wherein in Formula 1,
a moiety represented by 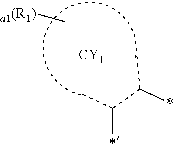
or a moeity represented by 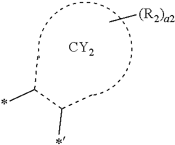
is each independently a moiety represented by one of Formulae CY1(1) to CY1(14): 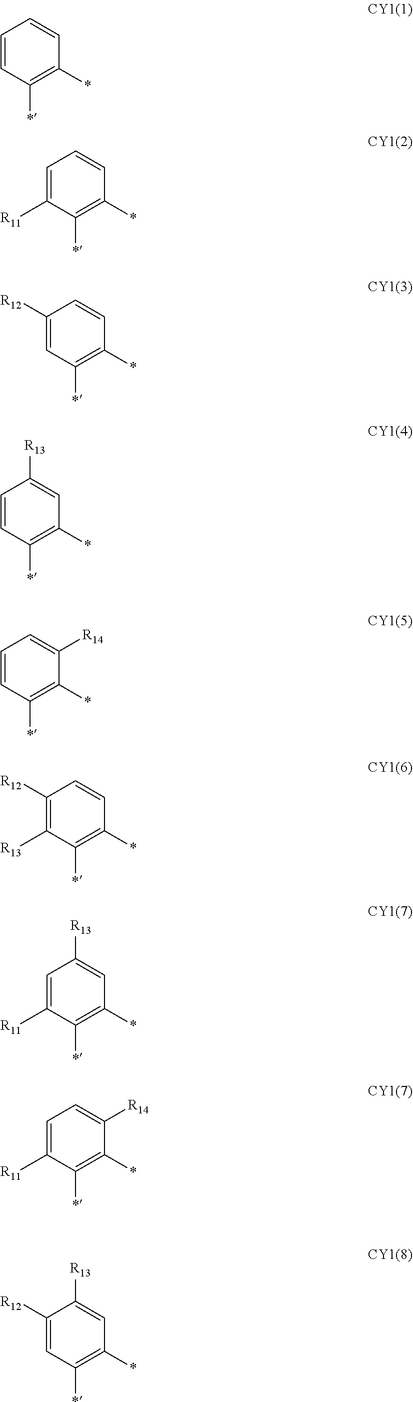 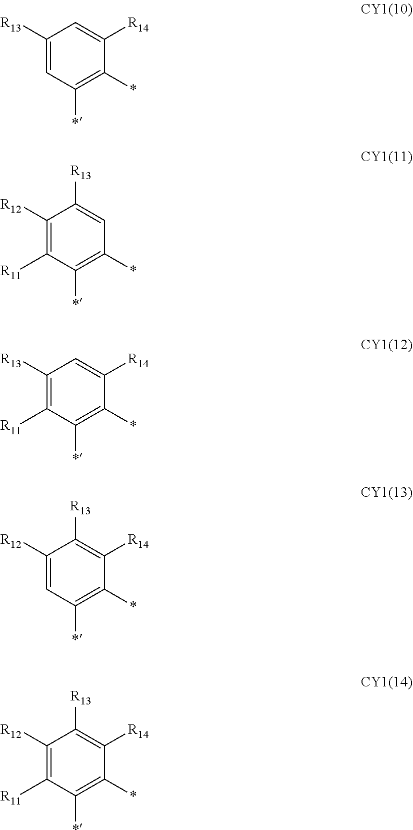
wherein in Formulae CY1(1) to CY1(14),
R₁₁ to R₁₄ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
* indicates a binding site to neighboring Y₁ in Formula 1,
*′ indicates a binding site to neighboring N in Formula 1, and
R₁₀ₐ and Q₁ to Q₃ are each the same as defined in Formula 1.

15. The condensed cyclic compound of claim 10, wherein in Formula 1,
a moiety represented by 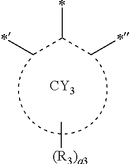
is a moiety represented by one of Formulae CY3(1) to CY3(6): 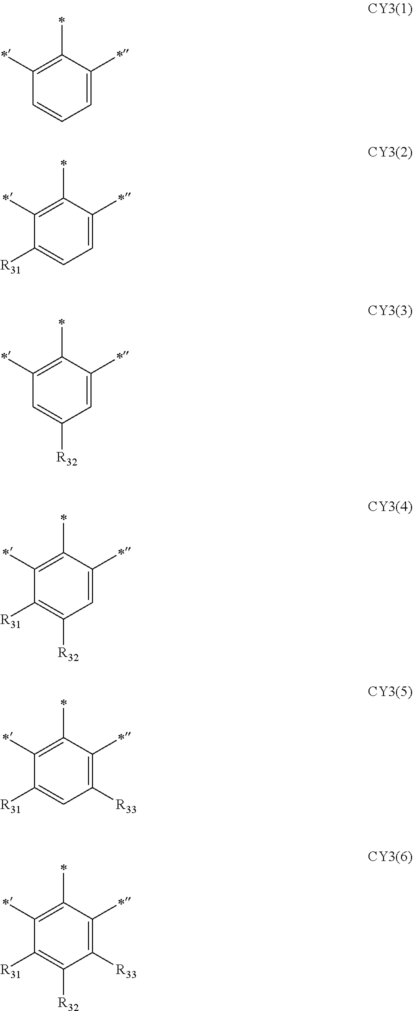
wherein in Formulae CY3(1) to CY3(6),
R₃₁ to R₃₃ are each independently deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
* indicates a binding site to neighboring Y₁ in Formula 1,
*′ and *″ each indicate a binding site to neighboring N in Formula 1, and
R₁₀ₐ and Q₁ to Q₃ are each the same as defined in Formula 1.

16. The condensed cyclic compound of claim 10, wherein Ar₁ to Ar₄ are each independently:
a phenyl group, a biphenyl group, or a naphthyl group; or
a phenyl group, a biphenyl group, or a naphthyl group, each substituted with deuterium or a C₁-C₁₀ alkyl group.

17. The condensed cyclic compound of claim 10, wherein
R₁ to R₃ are each independently hydrogen, deuterium, a C₁-C₆₀ alkyl group unsubstituted or substituted with at least one R₁₀ₐ, a C₆-C₆₀ aryl group unsubstituted or substituted with at least one R₁₀ₐ, a C₁-C₆₀ heteroaryl group unsubstituted or substituted with at least one R₁₀ₐ, a monovalent non-aromatic condensed polycyclic group unsubstituted or substituted with at least one R₁₀ₐ, or a monovalent non-aromatic condensed heteropolycyclic group unsubstituted or substituted with at least one R₁₀ₐ, and
R₁₀ₐ is the same as defined in Formula 1.

18. The condensed cyclic compound of claim 10, wherein R₁ to R₃ are each independently:
hydrogen or deuterium;
a C₁-C₂₀ alkyl group unsubstituted or substituted with deuterium; or
a group represented by one of Formulae 1A-1 to 1A-13: 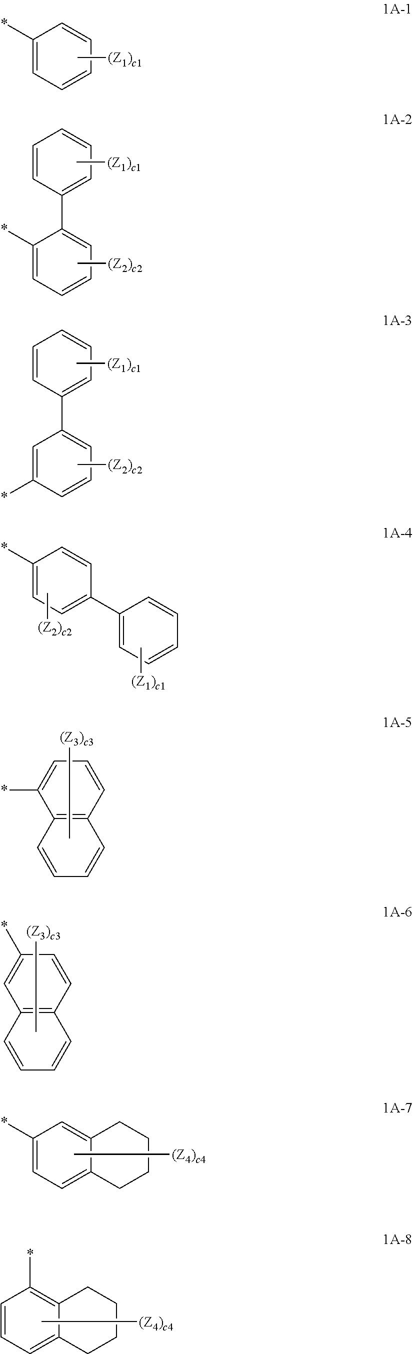 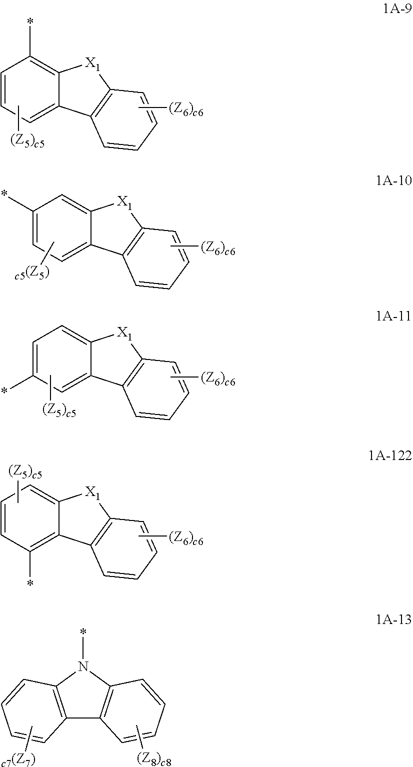
wherein in Formulae 1A-1 to 1A-13,
X₁ is O, S, N(Ria), C(R₁ₐ)(R_{1b}), or Si(R₁ₐ)(R_{1b}),
Z₁ to Z₈, R₁ₐ, and R_{1b} are each independently hydrogen, deuterium, —F, —Cl, —Br, —I, a hydroxyl group, a cyano group, a nitro group, a C₁-C₆₀ alkyl group unsubstituted or substituted with at least one R₁₀ₐ, a C₂-C₆₀ alkenyl group unsubstituted or substituted with at least one R₁₀ₐ, a C₂-C₆₀ alkynyl group unsubstituted or substituted with at least one R₁₀ₐ, a C₁-C₆₀ alkoxy group unsubstituted or substituted with at least one R₁₀ₐ, a C₃-C₆₀ carbocyclic group unsubstituted or substituted with at least one R₁₀ₐ, a C₁-C₆₀ heterocyclic group unsubstituted or substituted with at least one R₁₀ₐ, a C₆-C₆₀ aryloxy group unsubstituted or substituted with at least one R₁₀ₐ, a C₆-C₆₀ arylthio group unsubstituted or substituted with at least one R₁₀ₐ, —Si(Q₁)(Q₂)(Q₃), —N(Q₁)(Q₂), —B(Q₁)(Q₂), —C(═O)(Q₁), —S(═O)₂(Q₁), or —P(═O)(Q₁)(Q₂),
c1 is an integer from 0 to 5,
c2 and c6 to c8 are each independently an integer from 0 to 4,
c3 is an integer from 0 to 7,
c4 is an integer from 0 to 11,
c5 is an integer from 0 to 3,
* indicates a binding site to a neighboring atom, and
R₁₀ₐ and Q₁ to Q₃ are each the same as defined in Formula 1.

19. The condensed cyclic compound of claim 10, wherein a sum of a1+a2+a3 is 1 or more.

20. The condensed cyclic compound of claim 10, wherein the condensed cyclic compound is one of Compounds 1 to 132: 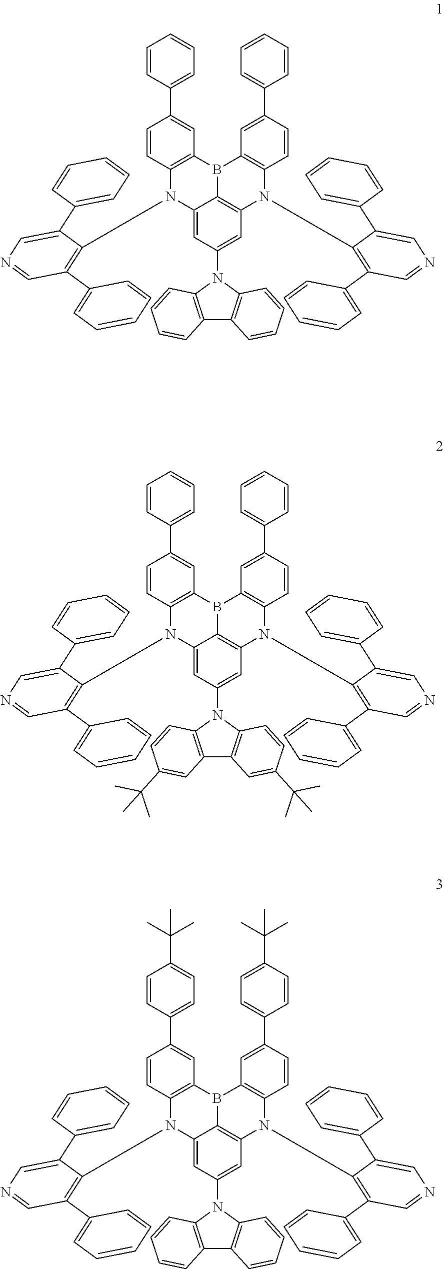 [SMILES: c1ccc(-c2ccc3c(c2)B2c4cc(-c5ccccc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1 ; CC(C)(C)c1ccc2c(c1)c1cc(C(C)(C)C)ccc1n2-c1cc2c3c(c1)N(c1c(-c4ccccc4)cncc1-c1ccccc1)c1ccc(-c4ccccc4)cc1B3c1cc(-c3ccccc3)ccc1N2c1c(-c2ccccc2)cncc1-c1ccccc1 ; CC(C)(C)c1ccc(-c2ccc3c(c2)B2c4cc(-c5ccc(C(C)(C)C)cc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1] 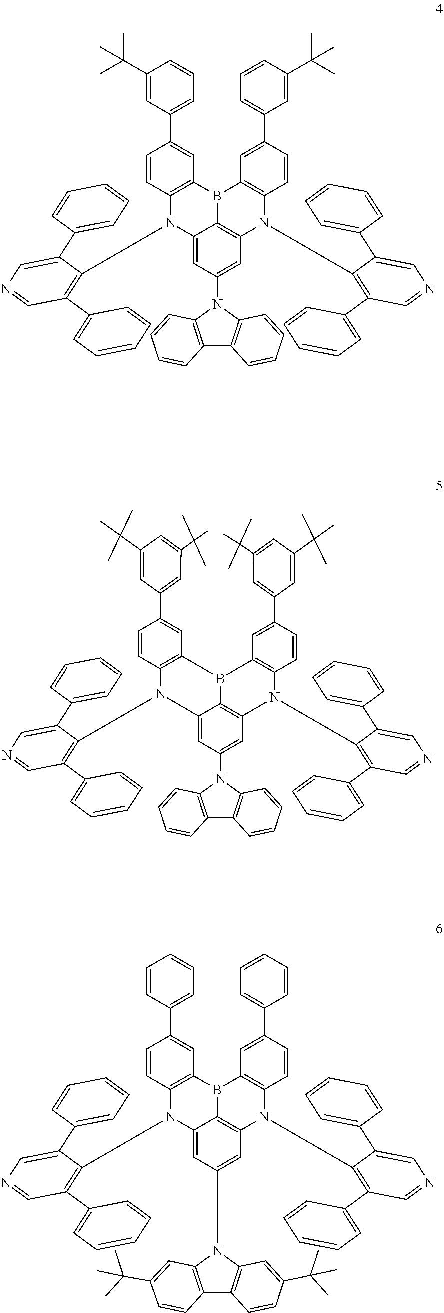 [SMILES: CC(C)(C)c1cccc(-c2ccc3c(c2)B2c4cc(-c5cccc(C(C)(C)C)c5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)c1 ; CC(C)(C)c1cc(-c2ccc3c(c2)B2c4cc(-c5cc(C(C)(C)C)cc(C(C)(C)C)c5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc(C(C)(C)C)c1 ; CC(C)(C)c1ccc2c3ccc(C(C)(C)C)cc3n(-c3cc4c5c(c3)N(c3c(-c6ccccc6)cncc3-c3ccccc3)c3ccc(-c6ccccc6)cc3B5c3cc(-c5ccccc5)ccc3N4c3c(-c4ccccc4)cncc3-c3ccccc3)c2c1] 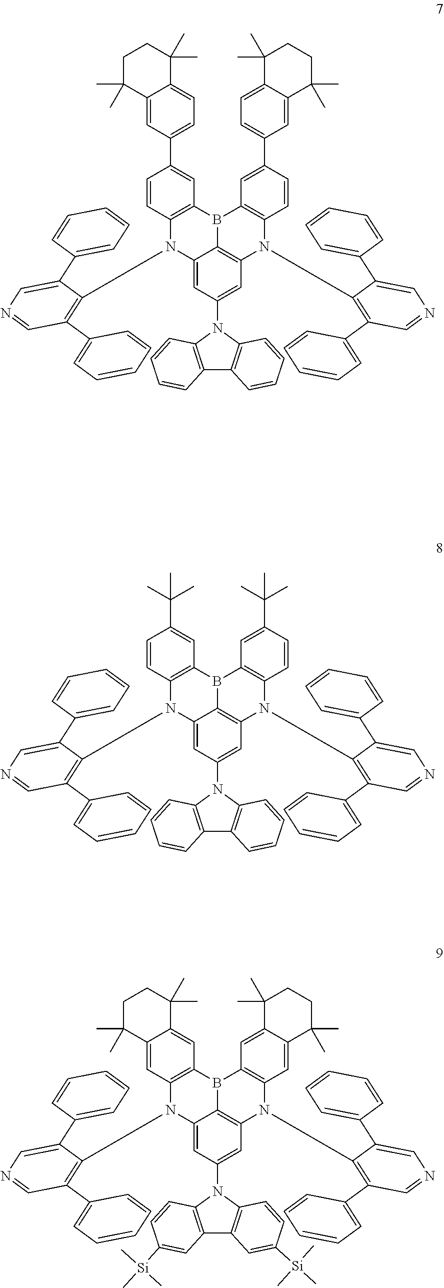 [SMILES: CC1(C)CCC(C)(C)c2cc(-c3ccc4c(c3)B3c5cc(-c6ccc7c(c6)C(C)(C)CCC7(C)C)ccc5N(c5c(-c6ccccc6)cncc5-c5ccccc5)c5cc(-n6c7ccccc7c7ccccc76)cc(c53)N4c3c(-c4ccccc4)cncc3-c3ccccc3)ccc21 ; CC(C)(C)c1ccc2c(c1)B1c3cc(C(C)(C)C)ccc3N(c3c(-c4ccccc4)cncc3-c3ccccc3)c3cc(-n4c5ccccc5c5ccccc54)cc(c31)N2c1c(-c2ccccc2)cncc1-c1ccccc1 ; CC1(C)CCC(C)(C)c2cc3c(cc21)B1c2cc4c(cc2N(c2c(-c5ccccc5)cncc2-c2ccccc2)c2cc(-n5c6ccc([Si](C)(C)C)cc6c6cc([Si](C)(C)C)ccc65)cc(c21)N3c1c(-c2ccccc2)cncc1-c1ccccc1)C(C)(C)CCC4(C)C] 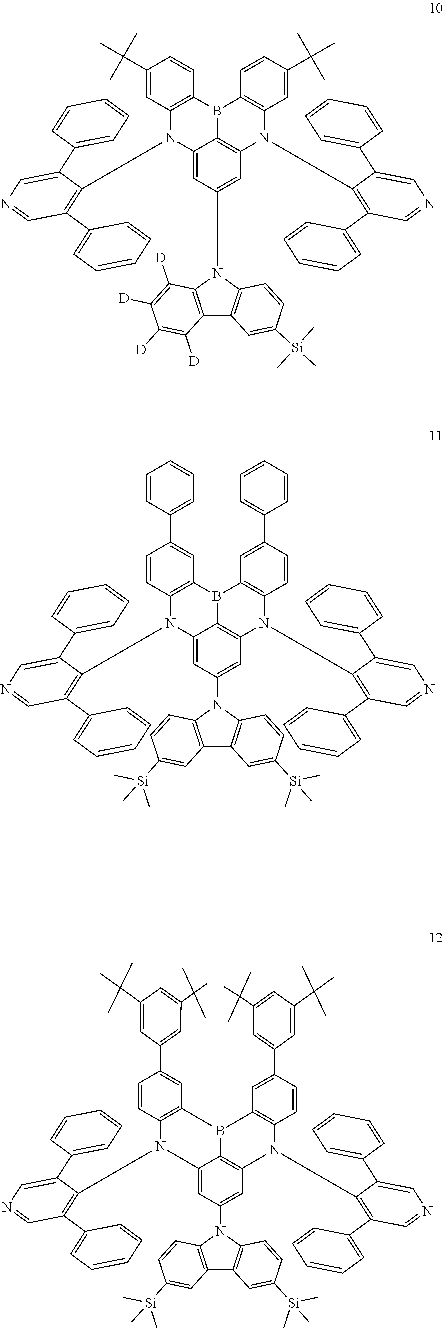 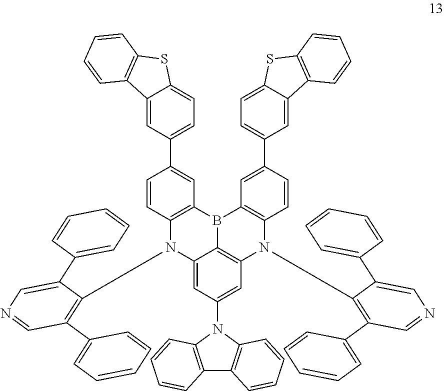 [SMILES: c1ccc(-c2cncc(-c3ccccc3)c2N2c3ccc(-c4ccc5sc6ccccc6c5c4)cc3B3c4cc(-c5ccc6sc7ccccc7c6c5)ccc4N(c4c(-c5ccccc5)cncc4-c4ccccc4)c4cc(-n5c6ccccc6c6ccccc65)cc2c43)cc1] 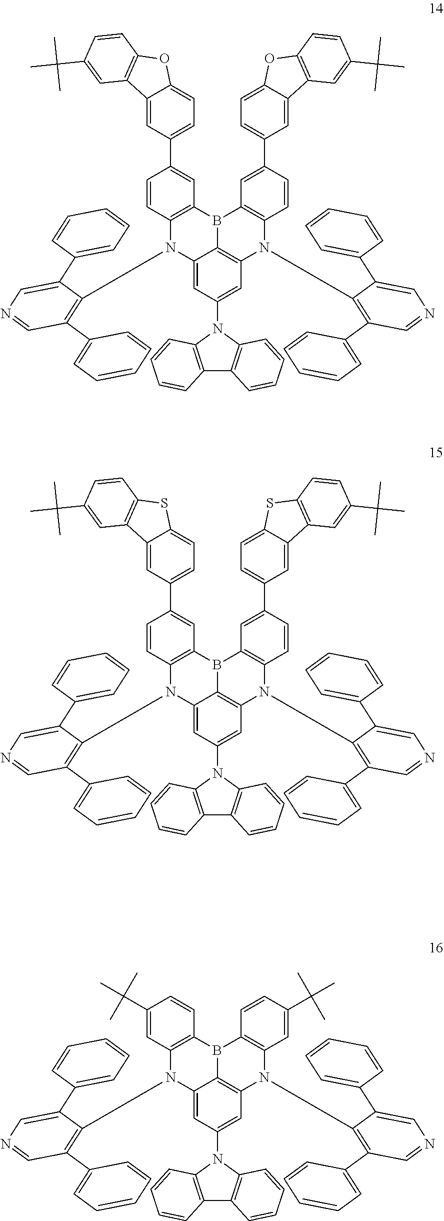 [SMILES: CC(C)(C)c1ccc2oc3ccc(-c4ccc5c(c4)B4c6cc(-c7ccc8oc9ccc(C(C)(C)C)cc9c8c7)ccc6N(c6c(-c7ccccc7)cncc6-c6ccccc6)c6cc(-n7c8ccccc8c8ccccc87)cc(c64)N5c4c(-c5ccccc5)cncc4-c4ccccc4)cc3c2c1 ; CC(C)(C)c1ccc2sc3ccc(-c4ccc5c(c4)B4c6cc(-c7ccc8sc9ccc(C(C)(C)C)cc9c8c7)ccc6N(c6c(-c7ccccc7)cncc6-c6ccccc6)c6cc(-n7c8ccccc8c8ccccc87)cc(c64)N5c4c(-c5ccccc5)cncc4-c4ccccc4)cc3c2c1 ; CC(C)(C)c1ccc2c(c1)N(c1c(-c3ccccc3)cncc1-c1ccccc1)c1cc(-n3c4ccccc4c4ccccc43)cc3c1B2c1ccc(C(C)(C)C)cc1N3c1c(-c2ccccc2)cncc1-c1ccccc1] 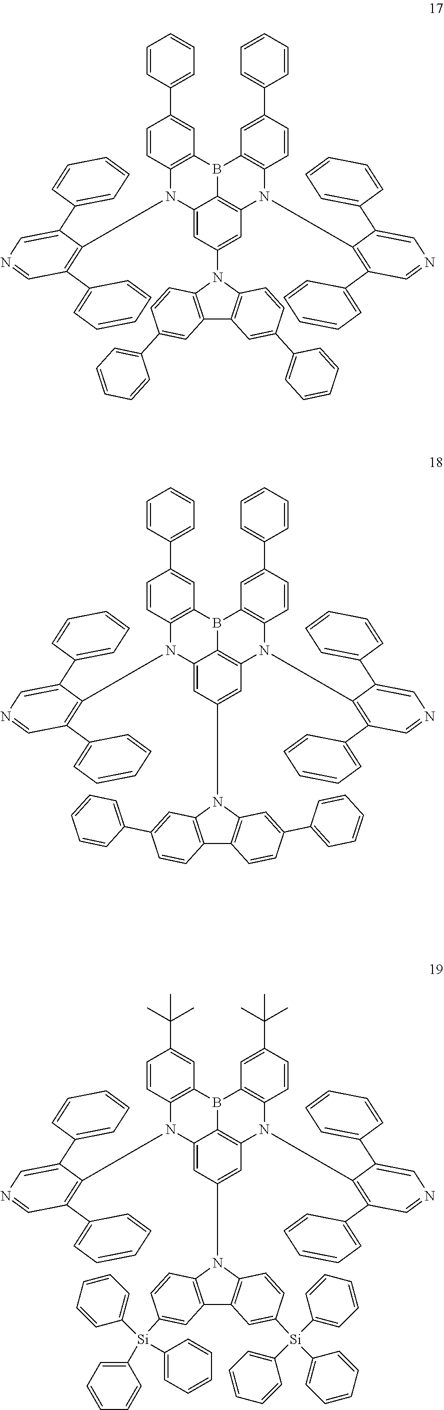 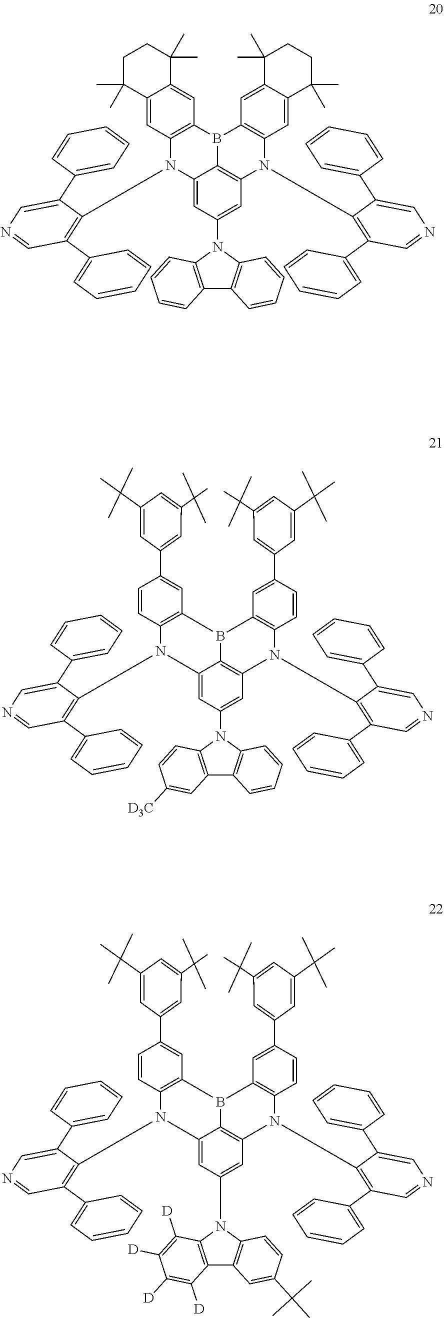 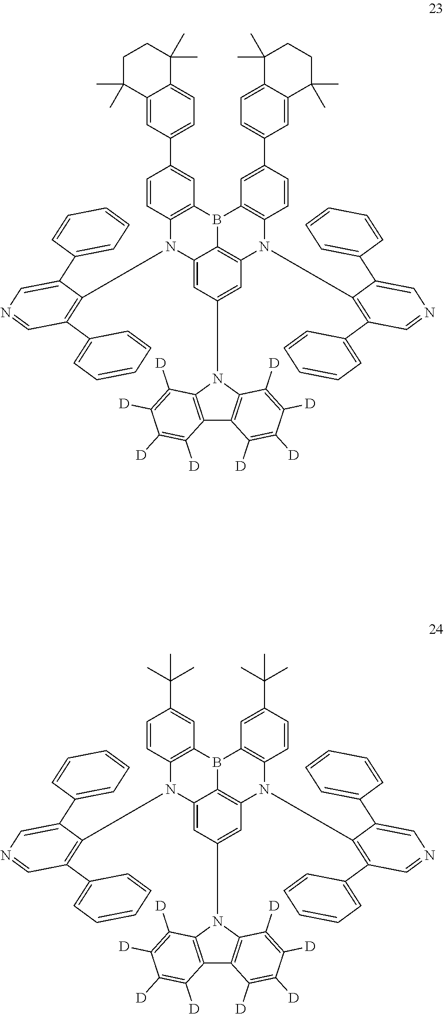 [SMILES: [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1ccc(-c4ccc5c(c4)C(C)(C)CCC5(C)C)cc1B3c1cc(-c3ccc4c(c3)C(C)(C)CCC4(C)C)ccc1N2c1c(-c2ccccc2)cncc1-c1ccccc1 ; [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1ccc(C(C)(C)C)cc1B3c1cc(C(C)(C)C)ccc1N2c1c(-c2ccccc2)cncc1-c1ccccc1] 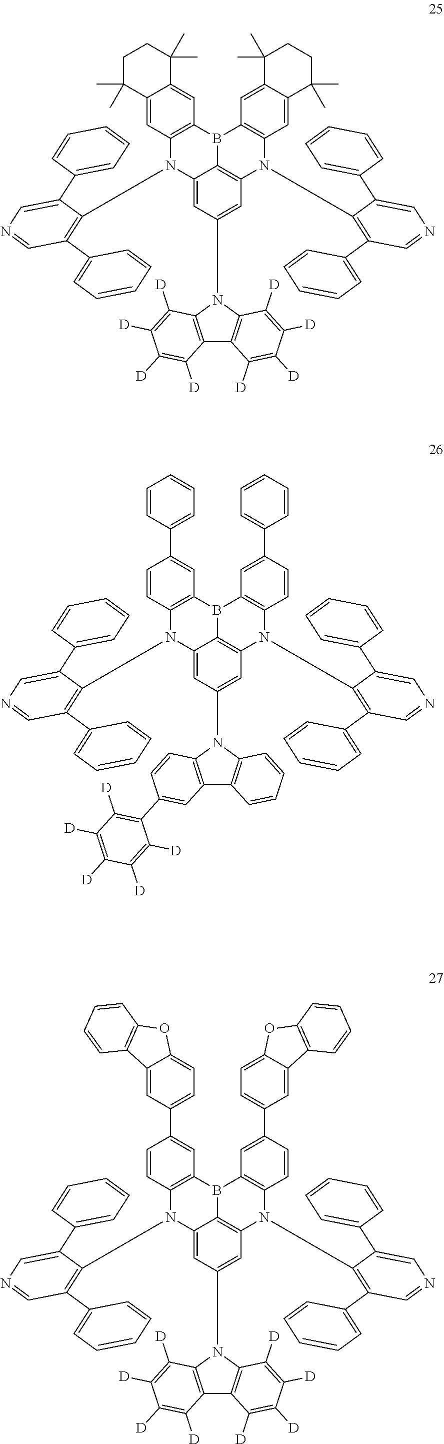 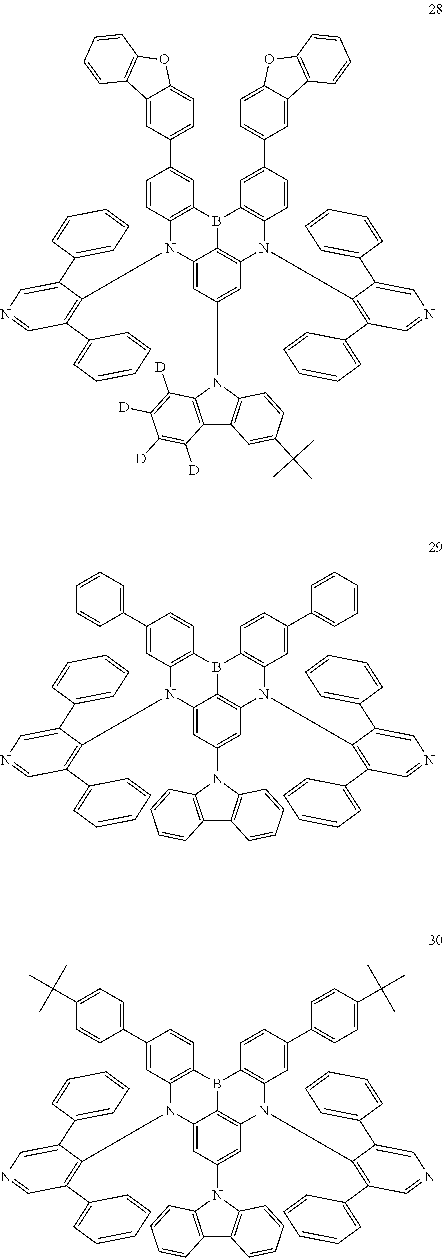 [SMILES: [2H]c1c([2H])c([2H])c2c(c1[2H])c1cc(C(C)(C)C)ccc1n2-c1cc2c3c(c1)N(c1c(-c4ccccc4)cncc1-c1ccccc1)c1ccc(-c4ccc5oc6ccccc6c5c4)cc1B3c1cc(-c3ccc4oc5ccccc5c4c3)ccc1N2c1c(-c2ccccc2)cncc1-c1ccccc1 ; c1ccc(-c2ccc3c(c2)N(c2c(-c4ccccc4)cncc2-c2ccccc2)c2cc(-n4c5ccccc5c5ccccc54)cc4c2B3c2ccc(-c3ccccc3)cc2N4c2c(-c3ccccc3)cncc2-c2ccccc2)cc1 ; CC(C)(C)c1ccc(-c2ccc3c(c2)N(c2c(-c4ccccc4)cncc2-c2ccccc2)c2cc(-n4c5ccccc5c5ccccc54)cc4c2B3c2ccc(-c3ccc(C(C)(C)C)cc3)cc2N4c2c(-c3ccccc3)cncc2-c2ccccc2)cc1] 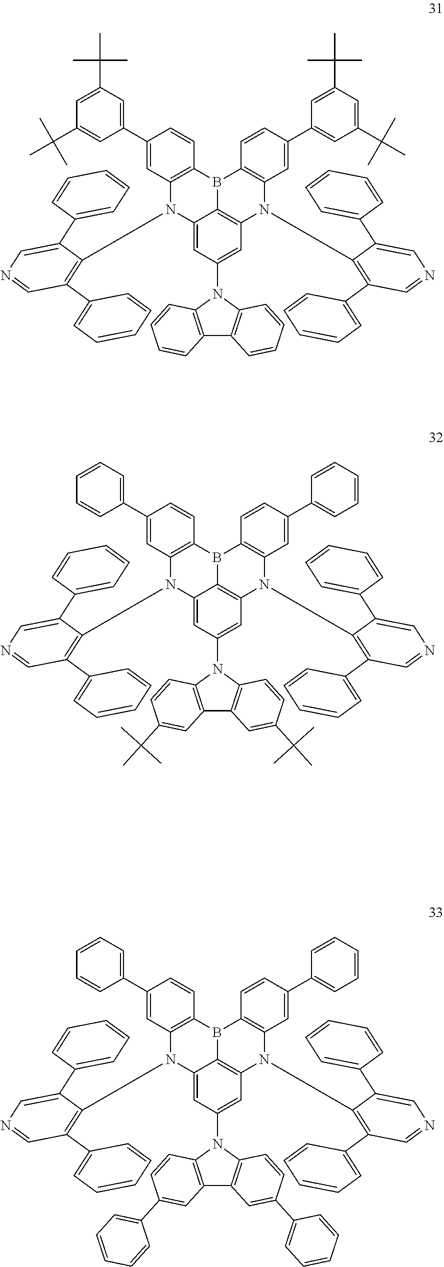 [SMILES: CC(C)(C)c1cc(-c2ccc3c(c2)N(c2c(-c4ccccc4)cncc2-c2ccccc2)c2cc(-n4c5ccccc5c5ccccc54)cc4c2B3c2ccc(-c3cc(C(C)(C)C)cc(C(C)(C)C)c3)cc2N4c2c(-c3ccccc3)cncc2-c2ccccc2)cc(C(C)(C)C)c1 ; CC(C)(C)c1ccc2c(c1)c1cc(C(C)(C)C)ccc1n2-c1cc2c3c(c1)N(c1c(-c4ccccc4)cncc1-c1ccccc1)c1cc(-c4ccccc4)ccc1B3c1ccc(-c3ccccc3)cc1N2c1c(-c2ccccc2)cncc1-c1ccccc1 ; c1ccc(-c2ccc3c(c2)N(c2c(-c4ccccc4)cncc2-c2ccccc2)c2cc(-n4c5ccc(-c6ccccc6)cc5c5cc(-c6ccccc6)ccc54)cc4c2B3c2ccc(-c3ccccc3)cc2N4c2c(-c3ccccc3)cncc2-c2ccccc2)cc1] 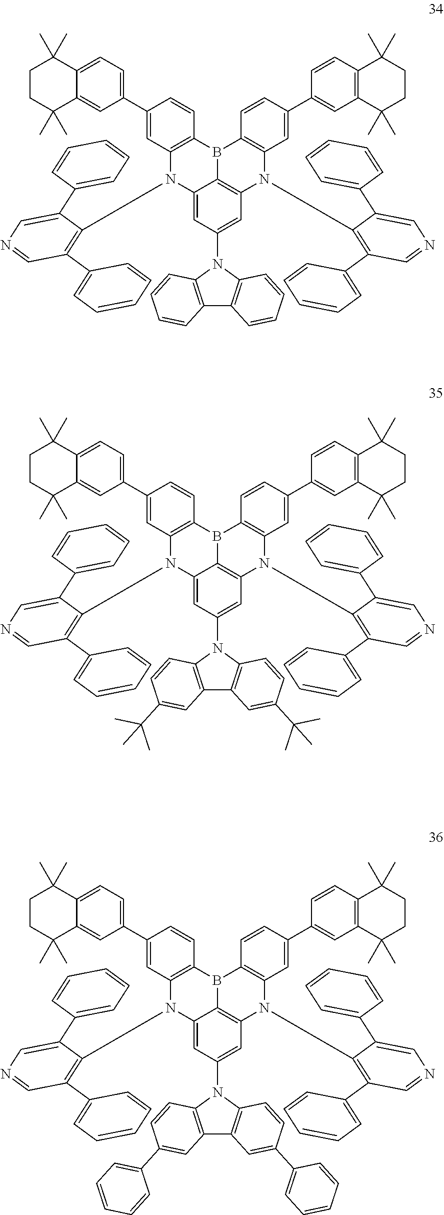 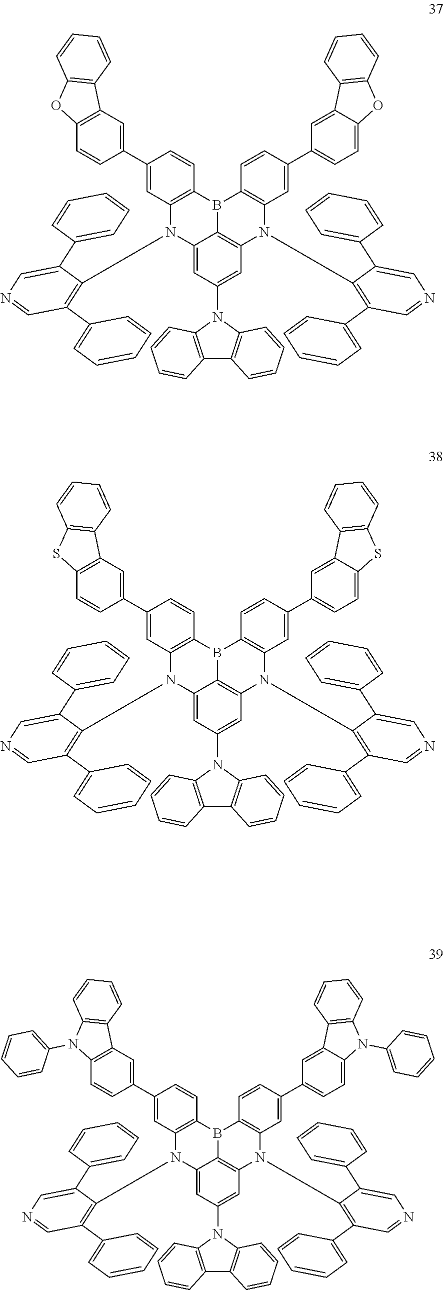 [SMILES: c1ccc(-c2cncc(-c3ccccc3)c2N2c3cc(-c4ccc5oc6ccccc6c5c4)ccc3B3c4ccc(-c5ccc6oc7ccccc7c6c5)cc4N(c4c(-c5ccccc5)cncc4-c4ccccc4)c4cc(-n5c6ccccc6c6ccccc65)cc2c43)cc1 ; c1ccc(-c2cncc(-c3ccccc3)c2N2c3cc(-c4ccc5sc6ccccc6c5c4)ccc3B3c4ccc(-c5ccc6sc7ccccc7c6c5)cc4N(c4c(-c5ccccc5)cncc4-c4ccccc4)c4cc(-n5c6ccccc6c6ccccc65)cc2c43)cc1 ; c1ccc(-c2cncc(-c3ccccc3)c2N2c3cc(-c4ccc5c(c4)c4ccccc4n5-c4ccccc4)ccc3B3c4ccc(-c5ccc6c(c5)c5ccccc5n6-c5ccccc5)cc4N(c4c(-c5ccccc5)cncc4-c4ccccc4)c4cc(-n5c6ccccc6c6ccccc65)cc2c43)cc1] 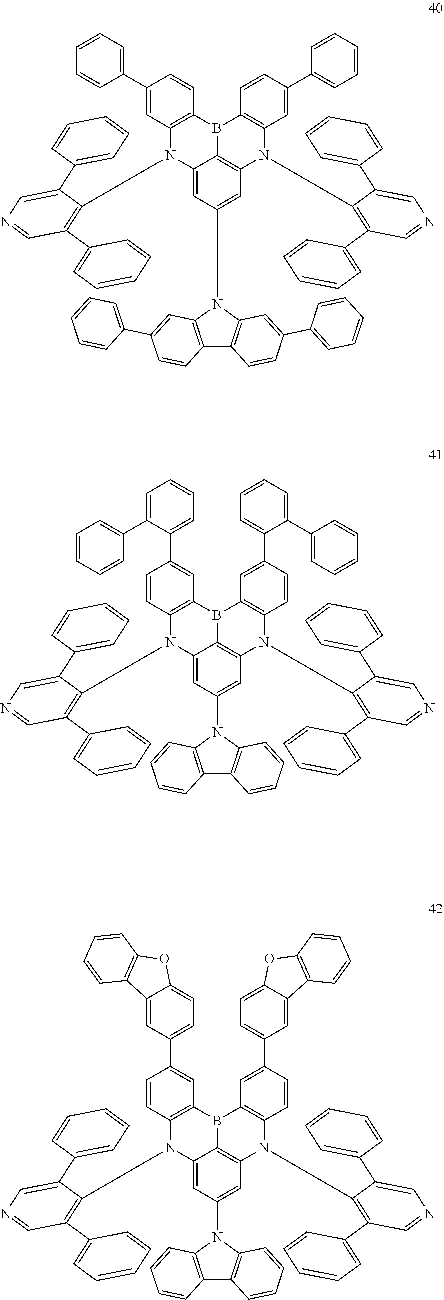 [SMILES: c1ccc(-c2ccc3c(c2)N(c2c(-c4ccccc4)cncc2-c2ccccc2)c2cc(-n4c5cc(-c6ccccc6)ccc5c5ccc(-c6ccccc6)cc54)cc4c2B3c2ccc(-c3ccccc3)cc2N4c2c(-c3ccccc3)cncc2-c2ccccc2)cc1 ; c1ccc(-c2ccccc2-c2ccc3c(c2)B2c4cc(-c5ccccc5-c5ccccc5)ccc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1 ; c1ccc(-c2cncc(-c3ccccc3)c2N2c3ccc(-c4ccc5oc6ccccc6c5c4)cc3B3c4cc(-c5ccc6oc7ccccc7c6c5)ccc4N(c4c(-c5ccccc5)cncc4-c4ccccc4)c4cc(-n5c6ccccc6c6ccccc65)cc2c43)cc1] 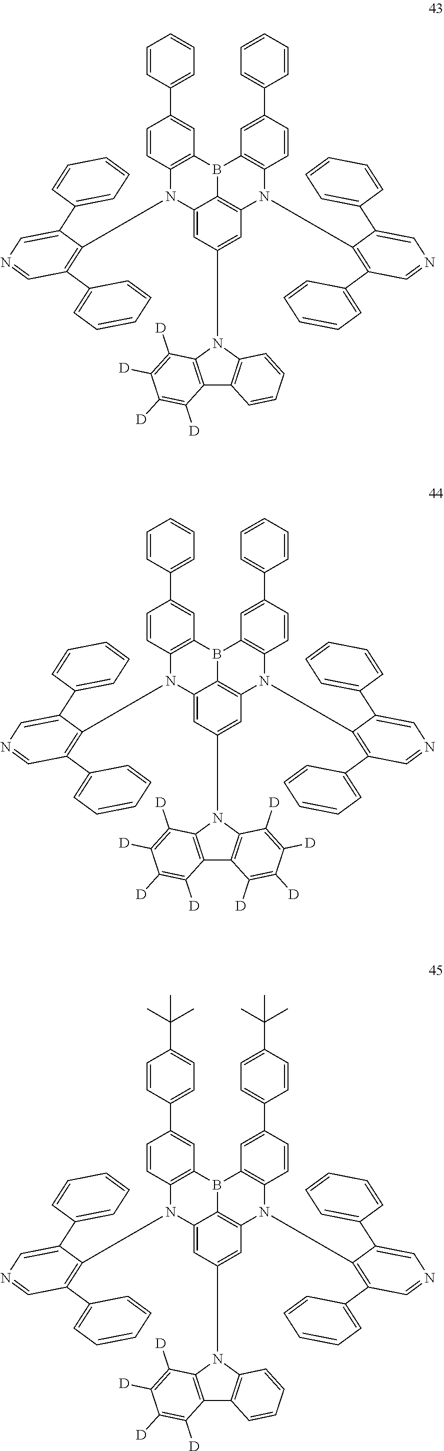 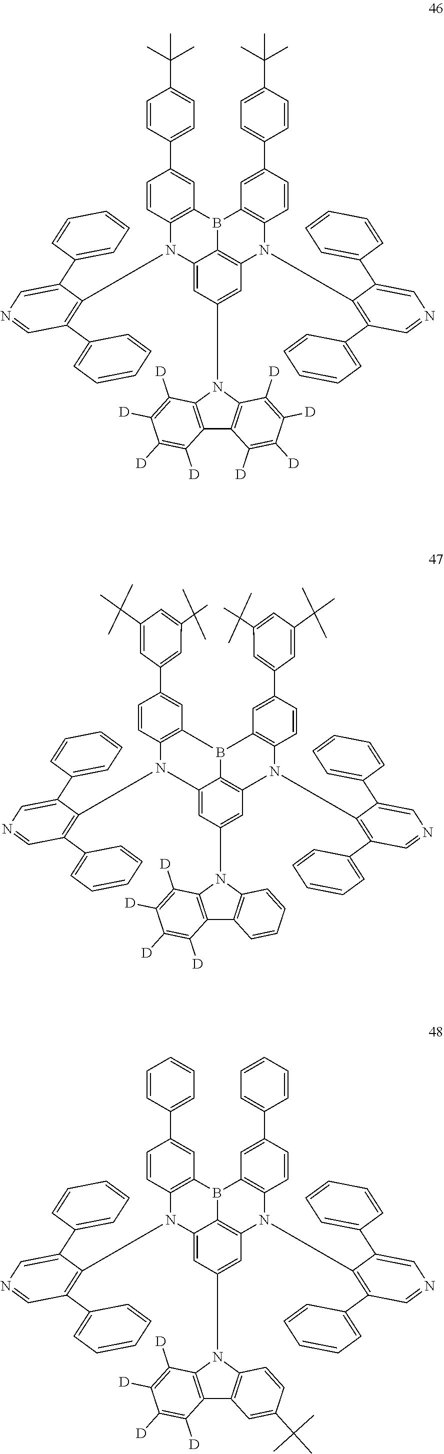 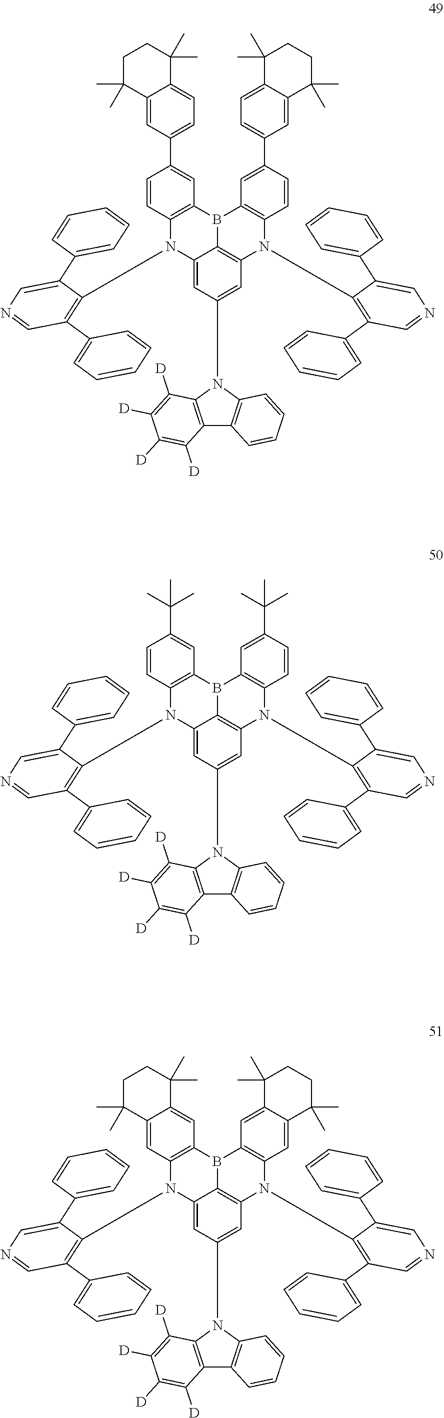 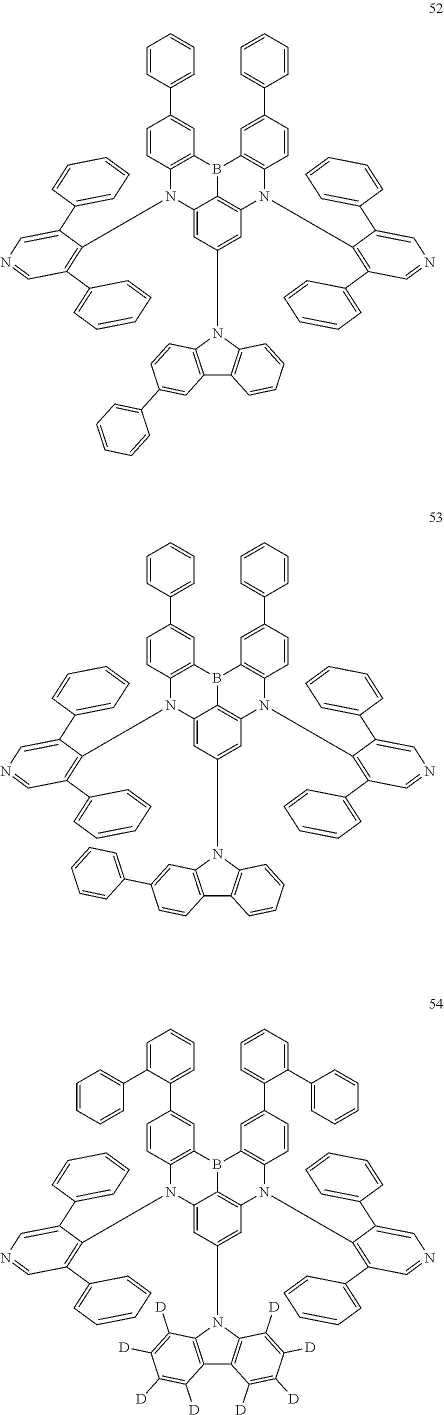 [SMILES: c1ccc(-c2ccc3c(c2)B2c4cc(-c5ccccc5)ccc4N(c4c(-c5ccccc5)cncc4-c4ccccc4)c4cc(-n5c6ccccc6c6cc(-c7ccccc7)ccc65)cc(c42)N3c2c(-c3ccccc3)cncc2-c2ccccc2)cc1 ; c1ccc(-c2ccc3c(c2)B2c4cc(-c5ccccc5)ccc4N(c4c(-c5ccccc5)cncc4-c4ccccc4)c4cc(-n5c6ccccc6c6ccc(-c7ccccc7)cc65)cc(c42)N3c2c(-c3ccccc3)cncc2-c2ccccc2)cc1 ; [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1ccc(-c4ccccc4-c4ccccc4)cc1B3c1cc(-c3ccccc3-c3ccccc3)ccc1N2c1c(-c2ccccc2)cncc1-c1ccccc1] 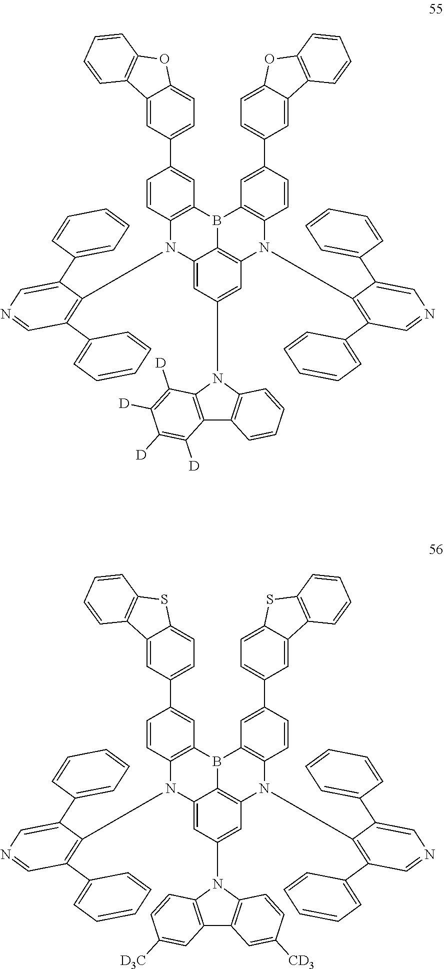 [SMILES: [2H]c1c([2H])c([2H])c2c(c1[2H])c1ccccc1n2-c1cc2c3c(c1)N(c1c(-c4ccccc4)cncc1-c1ccccc1)c1ccc(-c4ccc5oc6ccccc6c5c4)cc1B3c1cc(-c3ccc4oc5ccccc5c4c3)ccc1N2c1c(-c2ccccc2)cncc1-c1ccccc1 ; [2H]C([2H])([2H])c1ccc2c(c1)c1cc(C([2H])([2H])[2H])ccc1n2-c1cc2c3c(c1)N(c1c(-c4ccccc4)cncc1-c1ccccc1)c1ccc(-c4ccc5sc6ccccc6c5c4)cc1B3c1cc(-c3ccc4sc5ccccc5c4c3)ccc1N2c1c(-c2ccccc2)cncc1-c1ccccc1] 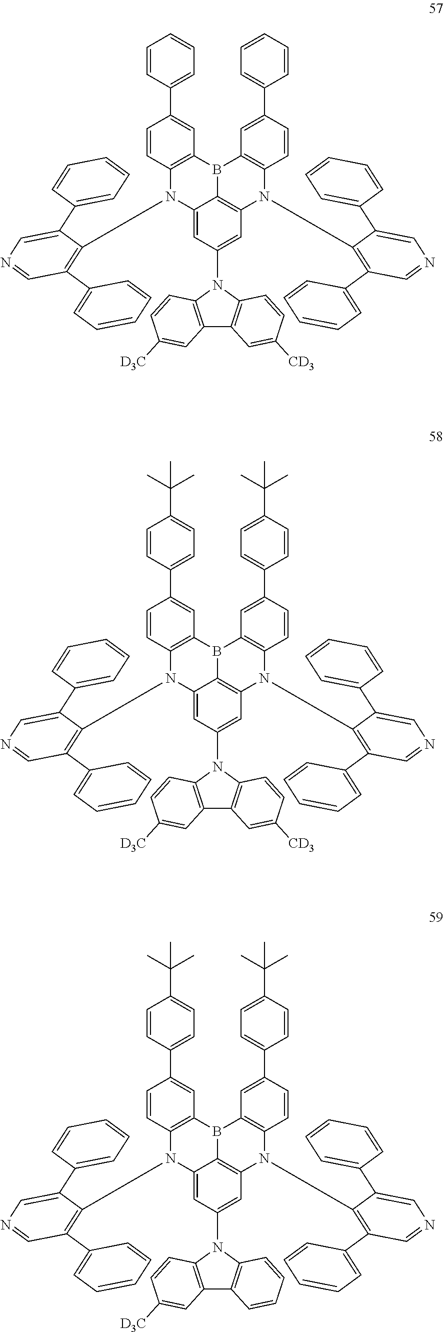 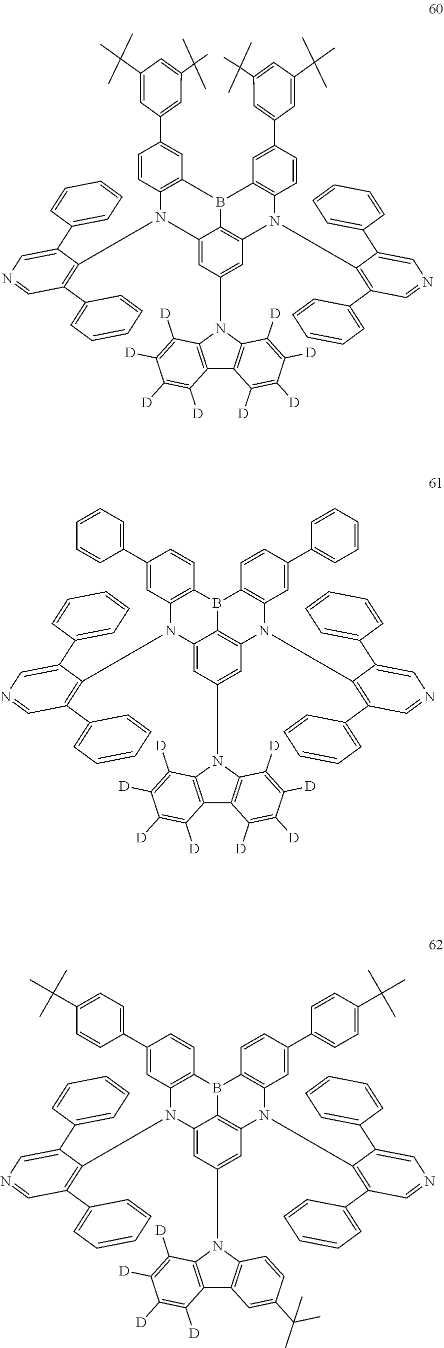 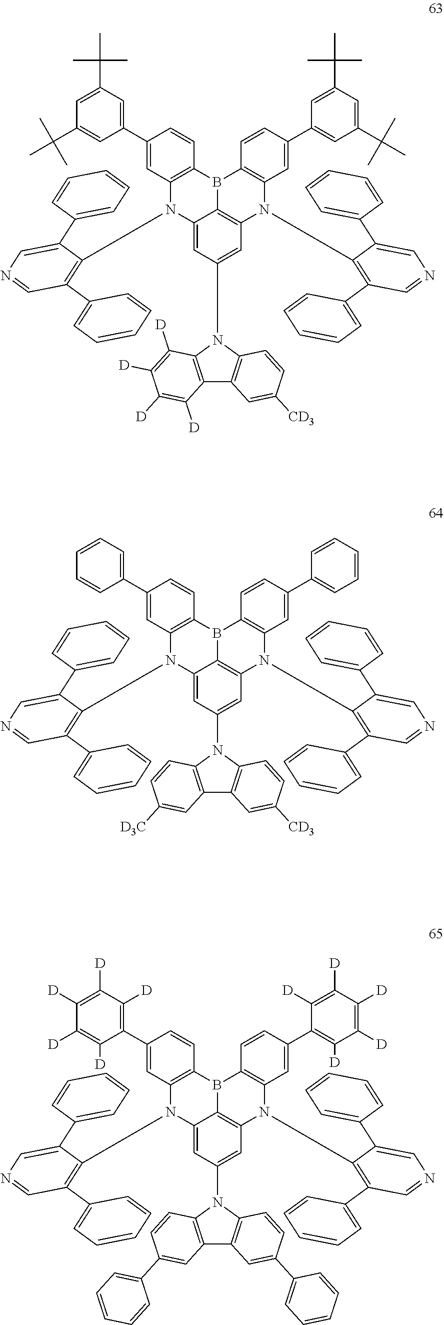 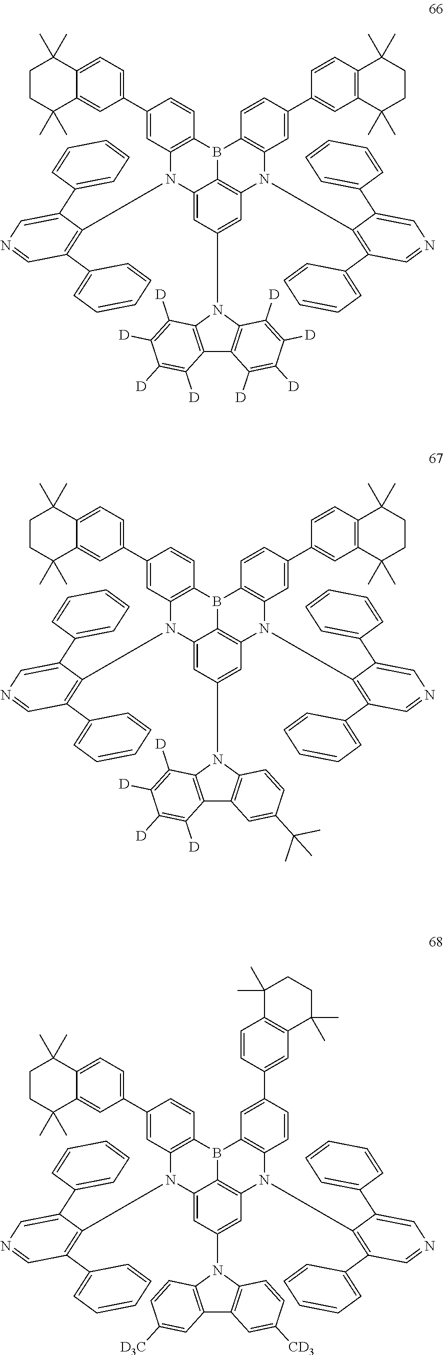 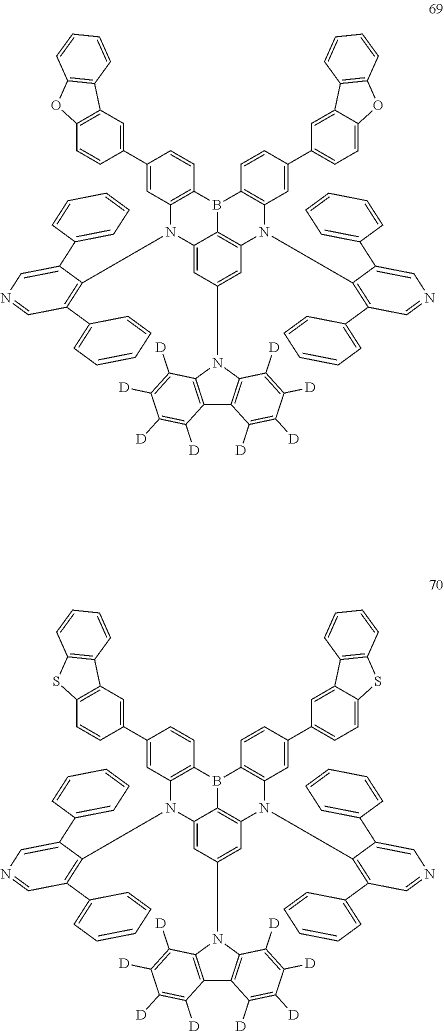 [SMILES: [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1cc(-c4ccc5oc6ccccc6c5c4)ccc1B3c1ccc(-c3ccc4oc5ccccc5c4c3)cc1N2c1c(-c2ccccc2)cncc1-c1ccccc1 ; [2H]c1c([2H])c([2H])c2c(c1[2H])c1c([2H])c([2H])c([2H])c([2H])c1n2-c1cc2c3c(c1)N(c1c(-c4ccccc4)cncc1-c1ccccc1)c1cc(-c4ccc5sc6ccccc6c5c4)ccc1B3c1ccc(-c3ccc4sc5ccccc5c4c3)cc1N2c1c(-c2ccccc2)cncc1-c1ccccc1] 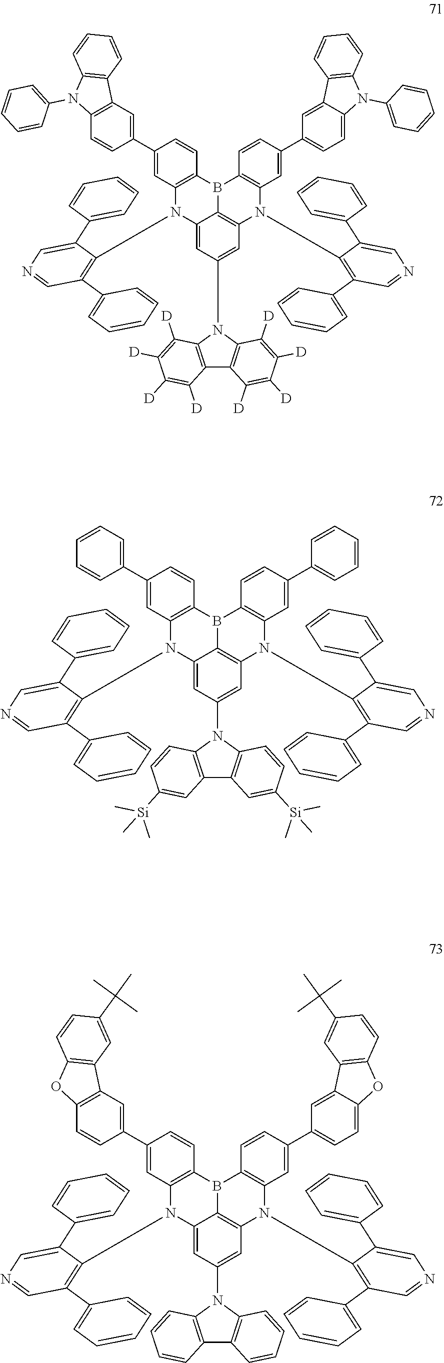 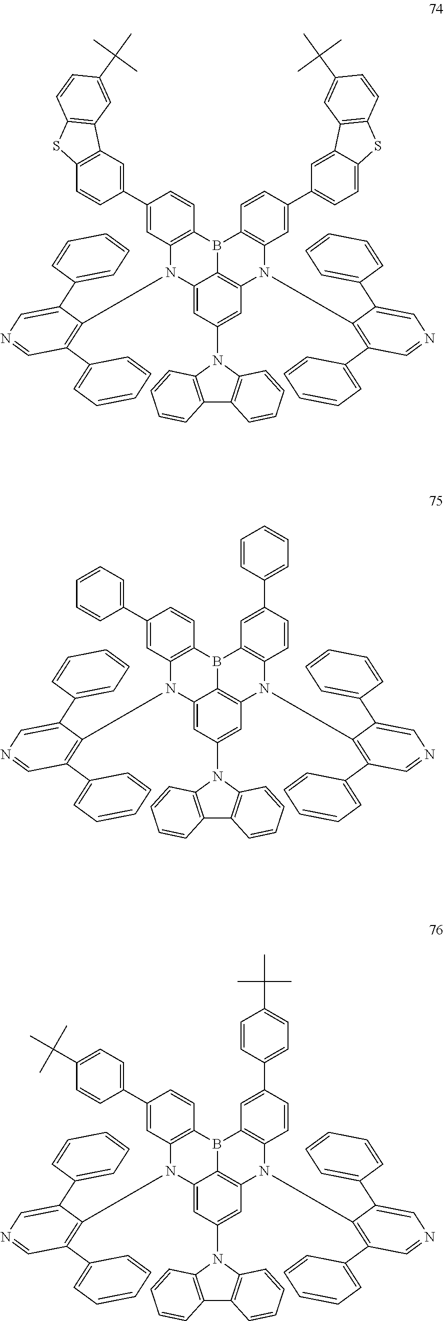 [SMILES: CC(C)(C)c1ccc2sc3ccc(-c4ccc5c(c4)N(c4c(-c6ccccc6)cncc4-c4ccccc4)c4cc(-n6c7ccccc7c7ccccc76)cc6c4B5c4ccc(-c5ccc7sc8ccc(C(C)(C)C)cc8c7c5)cc4N6c4c(-c5ccccc5)cncc4-c4ccccc4)cc3c2c1 ; c1ccc(-c2ccc3c(c2)B2c4ccc(-c5ccccc5)cc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1 ; CC(C)(C)c1ccc(-c2ccc3c(c2)B2c4ccc(-c5ccc(C(C)(C)C)cc5)cc4N(c4c(-c5ccccc5)cncc4-c4ccccc4)c4cc(-n5c6ccccc6c6ccccc65)cc(c42)N3c2c(-c3ccccc3)cncc2-c2ccccc2)cc1] 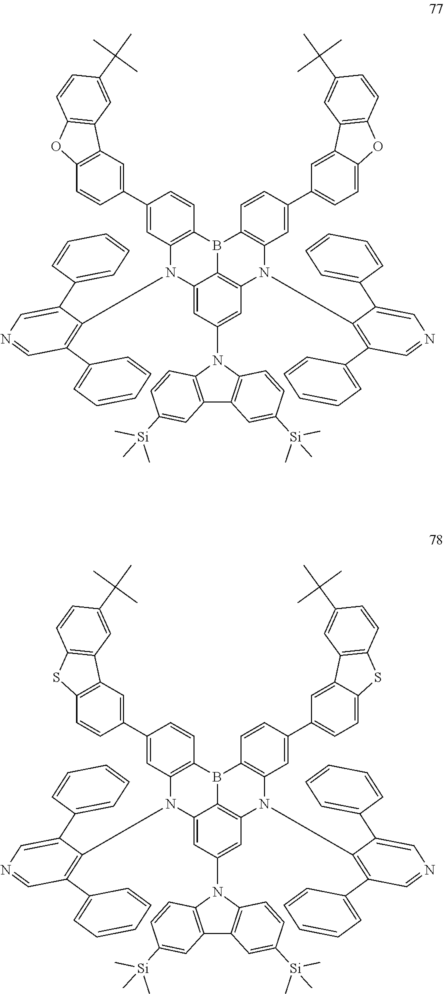 [SMILES: CC(C)(C)c1ccc2oc3ccc(-c4ccc5c(c4)N(c4c(-c6ccccc6)cncc4-c4ccccc4)c4cc(-n6c7ccc([Si](C)(C)C)cc7c7cc([Si](C)(C)C)ccc76)cc6c4B5c4ccc(-c5ccc7oc8ccc(C(C)(C)C)cc8c7c5)cc4N6c4c(-c5ccccc5)cncc4-c4ccccc4)cc3c2c1 ; CC(C)(C)c1ccc2sc3ccc(-c4ccc5c(c4)N(c4c(-c6ccccc6)cncc4-c4ccccc4)c4cc(-n6c7ccc([Si](C)(C)C)cc7c7cc([Si](C)(C)C)ccc76)cc6c4B5c4ccc(-c5ccc7sc8ccc(C(C)(C)C)cc8c7c5)cc4N6c4c(-c5ccccc5)cncc4-c4ccccc4)cc3c2c1] 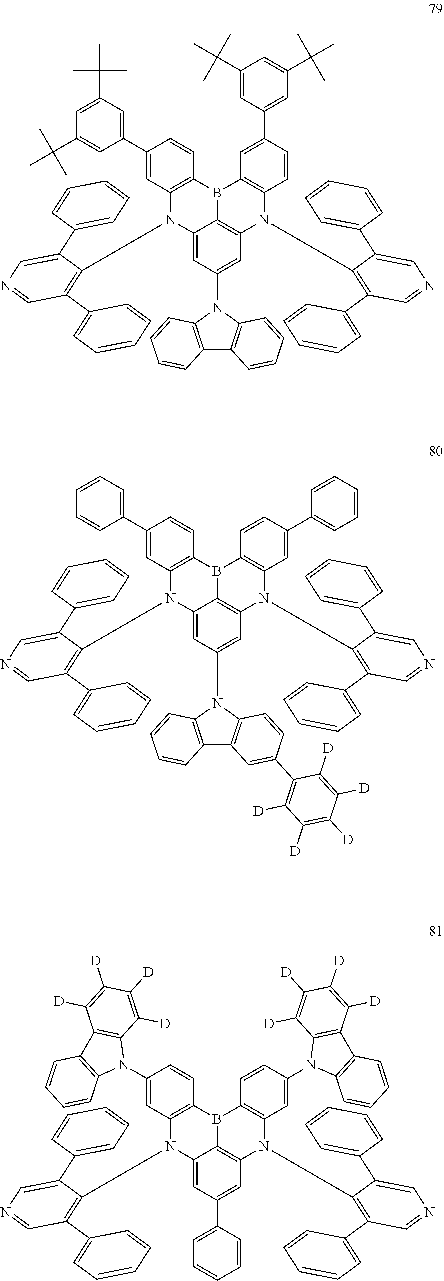 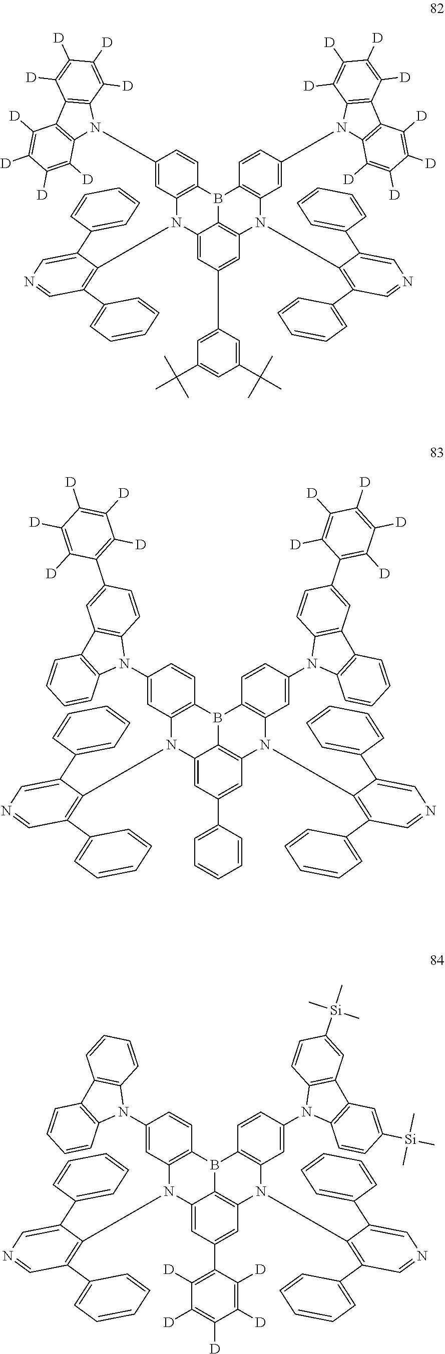 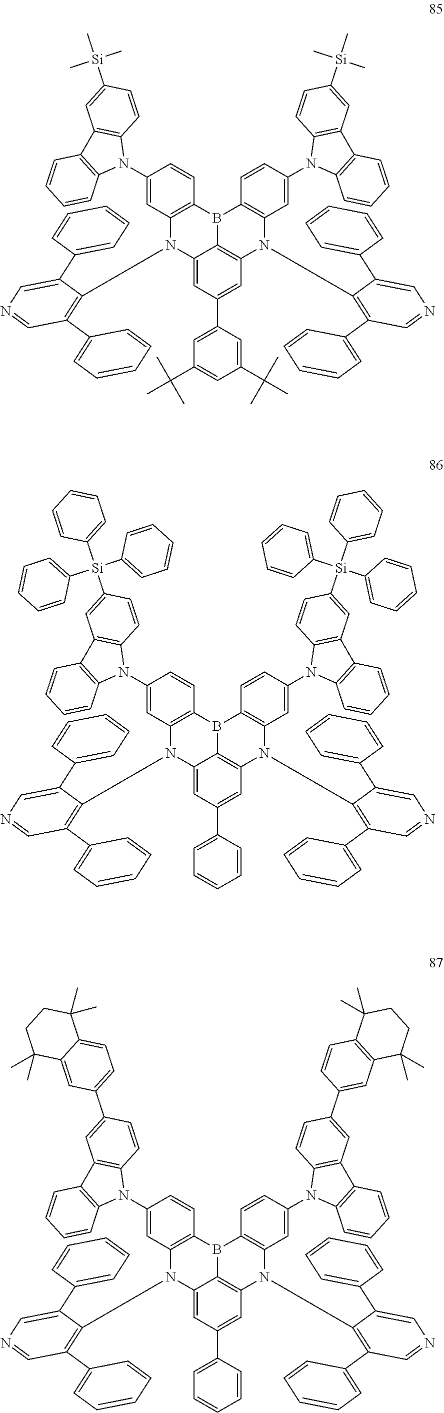 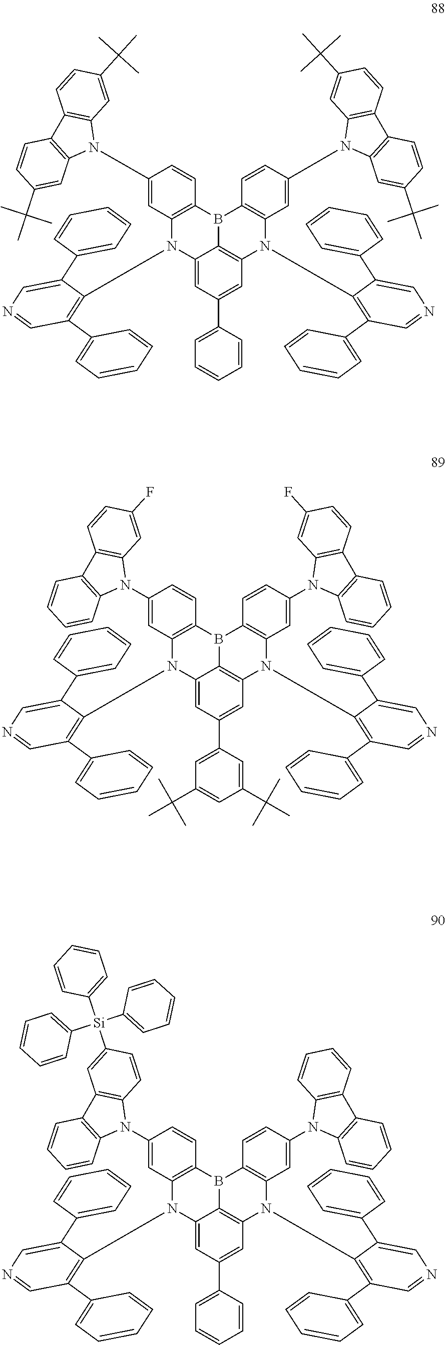 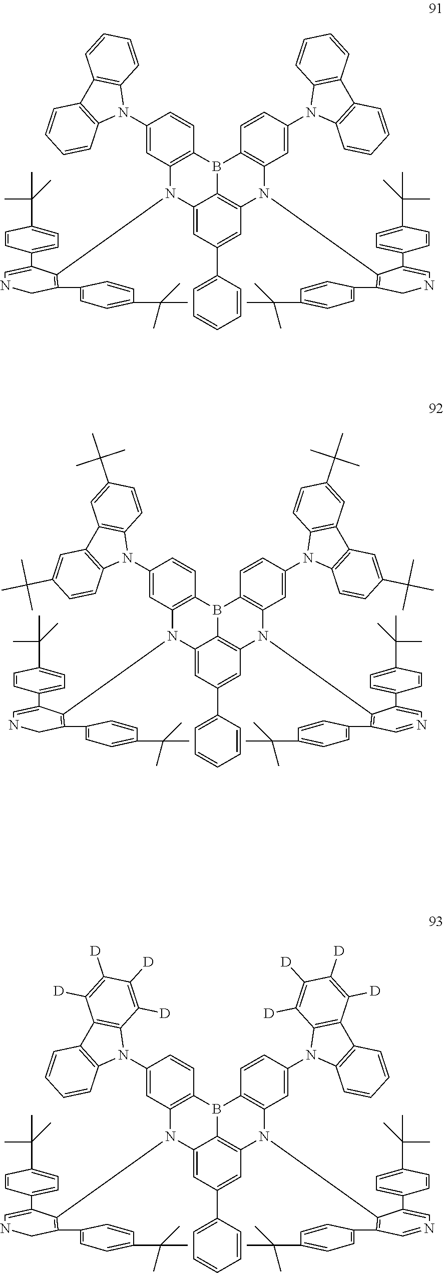 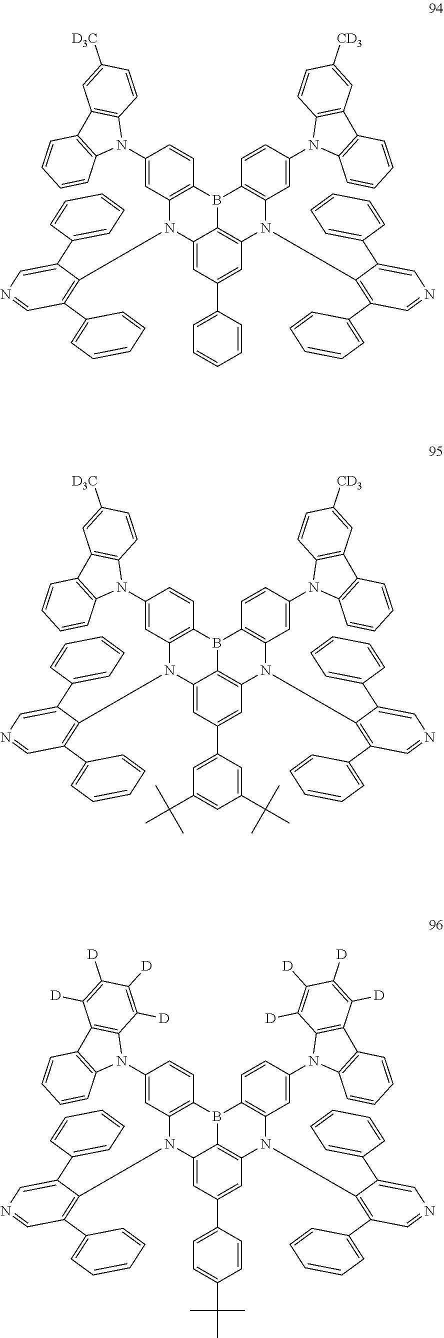 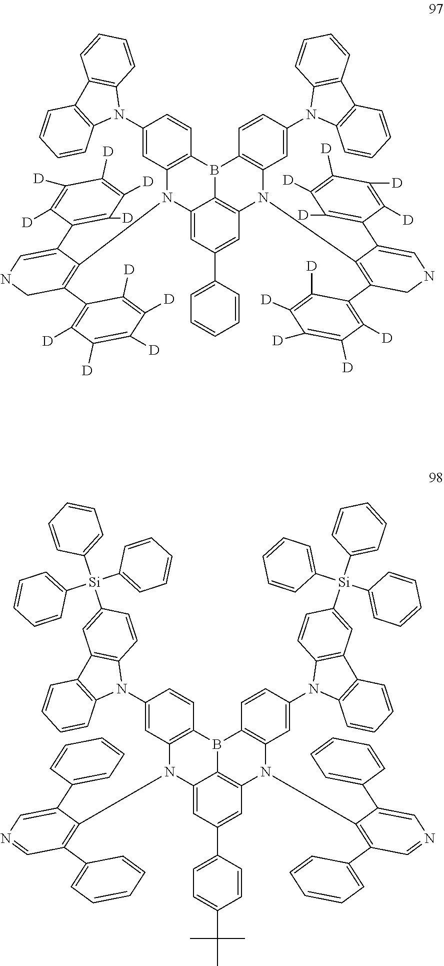 [SMILES: [2H]c1c([2H])c([2H])c(C2=CNCC(c3c([2H])c([2H])c([2H])c([2H])c3[2H])=C2N2c3cc(-n4c5ccccc5c5ccccc54)ccc3B3c4ccc(-n5c6ccccc6c6ccccc65)cc4N(C4=C(c5c([2H])c([2H])c([2H])c([2H])c5[2H])CNC=C4c4c([2H])c([2H])c([2H])c([2H])c4[2H])c4cc(-c5ccccc5)cc2c43)c([2H])c1[2H] ; CC(C)(C)c1ccc(-c2cc3c4c(c2)N(c2c(-c5ccccc5)cncc2-c2ccccc2)c2cc(-n5c6ccccc6c6cc([Si](c7ccccc7)(c7ccccc7)c7ccccc7)ccc65)ccc2B4c2ccc(-n4c5ccccc5c5cc([Si](c6ccccc6)(c6ccccc6)c6ccccc6)ccc54)cc2N3c2c(-c3ccccc3)cncc2-c2ccccc2)cc1] 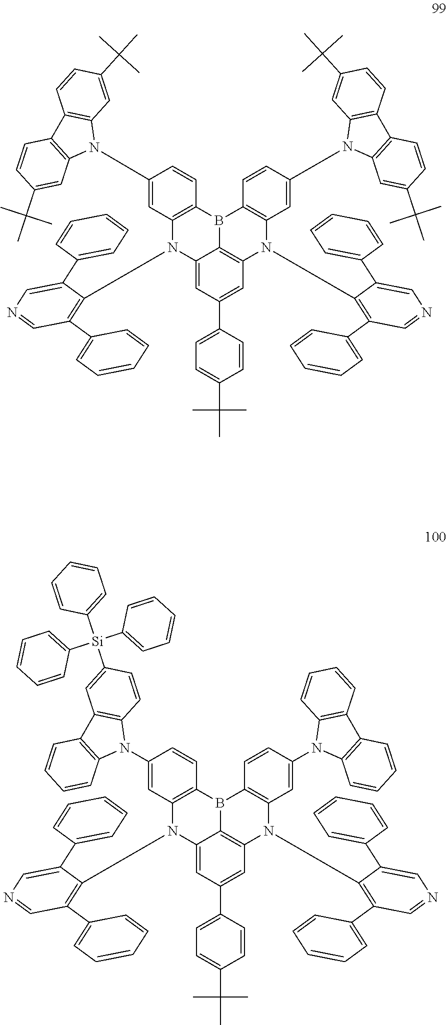 [SMILES: CC(C)(C)c1ccc(-c2cc3c4c(c2)N(c2c(-c5ccccc5)cncc2-c2ccccc2)c2cc(-n5c6cc(C(C)(C)C)ccc6c6ccc(C(C)(C)C)cc65)ccc2B4c2ccc(-n4c5cc(C(C)(C)C)ccc5c5ccc(C(C)(C)C)cc54)cc2N3c2c(-c3ccccc3)cncc2-c2ccccc2)cc1 ; CC(C)(C)c1ccc(-c2cc3c4c(c2)N(c2c(-c5ccccc5)cncc2-c2ccccc2)c2cc(-n5c6ccccc6c6cc([Si](c7ccccc7)(c7ccccc7)c7ccccc7)ccc65)ccc2B4c2ccc(-n4c5ccccc5c5ccccc54)cc2N3c2c(-c3ccccc3)cncc2-c2ccccc2)cc1] 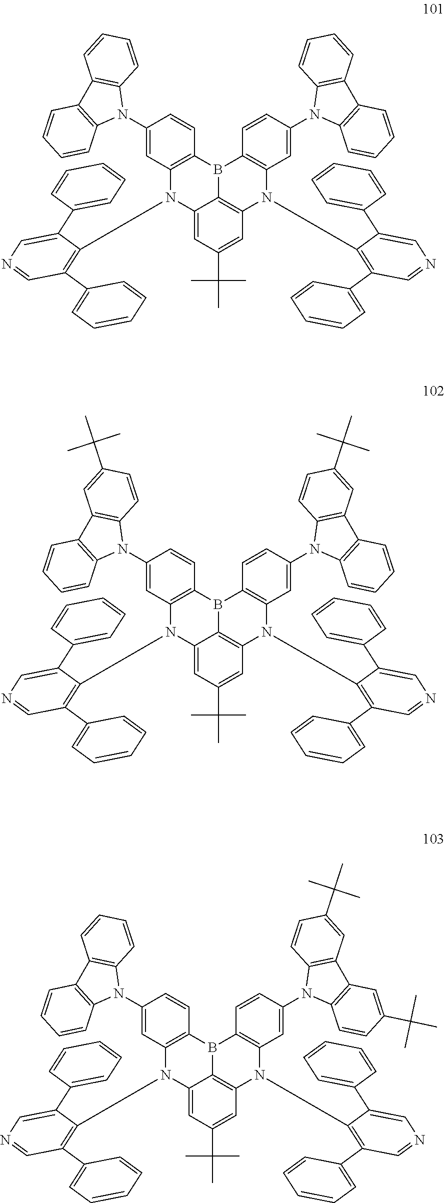 [SMILES: CC(C)(C)c1cc2c3c(c1)N(c1c(-c4ccccc4)cncc1-c1ccccc1)c1cc(-n4c5ccccc5c5ccccc54)ccc1B3c1ccc(-n3c4ccccc4c4ccccc43)cc1N2c1c(-c2ccccc2)cncc1-c1ccccc1 ; CC(C)(C)c1cc2c3c(c1)N(c1c(-c4ccccc4)cncc1-c1ccccc1)c1cc(-n4c5ccccc5c5cc(C(C)(C)C)ccc54)ccc1B3c1ccc(-n3c4ccccc4c4cc(C(C)(C)C)ccc43)cc1N2c1c(-c2ccccc2)cncc1-c1ccccc1 ; CC(C)(C)c1cc2c3c(c1)N(c1c(-c4ccccc4)cncc1-c1ccccc1)c1cc(-n4c5ccc(C(C)(C)C)cc5c5cc(C(C)(C)C)ccc54)ccc1B3c1ccc(-n3c4ccccc4c4ccccc43)cc1N2c1c(-c2ccccc2)cncc1-c1ccccc1] 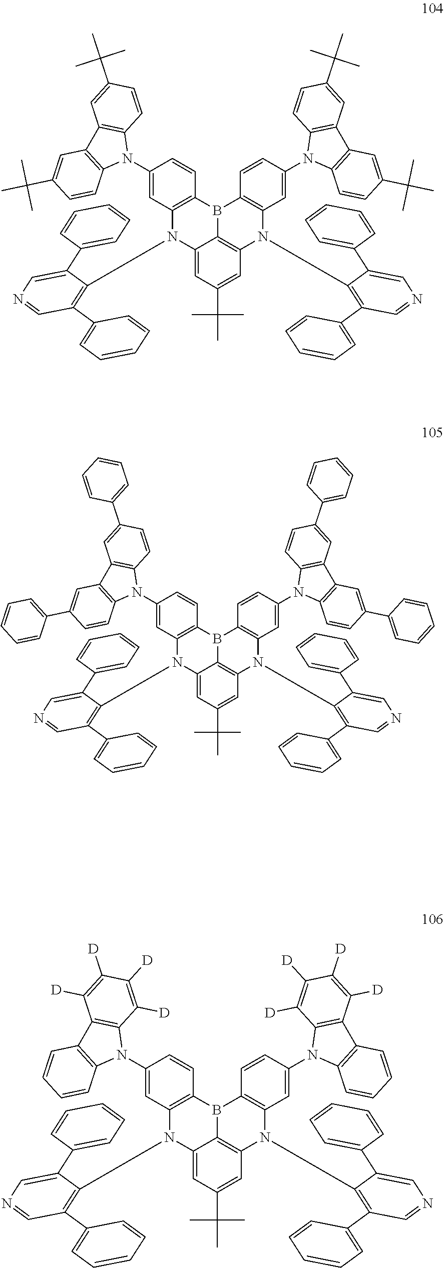 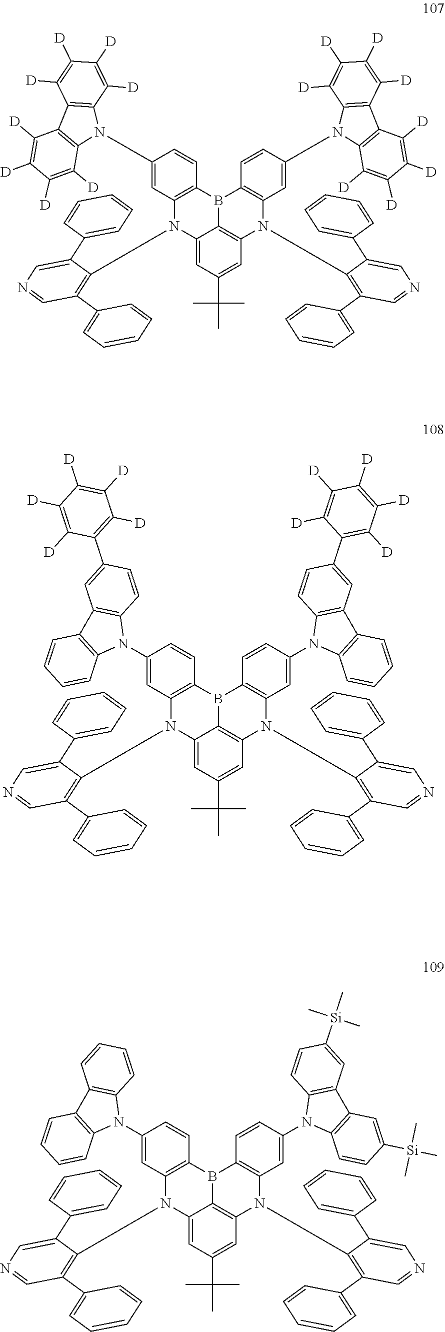 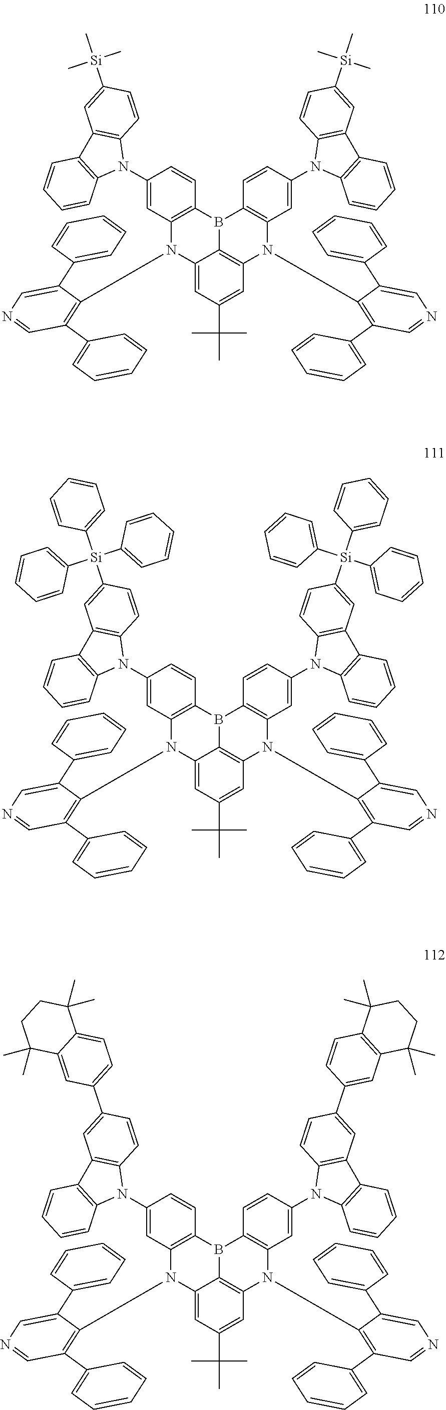 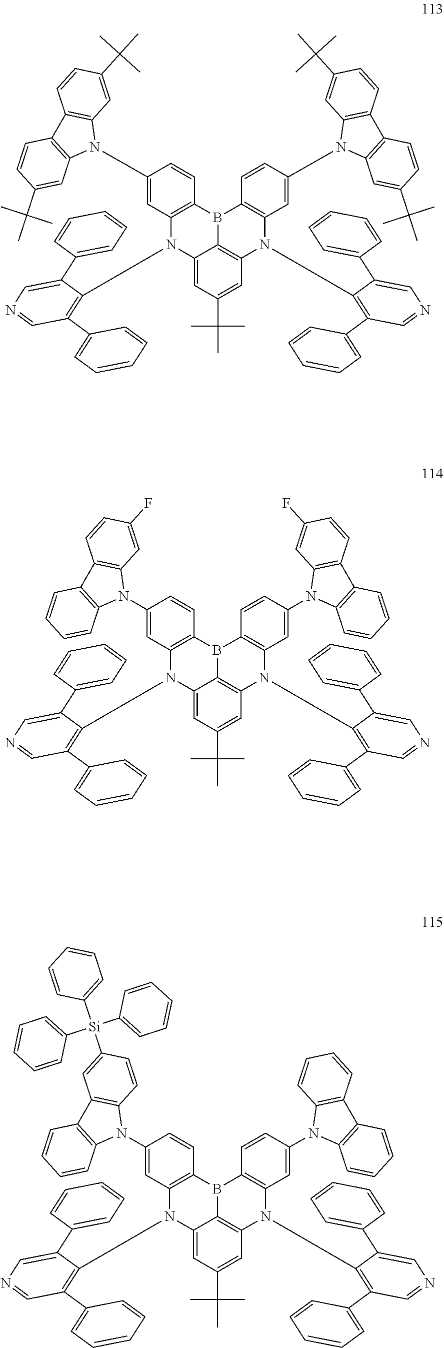 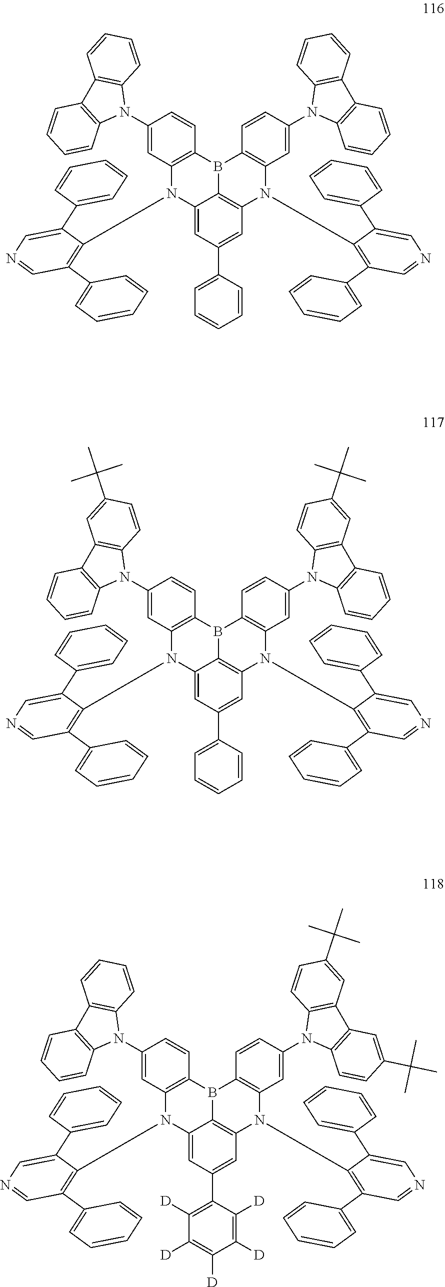 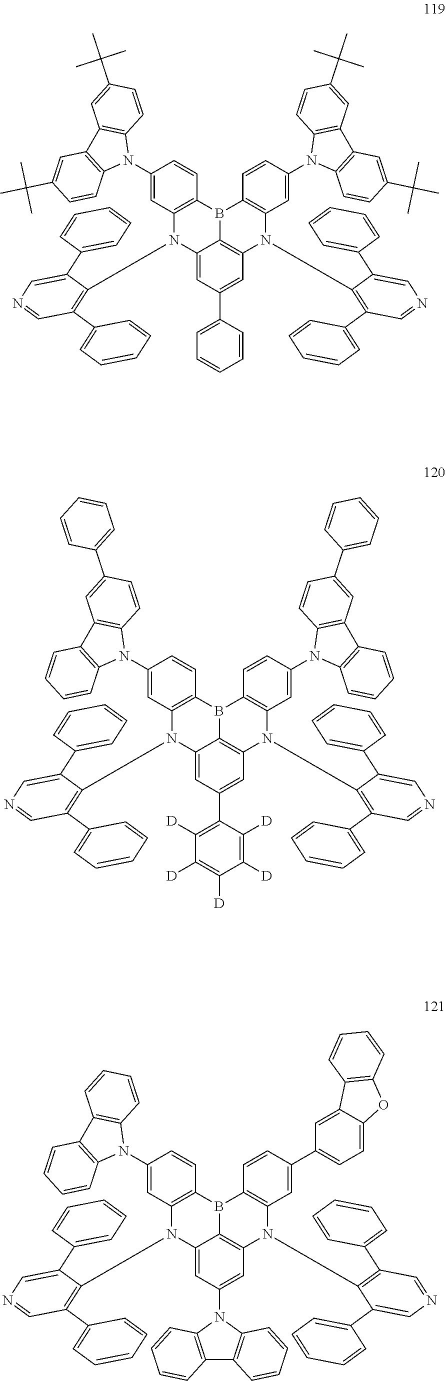 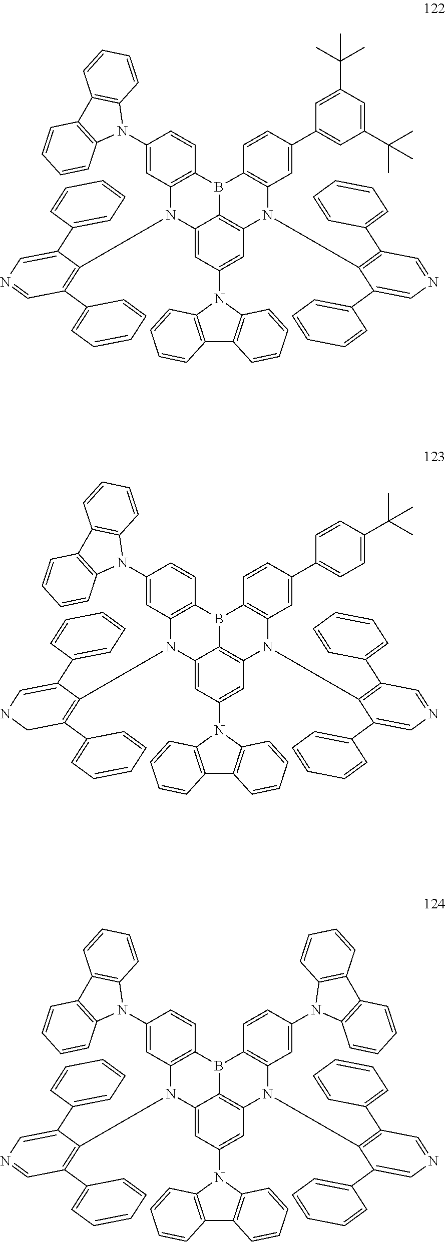 [SMILES: CC(C)(C)c1cc(-c2ccc3c(c2)N(c2c(-c4ccccc4)cncc2-c2ccccc2)c2cc(-n4c5ccccc5c5ccccc54)cc4c2B3c2ccc(-n3c5ccccc5c5ccccc53)cc2N4c2c(-c3ccccc3)cncc2-c2ccccc2)cc(C(C)(C)C)c1 ; CC(C)(C)c1ccc(-c2ccc3c(c2)N(c2c(-c4ccccc4)cncc2-c2ccccc2)c2cc(-n4c5ccccc5c5ccccc54)cc4c2B3c2ccc(-n3c5ccccc5c5ccccc53)cc2N4C2=C(c3ccccc3)CNC=C2c2ccccc2)cc1 ; c1ccc(-c2cncc(-c3ccccc3)c2N2c3cc(-n4c5ccccc5c5ccccc54)ccc3B3c4ccc(-n5c6ccccc6c6ccccc65)cc4N(c4c(-c5ccccc5)cncc4-c4ccccc4)c4cc(-n5c6ccccc6c6ccccc65)cc2c43)cc1] 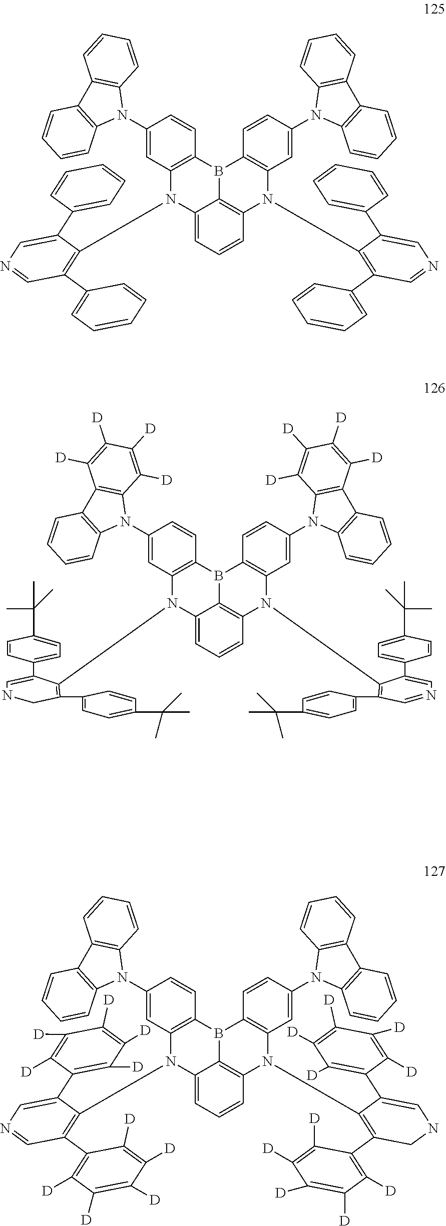 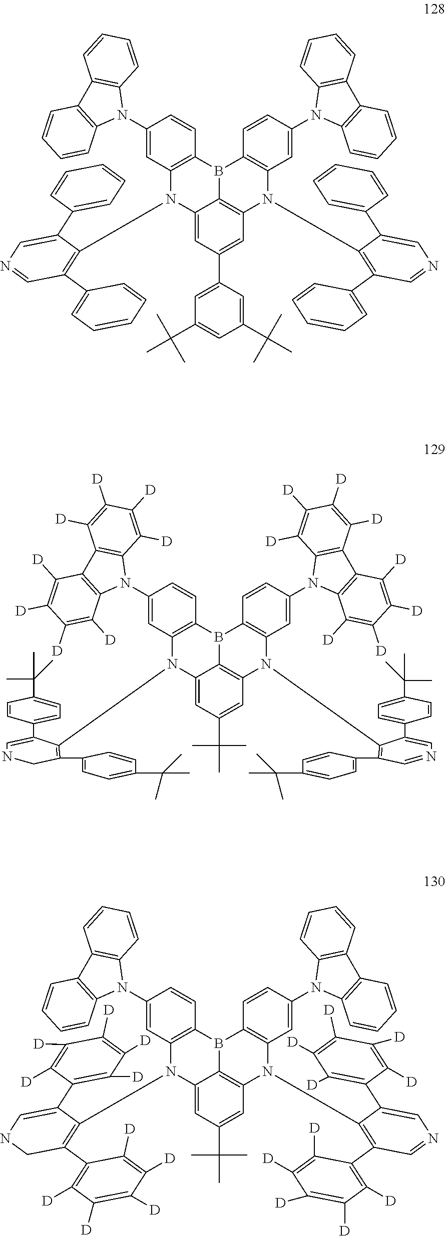 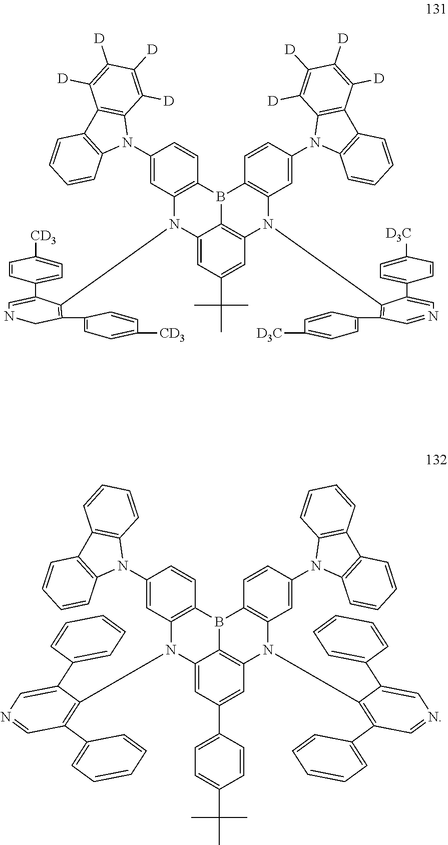 [SMILES: [2H]c1c([2H])c([2H])c2c(c1[2H])c1ccccc1n2-c1ccc2c(c1)N(C1=C(c3ccc(C([2H])([2H])[2H])cc3)CNC=C1c1ccc(C([2H])([2H])[2H])cc1)c1cc(C(C)(C)C)cc3c1B2c1ccc(-n2c4ccccc4c4c([2H])c([2H])c([2H])c([2H])c42)cc1N3c1c(-c2ccc(C([2H])([2H])[2H])cc2)cncc1-c1ccc(C([2H])([2H])[2H])cc1 ; CC(C)(C)c1ccc(-c2cc3c4c(c2)N(c2c(-c5ccccc5)cncc2-c2ccccc2)c2cc(-n5c6ccccc6c6ccccc65)ccc2B4c2ccc(-n4c5ccccc5c5ccccc54)cc2N3c2c(-c3ccccc3)cncc2-c2ccccc2)cc1]
